(19) United States
(12) Patent Application Publication
(10) Pub. No.: US 2024/0063340 A1
(43) Pub. Date: Feb. 22, 2024

(54) METHOD FOR RELAXING SEMICONDUCTOR FILMS INCLUDING THE FABRICATION OF PSEUDO-SUBSTRATES AND FORMATION OF COMPOSITES ALLOWING THE ADDITION OF PREVIOUSLY UN-ACCESSIBLE FUNCTIONALITY OF GROUP lll-NITRIDES

(71) Applicant: The Regents of the University of California, Oakland, CA (US)

(72) Inventors: Stacia Keller, Santa Barbara, CA (US); Umesh K. Mishra, Montecito, CA (US); Shubhra Pasayat, Goleta, CA (US); Chirag Gupta, Goleta, CA (US)

(73) Assignees: The Regents of the University of California, Oakland, CA (US); The Regents of the University of California, Oakland, CA (US)

(21) Appl. No.: 17/642,057

(22) PCT Filed: Sep. 10, 2020
(86) PCT No.: PCT/US20/50204

§ 371 Date: Mar. 10, 2022

Related U.S. Application Data
(60) Provisional application No. 62/962,113, filed on Jan. 16, 2020.
(60) Provisional application No. 62/927,486, filed on Oct. 29, 2019.
(60) Provisional application No. 62/898,178, filed on Sep. 10, 2019.

(51) Int. Cl. H01L 33/32; H01L 33/16; H01L 33/12; H01L 25/075; H01L 33/20

(52) U.S. Cl. CPC H01L 33/32; H01L 33/16; H01L 33/12; H01L 25/0753; H01L 33/20

(57) ABSTRACT

The present disclosure describes porous GaN layers and/or compliant substrates used to enable relaxation of previously strained top layers and the deposition of relaxed or partially relaxed on top. Relaxed In GaN layers are fabricated without generation of crystal defects, which can serve as base layers for high performance long wavelength light emitting devices (LEDs, lasers) solar cells, or strain engineered transistors. Similarly, relaxed AlGaN layers can serve as base layers for high performance short wavelength UV light emitting devices (LEDs, lasers) solar cells, or wide bandgap transistors.

### CROSS REFERENCE TO RELATED APPLICATIONS

This application claims the benefit under 35 U.S.C 119(e) of the following co-pending and commonly-assigned applications:
U.S. Provisional Patent Application No. 62/898,178, filed Sep. 10, 2019, by Stacia Keller, Umesh K. Mishra, Shubhra Pasayat, and Chirag Gupta, entitled “METHOD FOR RELAXING SEMICONDUCTOR FILMS INCLUDING THE FABRICATION OF PSEUDO-SUBSTRATES AND FORMATION OF COMPOSITES ALLOWING THE ADDITION OF PREVIOUSLY UN-ACCESSIBLE FUNCTIONALITY TO GROUP III-NITRIDES” Attorney's Docket No. 30794.702-US-P2 (2019-178-2);
U.S. Provisional Patent Application No. 62/962,113, filed Jan. 16, 2020, by Stacia Keller, Umesh K. Mishra, Shubhra Pasayat, and Chirag Gupta, entitled “ADVANCES IN THE USE OF POROUS MATERIALS FOR THE FABRICATION OF MATERIALS WITH ARBITRARY LATTICE CONSTANT” Attorney's Docket No. 30794.759-US-P1 (2019-178-2);
U.S. Provisional Patent Application No. 62/927,486, filed Oct. 29, 2019, by Stacia Keller, Umesh K. Mishra, Shubhra Pasayat, and Chirag Gupta, entitled “METHODS FOR ACHIEVING MONOLITHIC INTEGRATION OF COLOR TUNABLE LIGHT EMITTING DIODES (LEDS) WITHOUT ETCH DAMAGE OR WITH MINIMAL ETCH DAMAGE AND INCLUDING AN IMPROVED METHOD FOR RELAXING SEMICONDUCTOR FILMS FOR THE FABRICATION OF PSEUDO-SUBSTRATES” Attorney's Docket No. 30794.751-US-P1 (UC REF 2020-079-2);
all of which applications are incorporated by reference herein

### STATEMENT REGARDING FEDERAL FUNDING

This invention was made with Government support under Grant (or Contract) No. N00014-17-1-2106 and N00014-16-1-2933 awarded by the Office of Naval Research. The Government has certain rights in this invention.

### BACKGROUND OF THE INVENTION

### 1. Field of the Invention

The present disclosure relates to high quality pseudo-substrates and methods of making the same.

### 2. Description of the Related Art

(Note: This application references a number of different publications as indicated throughout the specification by one or more reference numbers as superscripts, e.g., ^{x}. A list of these different publications ordered according to these reference numbers can be found below in the section entitled “References.” Each of these publications is incorporated by reference herein.)

### SUMMARY OF THE INVENTION

The present disclosure describes the use of porous layers for the fabrication of devices such as, but not limited to, light emitting diodes, lasers, photodetectors, solar cells, and transistors. The present disclosure further describes how the porous layer can be used for device integration.

In one or more examples, porous GaN layers and/or compliant substrates are used to enable relaxation of previously strained top layers. In one example, relaxed InGaN layers are fabricated without generation of crystal defects, which can serve as base layers for high performance long wavelength light emitting devices (LEDs, lasers) solar cells, or strain engineered transistors, for example.

In one or more further examples, porous GaN is used to enable the fabrication of group-III nitride pseudosubstrates with arbitrary lattice constant, such as InGaN or AlGaN substrates, for example.

One or more further embodiments of the present invention allow the fabrication of light emitting diodes (LEDs) (especially micro-LEDs) with minimal etch damage or without etch damage. As LED size decreases, the perimeter to area ratio increases and thus the impact of the etch damage on the device performance becomes more pronounced. The etch damage results in an increased non-radiative recombination and therefore reduces efficiency of the device. As illustrated herein, by re-growing the LED structure on a patterned substrate, the LED can be fabricated in such a way that the need for a (p-n) mesa isolation can be avoided either completely or partially, thereby resulting in a LED with minimal etch damage and high efficiency. The use of a porous GaN based patterned substrate can result in color tunable monolithically integrated LED with minimal to no etch damage. Thereby an improved method for relaxing semiconductor films using porous GaN is described.

Example embodiments include, but are not limited to, the following.

1. A substrate or pseudo-substrate, comprising:
a first (e.g, semiconductor) layer on a layer comprising at least one of a porous layer or a compliant layer; and
second (e.g., semiconductor) layer on the first (e.g., semiconductor) layer so as to stretch or pull the underlying first (e.g, semiconductor) layer to conform the first (e.g., semiconductor) layer to the second semiconductor layer.

2. The substrate of example 1, wherein the layer is a porous layer.

3. The substrate of example 1, wherein at least one of the first layer or the layer comprise silicon, a III-Nitride, a group III-V material, a group II-VI material, a group I-III-VI material, a group IV semiconductor, an oxide material or a metal.

4. The substrate of any of the examples 1-3, wherein the second layer comprises a III-Nitride, a III-V material, a II-VI material, a I-III-VI material, or a group IV semiconductor, oxide or metal.

5. The substrate of any of the examples 1-4, wherein the stretching or pulling of the first semiconductor layer to conform the first semiconductor layer to the second semiconductor layer comprises straining the first semiconductor layer so that the first semiconductor layer has a lattice constant between a relaxed value for the lattice constant of the first semiconductor layer and a relaxed value for the lattice constant of the second semiconductor layer.

6. The substrate of any of the examples 1-5, wherein the first semiconductor layer is grown on or bonded to the porous semiconductor layer.

7. The substrate of any of the examples 1-7, further comprising a plurality of layers including the first semiconducting layer and the second semiconducting layer on top of the porous semiconducting layer, wherein the plurality of layers have a top continuous surface formed via coalescence of a layer or multiple layers in the plurality of layers which were segmented into an array of features.

8. The substrate of example 7, wherein the features comprise mesas or tiles having a square, triangular, circular, or rhombus shape.

9. The substrate of any of the examples 1-8, wherein the porous semiconductor layer is formed by electrochemical etching of a semiconductor comprising gallium nitride.

10. The substrate of any of the examples 1-9, wherein the porous layer comprises pores having a diameter in a range of 0.001-1000 micrometers.

11. The substrate of any of the examples 1-10, wherein the porous layer is comprised of nano-feature arrays.

12. The substrate of any of the example 1-11, wherein the porous semiconductor layer comprises etched pores.

13. The substrate of any of the examples 1-12, further comprising:
a growth substrate;
the layer comprising a porous semiconductor layer on or above the substrate; and
the first semiconductor layer comprising an at least partially relaxed semiconductor layer
having a lattice constant that is different than a lattice constant of the growth substrate such that the at least partially relaxed semiconductor layer would be coherently strained if grown directly on the growth substrate, or
such that the at least partially relaxed semiconductor layer would plastically relax under formation of crystal defects if grown directly on the growth substrate

14. The substrate of example 13, further including an intermediate semiconductor layer between the growth substrate and the porous semiconductor layer.

15. The substrate of example 14, with the substrate is removed so that a surface of the intermediate semiconductor layer, having an opposite polarity to an interface with the porous semiconductor layer, is exposed so as to flip a polarity of the device.

16. The substrate of any of the examples 1-15, wherein:
the layer comprising at least one of a porous layer or a compliant layer comprises etched patterns or openings;
the first semiconductor layer and/or the second semiconductor layer, or any further layer grown on top closes up a gap between the etched patterns or openings.

17. The substrate of any of the examples 13-16, wherein the porous layer comprises n-type gallium nitride and the at least partially relaxed layer comprises Indium, gallium, and nitrogen, or aluminum, gallium, and nitrogen.

18. The substrate of any of the examples 1-17, wherein:
the first semiconductor layer comprises a first at least partially relaxed InGaN layer,
the second semiconductor layer comprises a second at least partially relaxed InGaN layer having a higher indium composition and a larger thickness than the first at least partially relaxed InGaN layer.

19. The substrate of any of the examples 1-18, wherein the substrate comprises a compliant substrate for a device such that a lattice constant of the second semiconductor layer conforms to a lattice constant of the device bonded or grown on the second semiconductor layer.

20. The substrate of example 19, wherein the device comprises a III-Nitride layer bonded to the second semiconductor layer and the bond flips a polarity of the III-nitride layer.

21. The substrate of any of the examples 1-20, wherein:
the first semiconductor layer is compliant and changes its lattice constant to become strained upon deposition of additional layers on the first semiconductor layer.

22. The substrate of any of the examples 1-21, wherein at least one of the first semiconductor layer or second semiconductor layer are patterned with an array of openings on which a selective area regrowth of can be performed.

23. The substrate of any of the examples 1-22, wherein at least one of the first semiconductor layer or second semiconductor layer are composed of a multilayer or superlattice stack.

24. A substrate composed of or comprising a layer or multiple layers on top of a porous layer.

25. The substrate of any of the examples 1-24, wherein the second semiconductor layer comprises a selective area regrowth of a III-Nitride forming an array of light emitting devices having different dimensions and/or strain relaxation, so that each of the light emitting devices include an active region having a different indium content and emitting a different wavelength of electromagnetic radiation.

26. The substrate of any of the examples 1-25, wherein pores in the porous semiconductor layer are at least partially filled with gas, metal, phosphor, ferromagnetic material, magnetic material, semiconductor material, and/or other foreign material, or the porous layer is implanted with ions.

27. The substrate of any of the examples 1-26, wherein the porous layer is semi-insulating.

28. The substrate of example 27, wherein the porous layer is treated to render it semi-insulating prior to deposition of the first semiconducting layer.

29. The substrate of any of the examples 1-28, wherein the porous layer is treated to modify its physical properties.

30. A device, comprising:
a growth substrate;
a porous layer on or above the substrate;
an at least partially relaxed semiconductor layer on or above the porous layer; and
an optoelectronic or electronic device structure comprising the at least partially relaxed semiconductor layer or grown on the at least partially relaxed semiconductor layer, wherein:
the at least partially relaxed semiconductor layer has a lattice constant that is different than a lattice constant of the growth substrate such that the at least partially relaxed semiconductor layer would be coherently strained if grown directly on the growth substrate.

31. The device of example 30, wherein the porous layer comprises etched pores.

32. The device of example 30, wherein the growth substrate comprises gallium nitride, aluminum nitride, silicon, silicon carbide, or gallium arsenide.

33. The device of any of the examples 30-33, wherein the porous layer comprises silicon, silicon carbide or gallium arsenide, CdTe or any other group III-V semiconductor, group II-VI semiconductor, group I-III-VI semiconductor, or group IV semiconductor, an oxide material or a metal.

34. The device of example 33, wherein the at least partially relaxed semiconductor comprises InP, any composition of AlGaInP, CdZnTe or CdTe or any other group III-V semiconductor, group II-VI semiconductor, group I-II-VI semiconductor, or group IV semiconductor, and oxide, or a metal.

35. The device of any of the examples 30-34, wherein the porous layer comprises n-type gallium nitride and the at least partially relaxed layer comprises Indium and Gallium.

36. The device of any of the examples 30-34, wherein:
the at least partially relaxed semiconductor layer comprises an n-type InGaN layer,
the optoelectronic device structure comprises a strained light absorbing or light emitting InGaN active region between the n-type InGaN layer and a p-type InGaN layer.
the p-type InGaN layer is at least partially relaxed, and
the active region has a higher indium composition than the n-type InGaN layer and the p-type InGaN layer.

37. The device of any of the examples 30-35, wherein the electronic device structure comprises a transistor including:
a channel layer including indium and gallium, wherein the channel layer is relaxed or partially relaxed;
a gating layer adjacent the channel layer and comprising aluminum and gallium, wherein the gating layer is strained;
a source contact, a drain contact, and a gate contact to the channel layer; and wherein
the gating layer is between the at least partially relaxed III-nitride layer comprising InGaN and the channel layer.

38. The device of any of the examples 30-37, wherein the optoelectronic or electronic device structure is bonded to a compliant substrate.

39. The device of example 38, wherein the bonding to the compliant substrate flips a polarity of the III-nitride layer in the device structure adjacent the bond to the compliant substrate.

40. The device of any of the examples 30-39, wherein pores in the porous layer are at least partially filled with gas, metal, phosphor, ferromagnetic material, semiconductor material, and/or other foreign material, or the porous layer is implanted with ions.

41. The device of any of the examples 30-40, further including an intermediate semiconductor layer between the growth substrate and the porous layer.

42. The device of example 41, wherein a surface of the intermediate semiconductor layer, having an opposite polarity to an interface with the porous layer, is exposed by removal of the growth substrate so as to flip a polarity of the device.

43. The device of any of the examples 3042, further comprising an at least partially relaxed InGaN layer on or above the at least partially relaxed semiconductor layer comprising InGaN, the at least partially relaxed InGaN layer on top having a higher indium composition and a larger thickness than the at least partially relaxed semiconductor layer comprising InGaN below.

44. A device, comprising:
a compliant substrate;
an at least partially relaxed semiconductor layer bonded to the compliant substrate, wherein the at least partially relaxed semiconductor layer is bonded directly or indirectly to the compliant substrate; and
an optoelectronic or electronic device structure comprising the at least partially relaxed semiconductor layer or grown on the at least partially relaxed semiconductor layer, wherein:
the at least partially relaxed semiconductor layer has a lattice constant that is different than a lattice constant of a growth substrate on which the at least partially relaxed semiconductor layer was grown, such that the at least partially relaxed semiconductor layer on the growth substrate was coherently strained prior to bonding to the compliant substrate and prior to removal or partial removal of the growth substrate.

45. The device of example 44, further comprising an epitaxial structure including the at least partially relaxed semiconductor layer, wherein the epitaxial structure is bonded to the compliant substrate.

46. The device of example 44, wherein a surface of the epitaxial structure exposed by removal of the growth substrate has an opposite polarity to an interface with the at least partially relaxed semiconductor layer, so as to flip a polarity of the device.

47. The device of example 44, wherein the compliant substrate comprises a semiconductor layer on a porous semiconductor layer.

48. The device of example 47, wherein the semiconductor layer and the porous semiconductor layer comprise silicon, gallium arsenide, or III-Nitride, CdTe or any other III-V, II-VI or I-III-VI, or group IV semiconductor, oxide material or metal.

49. The device of any of the examples 44-48, wherein the at least partially relaxed semiconductor layer comprises III-Nitride, InP, any composition of AlGaInP, CdZnTc or CdTe or any other III-V, II-VI or I-III-VI, or group IV semiconductor, oxide material or metal.

50. A device, comprising:
a growth substrate;
a porous III-nitride layer on or above the growth substrate; and a layer on or above the porous III-nitride layer, wherein:
the layer is compliant and changes its lattice constant upon deposition of additional layers on the layer; and
the layer on or above the porous III-nitride layer is composed of the same material as the growth substrate and becomes a strained layer upon deposition of the additional layers and is part of an active region of the device.

51. A device, comprising:
a growth substrate;
a porous III-nitride layer on or above the growth substrate;
a layer, which is composed of the same material as the growth substrate, on or above the porous III-nitride layer, wherein the layer is compliant and changes its lattice constant becoming a strained layer upon deposition of additional layers; and
an optoelectronic or electronic device structure wherein the compliant layer which changed its lattice constant upon deposition of further layers is part of the active region of an electronic or optoelectronic device and wherein:
the additional or further layers include an at least partially strained III-nitride layer on top of the porous III-nitride layer and on top of the strained layer, and
the at least partially relaxed III-nitride layer has a lattice constant that is different than a lattice constant of the growth substrate such that the at least partially relaxed III-nitride layer would be coherently strained if grown directly on the growth substrate.

52. A device on a porous layer or fabricated utilizing a porous layer, wherein the sidewalls of the device are defined using a low power etch in order to mitigate etch related damage to the device.

53. The device of any of the examples 30-53, wherein the optoelectronic or electronic device comprises a laser, IR emitter, detector, transistor, filter, or integrated circuit.

54. A device, comprising:
a selective area growth above a porous layer forming an array of light emitting devices 2404 having different dimensions, wherein the different dimensions comprise an area of 15 microns by 15 microns or less so that each of the light emitting devices comprise micro LEDs having a lateral area of 15 microns by 15 microns or less.

55. A method of making a device, comprising:
providing a growth substrate;
providing a porous III-nitride layer on or above the growth substrate; and
providing a layer on or above the porous III-nitride layer, wherein:
the layer is compliant and changes its lattice constant upon deposition of additional layers on the layer; and
the layer on or above the porous III-nitride layer is composed of the same material as the substrate and becomes a strained layer upon deposition of the additional layers and is part of the active region of the device

56. A method of making a device, comprising:
depositing one or more device structures on or above a compliant substrate, wherein a first lattice constant of the compliant substrate conforms to a second lattice constant of a first layer of the device structure.

57. The method of example 56, wherein the compliant substrate comprises a first semiconductor layer on a porous layer and the first semiconductor layer has the first lattice constant conforming to the second lattice constant of the device structure?

58. The method of example 57, further comprising:
depositing a layer on a substrate:
growing the first semiconductor layer on the layer, wherein the first semiconducting layer is coherently strained;
forming pores in the layer so as to form the porous layer, such that the first semiconductor layer becomes relaxed or at least partially relaxed; and depositing the device structure on the first semiconductor layer.

59. The method of example 57, further comprising:
etching an array or pattern of openings or features in at least one of the first semiconductor layer or the porous layer; and
depositing the device structure on the array of openings or features.

60. A device on a porous layer or fabricated utilizing a porous layer, wherein the sidewalls of the device are defined using a low power etch in order to mitigate etch related damage to the device

61. The method or device of any preceding examples, wherein the optoelectronic or electronic device comprises a laser, IR emitter, detector, transistor, filter, or integrated circuit.

62. The method of example 59, further comprising:
depositing a second semiconductor layer on or above the first semiconductor layer, wherein the depositing of the second semiconductor layer coalesces the openings or features to form a continuous top surface; and
depositing the device structure on the continuous top surface.

63. The method of example 62, further comprising:
depositing a second semiconductor layer on or above the first semiconductor layer, wherein gaps between the features close and the features merge to form a merged layer having the continuous top surface upon relaxation or partial relaxation of the second semiconductor layer or layers above the porous layer; and
depositing the device structure on continuous top surface of the merged layer.

64. The method of example 63, wherein layers of the device structure grown on top of the merged etched features are strained to the lattice constant to the merged layer.

65. The method of example 56, comprising:
growing a semiconductor layer on or above a growth substrate, wherein the semiconductor layer is coherently strained;
bonding the semiconductor layer directly or indirectly to the compliant substrate;
removing the growth substrate or at least partially removing the growth substrate from the semiconductor layer, so that the semiconductor layer becomes relaxed or at least partially relaxed; and
depositing the device structure on the semiconductor layer.

66. The method of example 65, further comprising performing a heat treatment to aid relaxation of the semiconductor layer.

67. The method of example 65, further comprising growing a p-type GaN layer so that the p-type GaN layer is between the semiconductor layer, comprising a III-nitride layer, and the growth substrate, wherein removing or at least partially removing the growth substrate exposes a surface of the p-type layer having an opposite polarity to an interface of the p-type layer with the III-nitride layer, thereby flipping a polarity of the device structure.

68. The method of example 56, comprising:
obtaining the compliant substrate having an array of openings or forming the array of openings in the compliant substrate;
performing a growth in each of the openings, forming an array of light emitting devices comprising one of the light emitting devices in each of the openings, so that each of the light emitting devices are isolated from each other and include an active region having a different indium content and emitting a different wavelength of electromagnetic radiation.

69. The method of example 68, wherein the compliant substrate comprises a first semiconductor layer on a porous layer and the array of openings are etched into at least one of the first semiconductor layer or the porous layer.

70. The method of example 68, wherein the growth over the openings comprises a selective area regrowth.

71. The method of example 70, further comprising etching a mesa in the selective area regrowth and part of the layer or substrate outside the selective area regrowth.

72. The method of examples 71, wherein the etched mesas each have different dimensions and/or strain relaxation.

73. The device or method of any of the examples 68-72, wherein:
the indium content in each of the active regions is tailored by at least one of a size of the openings, a size of a gap between the openings, a shape of the openings, and a fill factor of the patterned layer, patterned mask, or patterned substrate comprising the openings.

74. The device of any of the examples, wherein the different dimensions comprise an area of 15 microns by 15 microns or less so that each of the light emitting devices comprise micro LEDs having a lateral area of 15 microns by 15 microns or less.

75. The method of example 74, wherein the size of the openings and the fill factor are determined by a ratio between the area of the openings and an area of a mask on the device or between the area of the openings and an area of the gaps between the openings.

76. The method of any of the examples 68-75, wherein the indium content is increased in areas wherein non-c-plane facets are formed during the selective area regrowth.

77. The method of any of the examples 68-75, wherein the porous layer comprises porous material including different porosity or pore density as a function of position in a lateral direction so that each of the light emitting devices are grown above a portion of the porous layer having a different porosity.

78. The method of any of the examples 68-75, wherein each of the openings have different dimensions such that each of the light emitting devices comprise III-nitride experiencing different degrees of strain relaxation and the different indium content associated with the different degrees of strain relaxation.

79. The method of example 78, wherein the different dimensions comprise an area of 15 microns by 15 microns or less so that each of the light emitting devices comprise micro LEDs having a lateral area of 15 microns by 15 microns or less.

80. The method of any of the examples, wherein the porous layer comprises porous gallium nitride and the light emitting devices comprise III-nitride.

81. The method of any of the examples with a compliant substrate, wherein the compliant substrate is compliant (or lattice matched) with the material in each of the different light emitting devices.

82. The method of any of the examples 68-81, wherein:
the light emitting devices include a polygonal cross-section having n-sides as viewed from the top, and
at least one of the sides is not etched and is etch damage free.

83. A method of making a pseudo-substrate or device, comprising:
growing a first III-nitride layer on or above a substrate;
etching pores in a top surface of the first III-nitride layer so as to form a porous layer having open pores;
growing a second III-nitride layer on or above the top surface so as to coalesce and close the pores; and
patterning openings into the porous layer and the second III-nitride layer on the porous layer or into the porous layer, the second III-nitride layer on the porous layer and a region of the first III-nitride layer below the porous layer;
so that the second III-nitride layer becomes relaxed or at least partially relaxed and the second III-nitride layer is conformal and can change its lattice constant upon growth of further III-nitride layers on top.

### BRIEF DESCRIPTION OF THE DRAWINGS

Referring now to the drawings in which like reference numbers represent corresponding parts throughout:

FIG. 1. (a) GaN microdisk array prepared by selective lateral undercut etching. (b) Light emission spectrum from an optically-pumped GaN disk after threshold. The inset shows the emission intensity versus excitation power. (c) SEM and (d) optical microscope image of the GaN microdisk with a nanoporous layer. SEM images of (e) GaN/air, and (f) GaN/porous—
GaN DBRs. From reference 5.

FIG. 2a. Method of fabricating relaxed or partially relaxed III-nitride layers according to one or more embodiments.

FIG. 2b. Method fabricating a device including relaxed or partially relaxed layers.

FIG. 3. Method of fabricating relaxed or partially relaxed layers including etching the porous layer.

FIG. 4. Method of fabricating relaxed or partially relaxed III-nitride layers according to one or more embodiments including bonding to a bonding substrate.

FIG. 5. Method of fabricating relaxed or partially relaxed III-nitride layers according to one or more embodiments including bonding to a bonding substrate and etching/heat treatment.

FIG. 6. Method of fabricating multiple devices including relaxed or partially relaxed III-nitride layers according to one or more embodiments including bonding to a bonding substrate.

FIG. 7. Method of fabricating relaxed or partially relaxed III-nitride layers according to one or more embodiments including bonding to a bonding substrate and an etch for further relaxation.

FIG. 8. Method of fabricating relaxed or partially relaxed III-nitride layers according to one or more embodiments including porous layer to activate p-GaN.

FIG. 9. Method of activating p-GaN and/or flipping polarity, according to one or more examples.

FIG. 10a. Schematic of substrate according to methods described herein with layer L3 having thickness and lattice constant a3.

FIG. 10b. Method of performing further growth, according to various examples, showing an additional layer L4 having thickness and lattice constant L4.

FIG. 11a. Schematic of substrate according to methods described herein, showing a layer L3 having thickness and lattice constant a3 and one or more layers or structure D5 (e.g., device structure) having thickness and lattice constant a5.

FIG. 11b. Method of performing further growth, according to various examples, showing a layer L3 having thickness and lattice constant a3, a layer L4 having thickness and lattice constant a4 and one or more layers D5 (e.g., device layer(s)) having thickness and lattice constant a5.

FIG. 12. Device structures according to various examples.

FIG. 13. Further examples of growing relaxed layers using porous III-nitride, including regrown layers.

FIG. 14. Further examples of growing relaxed layers using porous III-nitride, including multiple porous layers.

FIG. 15. Further examples of growing relaxed layers using porous III-nitride, including regrown layers including a strained layer.

FIG. 16. Further examples of growing relaxed layers using porous III-nitride, including relaxed/partially relaxed layers and bonding to a bonding substrate and etching to remove porous layer.

FIG. 17. Further examples of growing relaxed layers using porous III-nitride, including regrown layers, relaxed/partially relaxed layers and bonding to a bonding substrate.

FIG. 18. Further examples of growing relaxed layers using porous III-nitride, including layer lattice matched to relaxed layer and bonding to a bonding substrate

FIG. 19. Example patterns.

FIG. 20. Example structure with filled pores, wherein FIG. 20 illustrates pores filled with Eu.

FIG. 21a. How a spin memory works. FIG. 21b: Example structure with filled pores, wherein the pores are filled with metal.

FIG. 22. Schematic sample structure and (−1−14) Reciprocal space map (RSM) of the as grown InGaN/GaN epitaxial layer structure, displaying that the InGaN layer is coherently strained to the GaN layer underneath.

FIG. 23 Schematic sample structure and (−1−14) reciprocal space map (RSM) of the same GaN/InGaN sample as in FIG. 1 after forming a porous GaN layer underneath the previously coherently stained InGaN layer. The reciprocal space map demonstrates full relaxation of InGaN layer

FIG. 24a-c shows schematics illustrating devices and methods of making devices according to one embodiment described herein, wherein FIG. 24a shows regrowth, FIG. 24b shows mask material removal, FIG. 24c shows deposition of electrical contacts.

FIG. 24d-f shows schematics illustrating devices and methods of making an LED according to another embodiment described herein, wherein FIG. 24d shows regrowth, FIG. 24e shows dielectric material removal. FIG. 24e shows deposition of electrical contacts.

FIG. 25a-c shows schematics illustrating devices and methods of making devices according to yet another embodiment described herein, wherein FIG. 24a shows mask material deposition, FIG. 25b shows regrowth, FIG. 25c shows mask material removal, FIG. 25d shows formation of electrical contacts.

FIG. 26a-b shows schematics illustrating devices and methods of making devices according to another embodiment described herein, wherein FIG. 26a shows regrowth, FIG. 26b shows formation of electrical contacts,

FIG. 26c-d shows schematics illustrating devices and methods of making devices according to another embodiment described herein, wherein FIG. 26c shows mask material deposition. FIG. 26d shows regrowth, FIG. 26e shows mask material removal, and FIG. 26f shows formation of electrical contacts.

FIG. 26g shows etching one or more sides during fabrication of a light emitting diode (LED).

FIG. 27a-b shows schematics illustrating devices and methods of making devices according to yet another embodiment described herein, wherein FIG. 27a shows regrowth and FIG. 27b shows formation of electrical contacts.

FIG. 27c-e shows schematics illustrating devices and methods of making devices according to yet another embodiment described herein, wherein FIG. 27c shows mask dielectric deposition, FIG. 27d shows regrowth, FIG. 27e shows mask removal, and FIG. 27f shows contact formation.

FIG. 28a-c shows schematics illustrating devices and methods of making devices according to yet another embodiment described herein, wherein FIG. 28a shows regrowth and FIG. 28b shows formation of electrical contacts, and FIG. 28c shows another electrical contact formation example.

FIG. 28d-e shows schematics illustrating devices and methods of making devices according to yet another embodiment described herein, wherein FIG. 28d shows regrowth and FIG. 28e shows formation of electrical contacts.

FIG. 29a-b shows schematics illustrating devices and methods of making devices according to yet another embodiment described herein, wherein FIG. 29a shows regrowth and FIG. 29b shows formation of electrical contacts.

FIG. 29c shows an LED with and without etch damage according to one embodiment.

FIG. 29d shows an LED with and without etch damage according to another embodiment.

FIG. 30 illustrates color tunability and size dependent relaxation of base layers, leading to enhanced Indium incorporation on smaller tiles, leading to size dependent luminescence wavelength.

FIG. 31a-b shows schematics illustrating devices and methods of making devices according to yet another embodiment described herein, wherein FIG. 31a shows regrowth and FIG. 31b shows formation of electrical contacts.

FIG. 31c-d shows schematics illustrating devices and methods of making devices according to yet another embodiment described herein, wherein FIG. 28d shows regrowth and FIG. 28e shows formation of electrical contacts.

FIG. 31e shows an LED with and without etch damage according to another embodiment.

FIG. 32a illustrates an LED with etch damage on 2-sidewalls out of 4-sidewalls, the area outside the Violet/Blue rectangle represents the area on which the isolation etch occurs and the isolation etch occurs partially on the regrown area and partially outside the regrown area. FIG. 32b illustrates an LED with etch damage on 1-sidewall out of 4-sidewalls and an area outside the Violet/Blue rectangle represents the area on which the isolation etch occurs and the isolation etch occurs partially on the regrown area and partially outside the regrown area, FIG. 32c illustrates an area outside the Violet/Blue rectangle represents the area on which the isolation etch occurs. The isolation etch occurs completely outside the regrown area.

FIG. 33 illustrates an improved method for relaxing semiconductor films including the fabrication of pseudo-substrates and formation of composites allowing the addition of previously un-accessible functionality to group III-nitrides.

FIG. 34 illustrates a schematic of a substrate or device manufactured using an improved method for relaxing semiconductor films.

FIG. 35 illustrates an improved method for relaxing semiconductor films including the fabrication of pseudo-substrates and formation of composites allowing the addition of previously un-accessible functionality to group III-nitrides, including the formation of the porous layer.

FIG. 36a illustrates a substrate according to one example, comprising a GaN layer having lattice constant a4.

FIG. 36b illustrates a substrate according to another example, comprising an additional layer L4 on the GaN layer and having lattice constant a4.

FIG. 37 illustrates a substrate according to another example, comprising an additional layer L4 on the GaN layer and having lattice constant a4 and a device structure D5 on the layer L4.

FIG. 38a illustrates a compliant pseudo substrate comprising layer L3 having lattice constant a3 on porous layer L2 on layer L1 having lattice constant a1.

FIG. 38b illustrates a compliant pseudo-substrate of FIG. 38a after growth of layer L4 with larger lattice constant a4 on top.

FIG. 38c illustrates a compliant pseudo substrate comprising GaN having lattice constant a1 on porous layer L2 on GaN layer having lattice constant a1.

FIG. 38d illustrates a compliant pseudo-substrate of FIG. 38c after growth of layer L4 with larger lattice constant a4 on top of GaN layer, so that the GaN layer having lattice constant a1 now has lattice constant a4.

FIG. 39 illustrates a compliant substrate formed using patterned features and method of making the same.

FIG. 40 illustrates a compliant substrate formed using patterned features and method of making the same, according to another example.

FIG. 41 is a top view of the compliant substrate including tiles or patterned features.

FIG. 42 illustrates 1—Porosification via electrochemical etching, 2—treatment of layer 2: e.g. filling or coating pores, implant with atoms or ions, etc., for example to render it semi-insulating, 3—Regrowth or wafer bonding of layer or layer stack L₃, L₁ and L₂: examples: any group-III nitride, Si, SiC, or any III-V or II-IV group IV, or I-III-V semiconductor, or oxide materials, wherein L₃ examples include any group-III nitride, Si, SiC, or any III-V or II-IV group IV, or I-III-IV semiconductor, or oxide materials and the process can be conducted with or without treatment of porous layer (step 2).

FIGS. 43 and 44 illustrate a process wherein layers L 1 and L2 (silicon) can be composed of any suitable material, such as SiC, any III-V, II-IV, group IV, or I-III-IV semiconductor, or any oxide, for example, wherein layers L₃ in FIG. 43 and layer La in FIG. 43 (group III nitride) can be composed of SiC, SiGe, Ge, or any III-V, 1I-IV, group IV, or I-III-IV semiconductor semiconductor, or any oxide, for example.

FIG. 45 illustrates a process wherein the target heterostructure structure (a) the thickness of the layer L2 is larger than its critical thickness. The structure is fabricated by growing the structure upside down onto a GaN-on-porous-GaN pseudo-substrate, where the thin L3 top layer, layer L2, and the initial part of layer L1 are first grown strained to the GaN underlayer with lattice constant a₁ (b). When continuing the deposition of the layer L1 the layers above the porous GaN adopt the lattice constant a2 of the thick relaxed or partially relaxed layer L1 (c). The sample is then bonded epi down to a carrier wafer and the GaN base layer which was initially underneath the porous GaN layer is lifted off along the porous GaN layer. Any remaining material from the porous GaN layer and the thin GaN layer adjacent to the porous GaN material are then etched off resulting in the target structure (a). Layers L1 to L3 can be composed of any suitable nitride material. Instead of using porous GaN other materials sandwiched by a porous layer can be used, e.g. GaAs, InP, Si, SiC, or oxide materials, for example.

FIG. 46 illustrates the process when transitioning to material with smaller in plane lattice constant.

FIG. 47(a) Output voltage versus current density.

FIG. 47(b) Peak EL peak versus current density.

FIG. 47 (c) Electroluminescence at 50 A/cm² with FWHM of 22 nm, with peak at around 542 nm.

FIG. 48. Schematic structure of (a) high quality homoepitaxially grown material, with a buried n+ doped layer, (b) patterned to allow sidewall porosification etch of the n+doped layer, resulting in the formation of the flexible porous under-layer, (c) regrown relaxed AlₓGa₁₋ₓN deposited on these compliant pseudo substrates shown in (b), with degree of relaxation dependent on the lateral dimensions of the pattern on the pseudo-substrates, with smaller dimensions yielding higher relaxation.

FIG. 49. Reciprocal space maps around the GaN (1̅ 1̅ 24) reflection of 200 nm thick InₓGa₁₋ₓN on (a) compliant GaN pseudo-substrate with undoped GaN cap thickness=100 nm, on 800 nm thick porous GaN layer, and (b) on a co-loaded GaN-on-sapphire template

FIG. 50. Schematic structure of (a) as-grown sample, (b) post patterning, (c) post porosification, (d) scanning electron microscopy image of an 8 μm×8 μm tile post porosification tilted 250 from the normal.

FIG. 51. Cross-sectional schematic of the regrown green micro-LED structure (a) with the two variation parameters-dimension of the tile and mole-fraction of the n-InGaN layer, (b) post fabrication

FIG. 52 I-V characteristics for (a) 4 μm×4 μm sized μLEDs fabricated on tiles with varying sizes—8 μm (red), 10 μm (green), 12 μm (black), 20 μm (magenta) and on unpatterned non-porous region (blue) (b) and for 3.5 μm×3.5 μm (black), 5.5 μm×5.5 μm (magenta) and 7 μm×7 μm (lime green) sized μLEDs fabricated on 20 μm wide tiles (c) Mean EL wavelength dependent on current density, for 4 μm×4 μm sized μLEDs fabricated on tiles with varying sizes—8 μm (red, cross), 10 μm (green, downturned triangle), 12 μm (black, filled circle), 20 μm (magenta, filled square) and on unpatterned non-porous region (open square). (d) Mean EL wavelength dependent on device dimension fabricated on tiles with varying sizes 8 μm (red, cross), 10 μm (green, downturned triangle), 12 μm (black, filled circle), 20 μm (magenta, filled square) at 10 A/cm² (e) EL images of a 7 μm×7 μm sized μLED on a 20 μm wide tile at 5, 10 and 15 A/cm².

FIG. 53(a) I-V characteristics. (b) mean EL wavelength and (c) FWHM of the EL peak dependent on current density for 4 μm-4 μm sized μLEDs fabricated on 10 μm wide tiles with different mole-fraction of the n-InGaN region of the LED structure: x_{In}=0.04 (green, downturned triangle) and x_{In}=0.09 (orange, diamond)

FIG. 54. EL spectra of 4 μm-4 μm sized μLEDs fabricated on 10 μm wide tiles with different mole-fraction of the n-InGaN region of the LED structure: (a) x_{In}=0.04 (green) and (b) x_{In}=0.09 (orange), with EL images at 60 and 100 A/cm².

FIG. 55. Schematic structure of (a) as-grown sample, (b) post patterning, (c) post porosification, (d) as-grown co-loaded reference GaN-on-sapphire reference sample, (e) representation of (c) or (d) in FIG. 2, as the base layer for subsequent regrowths

FIG. 56. Schematic structure of the samples (GaN-on-porous GaN pseudo-substrate and the GaN-on-sapphire template) with the regrowth interfaces labeled. The GaN-on-sapphire template served as a co-loaded reference sample only for the first regrowth R1, as this sample exhibited cracks, and was hence dropped from the subsequent growths.

FIG. 57. (a) Reciprocal space map of the GaN-on-porous GaN pseudo-substrate after regrowth R1 around the GaN (1̅1̅24) reflection, 2 μm×2 μm AFM images after regrowth R1 (b) on the 10 μm×10 μm GaN-on-porous GaN tile, (c) crack-free region of the GaN-on-sapphire template, with respective microscopy images (e) and (f). A zoomed-in version of (e) is shown in (d)

FIG. 58 (a) Reciprocal space map of the GaN-on-porous GaN pseudo-substrate after regrowth R2 around the GaN (1̅1̅24) reflection, (b) with their 2 μm×2 μm AFM image on the 10 μm×10 μm tile, (c) and microscopy image showing no cracks on the patterned region.

FIG. 59 (a) Reciprocal space map of the GaN-on-porous GaN pseudo-substrate after regrowth R3 around the GaN (1̅1̅24) reflection, (b) with their 2 μm×2 μm AFM image on the 10 μm×10 μm tile, (c) and microscopy image, showing no cracks. (d) a 20 μm×20 μm AFM image confirmed the preferential growth at the top and bottom sidewalls of the tiles corresponding to the (Al,Ga)N a-plane (112̅0) compared to their orthogonal sidewalls corresponding to the (Al,Ga)N m-plane (11̅00).

FIG. 60 (a) Reciprocal space map of the GaN-on-porous GaN pseudo-substrate after regrowth R4 around the GaN (1̅1̅24) reflection, (b) with their 2 μm×2 μm AFM image on the 10 μm×10 μm tile, (c) and microscopy image, showing no cracks. (d) a 20 μm×20 μm amplitude retrace AFM image shows almost complete coalescence across the (Al,Ga)N a-plane (112̅0).

FIG. 61. Schematic structure of (a) as-grown sample with varying GaN cap thickness of t₁=60, 100 and 140 nm, (b) post porosification, (c) upon regrowth of InₓGa₁₋ₓN with varying thickness of t₂=100 and 200 nm

FIG. 62. Cross-sectional schematic of the green micro-LED structure

FIG. 63(a) Relaxation and a-lattice constant of 100 nm (circle) and 200 nm (squares) thick InₓGa₁₋ₓN layers grown on GaN-on-porous-GaN pseudo-substrates with different GaN cap layer thickness. The dotted gray straight line in the bottom figure corresponding to the lattice constant of the coherently strained InₓGa₁₋ₓN layer grown on the co-loaded GaN-on sapphire reference sample (b) 5 μm×5 μm AFM images of sample B2 (GaN cap thickness=100 nm, InₓGa₁₋ₓN thickness=200 nm) on the left and sample D2 (InₓGa₁₋ₓN thickness=200 nm grown strained on a co-loaded GaN-on-sapphire wafer) on the right (c) Reciprocal space maps of samples B2 (left) and D2 (right) around the GaN (1̅1̅24) reflection

FIG. 64. Plan view SEM image of 30 nm GaN-on-porous-GaN sample.

FIG. 65. (a) IV characteristics of the 5 μm×5 μm micro-LED on the compliant GaN-on-porous-GaN pseudo-substrate. (b) Normalized electroluminescence of the 5 μm×5 μm micro-LED and a 300 μm×300 μm LED fabricated on the co-loaded GaN-on-sapphire reference wafer measured at room temperature at a current density of 50 A/cm².

FIG. 66. Schematic structure of (a) as-grown sample, (b) post porosification, (c) upon regrowth of 100 nm of InGaN, corresponding RSMs measured using the GaN (1̅1̅24) reflection to evaluate the InGaN relaxation across the tiles shown in (d), (e) and (f). Vertical dashed line through the GaN peak corresponds to the fully strained InGaN lattice constant, and the slanted line through the GaN peak corresponds to fully relaxed InGaN lattice constant in (d), (e) and (f). The red dashed lines through the InₓGa₁₋ₓN and In_{y}Ga_{1-y}N peaks in (e) and (f), correspond to lines of constant indium mole fraction x or y, where the degree of relaxation varies from 0 to 100% from left to right. The InₓGa₁₋ₓN peak in (e) shifted to the right along the red dashed line in (f) as a result of regrowth of In_{y}Ga_{1-y}N layer. The vertical dashed lines through the InₓGa₁₋ₓN and In_{y}Ga_{1-y}N peaks in (f) show a slight offset corresponding to about 20% lattice mismatch between the two layers.

FIG. 67, 5 μm×5 μm AFM image of sample (a) A0 with 200 nm In_{0.08}Ga_{0.92}N before regrowth (b) Al upon regrowth of 100 nm In_{y}Ga_{1-y}N (c) C0 with 80 nm thick In_{0.09}Ga_{0.91}N before regrowth (d) C1 upon regrowth of 100 nm In_{y}Ga_{1-y}N (e) C2 upon regrowth of 200 nm In_{y}Ga_{1-y}N

FIG. 68. Epitaxial structure of samples with InₓGa₁₋ₓN layer thickness of 80 nm, with varying mole-fraction x (a) as-grown—samples B, C and D, (b) post porosification—sample B0, C0 and D0, (c) upon regrowth of 100 nm of In_{y}Ga_{1-y}N—samples B1, C1 and D1, and upon regrowth of 200 nm InGaN—samples B2, C2 and D2, (d) Lattice constant ‘a’ and corresponding In mole fraction of fully relaxed InGaN with the same lattice constant, after porosification, (open symbols, before regrowth, samples B0, C0 and D0), and after regrowth of 100 (filled circles, samples B1, C1, and D1) or 200 nm In_{y}Ga_{1-y}N (filled squares, samples B2, C2, and D2), versus mole fraction x in the as-grown InₓGa₁₋ₓN layers (e) (top plot) Lattice constant ‘a’ in angstrom, and corresponding mole fraction of a fully relaxed InGaN layer versus mole-fraction x of as grown InₓGa₁₋ₓN layers, after regrowth of 100 (triangles) or 200 nm In_{y}Ga_{1-y}N layers (rhombi), (bottom plot) Degree of relaxation of In_{y}Ga_{1-y}N layers, versus mole-fraction of InₓGa₁₋ₓN layers, after regrowth of 100 (triangles) or 200 nm In_{y}Ga_{1-y}N layers (rhombi). (f) Cross-sectional focused ion-beam SEM image of a 10 μm-10 μm tile cleaved through the centre, for the sample C2 (200 nm In_{y}Ga_{1-y}N regrown on 80 nm of InₓGa₁₋ₓN, where x=0.09 and y=0.11)

FIG. 69. The average V-defect density of the sample surface vs mole-fraction x of as grown InₓGa₁₋ₓN layers, for as grown samples (open circles), after regrowth of 100 nm In_{y}Ga_{1-y}N layers (filled circles) or 200 nm In_{y}Ga_{1-y}N layers (filled squares)

FIG. 70: (a) Sample consisting of 200 nm InₓGa₁₋ₓN (x>0.08) on top of 400 nm of GaN:Si with a doping of 5×10¹⁸ cm⁻³, on 2 μm thick u.i.d. GaN base layers on sapphire substrate. (b) Sample structure after patterning into 2, 5, or 10 μm wide and 2 mm long fins, (c) followed by a doping selective electrochemical etch, leading to porosification of the GaN:Si layer. (d) Top view representative schematic (not to scale) of the 2 mm×2 mm die after patterning and dry etch, (e) SEM image of the edge of the die.

FIG. 71: (a) Sample consisting of 200 nm InₓGa₁₋ₓN (x=0.08) on top of 800 nm of GaN:Si with a doping of 5×10¹⁸ cm⁻³, on 2 μm thick u.i.d. GaN base layers on sapphire substrate. (b) Sample structure after patterning into 10 μm×10 μm square tiles, followed by a doping selective electrochemical etch, leading to porosification of the GaN:Si layer. (c) Top view representative schematic (not to scale) of the 2 mm×2 mm die after patterning and dry etch, (d) SEM image of the edge of the die.

FIG. 72: (a) RSM of as-grown sample along the GaN (1̅1̅24) reflection, depicting the InGaN being almost fully strained to GaN, (b) RSM along the GaN (1̅1̅24) reflection (along the arrows) after patterning 2 μm wide fins and EC etch at 30V bias, demonstrating full InGaN relaxation perpendicular to the fins. (c) RSM along the GaN (1̅015) reflection (along the arrows) after patterning and EC etch at 30V bias, demonstrating partial InGaN relaxation parallel to the fins. (d) Cross sectional FIB images of the fin region post porosification for the 2 μm wide fins, with a porosity of 50-60%.

FIG. 73: Degree of relaxation perpendicular and parallel to the fins versus applied voltage for samples with varying fin widths

FIG. 74: (a) RSM of the as-grown epitaxial structure shown in FIG. 2 (a) along the GaN (1̅1̅24) reflection and (b) upon patterning into 10 μm×10 μm tiles followed by the porosification etch showing 45% bi-axial relaxation of the InGaN top layer FIG. 75: Photoluminescence images for planar GaN template and the tiled porous sample.

FIG. 76: Schematic of a device structure according to Example 6.

FIG. 77a. Electroluminescence spectra from 6 μm×6 μm sized micro-LED at different current densities. A blueshift in the peak emission wavelength from red to amber when the current density changes from 10 to 100 A/cm²

FIG. 77b. Light output power of the same device in μWatts versus applied current density.

FIG. 78a. Current density versus voltage curve for the 6 μm×6 μm device with a forward voltage of ˜3V.

FIG. 78b. The extracted external quantum efficiency versus applied current density.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

GaN and its ternary and quaternary compounds incorporating aluminum and indium (AlGaN. InGaN, AlInGaN) are commonly referred to using the terms (Al,Ga,In)N, III-nitride, III-N, Group III-nitride, nitride, Group III-N, Al_{(1-x-y})In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included, as well as transition metals such as Scandium (Sc) or Yttrium (Y), for example. On the group-V side, Phosphorus (P), Arsenic (As), Antimoni (Sb), and Bismut (Bi) can be included.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero 1 Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

A pseudo-substrate is an engineered wafer which can be used as base layer for the epitaxial growth of crystalline materials, for example, group-Ill nitrides or other semiconductor materials.

For a layer X grown on a layer Y, for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed.

Technical Description

### I. METHOD FOR RELAXING SEMICONDUCTOR FILMS INCLUDING THE FABRICATION OF PSEUDO-SUBSTRATES AND FORMATION OF COMPOSITES ALLOWING THE ADDITION OF PREVIOUSLY UN-ACCESSIBLE FUNCTIONALITY TO GROUP III-NITRIDES

### 1. Introduction

The present disclosure describes the fabrication of heterostructures comprising of individual, high crystal quality relaxed layers with different lattice constants, which were previously impossible to fabricate without introducing crystal defects. Thereby the invention enables the fabrication of pseudo-substrates with specific, desired lattice constants. The invention is particularly attractive for the fabrication of long-wavelength micro-LEDs, where problems in using standard phosphors for wavelength conversion arise.

The alloy system (Al,Ga,In)N, for example, is a direct band gap system with a band gap ranging from 6.1 eV for AlN to 0.7 eV for InN. The lattice mismatch between AlN and InN is, however, as large as 13%, with 10% mismatch between GaN and InN. Expanding the operation range of (Al,Ga,In)N devices into the green, yellow, and red range of the electromagnetic spectrum is therefore complicated by an extremely large lattice mismatch when GaN is considered as the substrate. To date, however, only bulk GaN substrates are available, and only a few attempts have been undertaken to fabricate thick InGaN layers on GaN as alloy substrates because of difficulties in the growth of InGaN using the typical substrate growth method, Hydride Vapor Phase Epitaxy (HVPE). Furthermore, relaxed InGaN layers have been demonstrated by growing thick, compositionally graded InGaN layers on GaN base layers [1]. This process, however, results in the formation of crystal defects, hampering device applications. In another approach, the formation of relaxed InGaN layers was pursued by taking advantage of the relaxation of the lattice constant in nano-features via coalescence of relaxed nano-feature arrays [2]. Patterned, partially relaxed InGaN substrates are provided by SOITEC, the in-plane lattice constant of the substrates, however, corresponds to a rather low In composition [3].

In addition, certain applications, for example multi-junction solar cells, require vertical stacking of relatively thin layers with large differences in their lattice constant.

For all lattice mismatched systems, the critical thickness of a mismatched layer, representing the maximum thickness for the deposition of a defect free layer, is inversely proportional to the lattice mismatch [4]. For In_{0.3}Ga_{0.7}N on GaN, for example, the critical thickness was estimated to be below 3 nm. In addition, when grown in the typical c-direction, the large lattice mismatch between GaN and InGaN layers is accompanied by the existence of large polarization fields in the crystal, which result in electron hole separation in InGaN/GaN quantum wells, reducing the recombination probability of excitons. Since in the typical Ga-polar InGaN/GaN heterojunction light emitting devices the internal polarization field is directed in the opposite direction than the externally applied electric field, further problems arise, in particular for solar cell applications. In all cases, a reduction in the lattice mismatch between the active area of the device and the surrounding layers would greatly expand device design opportunities.

In addition, the electron and hole transport properties in relaxed/partially relaxed layers on uniaxially strained films can be advantageous in electronic device applications. Advantages also arise from nitride films, which are now biaxially strained to the newly engineered lattice constant, for example biaxially tensile strained GaN on a relaxed InGaN.

The present disclosure describes film relaxation enabled through the insertion of porous GaN. Since the relaxation process is elastic, no crystal defects form in the course of the fabrication process.

To date, embedded porous GaN layers have been used for the fabrication of mirror stacks, taking advantage of the refractive index change, or to form a “soft” layer allowing exfoliation/layer separation for flexible electronics, for example [5, 6]. Thereby buried n-type doped GaN layers are opened from the side via hole (vias) or line etching followed by an electrochemical process which leads to the formation of pores, as described in references 2 and 3. Thereby the process is very fast and porous GaN can be formed underneath of large, many micron sized features, as illustrated in FIG. 1.

### 2. First Example: Relaxation Using a Porous Laver

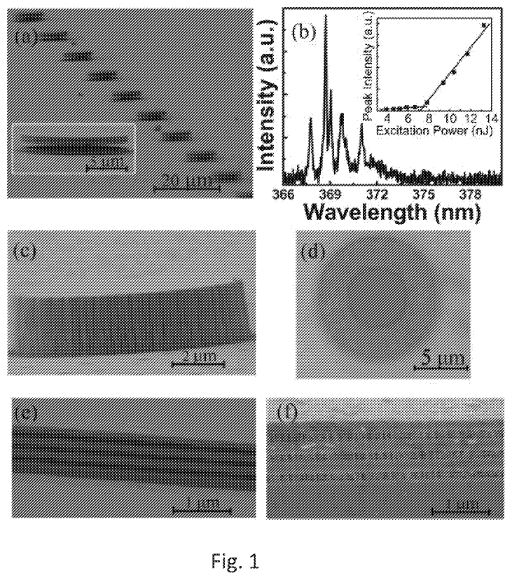

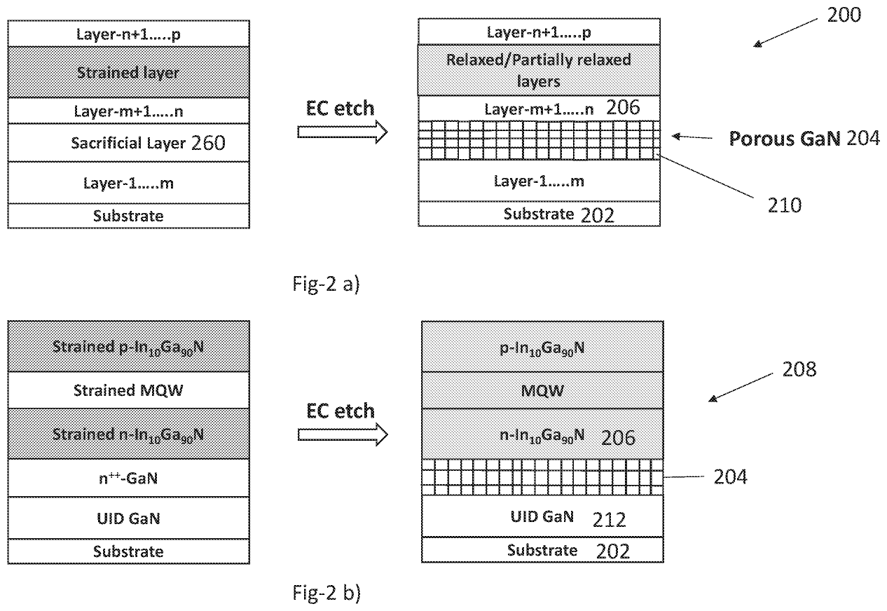

In one embodiment, on a substrate which may or may not be homogenous, first III-Nitride (III-N) layers are grown which may or may not be fully relaxed, followed by an n-type doped layer which can be used as a sacrificial layer to obtain porous III-N layer. Following the n-type layer, one or multiple strained layers may be grown (for example a bulk layer or super-lattice). Additionally, other layers might be inserted. Post growth, an electrical contact to the n-type layer may be made in one or multiple regions of the wafer. The electrical contact may need to be ohmic for best results. Thereafter, the wafer can be transferred to the wet etching apparatus (electrochemical or photo-electrochemical) where the embedded n-type layer is transformed into porous GaN, thus allowing the full or partial relaxation of the strained film above the porous GaN layer. This is illustrated in FIG. 2. FIG. 2a) shows the general layer structure and FIG. 2b) shows a specific example of the same

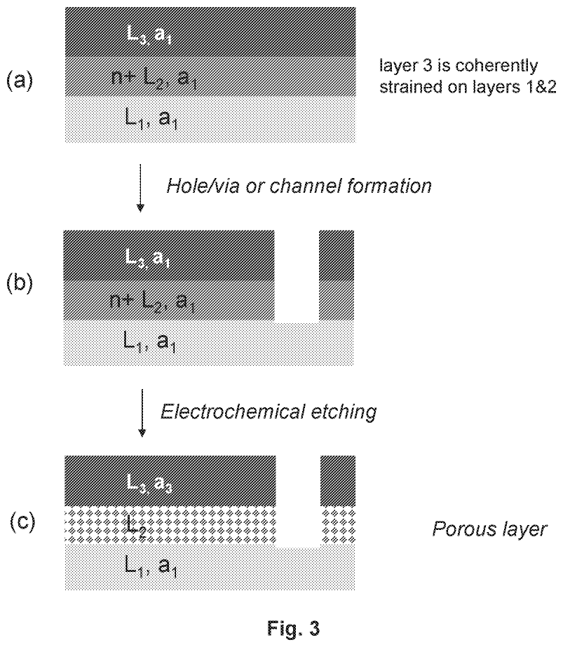

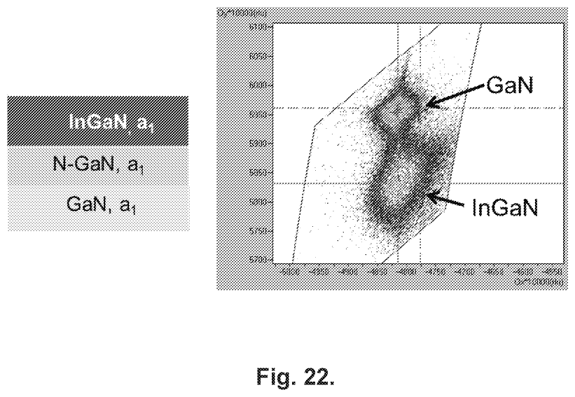

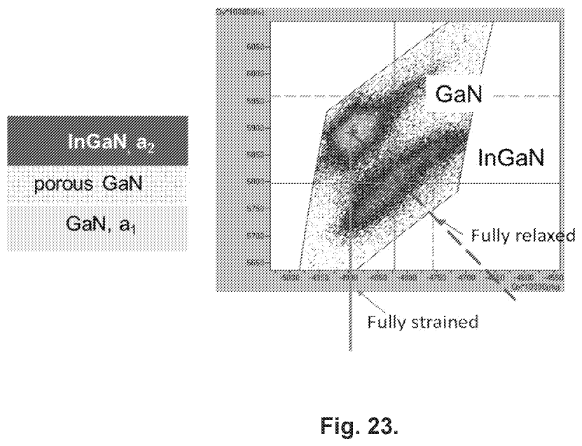

In another illustrative example of the present invention, in FIG. 3(a) an n-type doped GaN layer (L₂) is first grown on a relaxed GaN base layer (L₁) followed by a coherently strained InGaN layer (L₃), for example In_{0.15}Ga_{0.85}N, where all layers have the same in-plane lattice constant a₁. In the following lines and/or via arrays are etched into the layer structure, so deep that in one case the n-type layer is electrically connected to the electrode and the sidewalls of the n-type doped layer are opened (FIG. 3(b)). The wafer is then transferred to the electrochemical etching apparatus where the embedded n-type GaN layer is transformed into porous GaN, weakening its mechanical stability, allowing its deformation and relaxation of the InₓGa₁₋ₓN top layer L₃ adopting its relaxed in-plane lattice constant a₃ (FIG. 3(c)), for example creating a relaxed In_{0.15}Ga_{0.85}N layer. FIG. 22 illustrates the XRD reciprocal space map of a coherently strained InGaN layer, which fully relaxes after formation of a porous GaN layer underneath the InGaN layer (FIG. 23). If the coherently strained InGaN layer was grown on bulk GaN with very low threading dislocation densities in the order of 10⁵ to 10⁶ cm⁻², the relaxed InGaN layer will be characterized by the same very low threading dislocation density.

### 3. Second Example: Relaxation Using a Compliant Substrate

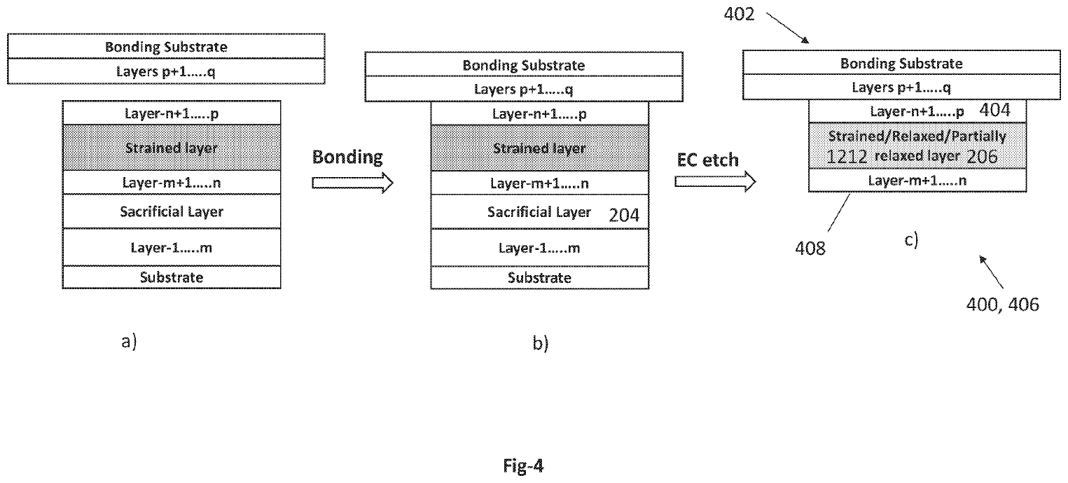

In another embodiment of the present invention as shown in FIG. 4, the epitaxial stack can be grown containing the sacrificial and strained layer/layers (FIG. 4a). The wafer can be then either partially or fully bonded to a substrate which may include III-N layers, oxide, metal etc (FIG. 4b)). The bonding substrate with layers may act as compliant substrate to allow full or partial relaxation of the strained layer. Prior to bonding, both wafers may undergo surface treatments (such as polishing, wet etching, dry etching etc.) to promote high quality bonding. Post bonding, the host substrate can be removed by performing wet etching (electrochemical or photo-electrochemical) (FIG. 4c). This method can be further used to flip polarity of the top layer. Multiple bonding and subsequent transfers may be employed to either flip polarity or preserve the original polarity of the top layer (post bonding and transfers).

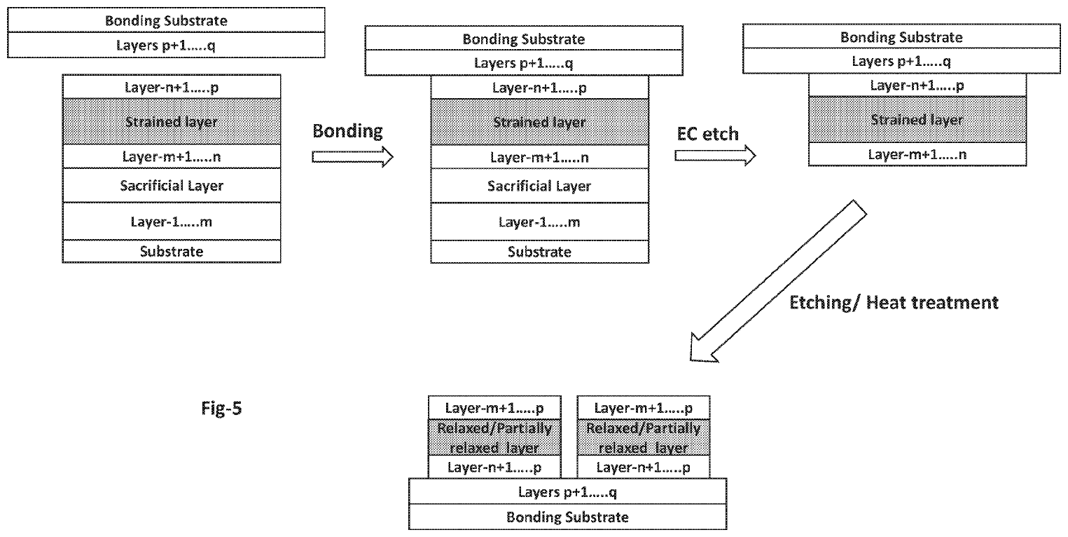

In another embodiment of the present invention shown in FIG. 5, additional etching (wet/dry or combination) or/and heat treatment can be performed post process as described in FIG. 4 to facilitate further elastic or plastic relaxation of the strained layer.

### 4. Third Example: Porous Layer and Bonded Substrate

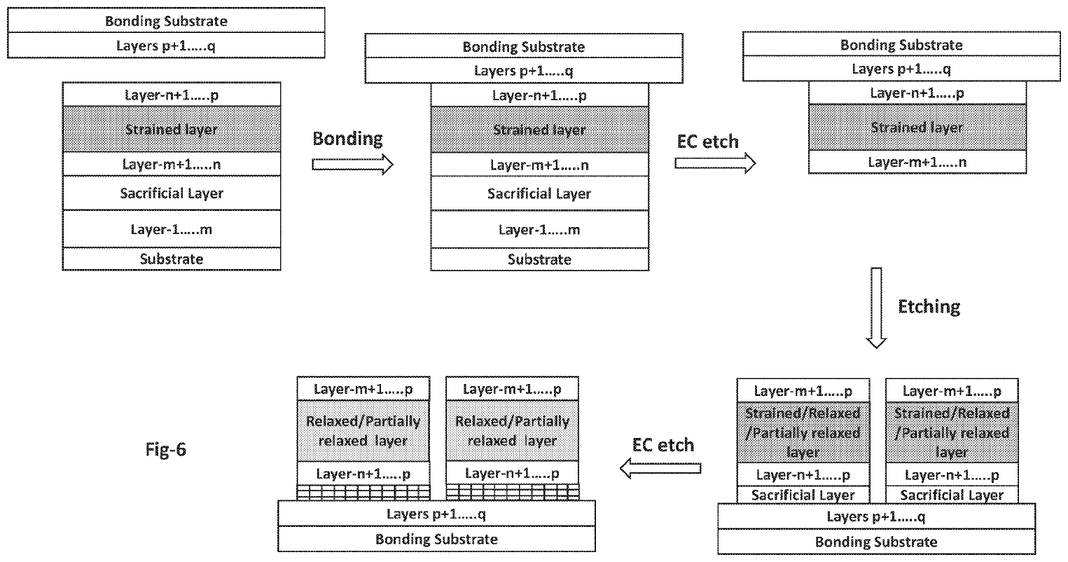

In another embodiment of the present invention shown in FIG. 6, porous GaN can be further utilized to obtain full or partial relaxation of the strained layers. Here, in this embodiment, multiple sacrificial layers are utilized. In the case of multiple sacrificial layers and multiple wet etches, other sacrificial layers may be protected by oxide, metal etc. deposition during the wet etch process for one of the sacrificial layers. First sacrificial layer may be used for original substrate removal similar to processes as described above (FIG. 4 and FIG. 5). The second layer is used to facilitate relaxation of the strained layer post bonding. This can be done in conjunction with etching or/and heat treatment as desired.

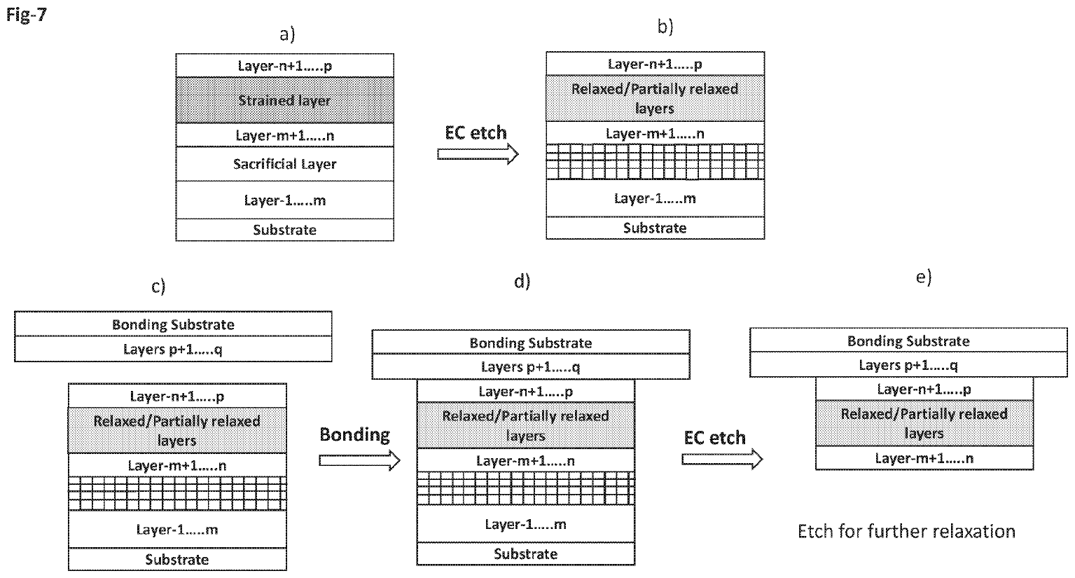

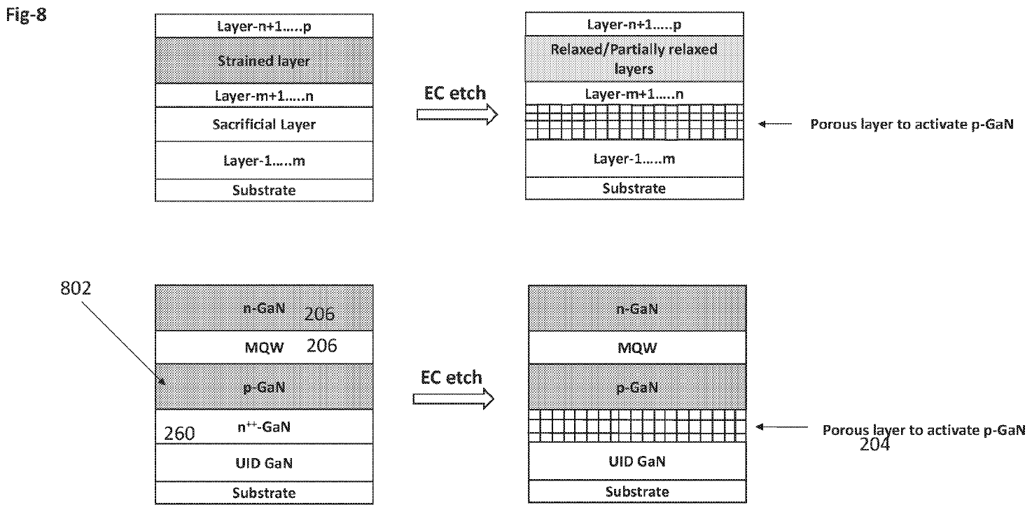

In another embodiment of the present invention shown in FIG. 7, porous III-N layer may be used to relax the strained layer (FIGS. 7a) and 7b)). Following full or partial relaxation through porous GaN, the wafer is further bonded to a host substrate (FIG. 7c)). The bonding process can be similar to as described above (FIG. 4 description). Here, the bonding is performed with full/partially relaxed layers (FIG. 7d)). Post bonding, wet etch can be employed to remove the original substrate (FIG. 7e)). Furthermore, processes described above involving etching, heat treatment, multiple porous GaN layers (FIG. 5 and FIG. 6) may be also be used to obtain further relaxation. This process or part of the process steps can be applied in a micro LED process, where a porous GaN layer can be formed underneath the entire ship, where it can serve not only for relaxation but also allows separation of the active part of the micro-LED structure from the previous substrate. This would, for example, allow reusing the original bulk GaN substrates the initially coherently strained layers were epitaxially grown upon.

### 5. Fourth Example: Activation of p-Type Laver

In another embodiment of the present invention as shown in FIG. 8, a buried p-type III-N layer can be activated by annealing through porous GaN. This is of particular importance for LED structures with bottom p-type layer.

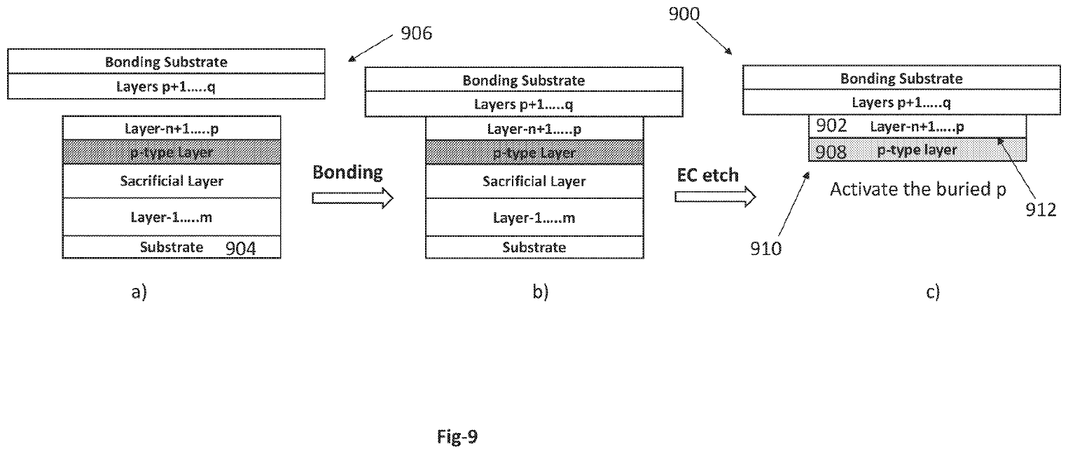

In another embodiment of the present invention, the epitaxial stack shown in FIG. 9a) contains a sacrificial layer followed by p-type layer. The wafer can be bonded to another substrate similar to the process described above (FIG. 4 description) (FIG. 9b)). Post bonding, the original substrate can be removed via wet etch. The p-type layer is now the top layer with polarity flipped (FIG. 9c)). The p-type layer can now be activated by annealing. Here, the sacrificial layer can also be subjected to wet etch to form porous GaN in steps 9a) and 9b) to activate the p-type layer prior to bonding or post-bonding respectively. In the third step, the porous III-N layer and the original substrate can be completely removed by wet etching process.

### 6. Fifth Example: Regrowth

In another embodiment of the present invention, regrowth can be performed on the epitaxial stack with porous III-N layer in between. Prior to regrowth, surface treatments (polishing, planarization, wet etch, wet treatments, dry etch etc.) may be performed to facilitate higher or high quality regrowth.

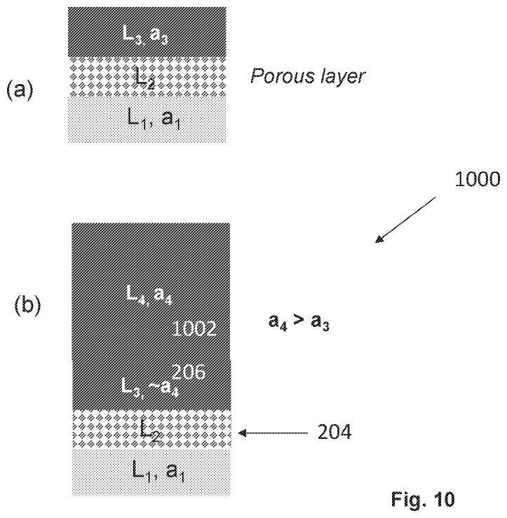

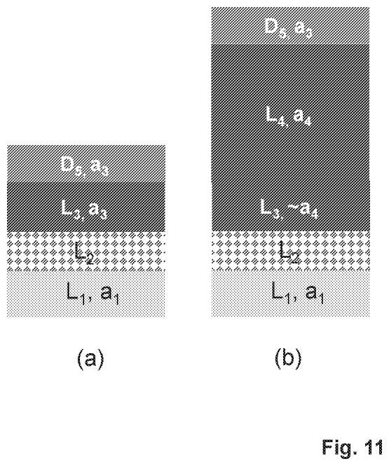

In another embodiment of the present invention, if it is desired to further increase In composition and lattice constant, the wafer is transferred back into the crystal growth chamber and the growth is continued with the deposition of an In_{y}Ga_{1-y}N top layer L₄ (y>x and a4>a₃). Once the thickness of the In_{y}Ga_{1-y}N layer L₄ gets closer to that of layer L₃, layer L₃ will start straining to adopt the lattice constant of the top layer L₄, a₄, as the thickness of layer L₄ increases (FIG. 10), for example allowing the fabrication of relaxed In_{0.3}Ga_{0.7}N. Furthermore, the same procedure can be repeated multiple times (with multiple porous GaN layers) to obtain desired In composition and lattice constant. If needed additional layers Lx can be stacked on top as desired for the application (FIG. 11).

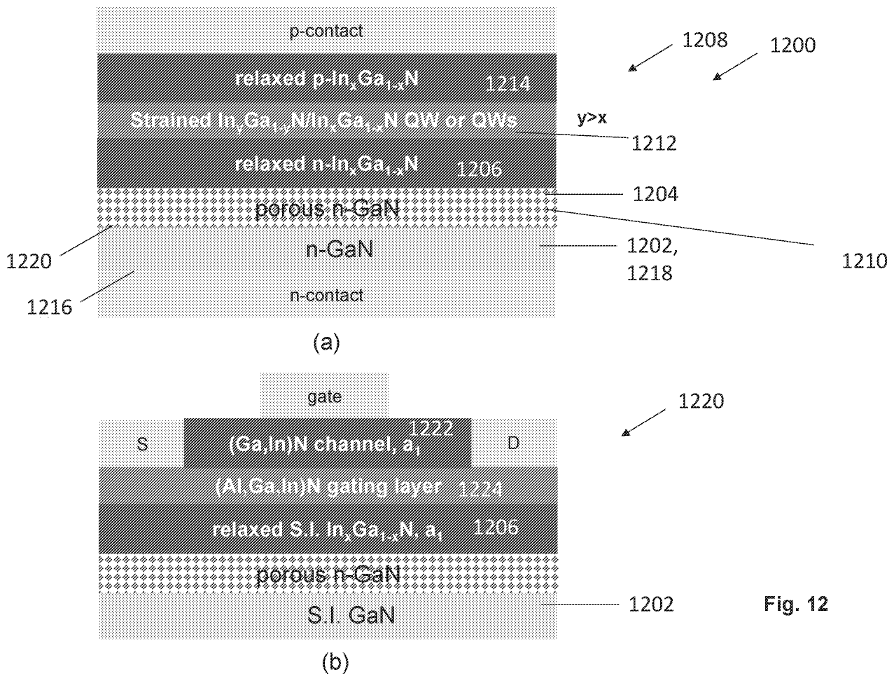

The active region of any device, D₅, such a quantum wells in case of light emitting devices (FIG. 12(a), or a thick InGaN layer in case of a solar cell followed by a p-InGaN layer can then be deposited on top. In case of a transistor, channel and gating layers would be grown (FIG. 12(b), example N-polar n-FET or Ga-polar p-FET). This can be done ex-situ after fabrication of the “pseudo-substrate” or the “active” device layers D₅ could be grown directly on top of layers L₃, prior to the formation of the embedded porous GaN, streamlining the process.

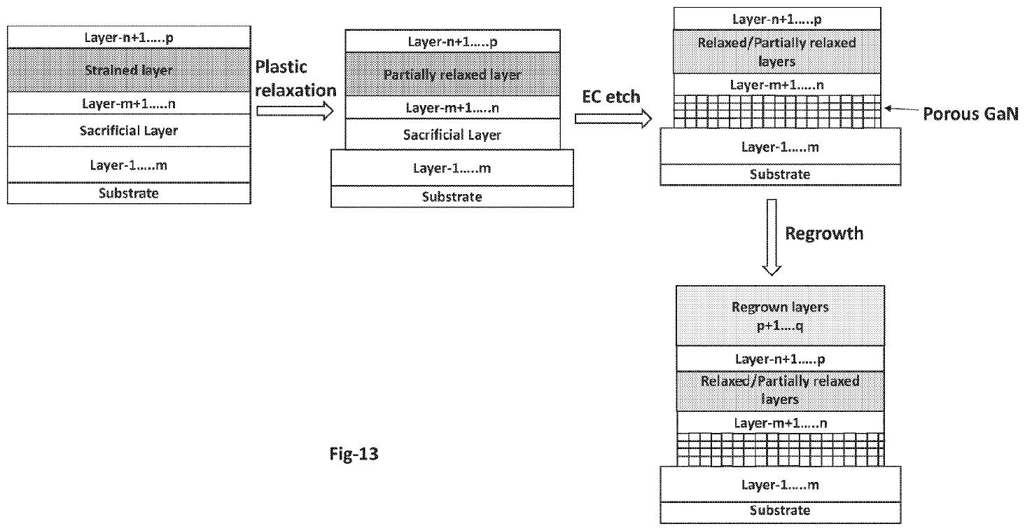

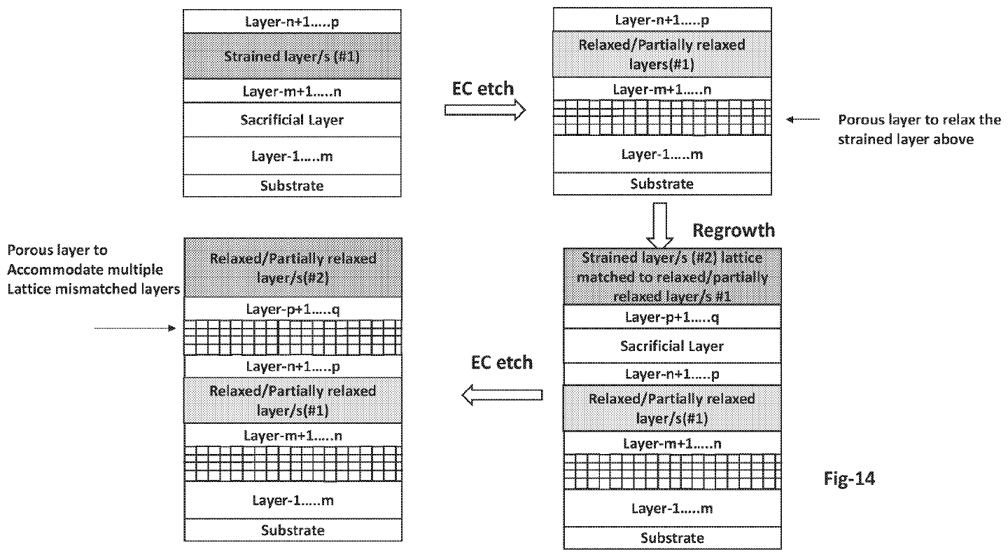

In another illustrative embodiment of the present invention (FIG. 13), regrowth can be performed on fully or partially relaxed layers with buried porous III-N layer. Similar multiple cycles can be performed to obtain desired lattice constant or thick relaxed III-N films (FIG. 14). Here, the first porous layer may not remain porous after regrowth.

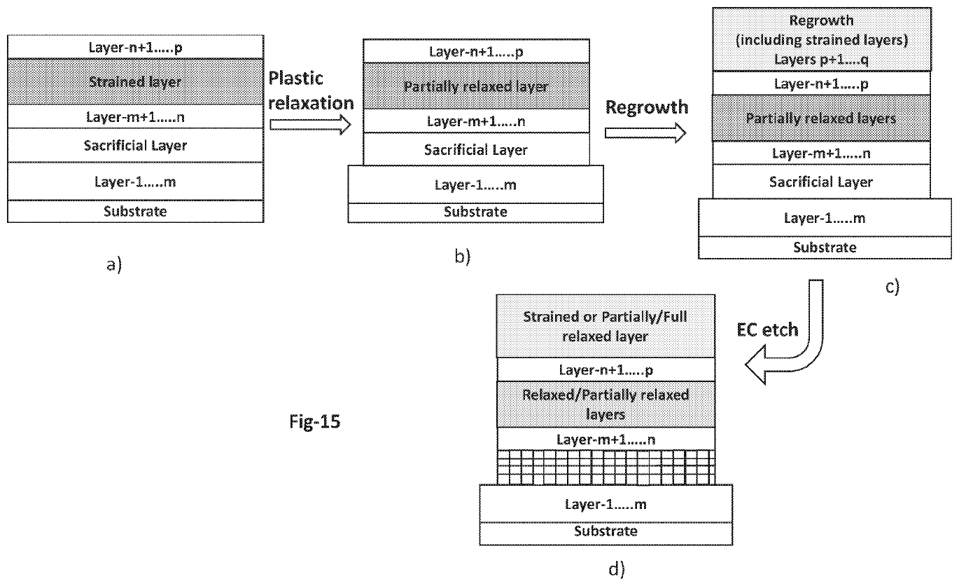

In another embodiment of the present invention, regrowth can be performed on a partially or fully relaxed layer (which is achieved by means other than porous III-N layer) (FIG. 15 a, b). Here, the thickness of the regrown layer may be kept thin relative to the partially relaxed layer to avoid restraining of that layer. Post regrowth, wet etch may be performed to obtain full relaxation or partial relaxation of layers above porous III-N layer (FIG. 15 c, d)).

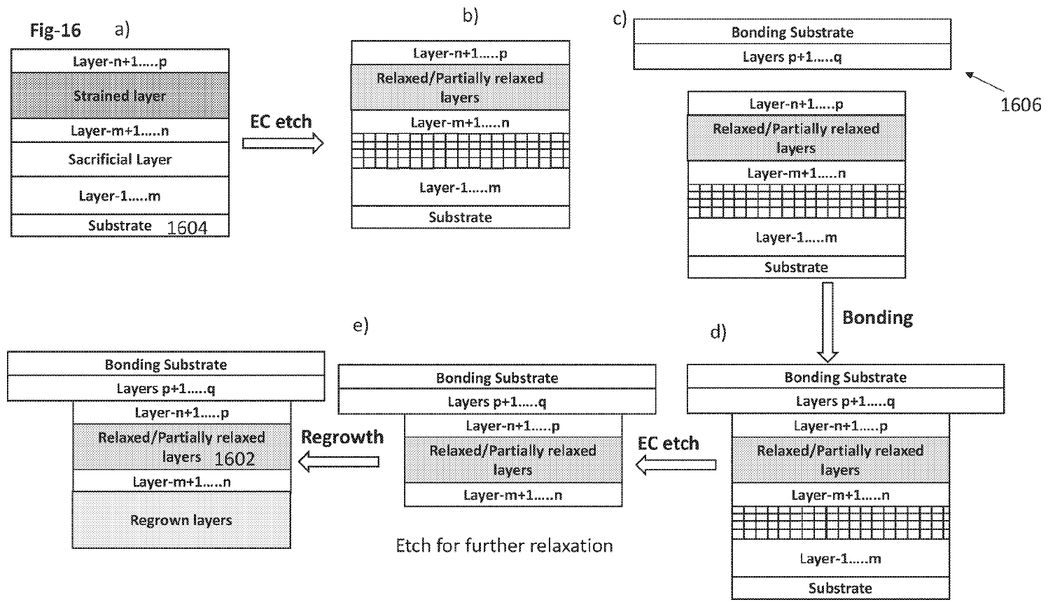

In another embodiment of the present invention, regrowth can be performed on structures shown in FIG. 4, FIG. 5, FIG. 6 and FIG. 7. FIG. 16 shows one such example. Here, prior to regrowth, multiple bonding and transfer cycles may be performed to obtain the preferred polarity interface for regrowth.

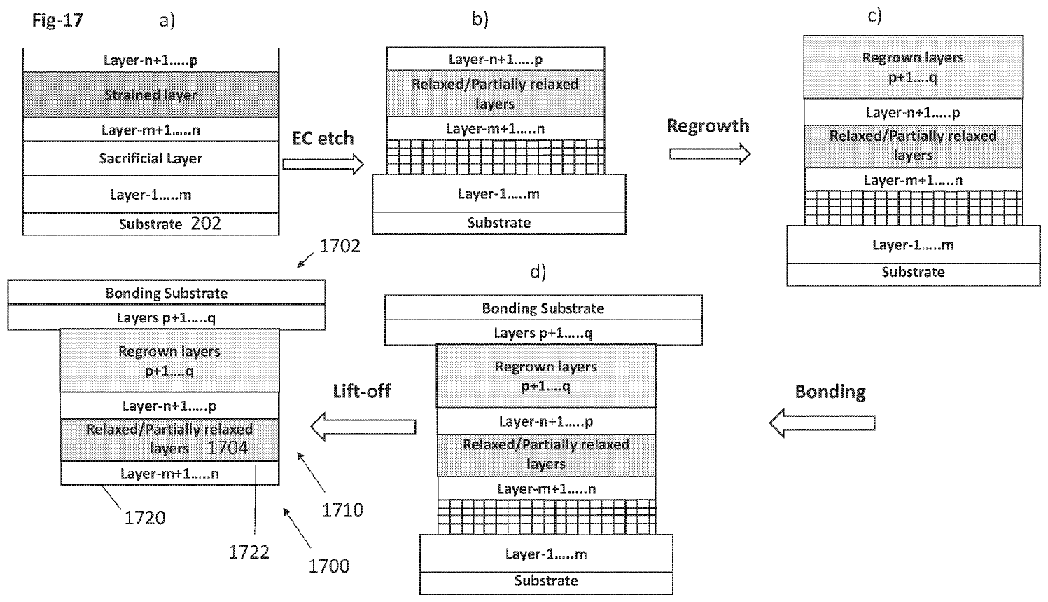

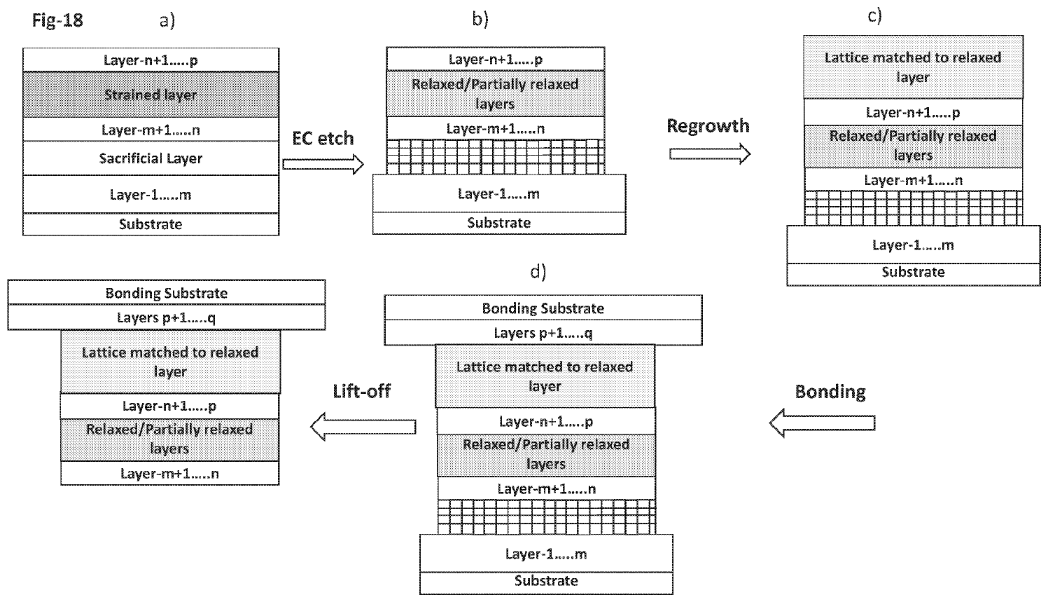

In another embodiment of the present invention, regrowth and/or heat treatment may be performed on epitaxial stack consisting porous layer (FIG. 17 a)-c)). This may facilitate bonding (FIG. 17d)) or lift-off (FIG. 17 e)). This may also be used to obtain thicker relaxed layer (FIG. 18).

While the above processes are primarily illustrated for increasing the in-plane lattice constant in comparison to the GaN substrate, the process can be used also for the creation of layers with an in-plane lattice constant smaller than GaN. Similarly, the process can be used for lattice constant engineering when growing on AlN substrates.

### 7. Further Examples

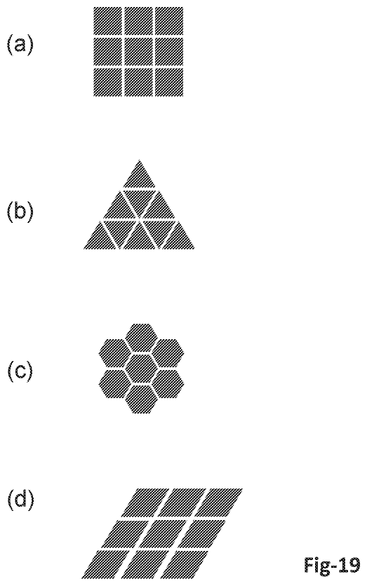

(a) The method can be applied to any orientation (and polarity) of the crystal under consideration, for example c-, m-, a-, and all semi-polar GaN orientations.
(b) Any individual layer or layers (Lₙ, Layer) can be replaced by multi-layer-stacks (multi quantum wells, super-lattices, graded layer).
(c) Instead of fully relaxing, the layers can partially relax.
(d) If desired, part of the layer or stack Lₙ can be a strained layer with respect to the lattice constant aₙ of the relaxed bulk of the layer or stack Lₙ.
(e) The film deposition can be performed by any crystal growth method, for example metal organic chemical vapor deposition (MOCVD), molecular beam epitaxy (MBE), hydride vapor phase epitaxy (HVPE), pulse laser deposition (PLD), or sputtering.
(f) The etching process to form the vias or trenches can be conducted by any technique, for example reactive ion beam etching or focused ion beam etching. If desired also wet etching, including electrochemical etching, or any combination of etching techniques can be used.
(g) If desired, the feature size and geometry created by etching can be chosen in such a way that additional effects, such as light extraction/or absorption via photonic crystals can be utilized.
(h) Similarly, the feature shape can be designed in such a way that a uniaxial strain is generated in the layers above the porous GaN layer. For example, in long ridges, the top layer(s) will relax perpendicular to the stripe direction, while staying strained along the ridge. Furthermore, features can be designed to obtain any degree of relaxation in any direction. For example, square shape to achieve equal partial or full biaxial relaxation.
(i) If desired, the layer stack above the porous layer which includes the active part of the device structure can be lifted off from the base wafer allowing, for example, reusing the GaN bulk substrate the layer stack was chosen to be grown on. This can be done via etching holes (vias) and/or other patterns (stripes/rectangles/circles). The latter would be attractive for micro-LEDs. Examples for pattern geometries are illustrated in FIG. 19.
(j) If desired the porous layer can be treated in such a way that it cannot be deformed any longer, “freezing in” the lattice constant. This can be performed by, for example, heating up the sample or filling the pores with a suitable substance. (j2) similarly the lattice constant can be fixated via coalescence of the previously separated features on top of porous GaN, for example by running recangels into stripes through coalescence in one direction, or by coalescing in more tthan one direction, possibly under formation of a planar film with the desired lattice constant.

Thereby the pattern spacing can be used as additional design parameter to engineer the lattice constant and the properties of the device structures.

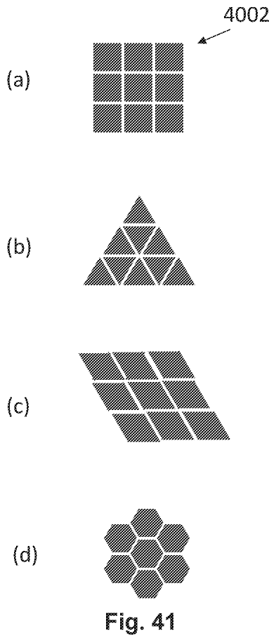

The pattern coalescence can be aided by applying appropriate pattern shapes, for example squares or triangles or rhombohedral/parallelogram patterns (FIG. 41). The advantage of a triangular or rhombohedral/parallelogram shape arises from the circumstance that group-III nitrides crystallize in a hexagonal lattice and when grown in the c or −c direction, the sidewalls of an equilateral triangle or rhombus have the same crystallographic properties. For other growth directions, such as a- or m-plane GaN, squares or rectangles would be preferred, for example.
(k) If desired, strained and relaxed layers can be stacked vertically.
(l) If the relaxation process leads to crinkling of the relaxed layer because of its larger in-plane lattice constant compared to the layer below the porous layer, the crinkling will lead to dislocation bending and dislocation annihilation in any layer grown on top of the crinkled relaxed layer.
(m) For any event partial instead of full relaxation of any layer can be utilized.
(n) If desired, prior to regrowth on porous III-N material, the wafer can undergo surface treatments such as polishing, etching, wet etch etc.
(o) If desired, post regrowth on porous III-N material, the layer stack above the porous layer which includes the active part of the device structure can be lifted off from the base wafer via etching holes (vias) and/or other patterns (stripes/rectangles/circles). The latter would be attractive for micro-LEDs.
(p) If desired, post regrowth on porous III-N material, electronic, photonic etc. devices can be fabricated with an intermediate or final step involving lifting off from the base wafer the (full or partial) layer stack above the porous layer.
(q) The re-film deposition on the porous III-N material can also be performed by any crystal growth method, for example metal organic chemical vapor deposition (MOCVD), molecular beam epitaxy (MBE), hydride vapor phase epitaxy (HVPE), pulse laser deposition (PLD), or sputtering.
(r) If desired, the porous III-N material layer thermally conductivity can be enhanced by introducing additional material such as diamond slurry etc. This can be performed prior to regrowth or any heat treatment as well.
(s) If desired, the porous nature of the III-N layer can be optimized such that to obtain a desired combination of relaxation and mechanical strength. For example, to facilitate regrowth, a certain pore size is required which may not provide full or desired relaxation of the strained layer. The trade-off between mechanical strength, relaxation and thermal conductivity can be optimized to suit different purposes such as regrowth, bonding and transfer etc.
(t) The properties of porous III-N layer may change post heat treatment or regrowth.
(u) There may or may not be additional layers between the porous GaN layer in the relaxed or partially relaxed layers (layer-m+1 . . . n in figures is an optional layer).
(v) The method can be used for dual channel/dual gate transistors, where the transistor layers forming the dual channels are grown on top of a sacrificial n-type layer. After fabricating transistors from the top side, the processed wafer is transferred to another wafer as described for LEDs, the sample is then processed to allow for the etching of the n-type sacrificial layer and removal of the bottom part of the original wafer. After further processing steps, the second gate is fabricated on top of the flipped wafer.
(w) The degree of strain can be varied over different regions of the wafer by changing the porosity achieved during electrochemical etching. The pore size and density tune the mechanical properties of the porous layer and the degree of relaxation of the layer or layers on top of the porous layer. This could be done, for example, by first forming trenches or vias in one region and forming small pores during electrochemical etching. Afterwards, trenches or vias are opened in other areas, followed by a second electrochemical etching step. The second etch step will further increase the pores in the first region, allowing a more complete relaxation of the material on top compared to the regions which were exposed to only one electrochemical etching step.
(x) The degree of strain relaxation can be used to tune the emission/absorption wavelength of devices.

### 8. Further Examples: Filling the Pores

Extending the application of porous GaN layers, the porous GaN layer can be used to add additional functionality to the layer structure, independent of the lattice constant considerations. Here, the porous GaN layer can be filled with material including foreign substances, which can either fill or coat the pores creating a composite or adsorb on the pore surface, functionalizing the porous GaN material.

For example, the porous GaN layer, which can be on the top or embedded into the group-III nitride layer structure can be exposed to gasses, leading to the absorption of the gas constituents on the pore surface. Combining gas exposure and heat up steps, material can be deposited inside the pores as well. This process can be used to incorporate magnetic substances, for example. Generally this invention allows the demonstration of devices, which were previously impossible or difficult to fabricate using standard group-III-nitride processes and also enable the integration of nitride based electronic and optoelectronic devices. Due to their high surface area, the porous GaN layers can also be used for sensing applications.

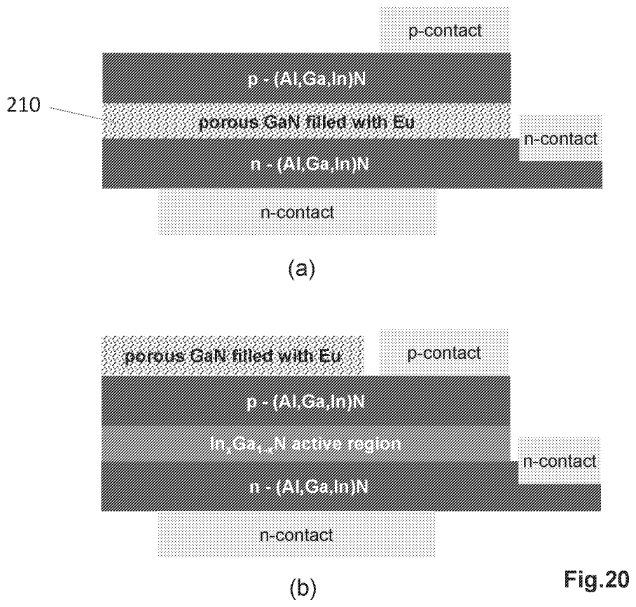

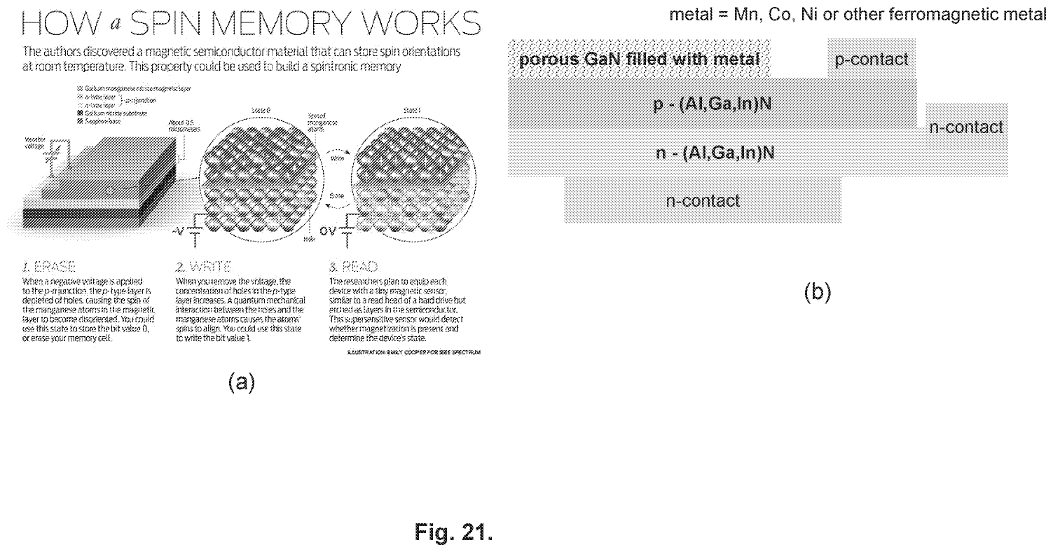

Porous GaN layers can be utilized as described in the following examples, with their application being not limited by the given examples:
(1) Filling a porous layer on top of a light emitting device structure with metals, for example europium (Eu) Eu doped GaN has been used for the fabrication of red LEDs using the internal Er emission at 1.54 μm [7]. The concentration of Eu, which can be incorporated into the GaN crystal without formation of defects, which can lead to non-radiative recombination, is, however limited (in the order of 10¹⁹ cm⁻³), and the intensity of the red emission is rather low. Replacing the GaN:Eu layer by a porous GaN layer which is filled with Eu increases the available amount of Eu by about 4 orders of magnitude, which would lead to a drastic increase of the intensity of the emitted red light. Thereby the porous layer which is filled with Eu can be the active layer, which is placed between the n- and p-type layers in an LED (FIG. 20(a)). In an alternate way, the porous layer which is filled with Eu can be positioned on top of a nitride LED to serve like a phosphor by absorbing the light emitted from the LED underneath and re-emitting red light. (FIG. 20(b)).
(2) Filling the porous layer with ferromagnetic materials such as metals like Co, Mn, or Ni, for implementing magnetic properties into the group III-nitride structure, for application in spintronics, for example. Currently GaMnN layers are used for magnetic applications as illustrated in FIG. 21(a) [8]. The solubility of Mn in GaN is, however, rather low (<10%). Replacing the GaMnN layer by a porous GaN layer which is filled with Mn, for example, will greatly increase the metal concentration again, allowing to improve the properties of the magnetic devices including spin-based electronic devices such as spin-torque devices.
(3) Filling a porous layer with a different material for thermal management by introducing a material with a high thermal conductivity, such as diamond or SiC for example. Thereby the porous layer can be positioned either below or above the active part of the device structures. Thermal management is particularly important for electronic devices, but also for lasers and other light emitting devices (see FIG. 11).
(4) Filling a porous layer with a metal such as Cu or Pt to create a highly conductive layer for interconnecting devices.
(5) Filling the porous layer with other semiconductor materials, such as (Al,Ga,In)(P,As,Sb) similar to (1) for assessing a wide range of emission wavelength
(6) Filling the porous layer with a nitride material which has a large lattice mismatch to GaN. Here the pores act like nanostructures allowing the deposition of material with a large lattice mismatch, as for example InN on GaN with a lattice mismatch of 10%.

As far as the pore filling process is concerned, the wafer with the vias or trenches with open porous layer sidewalls or a porous op layer is transferred into a reactor chamber, which can but must not be a MOCVD reactor chamber and exposed to a gaseous ambient containing the precursors for the material to be deposited inside the pores. For example tris(dipivaroylmethanate)europium [Eu(DPM)₃], cyclopentadienyl manganese tricarbonyl, dicobalt octacarbonyl for Eu, Mn, or Co deposition, or Si₂H₆ and C₂H₂ for filling with SiC or C. Thereby the sample can be heated simultaneously, or exposure and heating steps can be alternated, for example, while the remainder of the sample is or is not protected with capping layer(s) which can be removed afterwards.

### 9. Experimental Results

In our work, for the first time, we experimentally demonstrate the full relaxation of an initially compressively strained InGaN layer after formation of a porous GaN layer underneath. The epitaxial structure was grown on sapphire by MOCVD and consisted of a GaN base layer followed by a n-type doped GaN layer and a compressively strained 200 nm thick InGaN layer (In ˜13%). The InGaN layer was observed to be almost fully strained (˜96% strained from reciprocal space map) (FIG. 22).

To obtain InGaN relaxation, first a dry etch was performed on patterns defined by optical lithography. Thereby the dry etch was performed such that the n-type doped GaN layer was exposed on the sidewalls. Thereafter, an ohmic contact was obtained on one part of the wafer to facilitate electrochemical etching. Finally, electrochemical etching was performed to obtain porous GaN in the n-type doped GaN layer.

The reciprocal space map of post processed wafer indicated full relaxation of the InGaN film (FIG. 3), confirming that the buried porous GaN layer allowed the relaxation of the InGaN lattice. To the best of our knowledge, this is the first demonstration of full relaxation of thick InGaN film on top of porous GaN.

### DEVICE AND METHOD EXAMPLES

1. FIG. 2a and FIG. 12 illustrates a device 200, 1200 comprising:
a growth substrate 202 or base layer 1202;
a porous (e.g., semiconductor or III-nitride) layer 204, 1204 on or above the growth substrate; and
an at least partially relaxed (e.g., semiconductor or III-nitride) layer 206, 1206 on or above the porous III-nitride layer; and
an optoelectronic or electronic device structure 208, 1208 comprising the at least partially relaxed (e.g., semiconductor or III-nitride) layer 206 or grown on the at least partially relaxed III—(e.g., semiconductor or III-nitride) layer 206, wherein:
the at least partially relaxed (e.g., semiconductor or III-nitride) layer has a lattice constant that is different than a lattice constant of the growth substrate such that the at least partially relaxed (e.g., semiconductor or III-nitride) layer would be coherently strained if grown on the directly on the growth substrate.

2. The device of example 1, wherein the porous (e.g., semiconductor or III-nitride) layer comprises etched pores 210, 1210.

3. The device of example 1, wherein the growth substrate comprises gallium nitride or aluminum nitride, silicon, silicon carbide, or gallium arsenide.

4 The device of examples 1, 2 or 3, wherein the porous III-nitride layer 204 comprises n-type gallium nitride and the at least partially relaxed layer 206 comprises Indium and Gallium.

5. FIG. 12a illustrates the device 1200 of any of the examples 1-4, wherein:
the at least partially relaxed III-nitride layer comprises an n-type InGaN layer 1206,
the optoelectronic device structure comprises a strained light absorbing or light emitting InGaN active region 1212 between the n-type InGaN layer 1206 and a p-type InGaN layer 1214,
the p-type InGaN layer 1214 is at least partially relaxed, and
the active region has 1212 a higher indium composition than the n-type InGaN layer 1206 and the p-type InGaN layer 1214.

6. FIG. 12b illustrates the device 1220 of any of the examples 1-4, wherein the electronic device structure comprises a transistor including:
a channel layer 1222 including indium and gallium, wherein the channel layer is relaxed or partially relaxed;
a gating layer 1224 adjacent the channel and comprising aluminum and gallium, wherein the gating layer is strained;
a source contact (S), a drain contact (D), and a gate contact (G) to the channel layer, and wherein
the gating layer is between the at least partially relaxed III-nitride layer 1206 comprising InGaN and the channel layer 1222.

7. FIG. 4 illustrates the device of any of the examples 1-6, wherein the optoelectronic or electronic device structure 400 is bonded to a compliant substrate 402.

8. The device of example 7, wherein the bonding flips a polarity of the III-nitride layer 404 in the device adjacent the bond to the compliant substrate.

9. FIG. 20 illustrates the device of any of the examples 1-8, wherein pores 210 in the porous III-nitride layer are at least partially filled with gas, metal, phosphor, ferromagnetic material, semiconductor material, and/or other foreign material (in this case Eu, europium).

10. FIG. 2b further illustrates the device of any of the examples 1-9, further including an intermediate III-nitride layer 212 between the growth substrate and the porous III-nitride layer.

11. FIG. 12 illustrates The device of example 10, with the substrate removed so that a surface 1216 of the intermediate III-nitride layer 1218, having an opposite polarity to an interface 1220 with the porous III-nitride layer, is exposed so as to flip a polarity of the device 1200.

12. FIG. 10 illustrates the device 1000 of any of the preceding examples, further comprising an at least partially relaxed InGaN layer 1002 on or above the at least partially relaxed III-nitride layer 206 comprising InGaN, the at least partially relaxed InGaN layer 1002 having a higher indium composition (e.g., at least 30%) and a larger thickness than the at least partially relaxed III-nitride layer 206 (composition of no more than 15%).

13. FIG. 4 and FIG. 17 illustrate a device 400, 1700, comprising:
a compliant substrate 402, 1702;
an at least partially relaxed (e.g., semiconductor or III-nitride layer) 206, 1704 bonded to the compliant substrate, wherein the at least partially relaxed (e.g, III-nitride or semiconductor) layer is bonded directly or indirectly to the compliant substrate; and
an optoelectronic or electronic device structure 406 comprising the at least partially relaxed (e.g, semiconductor or III-nitride) layer 206, 1704 or grown on the at least partially relaxed (e.g., semiconductor or III-nitride) layer, wherein:
the at least partially relaxed (e.g., semiconductor or III-nitride) layer 206, 1704 has a lattice constant that is different than a lattice constant of a growth substrate 202 on which the at least partially relaxed (e.g., semiconductor or III-nitride) layer was grown, such that the at least partially relaxed (e.g., semiconductor or III-nitride) layer 206, 1704 on the growth substrate was coherently strained prior to bonding to the compliant substrate and prior to removal or partial removal of the growth substrate.

14. The device of example 13, further comprising an epitaxial structure 1710 including the at least partially relaxed (e.g., III-nitride) layer 206, 1704, wherein the epitaxial structure is bonded to the compliant substrate.

15. The device of example 14, wherein a surface 408, 1720 of the epitaxial structure exposed by removal of the growth substrate has an opposite polarity to an interface 1722 with the at least partially relaxed III-nitride layer, so as to flip a polarity of the device 1700.

16. The device of any of the examples 1-15, wherein the porous layer comprises silicon, silicon carbide or gallium arsenide CdTe or any other III-V, II-VI or I-III-VI, or group IV semiconductor, oxide material or metal.

17. The device of example 16, wherein the at least partially relaxed layer comprises InP, any composition of AlGaInP, CdZnTe or CdTe or any other III-V, II-VI or I-III-VI, or group IV semiconductor, oxide material or metal.

18. The device of any of the preceding examples, further comprising an at least partially relaxed InGaN layer on or above the at least partially relaxed semiconductor layer comprising InGaN, the at least partially relaxed InGaN layer on top having a higher indium composition and a larger thickness than the at least partially relaxed semiconductor layer comprising InGaN below.

19. FIGS. 2a and 2b illustrate a method of making a device 200, comprising: growing a first III-nitride layer 260 on or above a substrate 202; and growing a second III-nitride layer 206 on or above the first III-nitride layer 260, wherein the second III-nitride layer is coherently strained; and forming 210 pores in the first III-nitride layer 260, so that the second III-nitride layer 206 becomes relaxed or at least partially relaxed.

20. The method of example 19, wherein the forming comprises etching (e.g., electrochemical etching EC) the pores.

21. FIG. 8 illustrates the method of example 19, further comprising:
growing a p-type GaN layer 802 so that the p-type layer is between the first III-nitride layer 260 and the second III-nitride layer 206; and
annealing the p-type layer 802 so as to activate the p-type GaN layer.

22. FIG. 9 and FIG. 16 illustrates a method of making a device 900, 1600, comprising:
growing a III-nitride layer 1602, 902 on or above a growth substrate 1604, 904 wherein the first III-nitride layer is coherently strained;
bonding the III-nitride layer directly or indirectly to a compliant substrate 1606, 906;
removing the growth substrate 1604 or at least partially removing the growth substrate from the III-nitride layer, so that the III-nitride layer 1602 becomes relaxed or at least partially relaxed.

23. The method of example 22, further comprising performing a heat treatment to aid relaxation of the III-nitride layer.

24. FIG. 9 illustrates the method of example 19, further comprising growing a p-type GaN layer 908 so that the p-type GaN layer is between the III-nitride layer and the substrate, wherein removing or at least partially removing the growth substrate exposes a surface 910 of the p-type layer having an opposite polarity to an interface 912 of the p-type layer with the III-nitride layer, thereby flipping a polarity of the device 900.

### 10. References for Section I

The following references are incorporated by reference herein
[1] K. Hestroffer, F. Wu, H. Li, C. Lund, S. Keller, J. S. Speck, U. K. Mishra, Semicond. Sci. Technol. 30 (2015) 105015.
[2] S. Keller, C. Lund, T. Whyland, Y. Hu, C. Neufeld, S. Chan, S. Wienecke, F. Wu, S. Nakamura, J. S. Speck, S. P. DenBaars, U. K. Mishra, Semicond. Sci. Technol. 30 (2015) 105020.
[3] A. Even, G. Laval, O. Ledoux, P. Ferret, D. Sotta, E. Guinot, F. Levy, I. C. Robin, A Dussaigne, Appl. Phys. Lett. 110 (2017) 262103
[4] J. W. Matthews and A. E. Blakeslee: J. Cryst. Growth 27 (1974) 118.
[5] Y. Zhangl, S.-W. Ryu, C. Yerino, B. Leung, Q. Sun, Q. Song, H. Cao, and J. Han, Phys. Stat. Sol. B 247 (2010) 1713.
[6] T.-H. Chang, K. Xiong, S. H. Park, G. Yuan, Z. Ma & Jung Han, Scientific Reports 7 (2017) 6360.
[7] A. Nishikawa, T. Kawasaki. N. Furukawa, Y. Terai, Y. Fujiwara, Appl. Phys. Express 2 (2009) 071004.
[8] S. M. Bedair, J. M. Zavada, N. El-Masry, IEEE Spectrum, November 2010, p. 45.

### II. METHODS FOR ACHIEVING MONOLITHIC INTEGRATION OF COLOR TUNABLE LIGHT EMITTING DIODES (LEDS) WITHOUT ETCH DAMAGE OR WITH MINIMAL ETCH DAMAGE AND INCLUDING AN IMPROVED METHOD FOR RELAXING SEMICONDUCTOR FILMS FOR THE FABRICATION OF PSEUDO-SUBSTRATES

### 1. Introduction

High quality and highly efficient displays will form the backbone of an immersive digital experience. With the advent of near-eye display technologies such as augmented reality (AR), virtual reality (VR), and the expansion of mobile electronics, energy-efficient and monolithically integrated display technology is required to produce efficient, color-tunable, and lightweight displays. The incumbent display technologies such as the OLEDs, LCDs suffer from energy inefficiency. Consequently, Indium Gallium Nitride (InGaN) alloy based micro-LEDs have gained increased attention in the past few years to provide highly efficient display solutions. The III-N-based alloys, with its direct bandgap from about 0.7 eV (InN) to 6.2 eV (AlN), covers the entire visible spectrum and are ideal for monolithic integration of red, blue, and green (RBG) LEDs. Also, by relying on just one type of material system, besides the chip-level performance improvement, significantly lower manufacturing cost can be realized. While InGaN based blue and green LEDs have been demonstrated, red nitride based LEDs lag behind in efficiency compared to their blue and green counterparts. For this reason, scaled red micro-LEDs based on Aluminum Gallium Indium Arsenide/Phosphide (AlGaInP) have been used instead, which, however, suffer from low external quantum efficiency due to inefficient carrier confinement and high surface recombination velocity. Nitrides based red micro-LEDs with its high carrier confinement and relatively lower surface recombination velocity can solve this problem.

### 2. Technical Description

The present invention allows the fabrication of nitride based micro-LEDs (or LEDs) with minimal to no etch damage. This fabrication technique can be extended to achieve emission of any color (e.g., blue, green, or red) either individually or a combination.

In one embodiment of present invention, the LED epitaxial structure is regrown on a on a III-N patterned substrate. The shape and size of the pattern on the substrate can mimic the dimension of the desired LED shape and size. The patterned substrate (on which regrowth is to be performed) can be achieved in such a way that it restricts the LED structure epitaxial growth on the pattern (to a large extent). Thus, the epitaxial structure obtained post regrowth is self-isolated and can be used to fabricate LEDs without (or with minimal) etch damage. By using porous GaN based patterns with different sizes (for example, 5 μm, 10 μm and 15 μm), the degree of InGaN relaxation can be varied, resulting in different indium composition in the quantum wells (QWs) grown on differently sized patterns (on the same wafer) resulting in emissions at different wavelengths [1]. We have described in great detail how porous GaN can be used to obtain different degree of Indium incorporation in the QWs with a tile geometry [1, 2]. This method allows for the fabrication of color tunable monolithically integrated highly efficient micro-LEDs. In addition, herein an improved method for relaxing semiconductor films using porous GaN is presented.

Embodiments of the present invention are particularly attractive for the fabrication of micro-LEDs, where etch damage can result in extremely low LED efficiency.

### 3. First Example

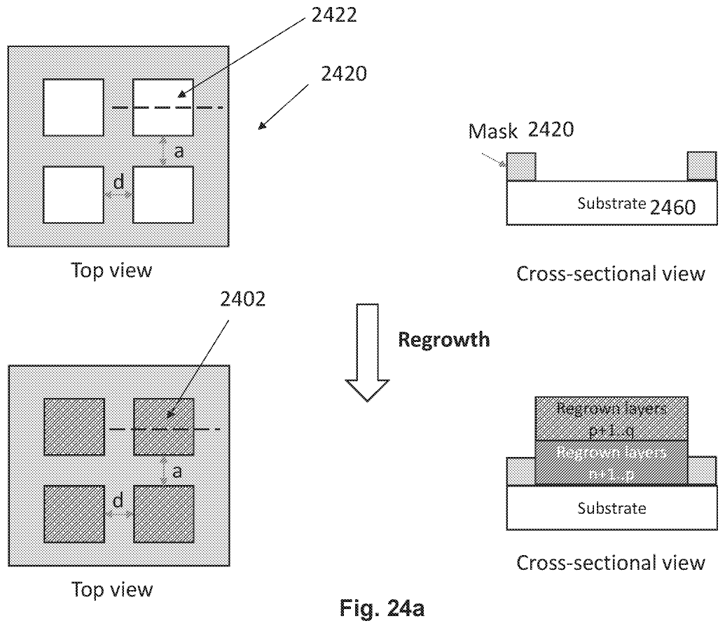

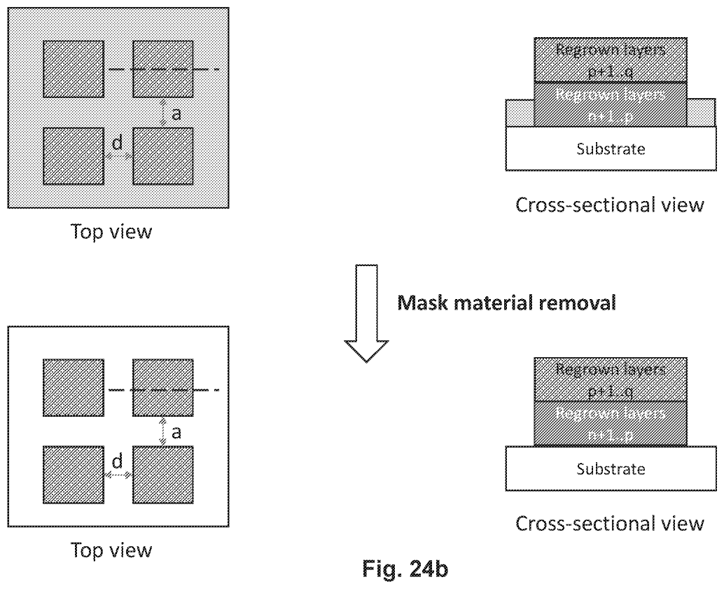

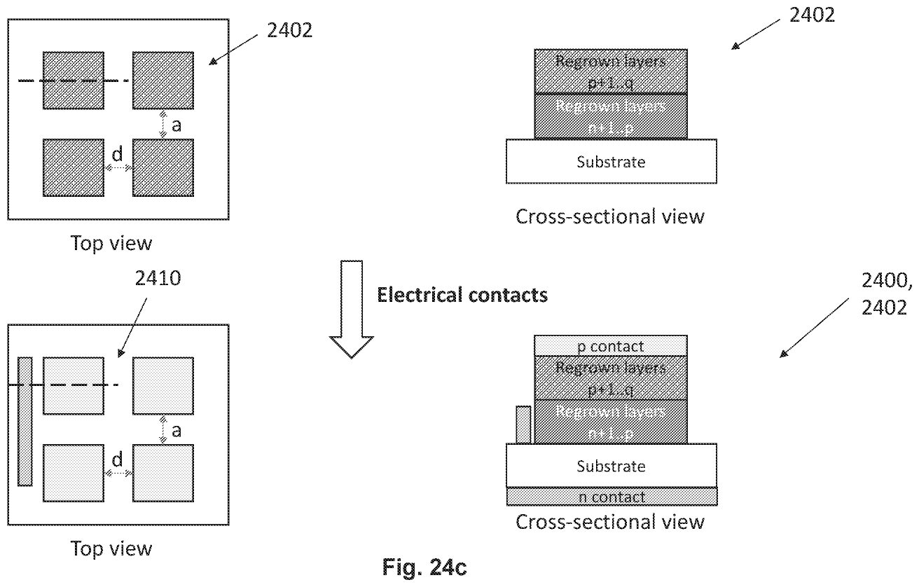

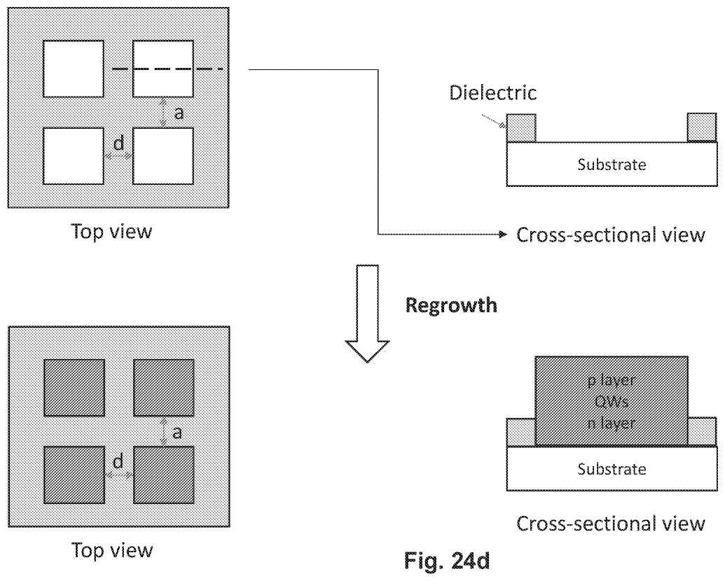

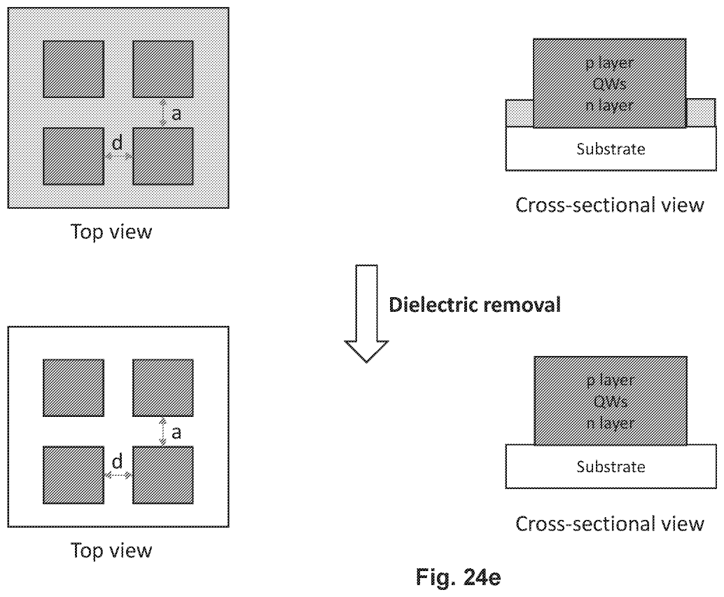

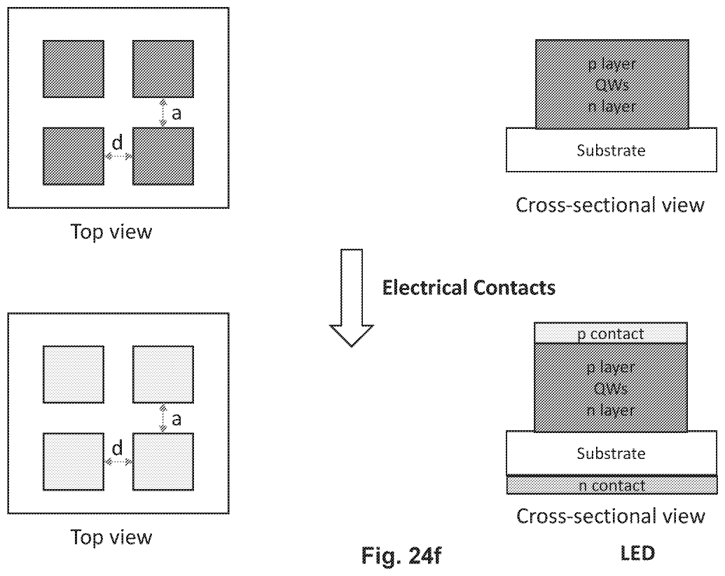

In one embodiment of the present invention, on a substrate which may or may not be homogenous, e.g., bulk n-GaN, or n-GaN on a foreign substrate such as sapphire, silicon, or SiC, for example, first a selective area growth (SAG) of III-Nitride (III-N) layers is performed (FIG. 24a). The masked material may constitute insulators, dielectrics, metals, semiconductors or any other material or combination of different materials which restricts the growth of III-N on the masked material compared to the substrate. The III-N layer thickness with respect to the thickness of the mask material may be equal, more, or less. The III-N layers constituting LED epitaxial structure will result in a self-isolated etch damage free LED structure. FIG. 24b illustrates masked material removal in the case of selective area growth or re-growth.

In one fabrication process, a conductive substrate can be utilized where ohmic contacts can be formed on the top of the SAG epitaxial structure and at the backside of the substrate or on the substrate (as shown in FIG. 24c) to form a etch damage free LED. Here, different dimension, shape and size SAG openings may be utilized to achieve LEDs with different color. Specific LED examples for this embodiment is shown in FIG. 24d-f. In one or more examples, the selective are deposition process can/may result in enhanced indium incorporation in the open areas, aided by the formation of non-c-plane facets during regrowth.

### 4. Second Example

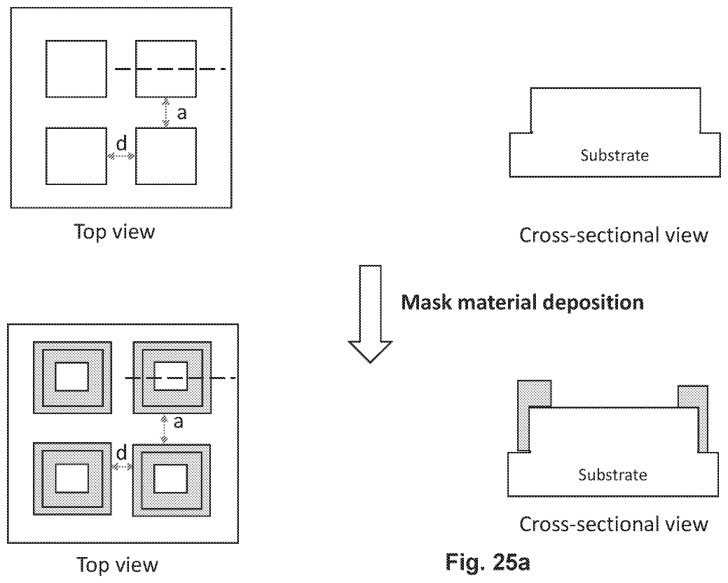

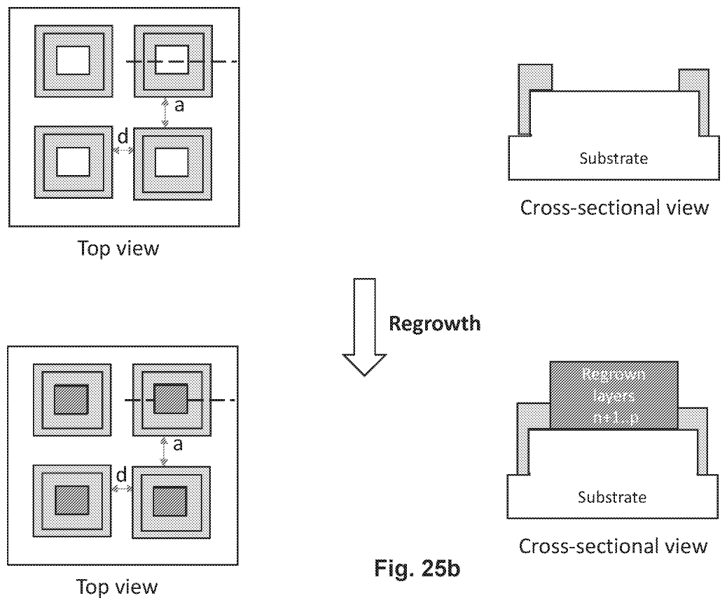

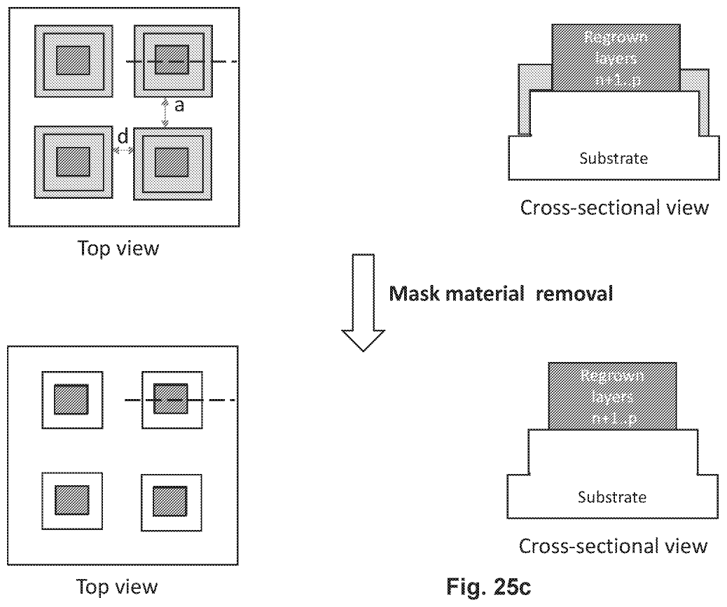

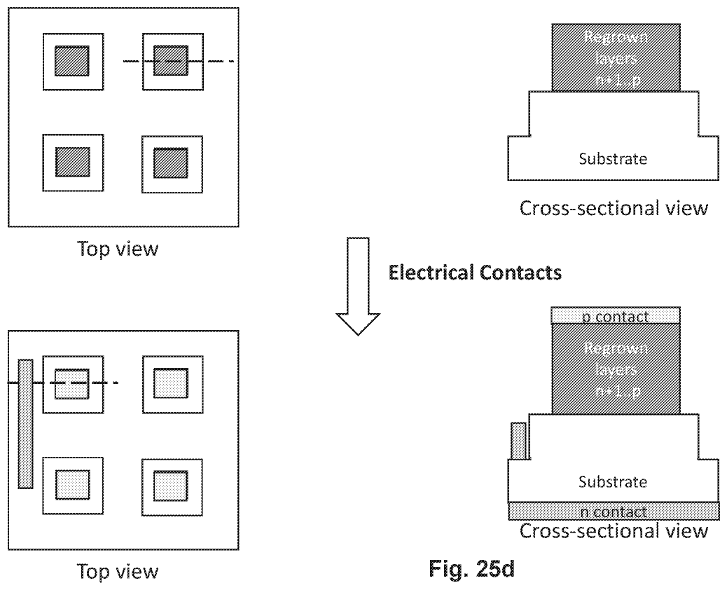

In another embodiment of the present invention, on a substrate which may or may not be homogenous, e.g. bulk n-GaN, or n-GaN on a foreign substrate such as sapphire, silicon, or SiC, for example, a homogenous pattern or patterns with varied and desired dimensions and shape are fabricated. Thus, a patterned substrate is obtained (FIG. 25a). Thereafter, on the patterned substrate, a selective area growth (SAG) of III-Nitride (III-N) layers is performed (FIG. 25b). The masked material may constitute insulators, dielectrics, metals, semiconductors or any other material or combination of different materials which restricts the growth of III-N on the masked material compared to the substrate. The III-N layer growth thickness with respect to the thickness of the mask material may be equal, more, or less. The III-N layers constituting LED epitaxial structure will result in a self-isolated etch damage free LED structure (upon masked material removal in the case of selective area growth or re-growth, as shown in FIG. 25c). In one exemplary fabrication process, a conductive substrate can be utilized where ohmic contacts can be formed on the top of the SAG epitaxial structure and at the backside of the substrate or on the substrate as shown in FIG. 25d to form a etch damage free LED. Here, different dimension, shape and size SAG openings may be utilized to achieve LEDs with different color as the indium content in the InGaN layers can/may depend on the pattern size and the fill factor, which describes the ratio between open and mask area, and the formation of non-c-plane facets during regrowth.

### 5. Third Example

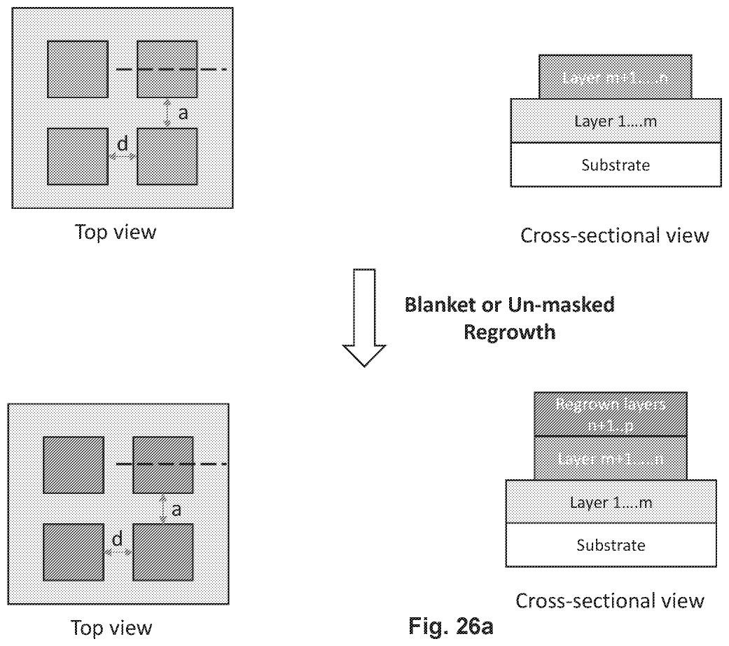

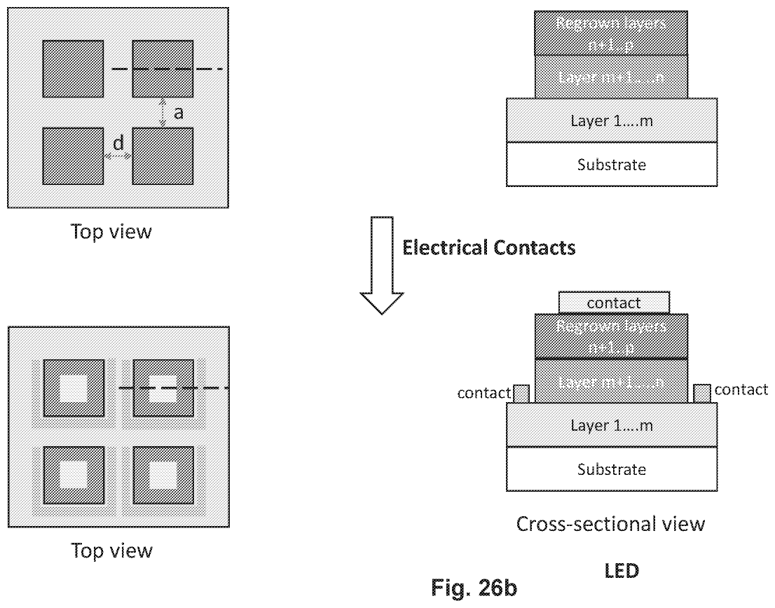

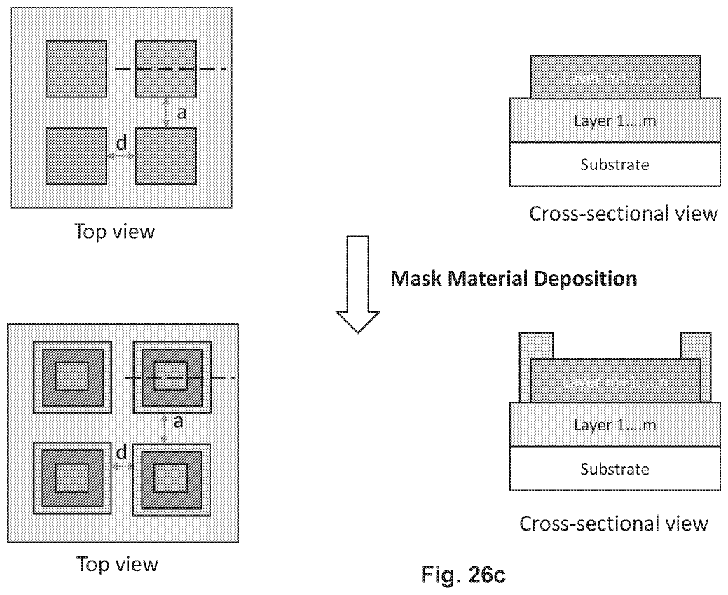

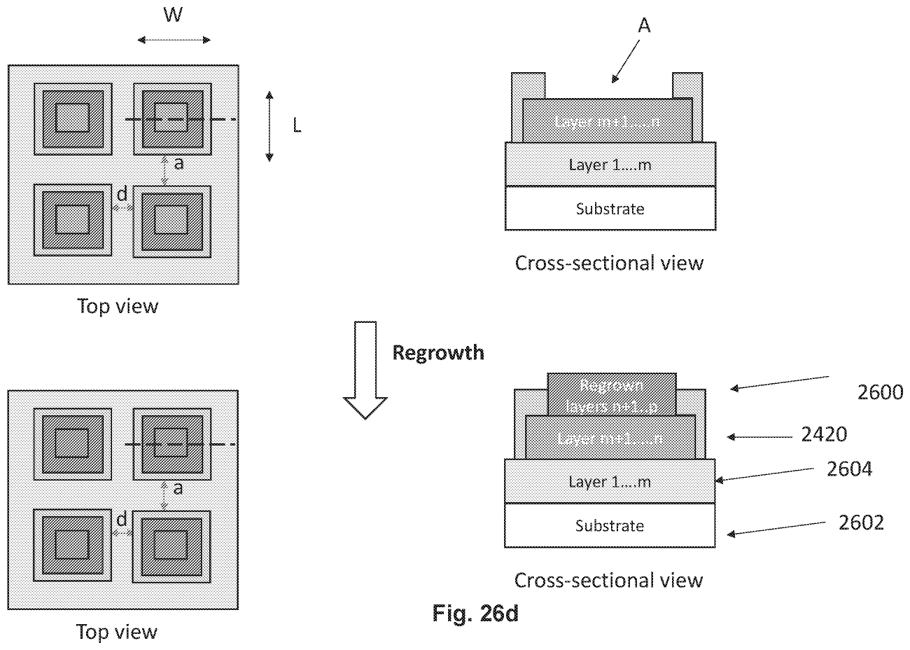

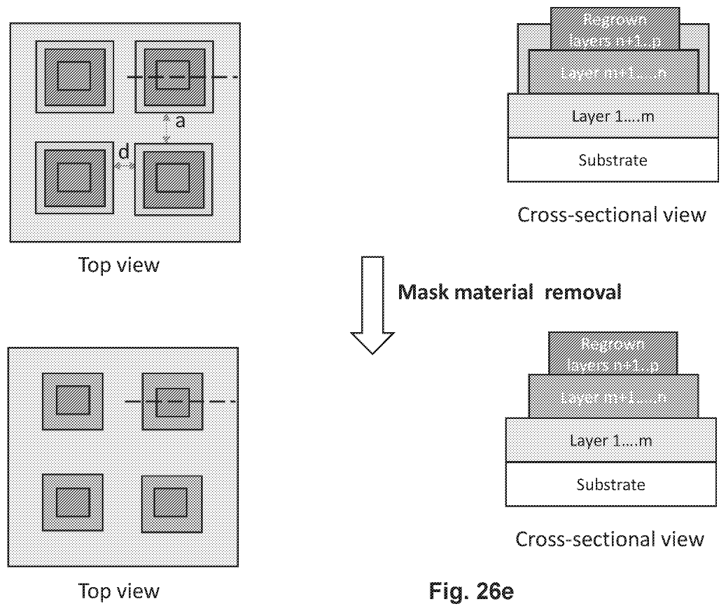

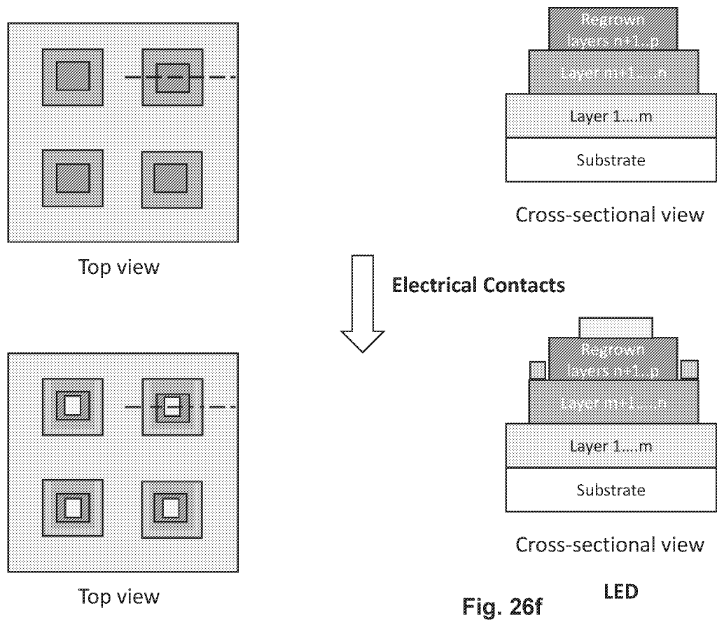

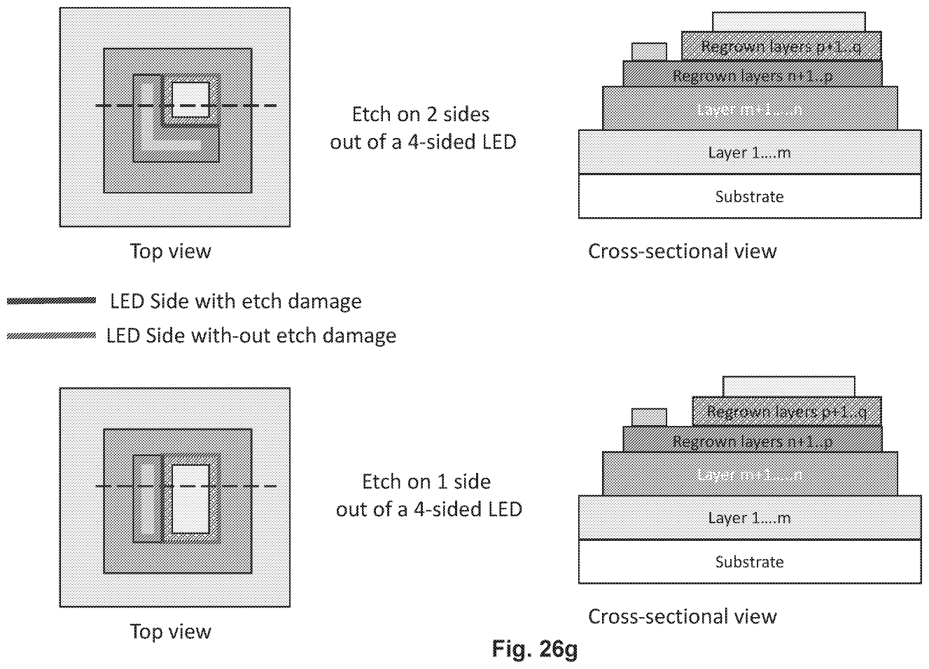

In a further embodiment of the present invention, on a substrate which may or may not be homogenous, first a III-Nitride (III-N) layer or layers are grown and patterned to produce homogenous patterns or patterns with varied and desired dimensions and shape. One or more of the III-N layers may or may not be porous. Thus, a patterned substrate consisting of III-N layers on the top is fabricated (FIG. 26). The pattern fabrication process on the III-N layer may utilize either dry etch, wet etch, or selective area regrowth. The etch to form patterns may end on the III-N layers (as shown in FIG. 26a) or on the substrate. The III-N layers may or may not be conductive with p- or n-type conductivity. Thereafter, a blanket or masked regrowth of III-N layers may be performed (FIG. 26a and FIG. 26c-e). The III-N layer re-growth thickness with respect to the thickness of the mask material may be equal, more, or less. The III-N regrown layers constituting LED epitaxial structure will result in a self-isolated etch damage free LED structure (upon masked material removal in the case of selective area growth or re-growth). With this self-isolated LED epitaxial structures, LEDs can be fabricated as shown in FIG. 26b and FIG. 26f. In the self-isolated LED epitaxial structures shown in FIGS. 26b and 26f, one electrical contact is made at the top and the second electrical contact may be formed on either Layer 1 . . . m or layer m+1 . . . n as shown in FIG. 26b and FIG. 26f respectively. The second contact may also be formed by etching the regrown layers and on either the regrown layers (as shown in FIG. 26g) or Layer 1 . . . m or layer m+1 . . . n underneath the regrown layers. The etch performed through the regrown layers may involve all n sides or <n sides or no sides of a polygon LED with n-sides (FIG. 26g). In the case of a circular LED pattern, the isolation etch as described above may involve either a circular etch pattern or a chord across the circular LED. Specific LED examples for this embodiment are shown in FIG. 26.

### 6. Fourth Example

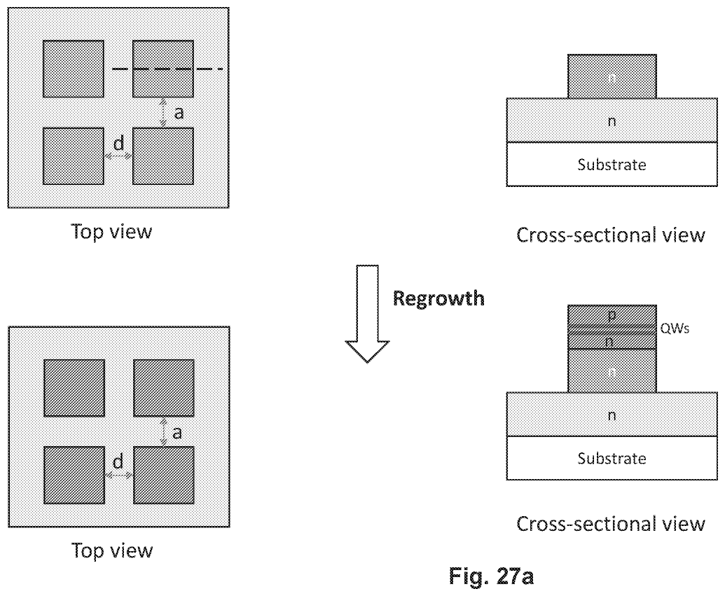

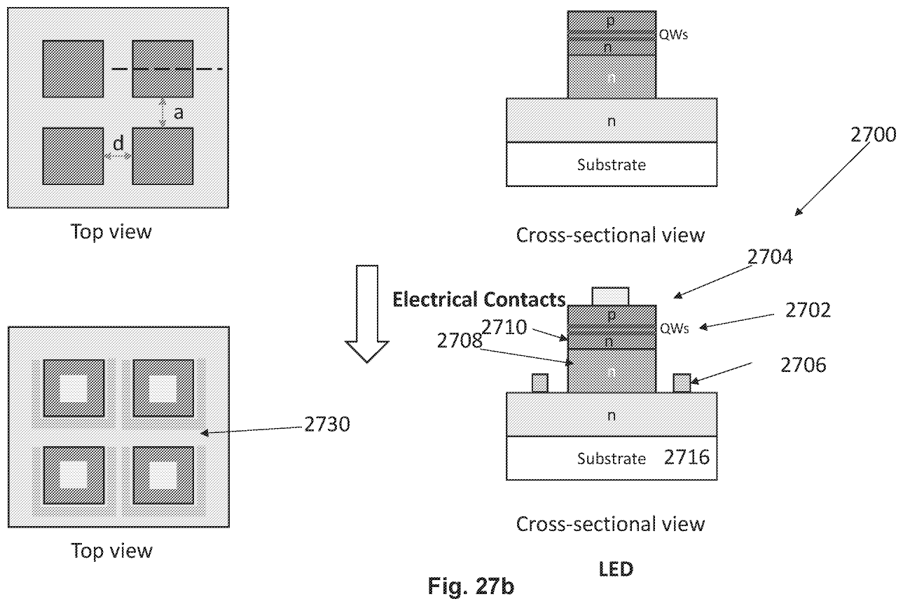

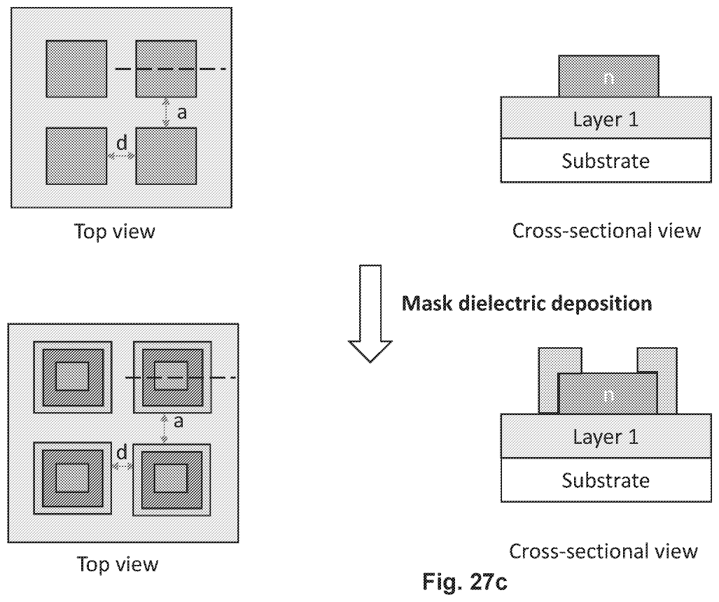

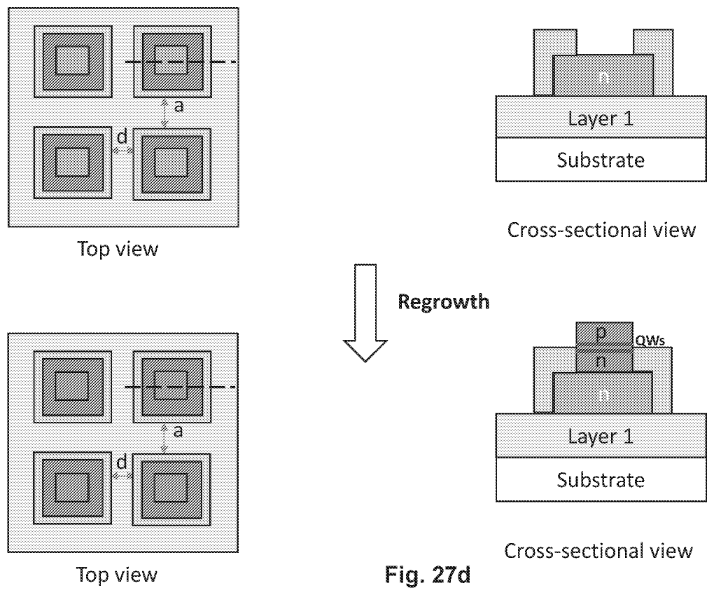

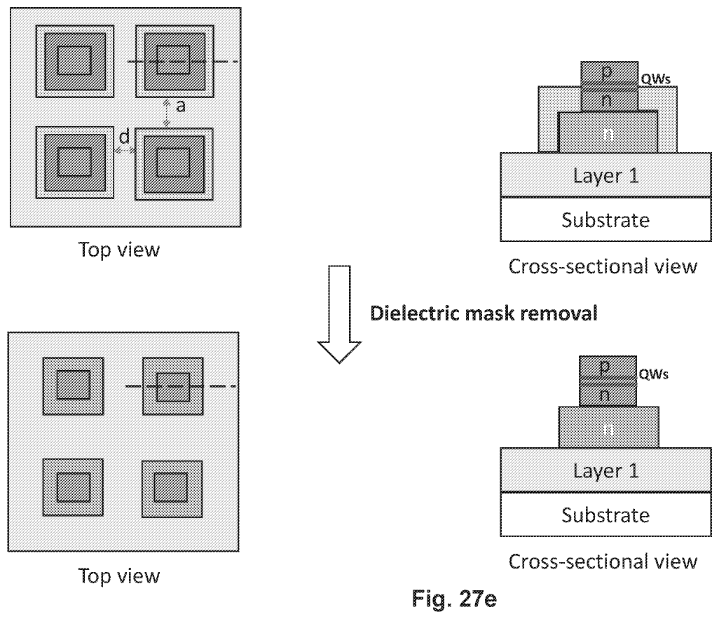

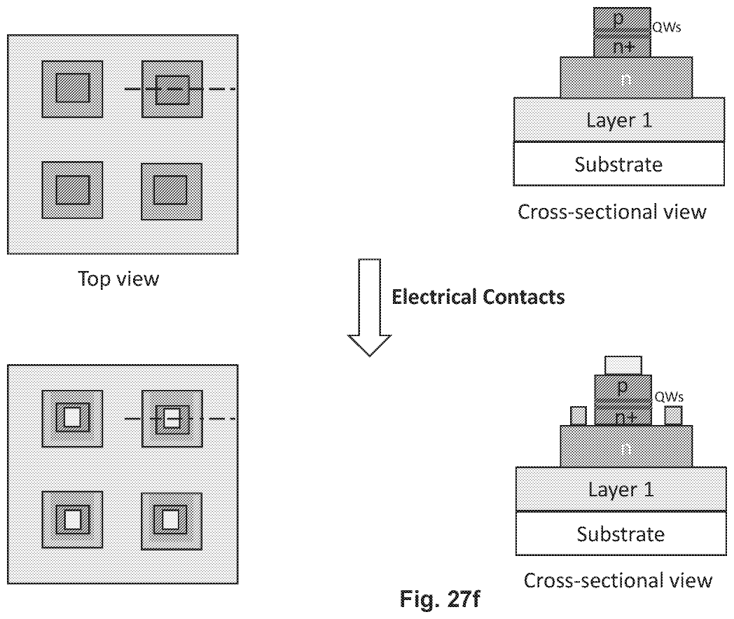

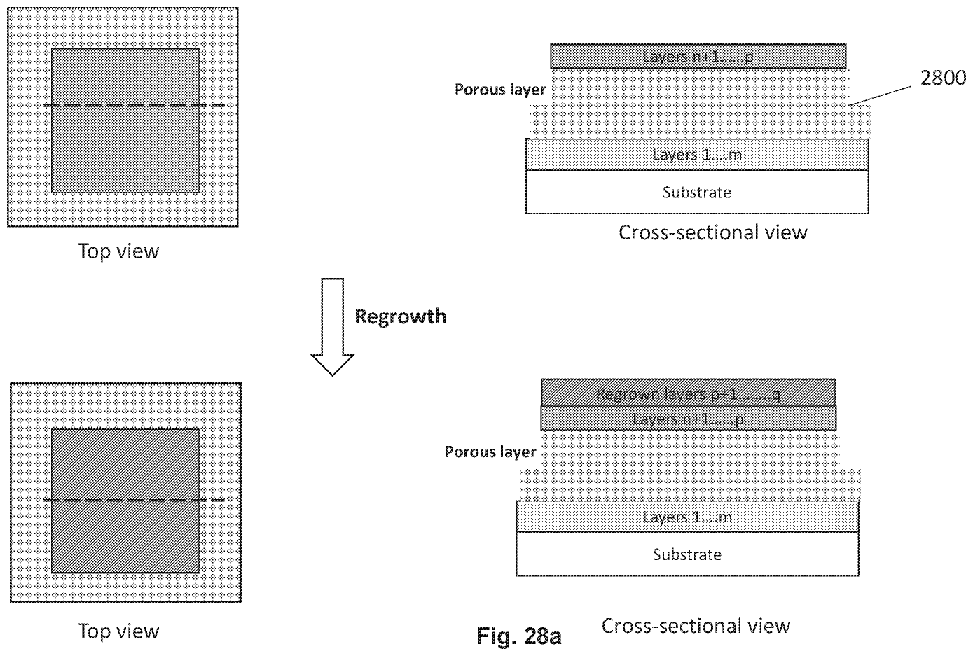

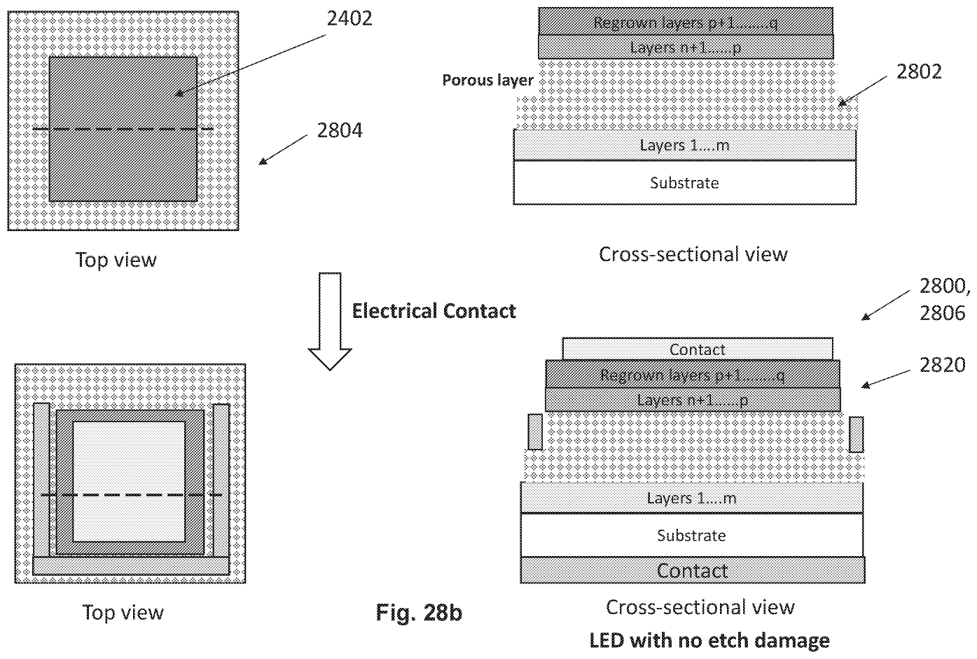

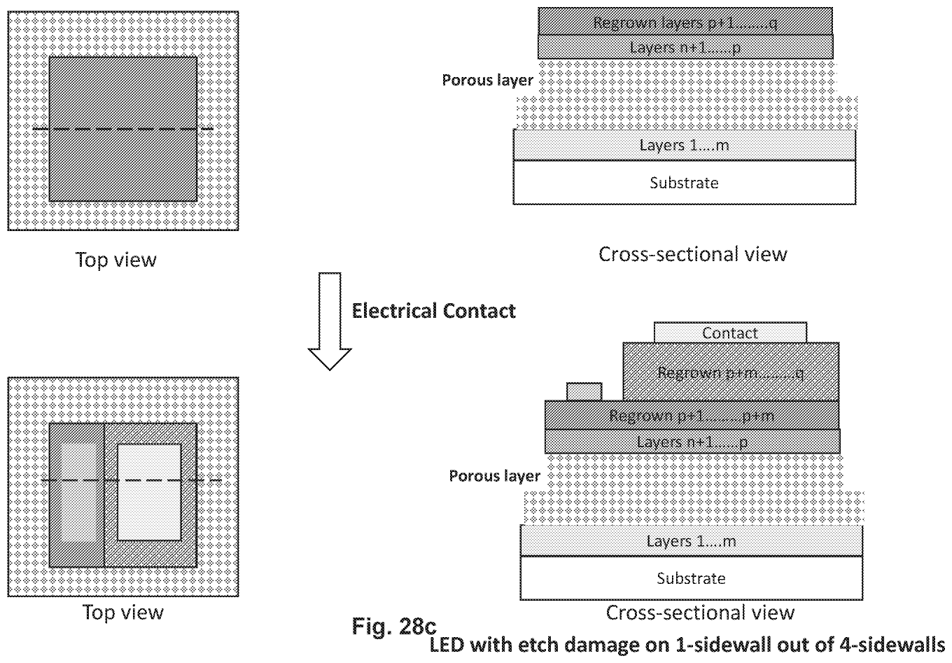

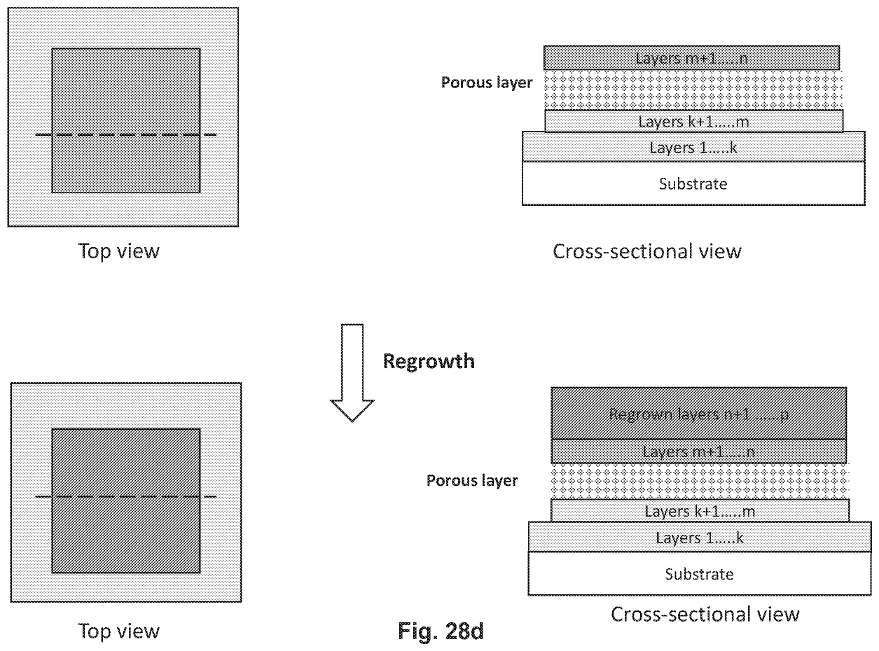

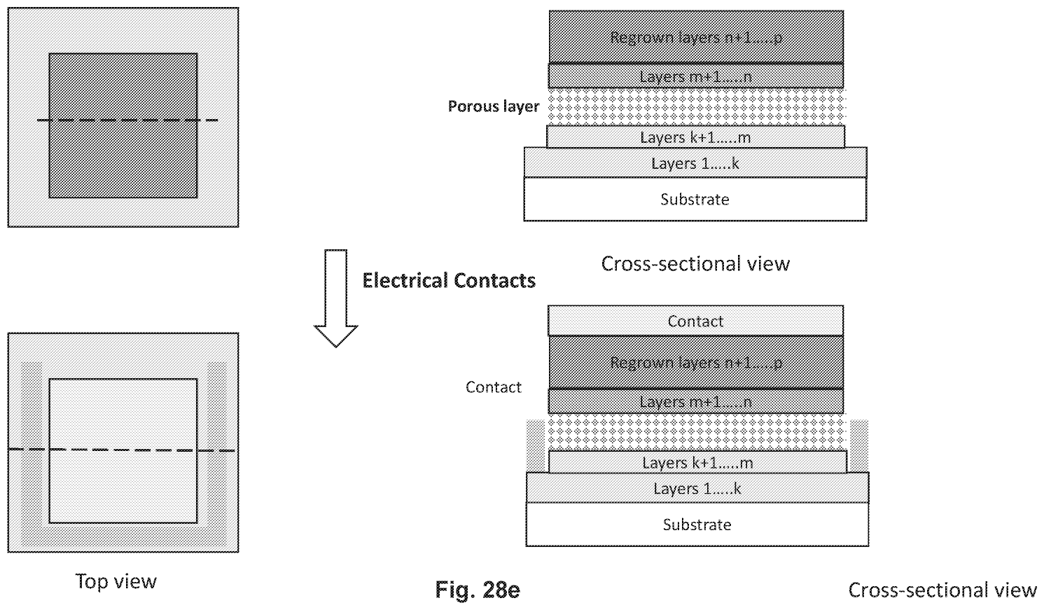

In one embodiment of the present invention, on a substrate which may or may not be homogenous, first a III-Nitride (III-N) layer or layers are grown and patterned to produce homogenous patterns or patterns with varied and desired dimensions and shape. Thereafter, an electro-chemical etch is performed to obtain one or more than one porous III-N layer or layers respectively. The top layer on the pattern may or may not be porous III-N material. The bottom region may or may not be porous III-N material (as shown in FIG. 27a and FIG. 27d respectively). Thereafter, a blanket or masked regrowth of III-N layers may be performed as described above. The III-N layer re-growth thickness with respect to the thickness of the mask material may be equal, more, or less. The III-N regrown layers constituting LED epitaxial structure will result in a self-isolated etch damage free LED structure (upon masked material removal in the case of selective area growth or re-growth) (FIG. 27a). The regrowth on the porous region may not affect the regrowth on the layers n+1 . . . p and the subsequent optical device formed on the regrown layers. In the self-isolated LED structures shown in FIG. 27a), one contact is made at the top and the second contact may be formed on the porous layers (FIG. 27b), backside of the substrate (FIG. 27b) or on layers 1 . . . m (FIG. 27e). The second contact may also be formed by etching the regrown layers and on either the regrown layers (p+1 . . . p+m) or Layer n+1 . . . p (FIG. 27c). The etch performed through the regrown layers may involve all n sides or <n sides or no sides of a polygon LED with n-sides (FIG. 27c). In the case of a circular LED pattern, the isolation etch as described above, may involve either a circular etch pattern or a chord across the circular LED. Specific LED examples for this embodiment is shown in FIG. 28a-d.

### 7. Fifth Example

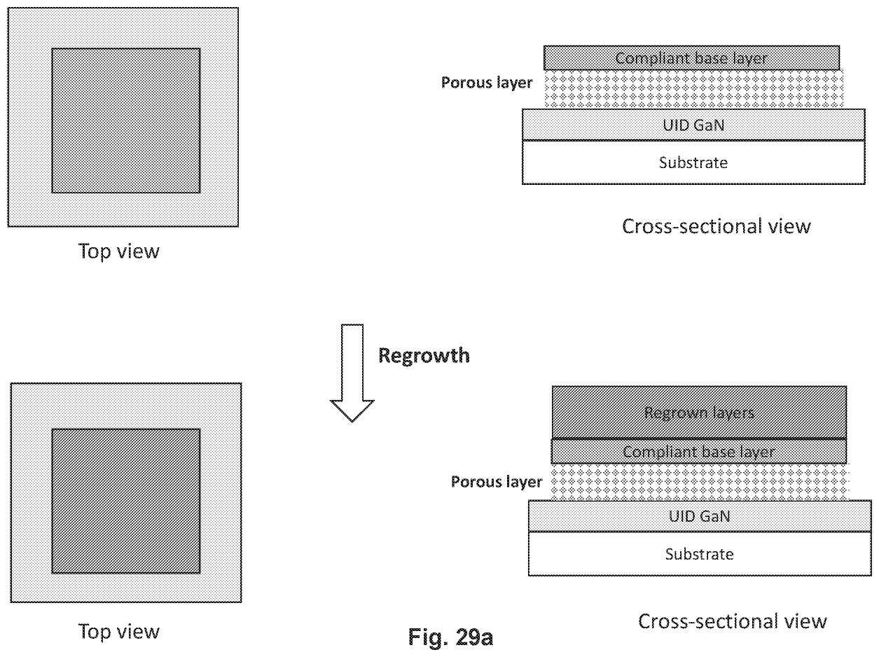

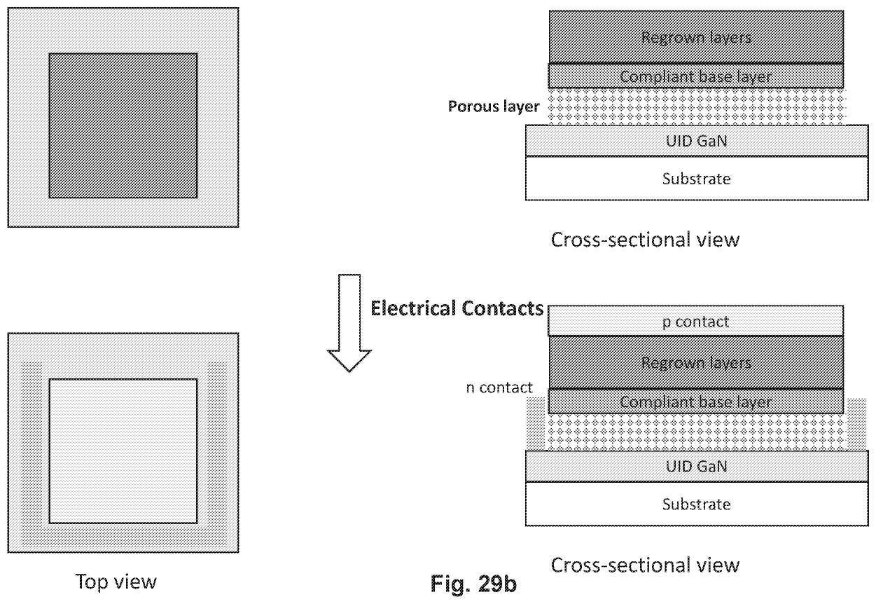

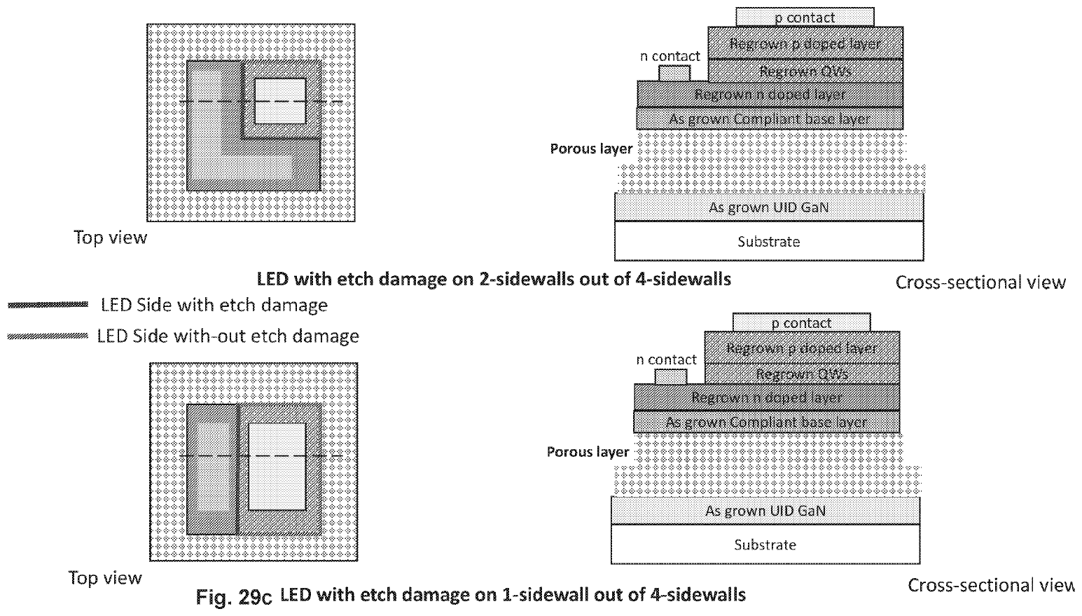

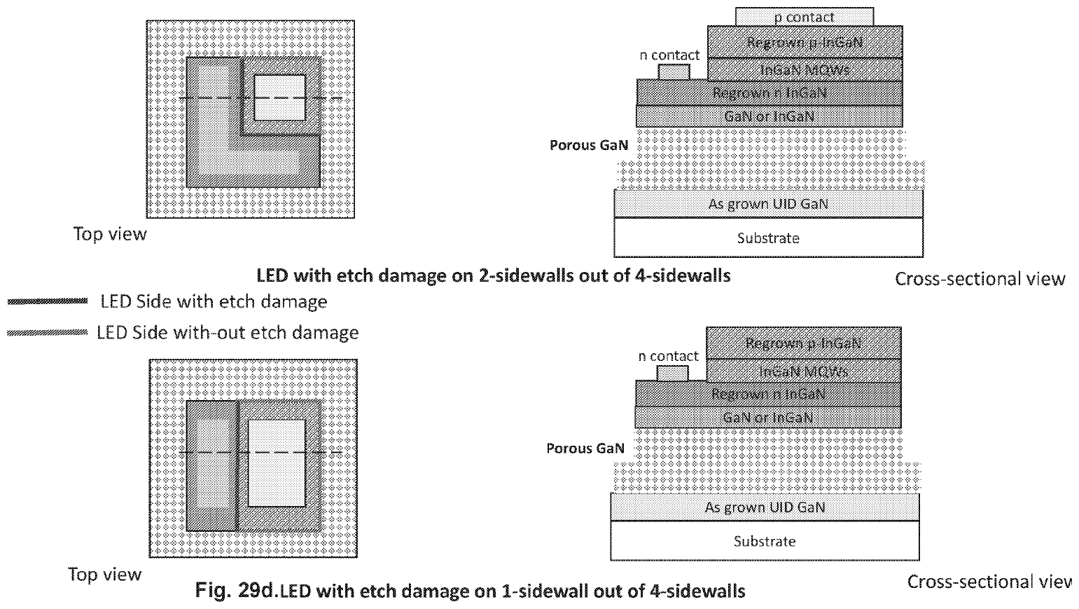

In one embodiment of the present invention, on a substrate which may or may not be homogenous, first a III-Nitride (III-N) layer or layers are grown and patterned to produce patterns with varied dimensions. Thereafter, an electro-chemical etch may be performed to obtain one or more than one porous III-N layer or layers respectively. The top layer on the pattern may or may not be porous III-N material. The bottom region may or may not be porous III-N material. Thereafter, a blanket or masked regrowth of III-N layers may be performed. A different dimension of the pattern may result in a different compliant nature of the porous III-N material underneath. The compliant nature of the porous material underneath can also be varied with the pore density or porosity. Therefore, each pattern on the wafer can be designed to have its unique compliant porous III-N layer. This unique compliant nature will result in a varied degree of the strain-relaxation of the layers grown or regrown on top of the porous III-N layer. By utilizing this varied degree of strain-relaxation, multi quantum wells (MQWs) with different indium or III-N composition may be obtained which will eventually result in light emission at different wavelengths. Therefore, the regrown epitaxial layers on varied pattern dimensions with porous III-N layer underneath will result in LED structures with capability to emit at different wavelengths on the same wafer. These layers may or may not self-isolated. The electrical contact scheme can follow the same method as described in the previous embodiment (FIGS. 27 and 28). Specific LED examples for this embodiment is shown in FIG. 29.

### 8. Sixth Example

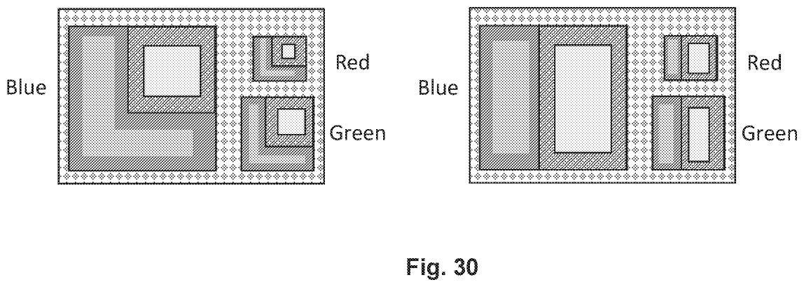

In one embodiment of the present invention, on a substrate which may or may not be homogenous, first a III-Nitride (III-N) layer or layers are grown and patterned to produce homogenous patterns or patterns with varied and desired dimensions and shape. Thereafter, an electro-chemical etch is performed to obtain one or more than one porous III-N layer or layers respectively. The top layer on the pattern is porous III-N material. The bottom region may or may not be porous III-N material (as shown in FIGS. 30a and 30c respectively). Thereafter, a blanket or masked regrowth of III-N layers may be performed as described above. The III-N layer re-growth thickness with respect to the thickness of the mask material may be equal, more, or less. The III-N regrown layers constituting LED epitaxial structure will result in a self-isolated etch damage free LED structure (upon masked material removal in the case of selective area growth or re-growth) (FIG. 30a and FIG. 30c). In the self-isolated LED structures shown in FIG. 30a, one contact is made at the top and the second contact may be formed on the backside of the substrate or on layers 1 . . . m (FIG. 30b). In the self-isolated LED structures shown in FIG. 30c, one contact is made at the top and the second contact may be formed on the backside of the substrate or on the porous layer (FIG. 30d). The second contact may also be formed by etching the regrown layers and on the regrown layers (as described above). The etch performed through the regrown layers may involve all n sides or <n sides or no sides of a polygon LED with n-sides.

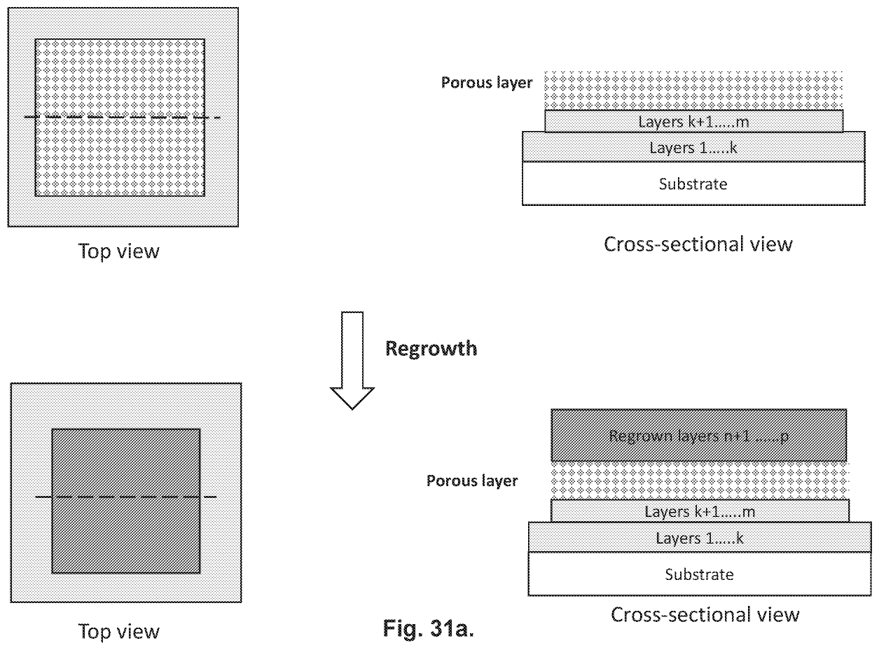

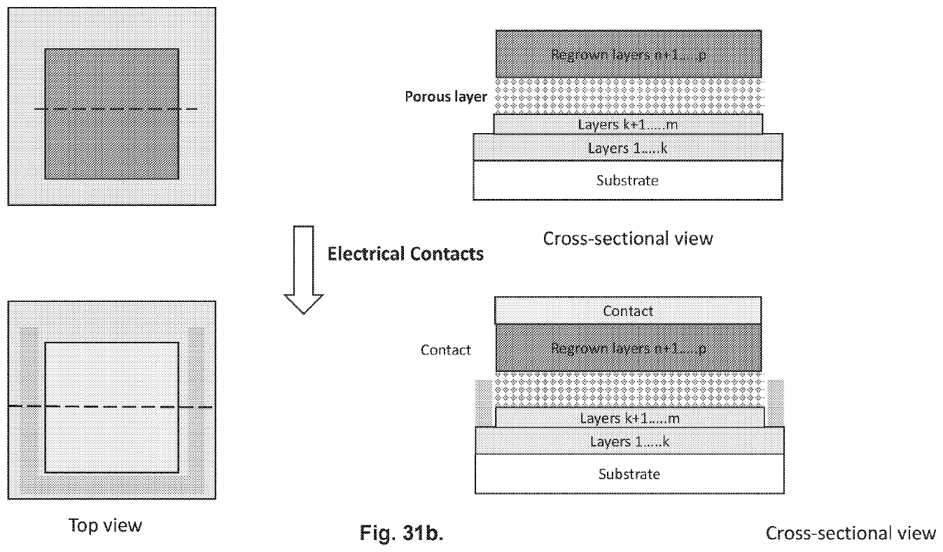

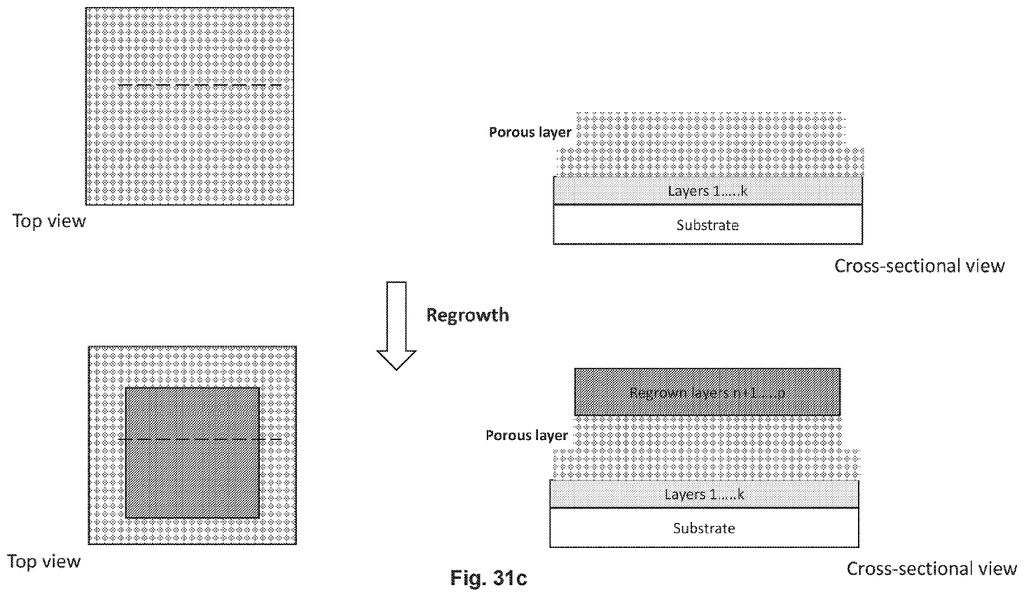

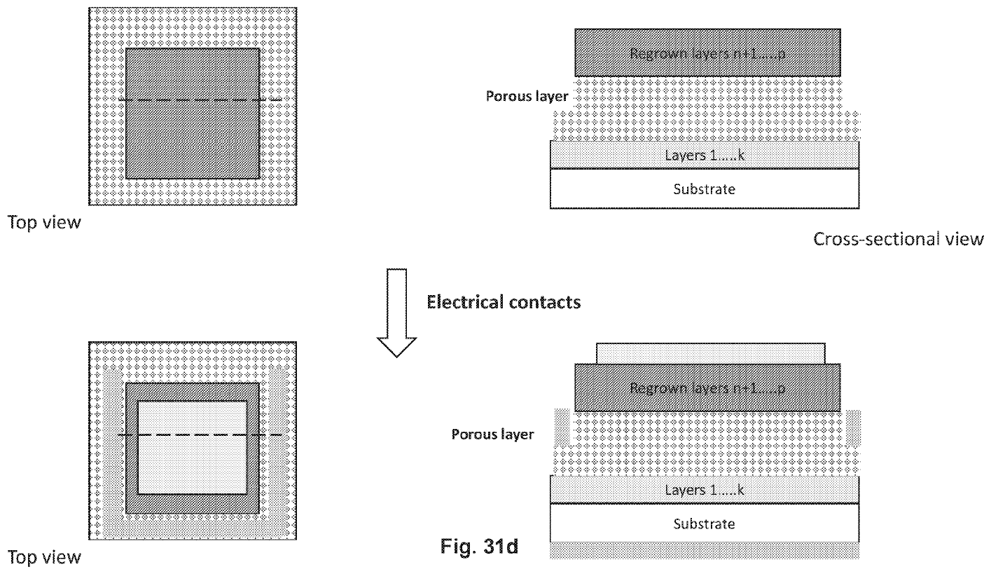

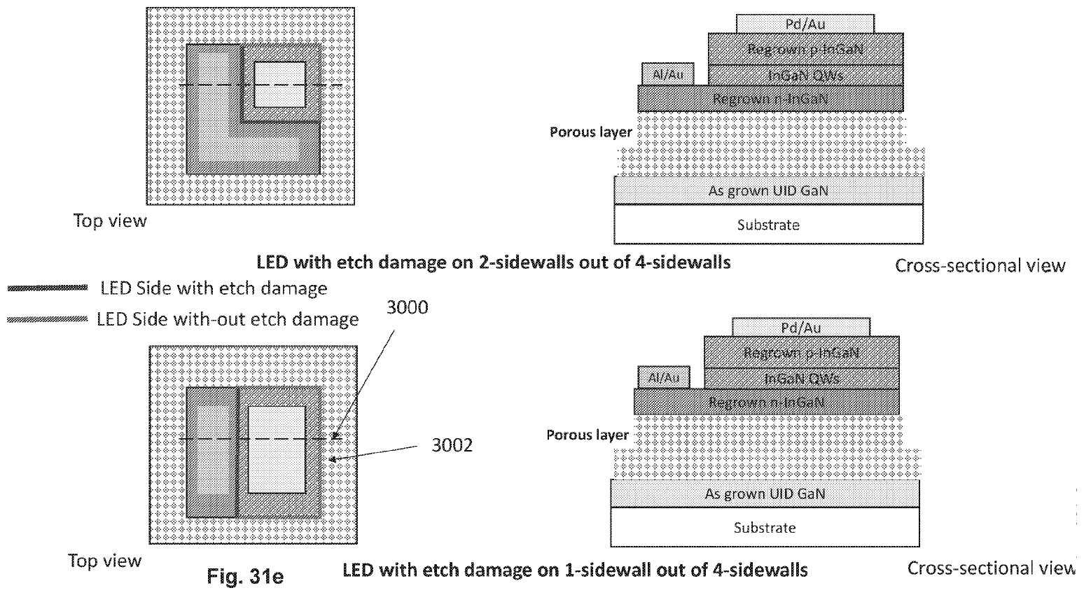

In the case of a circular LED pattern, the isolation etch as described above, may involve either a circular etch pattern or a chord across the circular LED. Specific LED examples for this embodiment is shown in FIG. 31e.

### 9. Possible Modifications and Variations

1. Substrate in the text above may refer to a substrate or a substrate with III-N layers grown or deposited.

2. The wafer area minus the patterned region may not play a role in the optical device due to the quality of the regrowth on that area. For example, the growth on the porous region (in FIG. 27a) may not affect the device layers grown on top of layers n+1 . . . p.

3. The regrowth of the epitaxial structures on a patterned substrate may result in an inclined or a straight sidewall which can be a crystallographic plane (m-plane or a-plane for example) or a combination of different crystallographic planes such as semi-polar planes. The regrowth may also occur on the sidewalls on the epitaxial structure.

4. The regrowth on the sidewall may be fully or partially utilized to inject carriers from the sidewall into the quantum wells.

5. The top contact may be electrically connected with the contact on the sidewall used for injection of carriers into the quantum wells. It may utilize a damage free planarization method to avoid contacting the entire sidewall instead contacting the desired portion of the sidewall.

6. Any fabrication process can be utilized on a self-isolated LED structure as described above to produce LEDs. The advantage of minimal to no etch damage results from self-isolated LED structure. Due to device design considerations, if an isolation etch is needed either to isolate the devices or to make n- or p-type contact to a conductive layer on the patterned region, the isolation etch may involve all n sides or <n sides or no sides of a polygon LED with n-sides. In the case of a circular LED pattern, the isolation etch as described above, may involve either a circular etch pattern or a chord across the circular LED.

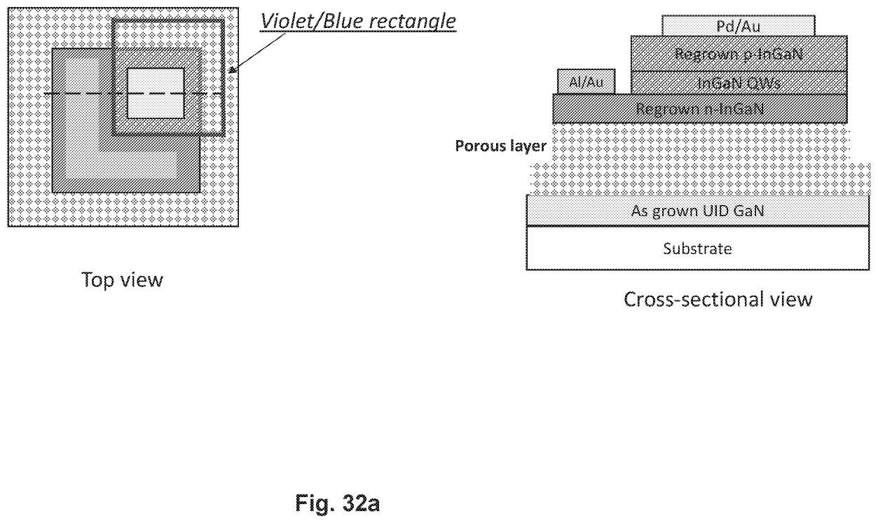

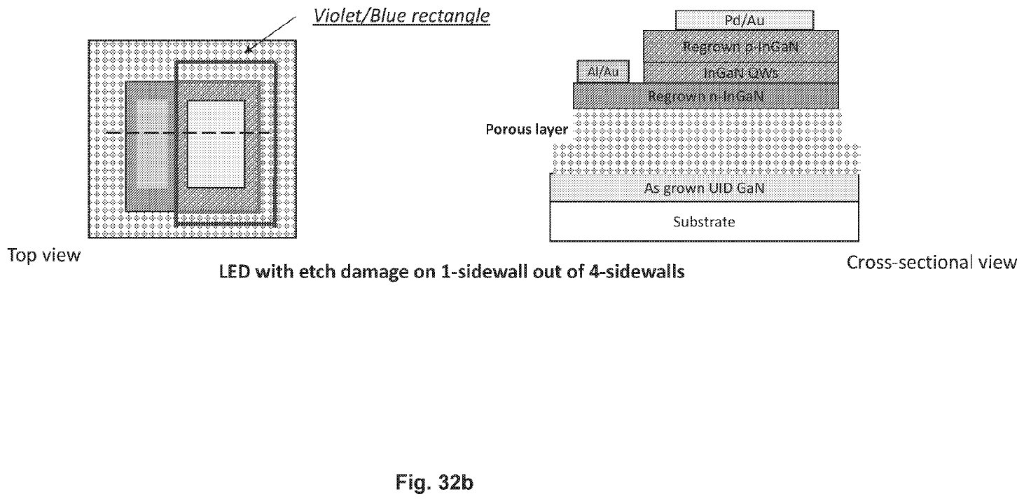

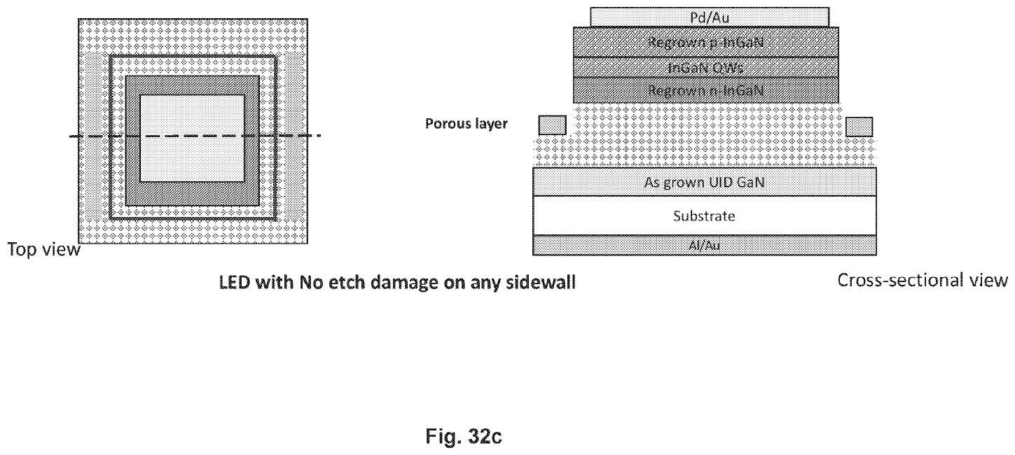

7. The isolation etch may partially utilize the regrown area and partially the area outside the regrown layers to minimize the impact of the etch damage on the sidewalls. The isolation may be performed completely inside and/or outside and/or on the regrown area to achieve varied device designs. Some examples of these designs are shown in FIG. 32.

8. The regrown LED structure may have a tunnel-junction at the top and can be activated from the sidewall. The activation process in a tunnel junction LED may require an isolation etch. The isolation etch, thus performed, may involve all n sides or <n sides or no sides of a polygon LED with n-sides. In the case of a circular LED pattern, the isolation etch as described above, may involve either a circular etch pattern or a chord across the circular LED.

9. Post-regrowth on the patterned substrate, a standard or innovative flip-chip LED fabrication process may also be utilized to obtain LEDs with etch-damage free sidewalls.

10. The contact to both n- and p-type layers can be metals, transparent oxides or a combination of both.

11. The porous layers described above can be used as DBR or mirrors to increase light extraction from LEDs.

12. The pattern dimension can be varied to allow varied Indium incorporation in the QWs for different LED patterns resulting in different color emissions.

13. The masked material may constitute insulators, dielectrics, metals, semiconductors or any other material or combination of different materials which restricts the growth of III-N on the masked material compared to the substrate. The III-N layer growth thickness with respect to the thickness of the mask material may be equal, more, or less.

14. The method can be applied to any orientation (and polarity) of the crystal under consideration, for example c-, m-, a-, and all semi-polar GaN orientations.

15. Any individual layer or layers can be replaced by multi-layer-stacks (multi quantum wells, super-lattices, graded layer).

16. The film deposition can be performed by any crystal growth method, for example metal organic chemical vapor deposition (MOCVD), molecular beam epitaxy (MBE), hydride vapor phase epitaxy (HVPE), pulse laser deposition (PLD), or sputtering.

17. The etching process discussed above to form the vias or trenches can be conducted by any technique, for example reactive ion beam etching or focused ion beam etching. If desired also wet etching, including electrochemical etching, or any combination of etching techniques can be used.

18. If desired, the feature size and geometry created by etching can be chosen in such a way that additional effects, such as light extraction/or absorption via photonic crystals can be utilized.

19. Similarly, the pattern shape can be designed in such a way that a uniaxial strain is generated in the layers above the porous GaN layer. For example, in long ridges, the top layer(s) will relax perpendicular to the stripe direction, while staying strained along the ridge. Furthermore, features can be designed to obtain any degree of relaxation in any direction. For example, square shape to achieve equal partial or full biaxial relaxation, hexagonal shape to obtain high packing density.

20. If desired, the layer stack above the porous layer which includes the active part of the device structure can be lifted off from the base wafer allowing, for example, reusing the GaN bulk substrate the layer stack was chosen to be grown on. This can be done via etching holes (vias) and/or other patterns (stripes/rectangles/circles). The latter would be attractive for micro-LEDs.

21. (j) If desired the porous layer can be treated in such a way that it cannot be deformed any longer, “freezing in” the lattice constant. This can be performed by, for example, heating up the sample or filling the pores with a suitable substance.

22. If desired, prior to growths on the substrate and/or regrowth on porous III-N material or with porous III-N material underneath, the wafer can undergo surface treatments such as polishing, etching, wet etch etc.

23. If desired, post regrowth on porous III-N material, the layer stack above the porous layer which includes the active part of the device structure can be lifted off from the base wafer via etching holes (vias) and/or other patterns (stripes/rectangles/circles). The latter would be attractive for micro-LEDs.

24. If desired, post regrowth on porous III-N material, electronic, photonic etc. devices can be fabricated with an intermediate or final step involving lifting off from the base wafer the (full or partial) layer stack above the porous layer.

25. The film re-deposition on the porous III-N material can also be performed by any crystal growth method, for example metal organic chemical vapor deposition (MOCVD), molecular beam epitaxy (MBE), hydride vapor phase epitaxy (HVPE), pulse laser deposition (PLD), or sputtering.

26. If desired, the porous III-N material layer thermally conductivity can be enhanced by introducing additional material such as diamond slurry etc. This can be performed prior to regrowth or any heat treatment as well.

27. If desired, the porous nature of the III-N layer can be optimized such that to obtain a desired combination of relaxation and mechanical strength. For example, to facilitate regrowth, a certain pore size is required which may not provide full or desired relaxation of the strained layer. The trade-off between mechanical strength, relaxation and thermal conductivity can be optimized to suit different purposes such as regrowth, bonding and transfer etc.

28. The properties of porous III-N layer may change post heat treatment or regrowth.

### 10. Improved Method for Relaxing Semiconductor Films Including the Fabrication of Pseudo-Substrates and Formation of Composites Allowing the Addition of Previously Un-Accessible Functionality to Group III-Nitrides

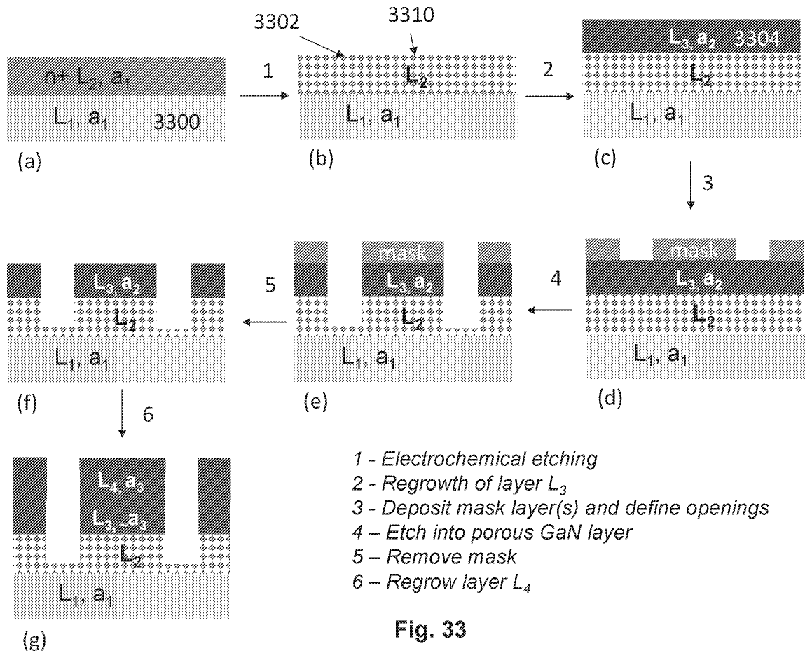

FIG. 33 illustrates a method for the fabrication of relaxed or partially relaxed group III nitride semiconductor films. While such wafers can be fabricated via porosification of a buried layer and lateral etching, here the etching can be performed from the top, significantly simplifying the etching process. In addition, the pore formation is uniform over the entire wafer. In a process using lateral etching of the porous layer, differences in the pore diameter and shape can occur between areas in the center of the “under etched” feature compared to the outer regions. Using the improved method described herein, after etching and fabrication of the porous top layer L2, a thin group III nitride layer L3 is deposited over the entire wafer, coalescing the top pores and forming a smooth film. In the following steps, mask layers are deposited on the wafer in such a way that a trench pattern, for example, can be etched afterwards. Thereby the trenches can penetrate into the bottom layer below the porous layer or just into parts of the porous layer. The pattern can have any shape, but could consist of stripes or squares, for example. Alternately an array of openings can be fabricated, where the openings have a circular shape, for example, or any other suitable shape.

After pattern etching and mask removal, the in plane lattice constant of the top layer (layer 3) is free to change and can adopt a lattice constant a2 different from that of layer L1, a1, below the porous layer. At this stage, the sample structure is the same as in the described in section I.

An additional layer L4, which can be composed of multiple sub layers 11 . . . 1x, is deposited on the patterned wafer. If the lattice constant of layer L4 or the sublayer stack, a4, is different from the lattice constant of layer L3, a3, the lattice constant of layer L3 can change in order to minimize the lattice mismatch between L4 and L3. In the case of a4≥a3, as in the case of InGaN growth on GaN, a3 will increase and allow the fabrication of a relaxed or partially relaxed InGaN layer or layer stack L4. In this scenario, layer L3 can consist of GaN. GaN can be deposited in such a way on the porous GaN layer L2 that a smooth high quality layer forms. After pattern formation, the top GaN layer serves as compliant pseudo substrate, as the lattice constant of the GaN layer L3 expands if, for example, InGaN is deposited on top. The expansion of the GaN layer L3 as has been demonstrated experimentally using GaN-on-porous-GaN samples fabricated using the previous technique based on lateral etching for pore formation.

Using GaN instead of InGaN as a compliant layer on top of the porous layer leads to an improved morphology of the consecutively grown layers, as the GaN top layer is smooth and free of the V-defects often observed for InGaN layers, in particular when grown using metal-organic chemical vapor deposition. The process based on GaN on porous GaN pseudo-substrates is further described in FIGS. 12 to 14, and summarized in FIG. 15.

This method can again be used for the fabrication of pseudo-substrates with larger but also smaller lattice constant compared to GaN, such as (In,Ga)N and (Al,Ga)N pseudo-substrates.

Thereby the method can be applied again also for any crystallographic orientation and any crystalline material system, using any crystal growth technique etc.

The improved method for the fabrication of porous GaN based pseudo-substrates can be used not only for optoelectronic devices such as LEDs, lasers, solar cells, and photodetectors, for example, but also for transistors and other electronic devices with increased functionality.

### 11. Advantages and Improvements

The invention enables the improvement of the performance of III-N opto-electronic devices (e.g., solar cells, light emitting devices, lasers, photodetectors). Embodiments of the present invention allow the fabrication of light emitting diodes (LEDs) (especially micro-LEDs) with minimal etch damage or without etch damage. For display application, micro-LEDs smaller than (10 μm)² are highly desired. However, as LED size decreases, the perimeter to area ratio increases and thus the impact of the etch damage on the device performance becomes significantly more pronounced. The etch damage results in an increased non-radiative recombination and therefore, reduces efficiency of the device, currently hampering the fabrication of micro-LEDs smaller than (10 μm)². As illustrated herein, by re-growing the LED structure on a patterned substrate, the LED can be fabricated in such a way that the need for a (p-n) mesa isolation can be avoided either completely or partially, thereby resulting in a LED with minimal etch damage and high efficiency. By using a porous GaN based patterned substrates, in addition color tunable monolithically integrated highly efficient micro-LEDs can be realized with this invention. In addition an improved process for the fabrication of porous GaN pseudo-substrates is presented, which simplifies the fabrication procedure and increases the pore uniformity.

### 12. Device and Method Examples

1. FIG. 24c and FIG. 27b illustrates a device 2400, comprising:
a growth (e.g., selective area growth (SAG)) 2402 of a III-Nitride forming an array of light emitting devices 2404 having different dimensions and/or strain relaxation, so that each of the light emitting devices include an active region 2702 (e.g. a quantum well QW) having a different indium content and emitting a different wavelength of electromagnetic radiation, wherein the growth 2402 is with or without a mask.

2. FIG. 24c illustrates the device of example 1, wherein the selective area growth comprises the light emitting devices that are isolated 2410 from each other.

3. FIG. 28c illustrates the device 2800 of example 1, further comprising:
a porous layer 2802 including a plurality of regions 2804 having different porosity or pore density; and
the array of light emitting devices 2806 on the porous layer, wherein each of the devices 2806 are on a different one of the regions of the porous layer.

4. The device of example 3, wherein the porous layer comprises a III-nitride layer.

5. FIG. 24a The device of example 1, further comprising a mask 2420, patterned substrate, or patterned layer having different sized openings 2422 or trenches, so that each of the light emitting devices comprises the selective area growth 2402 over a different one of the openings or trenches.

6. FIG. 26d illustrates the device 2600 of example 5, wherein the patterned substrate or patterned layer comprises III-Nitride or a foreign substrate 2602.

7. FIG. 26d illustrates the device of example 5, further comprising:
one or more III-nitride layers 2604 comprising n-type or p-type material; and
the mask 2420 or patterned layer deposited on the one or more III-nitride layers; and
the selective area growth on the mask or patterned layer.

8. FIG. 26d shows the device of examples 1-7, wherein the different dimensions (e.g., length L or width W) are such that each of the light emitting devices comprise III-nitride experiencing different degrees of strain relaxation and the different indium content associated with the different degrees of strain relaxation.

9. FIG. 26d shows the device of examples 1-4, wherein the different dimensions comprise a surface area A of 15 microns by 15 microns or less so that each of the light emitting devices comprise micro LEDs having a lateral area of 15 microns by 15 microns or less.

10. The device of example 5, wherein the patterned substrate comprises porous gallium nitride.

11. FIG. 28b shows the device of example 5, wherein the selective area regrowth is on a compliant base layer 2820 compliant (or lattice matched) with the material in each of the different light emitting devices.

12. FIG. 31e illustrates the device of examples 1-11, wherein:
the light emitting devices include a polygonal cross-section 3000 having n-sides as viewed from the top, and
at least one of the sides 3002 is not etched and is etch damage free.

13. FIG. 27b illustrates the device of examples 1-12, wherein each of the light emitting devices include an etched mesa 2710 and an electrical contact 2706 comprising metallization deposited on a region 2730 of a substrate 2716 next to the mesa.

14. The device of examples 1-13, wherein each of the light emitting devices comprises a plurality of selective area regrowths so that the light emitting devices include epitaxial layers having a plurality of different lateral dimensions.

15. FIG. 27b illustrates the device 2700 of examples 1-14, wherein the light emitting devices include 111-nitride layers including an n-type layer 2708, a p-type layer 2704, and an active region 2702 emitting electromagnetic radiation in response to an electric field applied between the n-type layer and the p-type layer.

16. FIG. 27b illustrates the device of examples 1-15, further comprising a first electrical contact 2706 comprising metallization on the light emitting device, on the substrate, or on a region 2730 between the light emitting devices.

17. FIGS. 24-32 illustrate a method of making device 2700, 2400 comprising:
obtaining a pattern including openings 2422 on a substrate 2460 or layer; and
performing a selective area growth (SAG) 2402 of a III-Nitride over the openings, forming an array of light emitting devices having different dimensions, so that each of the light emitting devices are isolated from each other and include an active region having a different indium content and emitting a different wavelength of electromagnetic radiation.

18. FIGS. 24-32 illustrate the method of example 17, wherein the layer or substrate comprises porous material including different porosity or pore density as a function of position in a lateral direction.

19. The method of examples 17 or 18, wherein the pattern comprises a mask on a substrate.

20. The method of examples 17-19, wherein the substrate or layer comprises III-nitride.

21. FIG. 30 illustrates the method or device of any of the preceding examples, wherein at least some of the light emitting devices emit red light, at least some of the light emitting devices emit blue light, and at least some of the light emitting devices emit green light.

22. The method or device of any of the preceding examples, wherein the light emitting devices are a light emitting diode or a laser diode.

23. The method or device of any of the preceding examples, wherein the patterned substrate or patterned layer is formed by etching the pattern into the layer or patterned substrate.

24. FIG. 32 illustrates the method or device of any of the preceding examples, further comprising the selective area regrowth on a substrate or layer, the selective area regrowth including an etched mesa including part of the selective area regrowth and part of the layer or substrate outside the selective area regrowth.

### REFERENCES FOR SECTION II

The following references are incorporated by reference herein.
1. Shubhra S Pasayat et al 2019 Semicond. Sci. Technol. 34 045009
2. S. Keller, U. K. Mishra, S. S. Pasayat and C. Gupta, “Method for relaxing semiconductor films including the fabrication of pseudo-substrates and addition of previously un-accessible functionality to group III-nitrides”, Provisional patent application filed on 7 Nov. 2018. UC Case No.: UC 2019-178 (U.S. Provisional Patent No. 62/756,933, G&C docket 30794.0702-US-P1) and U.S. Provisional Patent No. 62/898,178, filed Sep. 10, 2019 by S. Keller, U. K. Mishra, S. S. Pasayat and C. Gupta, entitled “Method for relaxing semiconductor films including the fabrication of pseudo-substrates and addition of previously un-accessible functionality to group III-nitrides”, UC 2019-178; G&C docket 30794.0702-US-P2).

### III. Advances in the Use of Porous Materials for the Fabrication of Materials with Arbitrary Lattice Constant

a. Utilizing Porous Group-III Nitride Materials

The Advances in the use of porous materials are based on the improved process for the fabrication of devices utilizing porous layers, involving the porosification of a planar surface layer over an entire wafer, regrowing a thin planar layer on top of the porous layer, and patterning the entire wafer afterwards. The patterned wafer than serves as pseudo-substrate for consecutive device growth as illustrated in FIG. 10 and shall be referred to as process B in the following.

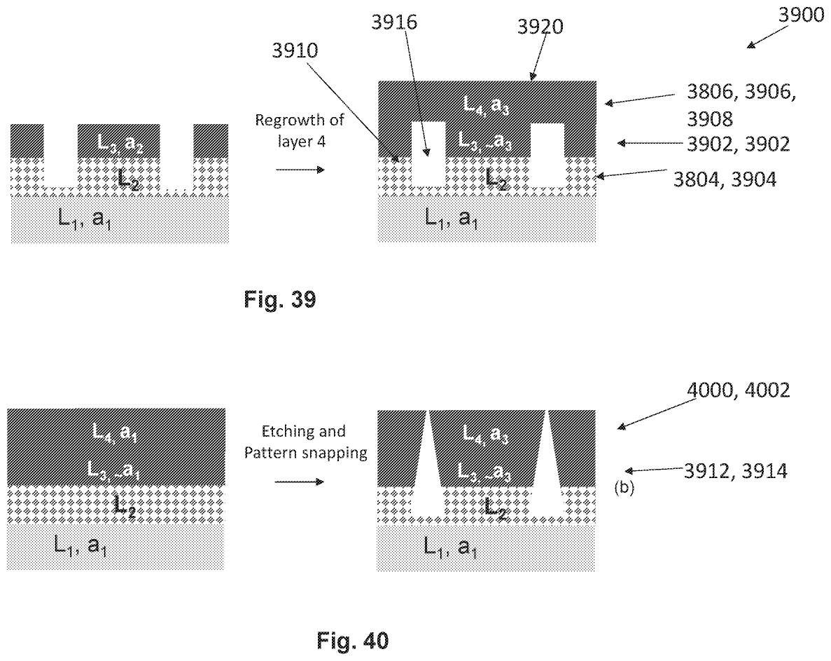

In another embodiment, in addition to the thin planar layer, a thicker planar layer or layer stack can be grown on top of the porous layer, followed by patterning the wafer. This process shall be referred to as process C (FIGS. 39 and 40). Using this process, the quality of the layers above the porous layer in terms of treading dislocation and defect density for example, can be superior to the layer below the porous layer.

Since the layers on top of the porous layer are compliant, the lattice constant of the layers on top of the porous layer is equal or close to that of the relaxed layers or the average lattice constant of a layer stack.

As in both cases. B and C, the patterning is performed post porosification, the gap between neighboring patterns can be small, as the need for a liquid solution to access and porosify a buried layer, as described in section I and referred to as process A in the following, is eliminated.

Due to the smaller gap between individual patterns the so called fill factor and the usable area of the wafer increase significantly. For example in the case of the 10×10 μm2 tiles separated by 2 μm wide trenches the fill factor was 0.694. If the trench spacing is reduced to 200 nm, the fill factor increases to 0.96.

In addition, if the gap between adjacent patterns is small, the patterns can be easily coalesced upon regrowth, allowing the fabrication of a planar wafer with an in-plane lattice constant different to that of the layer underneath the porous layer (FIG. 39).

Thereby the patterns can be coalesced with a thin layer of material different to the one the patterns are composed of. For example, if the patterns are composed of InGaN, they can be coalesced with a thin layer of GaN as described in reference 34. The coalescence layer can be grown in the presence of hydrogen in the growth ambient.

Upon pattern coalescence over a larger area, the compliant nature of the layers on top of the porous layer subsides, as there are no free sidewalls anymore which can accommodate the expansion or contraction of the film, for films originally under compression or under tension, respectively. This allows the fabrication of planar pseudo-substrates with a fixed in-plane lattice constant a. The dimensions of the gap between patterns become an additional design parameter.

Fixing the lattice constant is of particular interest for devices, were restraining of the layer stack is not desired, for example for (In,Ga)N/GaN or (In,Ga)N/(Sc, Al,Ga)N transistors, or photonic structures with higher band gap barrier layers.

In the case of layers with a lattice constant larger than that of the layer beneath the porous layer, such as for example GaN/porous GaN/(In,Ga)N (top), the degree of relaxation and the resulting in-plane lattice constant a will also depend on the width of the gap between adjacent patterns: if the gap is wider than the increase in width during the relaxation process, and no coalescence occurs, the degree of relaxation and the final lattice constant are independent of the gap width as previously described for case A in section I. However, as coalescence arrests the compliance, once the patterns merge, the lattice constant will not further increase. By this means the pattern spacing is an additional design parameter to modulate the in-plane lattice constant. Lateral modulation of the gap size will lead to a lateral modulation of the in-plane lattice constant.

In case B, where for example a planar InGaN layer or layer stack was regrown on the porous layer prior to patterning, the gap between patterns can be designed in such a way that the gaps close upon expansion of the top layers after patterning, which shall be referred to as pattern snapping in analogy to grain or island snapping during crystal growth, under formation of a planar wafer (FIG. 40).

In general the pattern spacing can be used again as additional design parameter to engineer the lattice constant and the properties of the device structures.

Both pattern coalescence or pattern snapping can be aided again by applying appropriate pattern shapes, for example squares or triangles or rhombohedral/parallelogram patterns (FIG. 41). The advantage of a triangular or rhombohedral/parallelogram shape arises from the circumstance that group-III nitrides crystallize in a hexagonal lattice and when grown in the c or −c direction, the sidewalls of an equilateral triangle or rhombus have the same crystallographic properties. For other growth directions, such as a- or m-plane GaN, squares or rectangles would be preferred, for example.

In addition the pattern shape can be used to influence the light extraction taking advantage of photonic crystal effects.

Both pattern size and gap width between patterns can be used to tune the operation wavelength of optoelectronic devices, also laterally over the wafer through local variation of t pattern size and gap width between patterns.

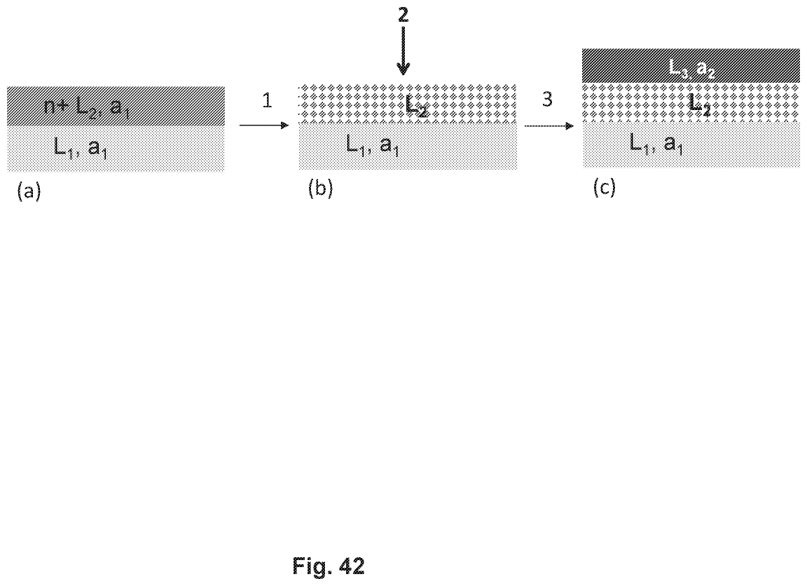

As described in Section I, the properties of the porous GaN layer can be altered after porosification. In case B and C, this process is eased as the porous layer is now also accessible from the top prior to regrowth of a planar top layer and not a buried layer as in case A described in Section I. The pores can be filled or coated with materials, which can be foreign materials, for example diamond slurry to enhance thermal conductivity, or metals, or magnetic materials (FIG. 42).

If it is desired that the porous layer is a semi-insulating layer, for example for transistor applications, the pores can be filled or coated with a magnesium doped nitride layer to deplete the charge in the pore walls, for example, or can be treated in any other suitable way to render the porous layer semi-insulating (FIG. 42). The resistivity has to remain high after growth.

Buried porous layers can be treated as well to render them semi-insulating, as described for the functionalization of porous layers, by accessing the porous layer from the side of an etched feature.

In addition, the porous layer can be implanted with suitable atoms or ions to change its properties, for example to render it semi-insulating again. The implantation can be performed prior to or after regrowth of a top layer. Implantation can also be performed on tile structures which were created via lateral porosification of a buried layer as described previously for case A, or after patterning in case of B and C.

If advantageous, the porous layer can be polished prior to regrowth of the top layer(s).

The above techniques can be applied to any crystallographic orientation of (B,Al,Ga,In)N and its alloys with other suitable elements such as Scandium, for example ScAlN. They can also be applied for other III-V semiconductors such as (Al,Ga,In)(N,P,As,Sb) or II-VI semiconductors, or group IV semiconductors, I-III-IV semiconductors, oxides or metals, for example, or for any suitable material or material system.

The film deposition on the porous III-N material can be performed by any crystal growth method, for example metal organic chemical vapor deposition (MOCVD), molecular beam epitaxy (MBE), hydride vapor phase epitaxy (HVPE), pulse laser deposition (PLD), chemical vapor deposition, or sputtering.

In addition to depositing a layer or layer stack on top of the porous layer, a layer or layer stack can be bonded to the porous layer.

The fabrication of the structures with porous materials can be performed on any substrate, for example silicon, sapphire, SiC, and bulk nitride substrates. This does not only apply to nitride films and porous nitride materials on such substrates. In addition, porous Si or SiC can be used as compliant layer, either by growing nitride or other material directly on a porous Si or SiC top layer, or by using Si or SiC substrates with an embedded porous layer. In addition, the process can be conducted using any III-V, group IV, II-IV, I-III-IV or oxide material, for example.

Similarly the layers above the oxide can be composed of any suitable material, for example any III-V, group IV, II-IV, I-III-IV or oxide material.

b. Using Porosity as Enabler for Integration

After device fabrication, the layer stack above the porous layer can be removed by any suitable technique, for example using tape, and transferred to a carrier wafer, or a device wafer, for example a silicon wafer with transistors or other already fabricated devices to enhance the functionality of the device wafer.

Integrating III-N and other III-V semiconductors with other materials such as Si or SOI is highly desirable and can be eased by using porous layers.

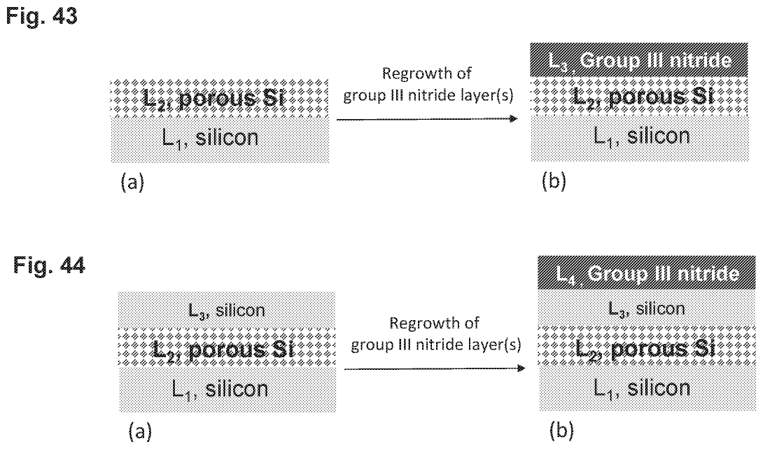

In another embodiment, one can supply a GaN layer on porous Si (FIG. 43) with the appropriate epi structure for any electronic component filters, transistors, etc. Different growths may be necessary for each component or they can be stacked. The wafers can then be fabricated to produce integrated circuits in one fab.

Here the group-III nitride layer stack can also be grown directly on porous Si or silicon with a buried porous Si layer. (FIGS. 42 to 44). Thereby the porous layer can again be treated to achieve certain properties prior to regrowth of the top layer, for example to render it semi-insulating, e.g. for transistor applications.

Instead of silicon, any suitable material can be used, for example, SiC, any III-V, II-IV, I-III-IV, or group IV semiconductor, or any oxide Using porous silicon or a porous group-III nitride layer on silicon, for example, will also mitigate differences in the thermal expansion coefficients between different materials. In addition the porous layer or layers can be used as mirrors by taking advantage of the refractive index differences in order to prevent light absorption in the underlying silicon substrate.

c. Using Porosity to Overcome Restrictions in the Fabrication of Strained Layer Stacks

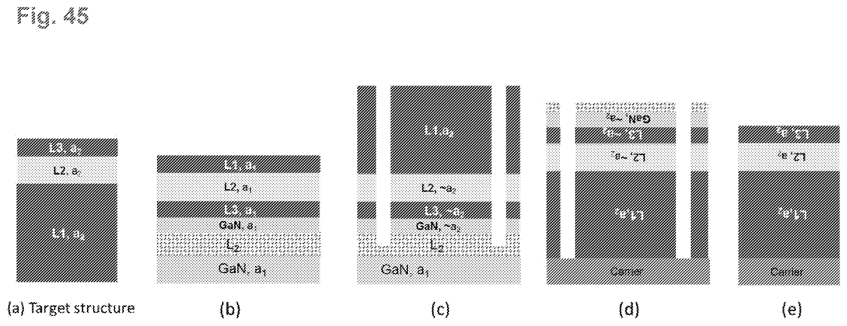

In this application porosity can be used to fabricate, for example, heterostructures with strained GaN layers. For example for transistors it is desired to increase the in-plane lattice constant a of GaN in order to obtain a reduced effective electron or hole mass. Growing strained GaN on AlGaN or AlN by MOCVD, however, has been observed to be difficult. This limitation can be overcome through the use of porosity by growing the layer structure upside down onto porous GaN, with the GaN channel layer close to the porous region. (FIG. 45) When inverting the structure, the GaN channel layer grown close to the porous GaN interlayer is first relaxed, and only after deposition of a thick layer with a lattice constant different from that of GaN on top, for example InGAN, the lattice constant of the GaN layer fully or partially adopts the lattice constant of the thick top layer thereby transforming into a strained layer. This technique can be used for any structure which benefits from circumventing critical thickness limitations in any material system.

In addition to the Nitrides, the conformal layer can be applied to any material system.

For example we can grow a thin layer of Si on porous Si, or place it onto the porous Si by other techniques such as bonding. Then we can grow any material we want say InP or any composition of AlGaInP which will stretch the underlying Si layer to conform. A laser then can be grown on a III-V on Si which can be a game changer in Si photonics

Similarly we can grow CdZnTe or CdTe on such a conformal layer which can revolutionize IR emitters and detectors, transistors, filters, and integrated circuits.

Though this procedure has been originally developed for GaN, it can change the game for all semiconductors (InN on Si included and GaAs). A porous semiconductor such as, but not limited to, porous silicon or porous GaAs can be used, for example.

Porous III-N and other porous materials can be used as substrates for electronics and photonics materials for all components including conventional III-Vs. All techniques MBE, HVPE, MOCVD etc. can be used for layer deposition.

Expanding the growth of III-N onto other materials such as glass, other insulators (AlN, SiO2 etc), metals (like Ion Beam Deposition; IBAD), ceramics, semiconductors and even plastics and polymers using porous GaN.

a. This base material can even be coalesced nanowires as an example. These nanowires could have different heights either via engineering or it could occur naturally in the growth process. We can then form a conformal layer connecting the wires covering a network of pores.

b. In general, we can form a porous layer on top of relatively poor-quality films (either by using doping selectivity or illumination or just blanket etching in a plasma, vapor, liquid or any other means).
c. Using any seed porous materials including porous Si, porous metals (Nb, Al, Sc, Hf etc) on which we grow the GaN conformal layer. Then we pattern and then we grow the active material on the patterned conformal surface. People have grown planar films on porous Si etc but not in this sequence.

d. Making Planar Porosification a Useful Technology

a. Establishing the parameter space and associated examples as to how deep the lateral GaN overgrowth goes into the porous GaN. Ideally, we want a fast formation of the GaN conformal layer on the porous layer without growth deep into pores as this may reduce porosity and affect how conformal the layer is. Here miscut can ease the process for Ga-polar along as well as N-polar nitride applications.

b. Since growth after patterning into conformal areas (tiles, fins etc) there may be a need to use selective area growth if the overgrown layers are thick. This may need a mask or just poisoned surfaces or which material deposition is inhibited or the deposited material does not do harm to the active layer. We can also imagine using the growth on the patterned surface(s) for useful purposes; passivation, other active layers, current confinement etc.

c. The Porosification Process can be Additionally Controlled by Illumination

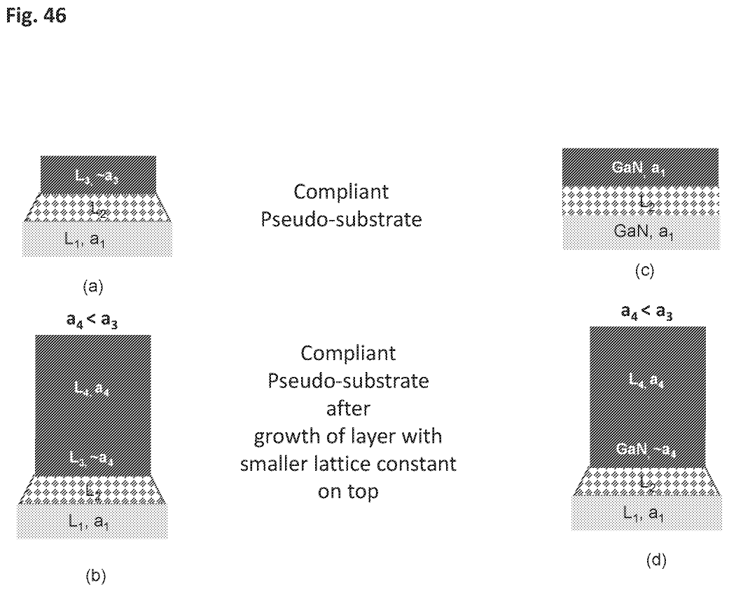

FIG. 46 illustrates the process when transitioning to a material with a smaller in-plane lattice constant.

### 13. Advances in the Fabrication of Micro-LEDs

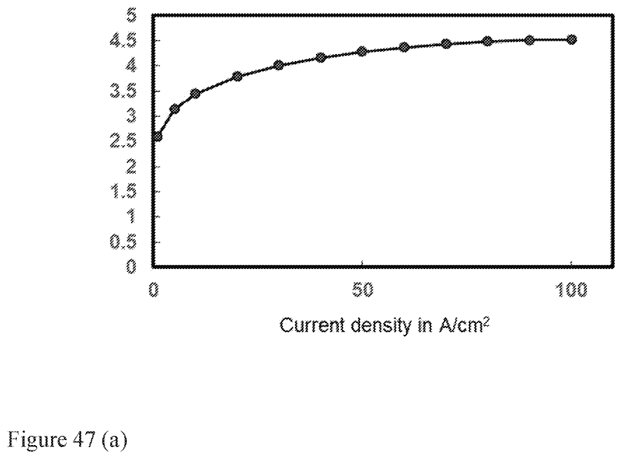

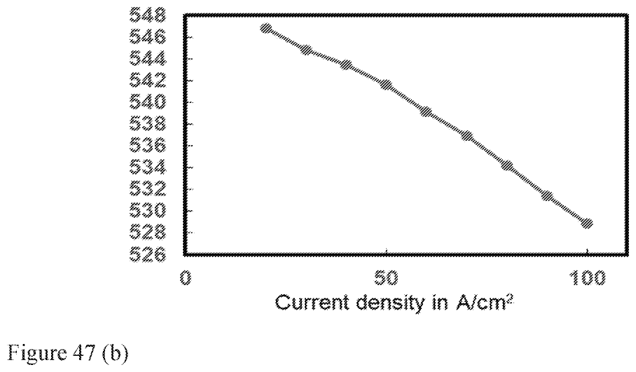

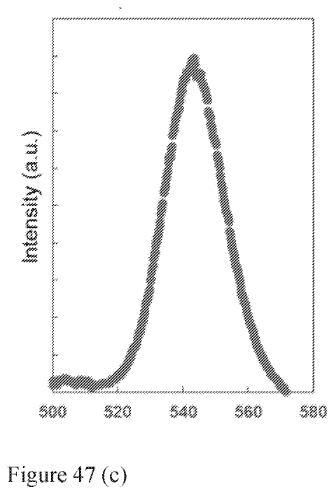

A light emitting-device with lateral dimension of active region equal to 2.5 μm was fabricated in which an ultra low power etch was utilized. The output voltage and peak wavelength for current densities up to 100 A/cm2 is shown in FIGS. 47 (a) and 47(b). The electroluminescence spectra at 50 A/cm2 is shown in FIG. 47 (c) with a full width half maximum wavelength of 22 nm. Any etching tool for example inductively coupled plasma (ICP), reactive ion etch (RIE), can be used. The etch chemistry may include only Cl2, or only BCl3 or both Cl2 and BCL3. The RF power for the plasma can be set to less than 50% of the tool's maximum capability. Low to moderate pressure must be maintained during the etch, to simulate a chemical etch which can expose crystal planes (GaN m- or a-plane) of GaN which may or may not lead to low damage. Although for the current the etch is optimized to be a vertical etch, but the etch utilized may or may not be vertical. This dry etch may or may not be combined with a wet etch utilizing wet chemistry like TMAH, KOH or H3PO4, or any other etchants at low or high temperatures. This etch can be performed with any masking material for example photoresist, or hard masks like thick dielectrics. Any etch chemistry which does not etch GaN, can be used to etch the masking material to expose the GaN to be etched.

### 14. Example with AlGaN on Porous GaN

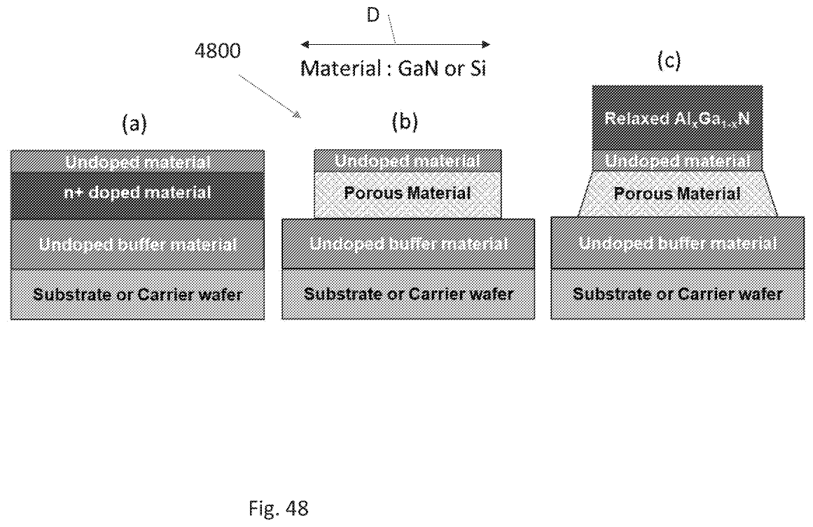

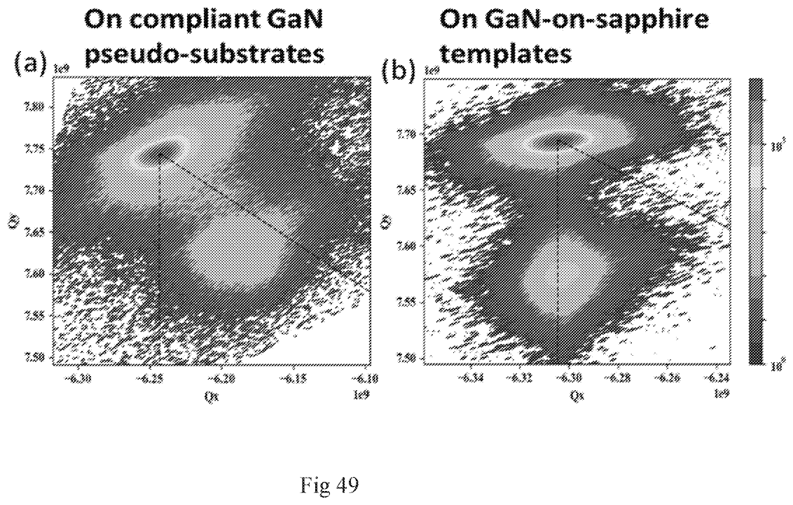

The (Al,Ga)—N alloy system is very attractive for ultraviolet (UV) optoelectronic devices and high-power, high-frequency electronic devices, owing to its ultra-wide bandgap (3.4 eV to 6 eV). The critical problem is the lack of lattice matched ternary substrates. The binary AlN substrate is currently not attractive for grid scale devices which are large current and therefore large area devices that demand large area substrates. However, when grown on readily available substrates such as GaN or Silicon, the high dislocation density of the (Al,Ga)N material negatively affects the device performance. Hence, the epitaxial growth of high quality, large area, AlxGa1-xN material as a pseudo-substrate is highly desired. One of the major challenges in obtaining AlxGa1-xN pseudo-substrates, is the tensile strain induced by the lattice mismatch between GaN (the conventionally used base layer) and AlxGa1-xN, leading to cracking of the epitaxial layers. By using porous GaN or Si based compliant layers, the strain can be relaxed elastically by the mechanically flexible porous under-layers enabling pseudo-substrates with arbitrary Al composition. FIG. 48 describes the process of generating such a substrate where the porous material is created by lateral electro-chemical etching initiated at mesa sidewalls. FIG. 48 degree of relaxation dependent on the lateral dimensions D of the pattern/patterned features 4800 on the pseudo-substrates, with smaller dimensions yielding higher relaxation.

The growth of relaxed or partially relaxed AlGaN on GaN-on-porous-GaN pseudo-substrates is described in more in example 2 below.

### DEVICE AND METHOD EXAMPLES

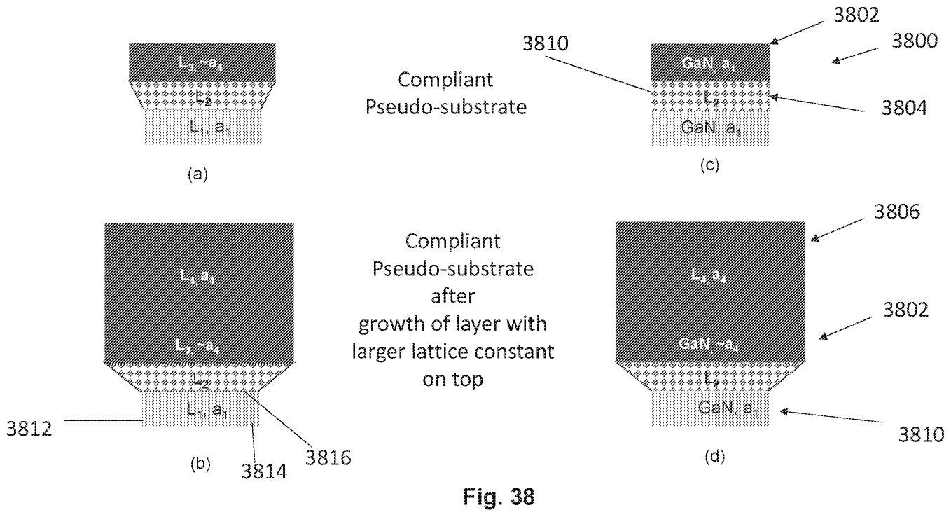

1. FIG. 38 illustrates a device, substrate or pseudo-substrate 3800, comprising:
a first (e.g., semiconductor) layer 3802 on a porous layer 3804 or compliant layer 3804; and
a second (e.g, semiconductor) layer 3806 on the porous layer or compliant layer so as to stretch or pull the underlying first (e.g., semiconductor) layer 3802 to conform the first (e.g. semiconductor) layer to the second (e.g., semiconductor) layer.

1b. FIG. 38 and FIG. 2 illustrate a device, substrate or pseudo-substrate 3800, comprising:
a first (e.g., semiconductor) layer 3806 on a compliant layer 3802, the first (e.g, semiconductor) layer 3806 stretching or pulling the underlying compliant layer 3802 to conform the first (e.g. semiconductor) layer.

2. The substrate or device of example 1 comprising an optoelectronic or electronic device comprising the second (e.g., semiconductor) layer or on top of the second (e.g, semiconductor) layer.

3. The substrate or device of any of the examples 1-2, wherein the first (e.g., semiconductor) layer 3802 and/or the porous layer comprise silicon, gallium arsenide, indium phosphide, or III-Nitride CdTe or any other group III-V material, group II-VI material or group I-III-VI material, or group IV semiconductor, oxide material or metal, where group I, II, III, IV, V, and VI refer to periods of the periodic table.

4. The substrate or device of any of the examples 1-3, wherein the second (e.g., semiconductor) layer 3806 comprises III-Nitride, III-V, InP, any composition of AlGaInP, CdZnTe or CdTe or any other group II-VI material or group I-II-VI material, or group IV semiconductor, oxide or metal, where group I, II, III, IV, V, and VI refer to periods of the periodic table.

5. The substrate or device of any of the examples 1-4, wherein the optoelectronic or electronic device comprises a laser, infrared emitter, detector, transistor, filter, or integrated circuit.

6. The substrate or device of any of the examples 1-10, wherein the stretching or pulling of the first semiconductor layer to conform the first semiconductor layer to the second semiconductor layer comprises straining the first semiconductor layer so that the first semiconductor layer has a lattice constant close to that of the second semiconductor layer or so that the first semiconductor layer has a lattice constant between a relaxed value for the lattice constant of the first semiconductor layer and a relaxed value for the lattice constant of the second semiconductor layer.

In one or more examples, since the first layer is close to the porous layer, if it is thin (as for example the GaN layer for in case of the gan-on-porous-gan pseudosubstrates, where the gan is about 100 nm thick) the lattice constant does not change much due to the mechanical limitations caused by the close proximity of the porous gan layer. The degree of relaxation increases with layer thickness and increasing strain.

7. FIG. 38 illustrates a device, comprising:
a first semiconductor layer 3802 on a porous semiconductor layer 3804; wherein the porous semiconductor layer is semi-insulating.

8. FIG. 38 illustrates a substrate 3800 composed of or comprising a layer 3802 or multiple layers 3802, 3806 on top of a porous layer 3804.

9. FIG. 39 illustrates a substrate 3900 composed of or comprising a layer 3902 or multiple layers 3902, 3906 on top of a porous layer 3904, wherein a continuous surface layer 3908 on top of the layer or multiple layers is formed via coalescence of individual features 3910 in the layer or the multiple layers which were segmented into an array of features, such as square mesas, for example.

10. A device on a porous layer or fabricated utilizing a porous layer, wherein the sidewalls of the device are defined using a low power etch in order to mitigate etch related damage to the device.

11. FIGS. 38 and 39 illustrate a method of making a device, comprising: positioning (e.g., growing or bonding) a semiconductor layer 3802 on a porous (e.g., semiconductor) layer 3804, wherein the porous semiconductor layer is on a substrate 3810.

12. The method of example 16, wherein the substrate comprises a second semiconductor layer 3906 on a foreign substrate 3810.

13. FIGS. 39, 40 and 41 illustrate the method of example 16, further comprising patterning or etching the semiconductor layer 3906 and the porous layer 3904 into an array of tiles 4000 or mesas 4002.

14. FIG. 38 and FIG. 39 illustrate a device 3800, 3900, comprising:
a semiconductor layer 3802, 3806 on a porous semiconductor layer 3804, wherein the porous semiconductor layer is on a substrate 3810.

15. The device of example 14, wherein the substrate 3810 comprises a second semiconductor layer on a foreign substrate.

16. FIGS. 39-41 illustrate the device of example 15, further comprising patterning or etching the semiconductor layer 3802, 3806 and the porous layer 3804 into an array of tiles 4000 or mesas 4002.

17. The device or method of any of the examples 1-16, wherein the porous semiconductor layer 3804 is formed by electrochemical (EC) etching of a semiconductor.

18. The device or method of any of the examples 1-16, wherein the porous layer 3804 comprises pores 3810 having a diameter in a range of 0.001-1000 micrometers.

19. FIG. 40 illustrates the device or method of any of the examples 1-18, wherein the porous layer is comprised of an array of nano-features 3912 or nanofeature arrays 3914.

20. FIG. 38 and FIG. 2b illustrate the substrate further comprising:
a growth substrate 202, 3810;
the layer 204, 3804 comprising a porous semiconductor layer on or above the substrate; and
the first semiconductor layer 3802, 206 comprising an at least partially relaxed semiconductor layer;
having a lattice constant that is different than a lattice constant of the growth substrate such that the at least partially relaxed semiconductor layer would be coherently strained if grown directly on the growth substrate, or
such that the at least partially relaxed semiconductor layer would plastically relax under formation of crystal defects if grown directly on the growth substrate

21. FIG. 38 illustrate the substrate of example 20, further including an intermediate semiconductor layer 3812 between the substrate and the porous semiconductor layer.

22. The substrate of example 21, with the substrate is removed so that a surface 3814 of the intermediate semiconductor layer, having an opposite polarity to an interface 3816 with the porous semiconductor layer, is exposed so as to flip a polarity of the device.

23. FIG. 39 illustrates the substrate 3900 of any of the examples 1-23, wherein:
the layer 3904 comprising at least one of a porous layer or a compliant layer comprises etched patterns 3910 or openings 3916;
the first semiconductor layer 3902 and/or the second semiconductor layer 3906, or any further layer grown on top closes up a gap between the etched patterns or openings.

24. The substrate of any of the examples, wherein the porous layer 3904 comprises n-type gallium nitride and the at least partially relaxed layer 3906 comprises Indium, gallium, and nitrogen, or aluminum, gallium, and nitrogen.

25. The substrate of any of the examples 1-24, wherein:
the first semiconductor layer 3802 comprises a first at least partially relaxed InGaN layer,
the second semiconductor layer 3806 comprises a second at least partially relaxed InGaN layer having a higher indium composition and a larger thickness L4 than the thickness L3 of the first at least partially relaxed InGaN layer.

26. The substrate of any of the examples 1-25, wherein the substrate 3800 comprises a compliant substrate for a device such that a lattice constant of the second semiconductor layer 3806 conforms to a lattice constant of (a first layer of) the device bonded or grown on the second semiconductor layer.

27. The substrate of example 26, wherein the device comprises a III-Nitride layer bonded to the second semiconductor layer 3806 and the bond flips a polarity of the III-nitride layer.

28. The substrate of any of the examples 1-27, wherein:
the first semiconductor layer 3802 is compliant and changes its lattice constant to become strained upon deposition of additional layers on the first semiconductor layer.

29. FIG. 39 illustrates the substrate of any of the examples 1-28, wherein at least one of the first semiconductor layer 3902 or second semiconductor layer 3906 are patterned with an array of openings 3916 on which a selective area regrowth can be performed.

30. The substrate of any of the examples 1-29, wherein at least one of the first semiconductor layer 3902, 4802 or second semiconductor layer 3906, 3806 are composed of a multilayer or superlattice stack.

31. FIGS. 38-40 illustrate a substrate 3800 composed of or comprising a layer 3802 or multiple layers 3802, 3806 on top of a porous layer 3804.

32. The substrate of example 29, wherein the selective area regrowth (SAG) comprises a III-Nitride forming an array of light emitting devices having different dimensions and/or strain relaxation, so that each of the light emitting devices include an active region having a different indium content and emitting a different wavelength of electromagnetic radiation.

33. FIG. 12 and FIG. 38 illustrate a device 1200, 3800, comprising:
a growth substrate 202, 3810.
a porous III-nitride layer 204, 3804 on or above the growth substrate; and
a layer 206, 3802 on or above the porous III-nitride layer, wherein:
the layer 206, 3802 is compliant and changes its lattice constant upon deposition of additional layers on the layer; and
the layer 206, 3802 on or above the porous III-nitride layer is composed of the same material as the substrate 202, 3810 and becomes a strained layer upon deposition of the additional layers and is part of the active region of the device

34. FIG. 8 and FIG. 38 illustrate a method of making a device, comprising:
providing a growth substrate 202, 3810;
providing a porous III-nitride layer 204, 3804 on or above the growth substrate; and
providing a layer 206 on or above the porous III-nitride layer, wherein:
the layer 206 is compliant and changes its lattice constant upon deposition of additional layers on the layer; and
the layer on or above the porous III-nitride layer is composed of the same material as the substrate and becomes a strained layer upon deposition of the additional layers and is part of the active region (e.g., multi quantum well MQW) of the device 800.

34. FIG. 38, FIG. 2, and FIG. 12 illustrate a device 3800, 200, 1200, comprising
a growth substrate 202, 1202, 3810;
a porous III-nitride layer 204, 3804 on or above the growth substrate;
a layer 206, 3802, 1212 which is composed of the same material as the growth substrate on or above the porous III-nitride layer, wherein the layer 206, 3802, 1212 is compliant and changes its lattice constant becoming a strained layer upon deposition of additional layers; and
an optoelectronic or electronic device structure 1208, 1220 where the compliant layer which changed its lattice constant upon deposition of further layers 1214 is part of the active region of an electronic or optoelectronic device and where the additional layers 1214 include an at least partially strained III-nitride layer 3806, 1214 on top of the porous III-nitride layer and on top of the strained layer wherein:
the at least partially relaxed III-nitride layer 206, 3802 has a lattice constant that is different than a lattice constant of the growth substrate 202, 3810 such that the at least partially relaxed III-nitride layer would be coherently strained if grown directly on the growth substrate.

35. FIGS. 33, 39, and 40 illustrate a device, comprising:
a growth substrate 3300;
a first III-nitride layer 3302, 3904 (e.g., comprising a porous layer) on or above the substrate;
a second III-nitride layer 3304, 3906 on or above a top surface of the first III-nitride layer, wherein the second III-nitride layer buries or closes up open pores or 3310 formed in the top surface so as to form a porous layer or wherein the second III-nitride layer closes up the gap between the etched patterns;
a plurality of openings or etched patterns extending through the second III-nitride layer and at and least into the porous layer;
an optoelectronic or electronic device structure comprising the second III-nitride layer and/or a layer grown on the second III-nitride layer, wherein:
the second III-nitride layer comprises of an at least partially relaxed III-nitride layer having ‘a’ lattice constant that is different than the ‘a’ lattice constant of the growth substrate such that the at least partially relaxed III-nitride layer would be coherently strained if grown on the directly on the growth substrate.

36. The device of example 35, wherein:
the first III-nitride layer and the at least partially relaxed III-nitride layer comprise gallium nitride;
the layer comprises an InGaN layer formed on the at least partially relaxed III-nitride layer comprising gallium nitride; and
the InGaN layer comprises an active region of the device.

37. FIGS. 39 and 40 illustrates a method of making a pseudo-substrate or device, comprising:
growing a first III-nitride layer on or above a substrate;
etching pores in a top surface of the first III-nitride layer so as to form a porous layer having open pores;
growing a second III-nitride layer on or above the top surface so as to coalesce and close the pores; and
patterning openings into the porous layer and the second III-nitride layer on the porous layer or into the porous layer, the second III-nitride layer on the porous layer and a region of the first III-nitride layer below the porous layer;
so that the region of the first III-nitride layer below the porous layer is coherently strained and the second III-nitride layer becomes relaxed or at least partially relaxed (the layer may serve as an etch stop layer for example). The second III-nitride layer is conformal and can change its lattice constant upon growth of further III-nitride layers on top.

38. The method of example 37, wherein the first III-nitride layer and the second III-nitride layer comprise gallium nitride, the method further comprising depositing an InGaN layer on top of the second III-nitride layer.

39. The method of examples 37-38, wherein the openings define the selective area growth (SAG) of the III-Nitride in examples 1-24 and forming the array of light emitting devices having different dimensions and/or strain relaxation.

40. The method or device of example 3, wherein the SAG comprises a growth up and laterally over the openings.

41. The method of examples 1-3, wherein the SAG comprises a growth up and laterally over the openings or pores.

42. FIG. 38 illustrates a method of making a device, comprising:
positioning (e.g., growing or bonding) a first semiconductor layer 3802 on a porous semiconductor layer 3804; and
growing a second semiconductor layer 3806 on the porous semiconductor layer so as to stretch or pull the underlying first semiconductor layer to conform the first semiconductor layer to the second semiconductor layer.

43. The method of example 42 according to any of the examples 2-5.

57. The method or device of examples 35-37, wherein the openings define the growth with or without a mask of the III-Nitride and forming the array of light emitting devices having different dimensions and/or strain relaxation.

58. The method or device of examples 35-37, wherein the growth with or without a mask or comprises a growth laterally over the openings between etched patterns above the porous layer.

59. The method or device of examples 35-37, wherein the growth with or without a mask comprises a growth up and laterally over the openings or pores.

60. FIG. 39 illustrates a method where the gaps between the etched features or patterns close upon relaxation or partial relaxation of the layer or the layer stack above the porous layer.

61. FIG. 39-40 illustrate a method where the layers which are grown on top of the merged etched features or patterns are strained to the lattice constant to the merged layer or the merged layer stack above the porous layer.

62. FIG. 3940 illustrate the device or method, wherein the indium content in the active regions comprising an InGaN layers is tailored by the pattern size, and the size of the gap between patterns, the pattern shape and the fill factor of the patterned layer, patterned mask, or patterned substrate.

63. The device or method of any of the examples with patterning, wherein the pattern size and the fill factor is determined by a ratio between an open and mask area on the device or between the area comprised by the features and the area associated with the gaps between the features.

64. The device or method of any of the examples 46-62, wherein the indium content is increased in areas wherein non-c-plane facets are formed during the selective area regrowth.

65. FIG. 38 illustrates a device, comprising:
a growth substrate 3810;
a porous III-nitride layer 3804 on or above the growth substrate; and
a layer 3802 on or above the porous III-nitride layer, wherein:
the layer is compliant and changes its lattice constant upon deposition of additional layers 3806 on the layer; and
the layer on or above the porous III-nitride layer is composed of the same material as the substrate and becomes a strained layer upon deposition of the additional layers.

66. FIG. 38 illustrates a method of making a device, comprising:
providing a growth substrate 3810;
providing a porous III-nitride layer 3804 on or above the growth substrate; and
providing a layer 3802 on or above the porous III-nitride layer, wherein:
the layer 3802 is compliant and changes its lattice constant upon deposition of additional layers on the layer; and
the layer on or above the porous III-nitride layer is composed of the same material as the substrate and becomes a strained layer upon deposition of the additional layers.

54. FIG. 38 illustrates a device, comprising
a growth substrate 3810;
a porous III-nitride layer 3804 on or above the growth substrate;
a layer 3802 which is composed of the same material as the substrate on or above the porous III-nitride layer, wherein the layer is compliant and changes its lattice constant becoming a strained layer upon deposition of additional layers; and
an optoelectronic or electronic device structure comprising the additional layers 3806 including an at least partially strained III-nitride layer on top of the porous III-nitride layer and on top of the strained layer wherein:
the at least partially relaxed III-nitride layer has a lattice constant that is different than a lattice constant of the growth substrate such that the at least partially relaxed III-nitride layer would be coherently strained if grown directly on the growth substrate.

55. The device or method of any of the preceding examples using
patterning wherein the growth over the openings or gaps is with or without the mask comprises selective area epitaxy or lateral epitaxial overgrowth.

56. A device or method wherein, in any of the examples reciting III-Nitride, any semiconductor, metal or oxide material can be used instead of the III-nitride in the example. Examples of semiconductor include but are not limited to silicon, gallium arsenide, or III-Nitride, CdTe or any other III-V, II-VI or I-III-VI, or group IV semiconductor.

57. The substrate of any of the examples, wherein the first semiconductor layer 3802 is grown on or bonded to the porous semiconductor layer 3804.

58. The substrate of any of the examples, further comprising a plurality of layers including the first semiconducting layer 3802 and the second semiconducting layer 3804 on top of the porous semiconducting layer 3804, wherein the plurality of layers have a top continuous surface 3920 formed via coalescence of a layer 3906 or multiple layers in the plurality of layers which were segmented into an array of features 3912 (e.g., having dimensions in a range of 1-1000 microns).

59. FIG. 41 illustrates the substrate of example 58, wherein the features comprise mesas or tiles having a square, triangular, circular, or rhombus shape.

60. FIG. 20 illustrates the substrate of any of the examples, wherein pores 210 in the porous semiconductor layer 3804 are at least partially filled with gas, metal, phosphor, ferromagnetic material, magnetic material, semiconductor material, and/or other foreign material, or the porous layer is implanted with ions.

61. The substrate of any of the examples, wherein the porous layer 3804 is semi-insulating.

62. The substrate of example 60, wherein the porous layer 3804 is treated to render it semi-insulating prior to deposition of the first semiconducting layer 3802.

63. The substrate of any of the examples, wherein the porous layer 3804 is treated to modify its physical properties.

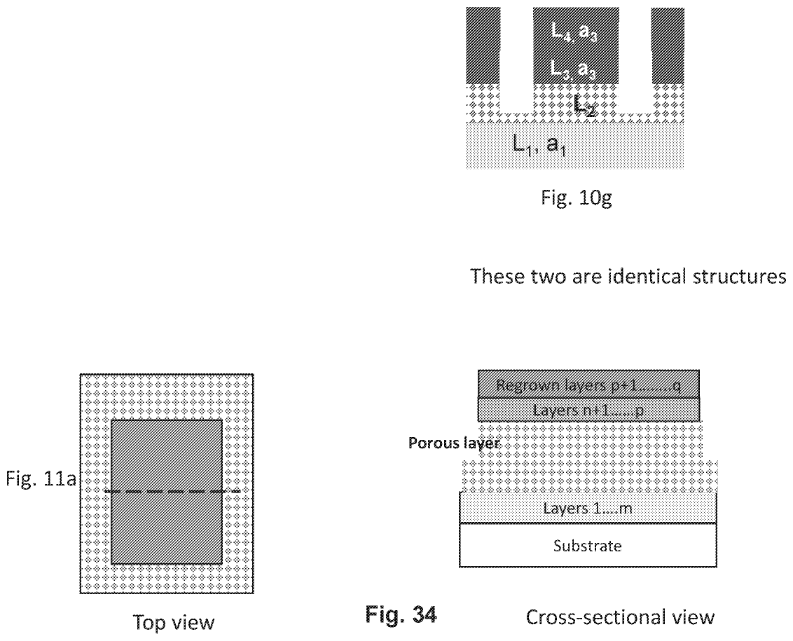

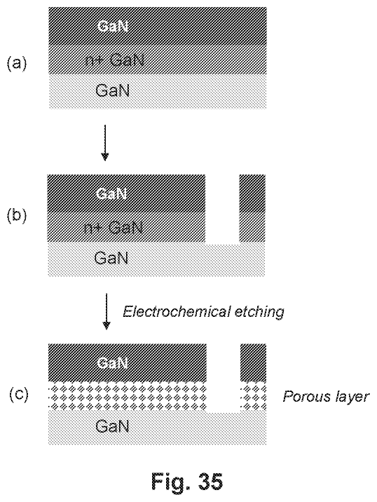

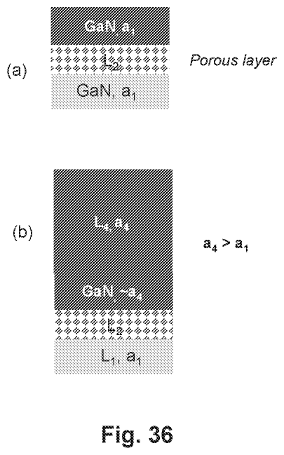

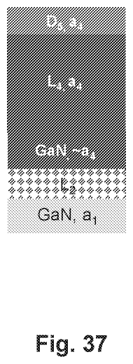

64. FIG. 2-41 further illustrate a method of making a device, comprising:
depositing one or more device structures on or above a compliant substrate, wherein a first lattice constant of the compliant substrate conforms to a second lattice constant of a first layer of the device structure.

65. The method of example 64, wherein the compliant substrate comprises a first semiconductor layer on a porous layer and the first semiconductor layer has the first lattice constant conforming to the second lattice constant of the device structure.

66. The method of example 64, further comprising:
depositing a layer on a substrate;
growing the first semiconductor layer on the layer, wherein the first semiconducting layer is coherently strained;
forming pores in the layer so as to form the porous layer, such that the first semiconductor layer becomes relaxed or at least partially relaxed; and depositing the device structure on the first semiconductor layer.

67. The method of example 64, further comprising:
etching an array or pattern of openings or features in at least one of the first semiconductor layer or the porous layer; and
depositing the device structure on the array of openings or features.

68. The method of any of the examples 64-67, wherein the optoelectronic or electronic device comprises a laser, IR emitter, detector, transistor, filter, or integrated circuit.

69. The method of any of the example 67, further comprising:
depositing a second semiconductor layer on or above the first semiconductor layer, wherein the depositing of the second semiconductor layer coalesces the openings or features to form a continuous top surface; and
depositing the device structure on the continuous top surface.

70. The method of example 69, further comprising:
depositing a second semiconductor layer on or above the first semiconductor layer, wherein gaps between the features close and the features merge to form a merged layer having the continuous top surface upon relaxation or partial relaxation of the second semiconductor layer or layers above the porous layer; and
depositing the device structure on continuous top surface of the merged layer.

71. The method of example 70, wherein layers of the device structure grown on top of the merged etched features are strained to the lattice constant to the merged layer.

72. The method of example 64, comprising:
growing a semiconductor layer on or above a growth substrate, wherein the semiconductor layer is coherently strained;
bonding the semiconductor layer directly or indirectly to the compliant substrate;
removing the growth substrate or at least partially removing the growth substrate from the semiconductor layer, so that the semiconductor layer becomes relaxed or at least partially relaxed; and
depositing the device structure on the semiconductor layer.

73. The method of any of the example 72, further comprising performing a heat treatment to aid relaxation of the semiconductor layer.

74. The method of example 72, further comprising growing a p-type GaN layer so that the p-type GaN layer is between the semiconductor layer, comprising a III-nitride layer, and the growth substrate, wherein removing or at least partially removing the growth substrate exposes a surface of the p-type layer having an opposite polarity to an interface of the p-type layer with the III-nitride layer, thereby flipping a polarity of the device structure.

75. The method of example 64, comprising:
obtaining the compliant substrate having an array of openings or forming the array of openings in the compliant substrate;
performing a growth in each of the openings, forming an array of light emitting devices comprising one of the light emitting devices in each of the openings, so that each of the light emitting devices are isolated from each other and include an active region having a different indium content and emitting a different wavelength of electromagnetic radiation.

76. The method of example 75, wherein the compliant substrate comprises a first semiconductor layer on a porous layer and the array of openings are etched into at least one of the first semiconductor layer or the porous layer.

77. The method of example 75, wherein the growth over the openings comprises a selective area regrowth.

78. The method of example 77, further comprising etching a mesa in the selective area regrowth and part of the layer or substrate outside the selective area regrowth.

79. The method of examples 78, wherein the etched mesas each have different dimensions and/or strain relaxation.

80. The device or method of any of the examples with patterned openings, wherein:
the indium content in each of the active regions is tailored by at least one of a size of the openings, a size of a gap between the openings, a shape of the openings, and a fill factor of the patterned layer, patterned mask, or patterned substrate comprising the openings.

81. The method of any of the examples with patterned openings, wherein the size of the openings and the fill factor are determined by a ratio between the area of the openings and an area of a mask on the device or between the area of the openings and an area of the gaps between the openings.

82. The method of any of the examples with selective area regrowth, wherein the indium content is increased in areas wherein non-c-plane facets are formed during the selective area regrowth.

83. The method of any of the examples with a plurality of light emitting devices, wherein the porous layer comprises porous material including different porosity or pore density as a function of position in a lateral direction so that each of the light emitting devices are grown above a portion of the porous layer having a different porosity.

84. The method of any of the examples with openings, wherein each of the openings have different dimensions such that each of the light emitting devices comprise III-nitride experiencing different degrees of strain relaxation and the different indium content associated with the different degrees of strain relaxation.

85. The method of example 84, wherein the different dimensions comprise an area of 15 microns by 15 microns or less so that each of the light emitting devices comprise micro LEDs having a lateral area of 15 microns by 15 microns or less.

86. The method of any of the examples with light emitting devices, wherein the porous layer comprises porous gallium nitride and the light emitting devices comprise III-nitride.

87. The method of any of the examples with light emitting devices on a compliant substrate, wherein the compliant substrate is compliant (or lattice matched) with the material in each of the different light emitting devices.

88. The method of any of the examples with light emitting devices, wherein:
the light emitting devices include a polygonal cross-section having n-sides as viewed from the top, and
at least one of the sides is not etched and is etch damage free.

89. A method of making a pseudo-substrate or device, comprising:
growing a first III-nitride layer on or above a substrate;
etching pores in a top surface of the first III-nitride layer so as to form a porous layer having open pores;
growing a second III-nitride layer on or above the top surface so as to coalesce and close the pores; and
patterning openings into the porous layer and the second III-nitride layer on the porous layer or into the porous layer, the second III-nitride layer on the porous layer and a region of the first III-nitride layer below the porous layer;
so that the second III-nitride layer becomes relaxed or at least partially relaxed and the second III-nitride layer is conformal and can change its lattice constant upon growth of further III-nitride layers on top.

### IV. ILLUSTRATIVE EXAMPLES OF EMBODIMENTS DESCRIBED HEREIN

### Example 1: Color-Tunable <10 μm Square InGaN Micro-LEDs on Compliant GaN-On-Porous-GaN Pseudo-Substrates

In this study, two methods to tune the emission wavelength of micro-LEDs fabricated on tile patterned compliant GaN-on-porous-GaN pseudo-substrates (PS) are presented. The mechanical flexibility of porous GaN was utilized to relax the strain induced during the growth of LED structures with n- and p-InGaN layers and enhance the indium incorporation via the composition pulling effect. The first approach involved only varying the size of the PS square tiles used for LED structure regrowth, from 20×20 μm2 to 8×8 μm2. Higher n-InGaN base layer relaxation with decreasing tile size resulted in a red shift of emission from 525 nm to 561 nm with no change in the growth conditions. The second method involved changing the mole-fraction, x, of the n-InxGa1-xN base layer of the LED structure from 0.04 to 0.09 by reducing growth temperature, while keeping the high temperature growth conditions of the MQW and p-InGaN targeting 530 nm emission. The resulting wavelength shift was a remarkable 536 to 616 nm due to the stronger composition pulling effect providing a pathway to enable high indium content MQW active regions to be grown at high temperature.

Highly efficient III-nitride based light-emitting diodes (LEDs) have been extensively employed in solid-state lighting [1]. Recently (In,Ga)N based micron-sized LEDs (pLEDs) have gained increased attention for display applications owing to their reliability, high luminous efficiency, chemical robustness and small form-factor [2]. Compared to organic light-emitting diodes and liquid crystal displays, monochromatic pLEDs have shown higher resolution, efficiency and contrast ratio making them ideal for a broad range of display applications, from near-eye head-mounted display to large-area self-emitting display [3-7]. Additionally, LEDs offering GHz modulation bandwidth are being developed for high-speed transmitters in visible-light communication (VLC) [8-9]. Owing to their small form-factors, μLEDs are also being considered to possess immense potential in medical applications [10-13] and mask-free lithography [14]. Recent reports have also predicted that pLEDs with mesa dimensions of <10 μm are desirable for next generation displays (8K TVs, smart watches, AR/VR headsets and smartphones) to meet the cost targets necessary for commercialization [15]. Often terms such as nanowires, nano-LEDs or nanorods are used to describe devices with dimensions of few microns or less and are typically fabricated using bottom-up growth techniques. However, in the current report, we limit the term pLEDs to devices with dimensions below 100 μm fabricated via conventional top-down processing methods.

It has been widely reported that the external quantum efficiency (EQE) of μLEDs decreases with size [5, 16-17]. As the device size decreases, the surface-area-to-volume ratio of the LEDs increases, often leading to a rise in nonradiative Shockley-Read-Hall (SRH) recombination at the edge of the device active region, resulting in a decrease in EQE. Etching of the LED mesas can lead to the formation of various crystallographic defects at the mesa sidewalls, dangling bonds, and possibly enhanced impurity incorporation, all of which can introduce trap states within the bandgap that act as nonradiative recombination centers [18-19]. So far, there is only one report on the EQE of LEDs with sizes below 5 μm for blue and green InGaN LEDs [20], and no reports exist on luminescence of pLEDs emitting at wavelength longer than 540 nm with these dimensions.

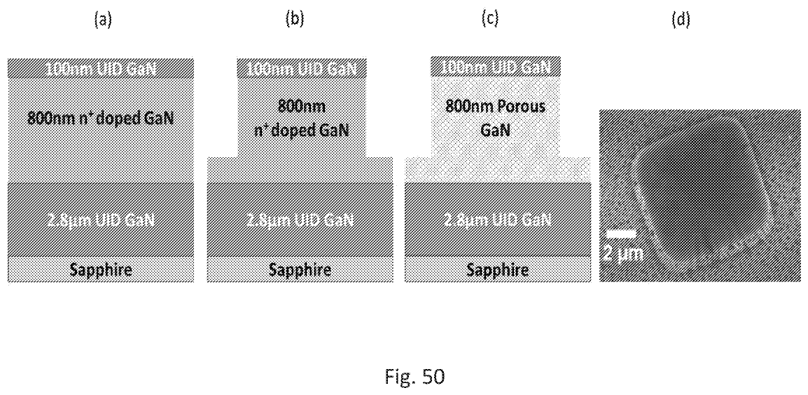

Achieving high efficiency III-nitride based pLEDs with electroluminescence (EL) beyond 540 nm is also very challenging as the EQE of these devices often decreases significantly with increasing emission wavelength due to multiple reasons [2, 21-23]. One major reason is the increase in lattice mismatch between the InGaN active region of the LED and the n-GaN base layer with increasing indium composition, which can induce various defects in the active region [24]. Hence a reduction in the lattice mismatch between active region and base layer, achieved through the implementation of relaxed InGaN base layers, is highly desirable, as it yields better QW material quality and higher indium incorporation efficiency. Various attempts have been made to fabricate as-grown relaxed InGaN buffers on substrates such as ZnO [25-27] and ScAlMgO4 [28-29], on partially relaxed engineered InGaN substrates [30], on plastically relaxed InGaN buffer layers obtained using MBE [31-33] and on coalesced relaxed nano-feature arrays [34]. 80 to 200 nm wide InGaN fins were shown to uni-axially relax perpendicular to the fin direction [35-36]. Recently, we demonstrated uni-axial and bi-axial InGaN relaxation in the micron-sized regime using porous GaN under layers [37]. Due to its high surface-to-volume ratio, porous GaN exhibits reduced mechanical stiffness with increased porosity [38]. In the experiment, 100 to 200 nm InxGa1-xN layer were originally grown strained onto n-type silicon doped GaN layers. Afterwards, the wafers were removed from the MOCVD chamber and patterned into micron sized stripes or tiles, followed by porosification of the silicon doped GaN underlayer in a manner as shown in FIG. 50. After porosification, the InGaN layers relaxed and adopted an in-plane lattice constant larger than GaN. Thereby the degree of InGaN strain relaxation strongly depended on the feature size, with larger features relaxing to a lesser extent due to the presence of higher spatial restraints when compared to smaller feature sizes [37]. Using these relaxed InGaN-on-porous-GaN wafers as pseudo-substrates for InGaN growth we observed enhanced indium incorporation into the InGaN layers deposited on the pseudo-substrates compared to those grown on GaN-on-sapphire base layers [37,39]. The enhanced indium uptake from the gas phase was attributed to the decrease in the lattice mismatch between growing InGaN layer and relaxed InGaN base layer. This effect had been observed in previous studies and was referred to as the composition pulling effect [25, 30-33]. Similarly. InGaN/GaN multi-quantum wells (MQWs) deposited on relaxed InGaN-on-porous-GaN wafers exhibited a 45 nm redshift in the MQW emission wavelength compared to the same structures grown on GaN base layers [37]. Interestingly, the initial InGaN layers on top of porous GaN further relaxed upon consecutive InGaN growth, revealing the compliant nature of these InGaN pseudo-substrates [39]. Taking advantage of the compliant nature of layers positioned on top of porous GaN, we recently demonstrated high fill-factor 10×10 μm2 square patterned compliant GaN-on-porous-GaN layers for the growth of relaxed or partially relaxed InGaN [40]. Replacing the top layer of the pseudo-substrate with GaN (instead of InGaN) maintained the compliant nature while enabling the deposition of InGaN structures with significantly reduced V-defects. In this work we utilize these compliant GaN-on-porous-GaN pseudo-substrates (PSs) to fabricate color-tunable micro-LEDs with device dimensions of less than 10 μm. We evaluated two methods. The first approach involved only varying the size of the PS square tiles used for LED structure regrowth, from 20×20 μm2 to 8×8 μm2. Higher relaxation of the n-InGaN base layer with decreasing tile size resulted in a red shift of emission from 525 nm to 561 nm with no change in the growth conditions. The second method involved explicitly changing the mole-fraction, x, of the n-InxGa1-xN base layer of the LED structure from 0.04 to 0.09 by reducing growth temperature, while keeping the preferred high temperature growth conditions of the MQW and p-InGaN. The latter resulted in a remarkable 80 nm red shift from 536 nm on PS epi with n-In0.04Ga0.96N compared to 616 nm on PS epi with n-In0.09Ga0.91N because of a stronger compositional pulling effect.

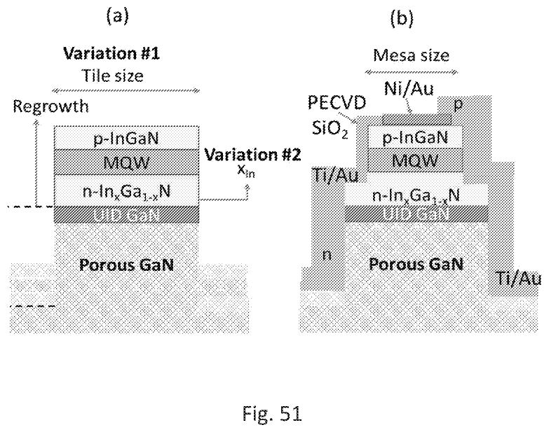

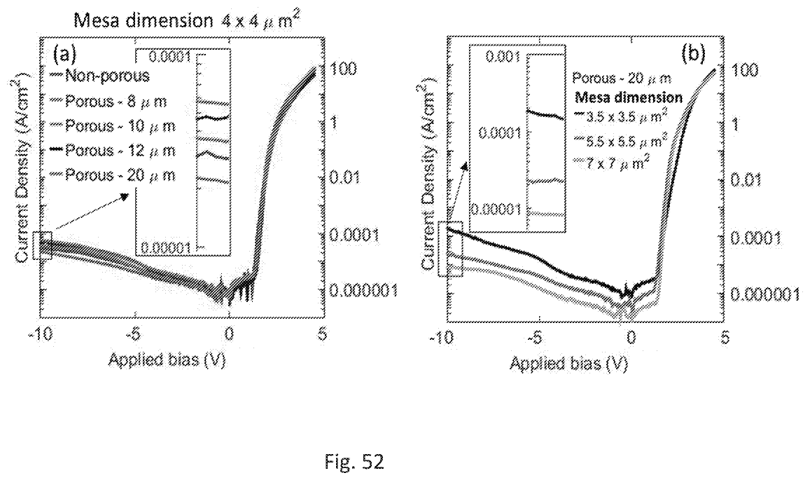

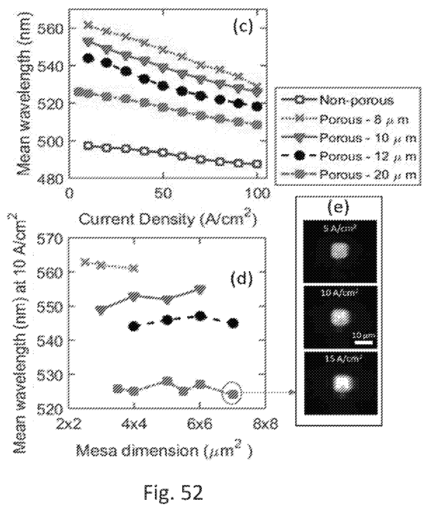

All epitaxial layers in this study were grown by metal-organic chemical vapor deposition (MOCVD) using the precursors trimethylgallium (TMGa), triethylgallium (TEG, for InGaN growths), trimethylindium (TMI), ammonia, and disilane on c-plane sapphire substrates. The epitaxial layer structure for PS fabrication consisted of a 2.8 μm-thick unintentionally doped (UID) GaN layer followed by 800 nm-thick Si-doped GaN with a doping of 5×1018 cm-3, and a 100 nm-thick UID GaN cap layer (FIG. 50(a)). The samples were first patterned and dry etched using a 100 W BCl3/Cl2 etch chemistry resulting in ‘w’ μm×‘w’ μm wide tiles (w=8, 10, 12, 20) on the same die (die size 2 mm×2 mm), with a total etch depth of 550 nm (FIG. 50(b)). A part of each die was protected from the electrochemical (EC) etch so that the underlying n+ GaN remained non-porous and the subsequently grown InGaN heterostructures remained strained to the GaN lattice constant in these regions. This allowed for a direct comparison between the strained and the relaxed/partially relaxed InGaN devices grown on these pseudo-substrates [as in ref. 41]. Afterwards, a doping selective EC etch was used for the porosification of the 800 nm-thick GaN:Si layers [37]. The EC etch was performed with a metal contact to the 800 nm-thick n+ GaN:Si layer on the sample as anode and a Pt wire which acted as the cathode. The etch progressed as a result of the current flowing through this GaN:Si layer etching the region exposed to the 0.3 M oxalic acid electrolyte, resulting in the formation of tiles comprised of GaN on top of porous GaN as shown in FIGS. 50(c) and (d) [42]. Two different LED structures were grown on these GaN-on-porous-GaN PSs. The LED structures were composed of 180 nm of Si-doped InxGa1-xN with x=0.04 or x=0.09, which was capped with 30 nm of Si-doped n-type GaN and 10 nm UID GaN prior to the growth of the active region. The active region consisted of three multi-quantum wells (MQWs) composed of 3 nm In0.2Ga0.8N, a 2-nm-thick Al0.1Ga0.9N cap layer and 10 nm UID GaN, grown as discussed in detail elsewhere [43]. A 120 nm Mg-doped p-In0.04Ga0.96N layer was grown on top of the last QW followed by a 16-nm-thick Mg-doped p++-In0.04Ga0.96N contact layer. The thickness and nominal composition of each layer was determined via x-ray diffraction (XRD) from separate calibration samples composed of InGaN layers grown coherently strained on GaN base layers. As discussed in the introduction, the same layers typically contain higher amounts of indium when deposited on the compliant PSs. Following growth, the active region was isolated using a low power BCl3/Cl2 based reactive ion etch (RIE) [44], followed by 200 nm SiO2 dielectric deposition using plasma-enhanced chemical vapor deposition (PECVD). The contact regions were opened with a wet etch using buffered HF, followed by deposition of the 2 nm/5 nm Ni/Au p-contact metal stack and a combined n-contact and pad contact stack consisting of 30 nm/500 nm Ti/Au. It should be noted that this fabrication process can be further optimized to enhance the light output performance. However, in this study focusing on electroluminescence (EL) wavelength tunability, a basic fabrication process was used. The cross-sectional schematics of the micro-LED structure before and after fabrication are shown in FIGS. 51(a) and 52(b), respectively.

The samples were characterized using JEOL7600F scanning electron microscopy (SEM) tool operated at 10 kV. Optical measurements were conducted on-wafer, with light being collected through the sapphire substrate within approximately a 60° half-angle cone normal to the substrate. This geometry was preferred over the measurement of packaged devices in an integrating sphere as it more accurately imitated how micro-LEDs are used in displays [20]. The limited collection angle, however, caused the measured EQE values to be lower compared to values obtained if the devices were packaged with the total extracted light collected in an integrating sphere (as in ref. 5). The collection surface was an optical diffuser coupled to a fiber optic cable, whose output was collimated and focused into a monochromator using a thermoelectrically cooled Synapse CCD detector to record the EL spectra. For each device, EL spectra were measured at room temperature at various current densities and integrated across all relevant wavelengths to calculate the optical power, Popt. The EQE was calculated using the following equation:

$$EQE = \frac{{P}_{opt} \times λ}{\frac{J A}{q} \times h c} \qquad ( 1 )$$

where, h (Planck's constant), c (speed of light) and q (charge of an electron) are physical constants, λ is the mean wavelength of electroluminescence spectrum, J is the current density and A is the dimension of light emitting region (active region) of the device.

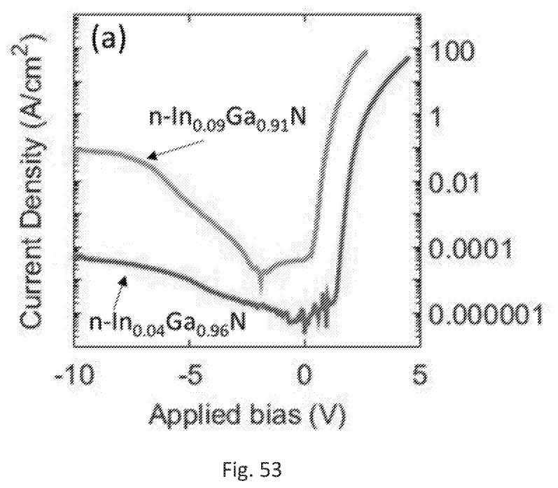

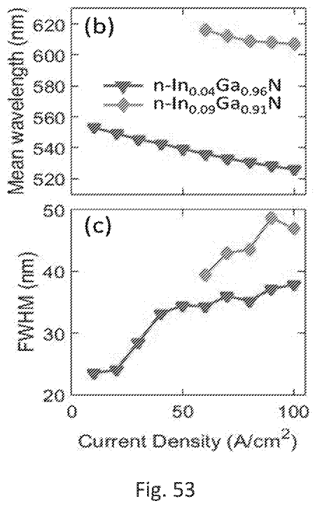

In the first experiment, we examined the effect of different tile sizes ‘w’ of the GaN-on-porous-GaN PS on the emission wavelength, varying ‘w’ from 8 to 20 μm. The μLED active region dimension or mesa size was kept constant at 4 μm×4 μm for all devices. The pLEDs fabricated on the 8, 10, 12 and 20 μm wide tiles exhibited EL at mean wavelengths of 561, 553, 544 and 525 nm (with estimated MQW indium content of 0.245, 0.24, 0.23 and 0.22), respectively, under 10 A/cm2 direct current. The redshift with decreasing tile width is illustrated in FIG. 53(c). The higher degree of relaxation in the n-InGaN layer on smaller tiles resulted in a higher n-InGaN in-plane lattice constant and led to an increased indium uptake during the growth of the InGaN MQW active region of the LEDs due to the composition pulling effect [25, 30-33, 35, 37, 45] resulting in the redshift of the EL peak. For comparison, a device of the same mesa size (4 μm×4 μm) from the non-porous region of the same die was also analyzed, which under the same measurement condition exhibited EL at 497 nm (with estimated MQW indium content of 0.2), which was considerably shorter wavelength emission compared to the pLEDs with porous GaN underlayers, as also shown in FIG. 53(c). On the non-porous region of the die, the InGaN heterostructures were grown strained to the GaN lattice constant, leading to a lower indium uptake during deposition of the quantum well region. The redshift observed between porous and non-porous region was similar to the observations reported in our previous study [40]. All the above pLEDs showed a similar turn-on voltage of ˜3 to 3.5V, even with a large variation in emission wavelength, the reason behind which is currently not well understood and will be the topic of a forthcoming study. Moreover, there was no clear trend in the series resistance as well as reverse leakage current between pLEDs with the same mesa size of 4 μm×4 μm fabricated on 8, 10, 12 and 20 μm wide tiles as can be seen from the I-V curves in FIG. 53(a). As all devices had a similar device structure, LED dimensions, and doping, nominally the same series resistances and reverse leakage currents were expected. We currently attribute the minor discrepancies to processing and/or growth variations.

For each tile width, the μLED mesa size was also varied. A plot of the mean EL wavelength dependence on size at 10 A/cm2 for all tile sizes under consideration is shown in FIG. 53(d). The emission spectra were observed to be largely independent of the LED mesa size, suggesting a uniform indium incorporation across each tile as can also be observed from the EL images of a 7 μm×7 μm device on a 20 μm wide tile in FIG. 53(e). For 8 μm wide tiles, pLEDs with active regions of 2.5, 3 and 4 μm exhibited nominally the same mean EL wavelength of 562 nm at 10 A/cm2, with a maximum variation of ±4 nm across these devices for any given current density. The on-wafer EQE, measured in the manner previously described, ranged between 0.12% and 0.2% at 100 A/cm2. For 10 μm wide tiles, pLEDs with active regions of 3, 4, 5 and 6 μm emitted nominally at the same mean EL wavelength of 552 nm at 10 A/cm2, with a maximum variation of ±3 nm across devices (for any given current density) and on-wafer EQE of ˜0.2-0.4% at 100 A/cm2. The pLEDs with active regions of 4, 5, 6 and 7 μm fabricated on 12 μm wide tiles showed EL at nominally the same mean wavelength of 545 nm at 10 A/cm2, with a maximum variation of +2 nm across devices (for any given current density) and on-wafer EQE of ˜25-0.43% at 100 A/cm2. On 20 μm tiles, LEDs with active regions of 3.5, 4, 5, 5.5, 6 and 7 μm exhibited nominally at the same mean EL wavelength of 526 nm at 10 A/cm2, with a maximum variation of 2 nm across devices (for any given current density) and on-wafer EQE of ˜0.25-0.44% at 100 A/cm2. All devices showed a linear rise in EQE with increasing current density with no signs of saturation. There was a clear trend of increase in EQE with increasing μLED size as has been observed in studies [16-18]. As mentioned before, this trend arose from an increased surface-area-to-volume ratio for decreased μLED size, which increases nonradiative SRH recombination at the edge of the device mesa. Etched surfaces are known to possess crystallographic defects, impurities, nitrogen vacancies, and dangling bonds that can introduce trap states within the bandgap which can act as nonradiative recombination centers. The decline in EQE with decreasing μLED size can be suppressed through further improvements in the μLED fabrication process. There was also a clear trend of decrease in reverse leakage current with increasing μLED size as observed for μLEDs with mesa sizes 3.5 μm×3.5 μm, 5.5 μm×5.5 μm and 7 μm×7 μm fabricated on the same tile size of 20 μm×20 μm tile size in FIG. 53 (b), as has also been observed in studies [16, 46-48]. The device with smaller size exhibit higher leakage current because of higher surface leakage as the etch damage impact is more pronounced with higher perimeter to area ratio. At higher current densities (in the forward bias) where high injection effects and series resistance dominate, results in all the devices exhibiting similar IV characteristics indicating comparable carrier transport across device sizes.

The μLED analysis further showed a blueshift in the EL wavelength with increasing current density, which was more severe for devices fabricated on smaller tiles. As the indium incorporation in the InGaN wells of the MQW active region increased with decreasing tile size, the barriers of the MQWs were still composed of AlGaN and GaN, giving rise to higher piezo-electric fields in the LED active region and hence a higher quantum confined Stark effect (QCSE). This blueshift can be lowered by using InGaN as barrier material in the MQWs.

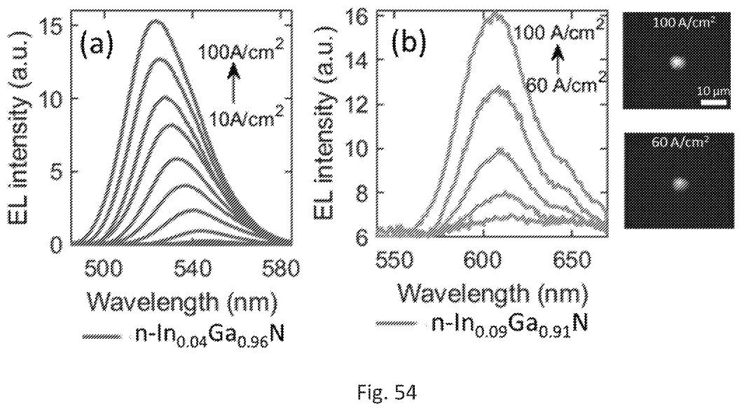

In the second experiment, the growth conditions of the n-InxGa1-xN region were tuned (growth temperature lowered by 45° C.) in order to increase the nominal mole-fraction ‘x’ from 0.04 to 0.09. μLEDs with 4 μm×4 μm active regions were fabricated on 10 μm wide tiles. For x=0.04, the devices from the first experiment were used, exhibiting a turn on at ˜3 V and EL at 553 nm at 10 A/cm2, with an on-wafer EQE of 0.4% at 100 A/cm2 and estimated MQW indium content of 0.24. In contrast, the μLEDs with nominal n-In0.09Ga.91N layer showed a turn on voltage of ˜2V and about two to three orders of magnitude higher reverse leakage current compared to the μLEDs with nominal n-In0.04Ga.96N layer as shown in FIG. 54 (a). The EL at 616 nm at 60 A/cm2 DC with an on-wafer EQE of 0.001% at 100 A/cm2 as shown in FIGS. 54 (b-c) and 55 (the device emission was not strong enough to be measured with the current measurement set-up for lower current densities). Compared to the green emitting μLEDs, as the indium composition increased in the n-InxGa1-xN base layer as well as the quantum well for the orange emitting μLED, enhanced v-defect formation led to the introduction of a lot of leakage pathways. This led to an enhanced leakage current in the orange μLED. The n-InxGa1-xN layer for the sample with a nominal ‘x’¬ of 0.09 adopted a larger in-plane lattice constant compared to the LED structures with nominal n-In0.04Ga.96N layer, leading to a higher indium incorporation into the InGaN quantum wells, even though the growth conditions for the quantum wells were the same for both samples. The estimated indium content in the MQW for this device was around 0.3. As described before, this was a result of the composition pulling effect, leading to a redshift in the EL from 536 nm to 616 nm for the sample with higher indium mole-fraction, at 60 A/cm2 in the n-InGaN layer. The full-width half maximum (FWHM) of the spectra for both the devices increased with rising injection current due to band filling effects [22,49]. Although the EQE value (and the yield) of the sample with nominal n-In0.09Ga.91N layer was much lower compared to the sample with n-In0.04Ga.96N layer, this result demonstrates the potential of this technology for the fabrication of strain relaxed color-tunable μLEDs.

In conclusion, two techniques to tune the emission wavelength of InGaN μLEDs grown on tile patterned compliant GaN-on-porous-GaN pseudo-substrates (PS) were investigated. Two design parameters affected the strength of the composition pulling effect and thereby the emission wavelength of the long wavelength μLEDs. The first method involved varying the tile size of the PSs utilized for the LED structure regrowth from 20×20 μm2 to 8×8 μm2, leading to an EL redshift from 525 to 561 nm with decreasing tile size at 10 A/cm2. The second method involved changing the mole-fraction of the n-InxGa1-xN layer of the LED structure, keeping the growth conditions of the MQW and p-InGaN the same. The μLED structure with the higher nominal composition of x=0.09 in the n-InxGa1-xN layer emitted at a considerably longer wavelength of 616 nm compared to μLEDs with x=0.04 in the n-InxGa1-xN layer which emit at 536 nm, both measured at 60 A/cm2. We attribute this wavelength shift to the composition pulling effect. With either technique, or a combination of both techniques, color-tunable monolithically integrated nitride based RGB μLED arrays can be fabricated.

### REFERENCES FOR FIRST EXAMPLE

[1] Nakamura, S. and Krames. M. R., Proc. IEEE vol. 101, pp. 2211-2220 (2013)
[2] Ding, K., Avrutin, V., Izyumskaya, N., Özgur, Ü. and Morkoç, H., Appl. Sci. vol. 9, pp. 1206 (2019).
[3] Olivier, F., Tirano, S., Dupré, L., Aventurier, B., Largeron, C. and Templier, F., J. Lumin. vol. 191, pp. 112-116 (2017).
[4] Day, J., Li, J., Lie, D. Y. C., Bradford, C., Lin, J. Y. and Jiang, H. X., Appl. Phys. Lett. Vol. 99, pp. 2-4 (2011).
[5] Hwang, D., Mughal, A., Pynn, C. D., Nakamura, S. and DenBaars, S. P., Appl. Phys. Express vol. 10, pp. 032101 (2017).
[6] Gong, Z., Gu, E., Jin, S. R., Massoubre, D., Guilhabert, B., Zhang, H. X., Dawson, M. D., Poher, V., Kennedy, G. T., French, P. M. W., and Neil, M. A. A., J. Phys. D Appl. Phys. vol. 41, pp. 094002 (2008).
[7] Jiang, H. X., Jin, S. X., Li, J., Shakya, J. and Lin, J. Y., Appl. Phys. Lett. vol. 78, pp. 1303-1305 (2001).
[8] Green, R. P., McKendry, J. J. D., Massoubre, D., Gu, E., Dawson, M. D. and Kelly, A. E., Appl. Phys. Lett. vol. 102, pp. 091103 (2013).
[9] Rajbhandari, S., McKendry, J. J. D., Hernsdorf, J., Chun, H., Faulkner, G., Haas, H., Watson, I. M., O'Brien, D. and Dawson, M. D., Semicond. Sci. Technol. vol. 32, pp. 023001 (2017).
[10] Poher, V., Grossman, N., Kennedy, G. T., Nikolic, K., Zhang, H. X., Gong, Z., Drakakis, E. M., Gu, E., Dawson, M. D. and French, P. M. W., J. Phys. D Appl. Phys. vol. 41, pp. 094014 (2008)
[11] Grossman, N., Poher, V., Grubb, M. S., Kennedy, G. T., Nikolic, K., McGovern, B., Berlinguer Palmini, R., Gong, Z., Drakakis, E. M., Neil, M. A., J. Neural Eng. vol. 7, pp. 016004 (2010)
[12] Zarowna-Dabrowska, A., Neale, S. L., Massoubre, D., McKendry, J., Rae, B. R., Henderson, R. K., Rose, M. J., Yin, H., Cooper, J. M. and Gu, E., Opt. Express vol. 19, pp. 2720 (2011)
[13] Goßler, C., Bierbrauer, C., Moser, R., Kunzer, M., Holc, K., Pletschen, W., Köhler, K., Wagner, J., Schwaerzle, M. and Ruther, P., J. Phys. D Appl. Phys. vol. 47, pp. 205401 (2014)
[14] Guilhabert, B., Massoubre, D., Richardson, E., McKendry, J. J. D., Valentine, G., Henderson, R. K., Watson, I. M., Gu, E. and Dawson, M. D., IEEE Photonics Technol. Lett. vol. 24, pp. 2221-2224 (2012)
[15] Paranjpe, A., Montgomery, J., Lee, S. M. and Morath, C., SID Symposium Digest of Technical Papers vol. 49, pp. 597-600 (2018)
[16] Olivier, F., Daami, A., Licitra, C. and Templier, F., Appl. Phys. Lett. vol. 111, pp. 022104 (2017)
[17] Tian, P., McKendry, J. J., Gong, Z., Guilhabert, B., Watson, I. M., Gu, E., Chen, Z., Zhang, G. and Dawson, M. D., Appl. Phys. Lett. vol. 101, pp. 231110 (2012).
[18] Bulashevich, K. A. and Karpov, S. Y., Phys. Status Solidi RRL vol. 10, pp. 480-484 (2016).
[19] E. F. Schubert “Light-Emitting Diodes” (Cambridge University Press, Cambridge. 2006).
[20] Smith, J. M., Ley, R., Wong, M. S., Back, Y. H., Kang, J. H., Kim, C. H., Gordon, M. J., Nakamura, S., Speck, J. S., and DenBaars, S. P., Appl. Phys. Lett. vol. 116, pp. 071102 (2020)
[21] Mukai, T., Yamada, M., and Nakamura, S., Jpn. J. Appl. Phys. vol. 38, pp. 3976 (1999)
[22] Funato, M., Ueda, M., Kawakami, Y., Narukawa, Y., Kosugi. T., Takahashi, M. and Mukai, T., Jpn. J. Appl. Phys. 45, L659 (2006).
[23] Crawford, M. H., IEEE J. Sel. Top. Quantum Electron. vol. 15, pp. 1028 (2009).
[24] Langer, T., Kruse, A., Ketzer, F. A., Schwiegel, A., Hoffmann, L., Jönen, H., Bremers, H., Rossow, U. and Hangleiter, A., Phys. Status Solidi C 8, 2170 (2011).
[25] Kobayashi, A., Ohta, J. and Fujioka, H., J. Appl. Phys., vol. 99, 123513 (2006)
[26] Wang, S. J., Li, N., Park, E. H., Feng, Z. C., Valencia. A., Nause, J., Kane, M., Summers, C. and Ferguson, I., Phys. Status Solidi C, vol. 5, pp. 1736-1739 (2008)
[27] Lei, Y., Xu, J., Zhu, K., He, M., Zhou, J., Gao, Y., Zhang, L. and Chen, Y., J. Disp. Technol., vol 9, pp. 377-381 (2013)
[28] Ozaki, T., Takagi, Y., Nishinaka, J., Funato, M. and Kawakami, Y., Appl. Phys. Express, vol. 7, 091001 (2014)
[29] Ozaki. T., Funato, M. and Kawakami, Y, Appl. Phys. Express. vol. 8, 062101 (2015)
[30] Even, A., Laval, G., Ledoux, O., Ferret, P., Sotta, D., Guiot, E., Levy, F., Robin, I. C. and Dussaigne, A., Appl. Phys. Lett., vol. 110, 262103 (2017)
[31] Däubler, J., Passow, T., Aidam, R., Köhler, K., Kirste, L., Kunzer, M. and Wagner, J., Appl. Phys. Lett., vol. 105, 111111 (2014)
[32] Hestroffer, K., Wu, F., Li, H., Lund, C., Keller, S., Speck, J. S. and Mishra, U. K., Semicond. Sci. Technol., vol. 30, 105015 (2015)
[33] Lund, C., Hestroffer, K., Hatui, N., Nakamura. S., DenBaars, S. P., Mishra, U. K. and Keller, S., Appl. Phys. Express, 2017, 10, 111001(2017)
[34] Keller, S., Lund, C., Whyland, T., Hu, Y., Neufeld, C., Chan, S., Wienecke, S., Wu, F., Nakamura, S., Speck, J. S., DenBaars, S. P. and Mishra. U. K., Semicond. Sci. Technol., vol. 30, 105020 (2015)
[35] Keller, S., Schaake, C., Fichtenbaum, N. A., Neufeld, C. J., Wu, Y., McGroddy, K., David, A., DenBaars, S. P., Weisbuch, C., Speck, J. S. and Mishra, U. K., J. Appl. Phys., vol. 100, 054314 (2006)
[36] Gupta, C., Tsukada, Y., Romanczyk, B., Pasayat, S. S., James, D. A., Ahmadi, E., Keller, S. and Mishra, U. K., Jpn. J. Appl. Phys., vol. 58, 030908 (2019)
[37] Pasayat, S. S., Gupta, C., James, D. A., Cohen, D., DenBaars, S. P., Nakamura. S., Keller S., and Mishra, U. K., Semicond. Sci. Technol., vol. 34, 115020 (2019)
[38] Huang, S., Zhang, Y., Leung, B., Yuan, G., Wang, G., Jiang. H., Fan, Y., Sun, Q., Wang J., Xu, K. and Han J., ACS Appl. Mater. Interfaces, vol. 5, 11074 (2013)
[39] Pasayat, S. S.; Gupta, C.; Wang, Y.; DenBaars, S. P.; Nakamura. S.; Keller, S.; Mishra. U. K., Materials, vol. 13, 213 (2020)
[40] Pasayat, S. S., Gupta, C., Wong, M. S., Wang, Y., Nakamura, S., DenBaars, S. P., Keller, S. and Mishra, U. K., Appl. Phys. Lett., vol. 116, pp. 111101 (2020)
[41] Li. W., Pasayat. S. S., Guidry, M., Romanczyk. B., Zheng, X., Gupta, C., Hatui, N., Keller, S. and Mishra, U. K., accepted in Semicond. Sci. Technol. (2020)
[42] Zhang. Yu., Ryu, S. W., Yerino, C., Leung, B., Sun, Q., Cao. H. and Han, J., Phys. Status Solidi B, vol. 247, 1713 (2010)
[43] Alhassan A. I, Farrell R M., Saifaddin, B., Mughal, A., Wu, F., DenBaars, S. P., Nakamura, S. and Speck, J. S., Opt. Express, vol. 24, 17868 (2016)
[44] Gupta, C., Lund, C., Chan, S. H., Agarwal, A., Liu, J., Enatsu, Y., Keller, S. and Mishra, U. K., IEEE Electron Device Lett., vol. 38, pp. 353-355 (2017)
[45] Hiramatsu, K., Kawaguchi, Y., Shimizu, M., Sawaki, N., Zheleva, T., Davis, R. F., Tsuda, H., Taki, Kuwano, N. and Oki, K., MRS Internet J. Nitride Semicond., vol. 2, e6 (1997)
[46] Konoplev, S. S., Bulashevich, K. A., and Karpov, S. Y., Phys. Status Solidi A, vol. 215, pp. 1700508 (2017).
[47] Gong, Z., Jin, S., Chen, Y., McKendry, J., Massoubre, D., Watson, I. M., Gu, E. and Dawson, M. D., J. Appl. Phys. vol. 107, pp. 1 (2010).
[48] Wong, M. S., Hwang, D., Alhassan, A. I., Lee, C., Ley, R., Nakamura, S. and DenBaars, S. P., Opt. Express vol. 26, pp. 5787 (2018)
[49] S. P. Chang, S. P., Wang, C. H., Chiu, C. H., Li, J. C., Lu, Y. S., Li, Z. Y., Yang, H. C., Kuo, H. C., Lu, T. C. and Wang, S. C., Appl. Phys. Lett. vol. 97, pp. 251114 (2010)

### Example 2: Method of Growing Elastically Relaxed Crack-Free AlGaN on GaN as Substrates for Ultrawide Bandgap Devices Using Porous GaN

Crack-free 1.3 μm thick elastically relaxed AlₓGa₁₋ₓN layers were demonstrated on compliant high fill-factor 10×10 μm² tile patterned GaN-on-porous-GaN pseudo-substrates (PS). The porous GaN was utilized as a semi-flexible under-layer. The AlₓGa₁₋ₓN layer was grown in steps of 200, 300, 400 and 400 nm. While the AlₓGa₁₋ₓN layer regrown on a co-loaded GaN-on-sapphire template cracked after deposition of only 200 nm AlGaN, on the GaN-on-porous GaN patterned substrates, no cracks were observed, and smooth films were achieved. In addition, an enhanced aluminum uptake was observed as the AlGaN growths progressed on the GaN-on-porous-GaN PS, owing to composition pulling effect, until the point when the tiles started to coalesce. Upon further regrowth on these coalesced tiles the aluminum uptake saturated, while the surface remained crack-free and smooth.

The large bandgap energy tunability of (Al,Ga)N from 3.4 eV for GaN to 6.1 eV for AlN allows for light emitting diodes (LEDs) spanning the ultra-violet (UV) wavelength range from 210 to 341 nm, which find applications in sensing, water purification, sterilization, medical diagnostics, lithography, UV curing, security systems and plant lighting [1]. Due to their ultra-wide bandgap, (Al,Ga)N alloys are also attractive for electronic applications such as high power, high frequency and power switching devices [2]. For these applications, large area AlₓGa₁₋ₓN substrates are very attractive. When AlₓGa₁₋ₓN is grown on readily available substrates such as sapphire or silicon, often films with relatively high dislocation densities are obtained [3-4]. Threading dislocations and point defects are the main causes for non-radiative recombination in UV LEDs, leading to reduced internal and external quantum efficiencies [1,3]. When grown on GaN, the tensile strain induced by the lattice mismatch between GaN and AlₓGa₁₋ₓN leads to the cracking of thicker AlGaN layers [5]. Using plastic relaxation, crack-free Al_{0.2}Ga_{0.8}N layers on GaN templates have been demonstrated using lateral overgrowth of buried cracks [6]. Several research groups have also pursued air-bridged lateral growth of AlGaN on porous GaN or AlN base layers with an aim to reduce the dislocation density [7-8] or as a sacrificial layer for thin-film flip chip UV LEDs [9]. Bulk AlN substrates with low dislocation density can be considered as an alternative to the above methods, however they are currently very expensive and not available in large diameters [10]. The work presented here is focused on the growth of high quality elastically-relaxed crack-free AlGaN using porous GaN underlayers, with a pathway towards a large area AlGaN substrate with low dislocation densities for efficient ultra-wide bandgap optoelectronic and electronic devices.

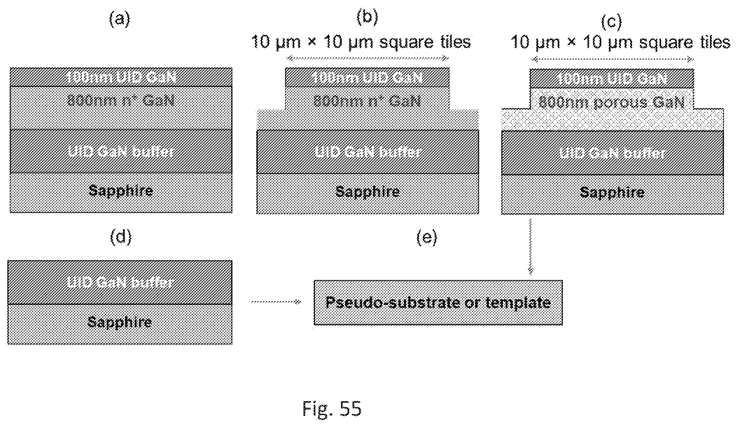

Recently, we demonstrated 10 μm×10 μm patterned compliant GaN-on-porous-GaN pseudo-substrates (PS) [11]. Due to its high surface-to-volume ratio, porous GaN exhibits reduced mechanical stiffness with increased porosity [12], akin to porous silicon [13]. To set our current AlGaN-on-porous GaN experiments in context we briefly describe our experiments of growing InGaN on compliant GaN-porous-GaN PS. In these previous experiments, a 60-140 nm thick GaN layer was grown onto n-type silicon doped GaN layers. Afterwards, the wafers were removed from the MOCVD chamber and patterned into 10 μm×10 μm sized tiles followed by porosification of the silicon doped GaN underlayer as shown in FIG. 55. Onto these compliant GaN-on-porous-GaN PSs, relaxed or partially relaxed InGaN layers were grown, taking advantage of the compliant nature of layers positioned on top of porous GaN [14]. When using these relaxed InGaN layers on GaN-on-porous-GaN pseudo-substrates as base layers, we observed enhanced indium incorporation into the InGaN layers deposited on the pseudo-substrates compared to those grown on GaN-on-sapphire base layers [11]. The enhanced indium uptake from the gas phase was attributed to the decrease in the lattice mismatch between growing InGaN layer and relaxed InGaN base layer. This effect had been observed in previous studies and was referred to as the composition pulling effect [15-19]. In this work we utilize these compliant GaN-on-porous-GaN pseudo-substrates (PSs) to grow crack-free relaxed AlₓGa₁₋ₓN.

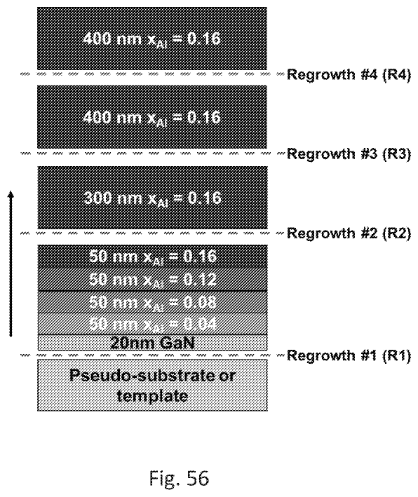

All epitaxial layers in this study were grown by metal-organic chemical vapor deposition using the precursors trimethylgallium (TMGa), trimethylaluminum (TMA), ammonia, and disilane on c-plane sapphire substrates. The epitaxial layer structure of the samples for porosification consisted of a 2.8 μm-thick unintentionally doped (UID) GaN layer followed by 800-nm-thick Si-doped GaN with a doping of 5×10¹⁸ cm⁻³, and a 100 nm-thick UID GaN cap layer (FIG. 55(a)). The sample was first patterned and dry etched using a 100 W BCl₃/Cl₂ etch chemistry resulting in 10 μm×10 μm wide tiles (FIG. 55(b)), with a total etch depth of 550 nm. In order to ease sample alignment, the mutually orthogonal sidewalls of the tiles were aligned parallel to the GaN [11̅00] and GaN [112̅0] direction, respectively. The spacing between each tile was 2 μm, making the fill factor 10 μm×10 μm per 12 μm×12 μm, or 69%. Afterwards a doping selective electrochemical (EC) etch was used for the porosification of the exposed regions of the 800 nm thick GaN:Si layers [20]. The EC etch was performed with a metal contact to the 800-nm-thick n+ GaN:Si layer on the sample as anode and a Pt wire which acted as the cathode. The etch progressed as a result of the current flowing through this GaN:Si layer etching which was exposed to the 0.3 M oxalic acid electrolyte resulting in the formation of tiles comprised of planar GaN on top of porous GaN as shown in FIG. 55(b) [11,21]. Following this process, the sample was used as pseudo-substrate for a series of AlₓGa₁₋ₓN regrowths at a temperature of 1353 K (1080° C.) and pressure of 13.33 kPa (100 torr). A total of four regrowths were performed on these samples (FIG. 56), with the morphology and strain state characterization performed after each regrowth. A co-loaded planar GaN-on-sapphire template served as reference sample for the first regrowth but was excluded from subsequent regrowths due to appearance of cracks on its surface. The compositions of the AlₓGa₁₋ₓN layers mentioned here and in the schematic structure in FIG. 56, corresponded to the compositions obtained in separate calibration runs on GaN-on-sapphire templates and will be referred to as nominal compositions. The actual compositions were obtained via x-ray diffraction measurements as discussed later. The first regrowth (R1) consisted of 20 nm GaN, followed by 50 nm each of AlₓGa₁₋ₓN with x_{Al}=0.04, 0.08, 0.12 and 0.16. The molar flows for TMAl were 0.98, 1.43, 2.24, 2.69 μmol/min and for TMGa were 14.6, 10.2, 10.2, 8.8 μmol/min, for each of these layers, respectively with a constant NH₃ flow of 178 mmol/min. The molar fraction of aluminum in the gas phase is typically higher than those measured in the solid phase for AlₓGa₁₋ₓN films grown strained on GaN. This is due to the pre-reactions between TMAl and NH₃ and hence a sub-linear relationship between the solid aluminum composition and the molar flows of the precursors was obtained as observed in studies [22-24]. The first 20 nm of GaN served as a transition layer, before introducing any misfit strain into the structure. This 20 nm along with the 100 nm GaN top layer already present in the pseudo-substrate act as compliant intermediate layer between the flexible porous GaN layer underneath and the lattice mismatched layers grown above, as reported in ref. [11]. The second regrowth (R2) consisted of 300 nm of constant composition AlₓGa₁₋ₓN with a nominal mole fraction x_{A1}=0.16. The third (R3) and fourth (R4) regrowth were 400-nm-thick constant composition AlₓGa₁₋ₓN layers with a nominal mole fraction x_{Al}=0.16. Before placing the sample back into the MOCVD chamber, it was solvent cleaned using acetone and isopropanol followed by deionized water rinse, to remove any contaminants introduced during various characterization steps. Before every regrowth, the sample was also dipped in buffered HF followed by a deionized water rinse, to remove any unintentional oxide layer formed on the surface. The surface morphology of the samples was assessed using an Asylum MFP3D atomic force microscope (AFM) and optical microscopes. High resolution X-ray diffraction (XRD) (ω-2θ)-ω reciprocal space maps (RSMs) were recorded around the GaN (1̅1̅24) reflection to evaluate AlₓGa₁₋ₓN relaxation across the tiles.

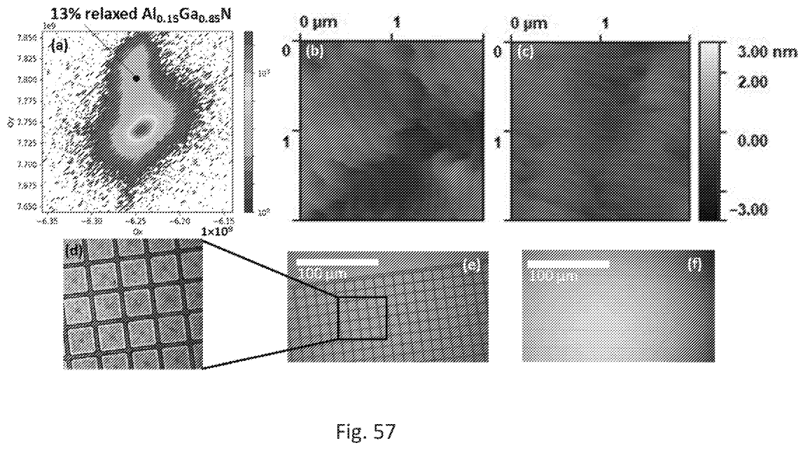

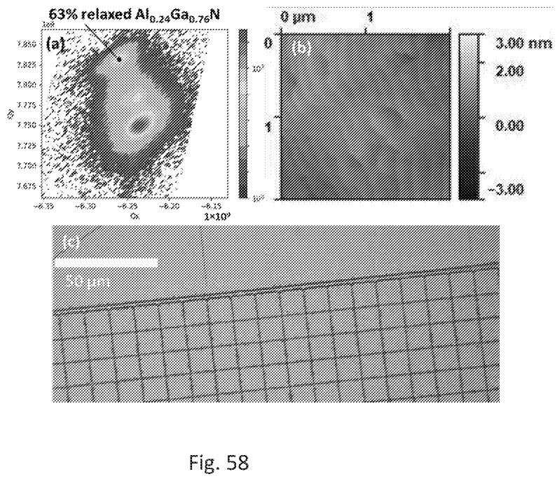

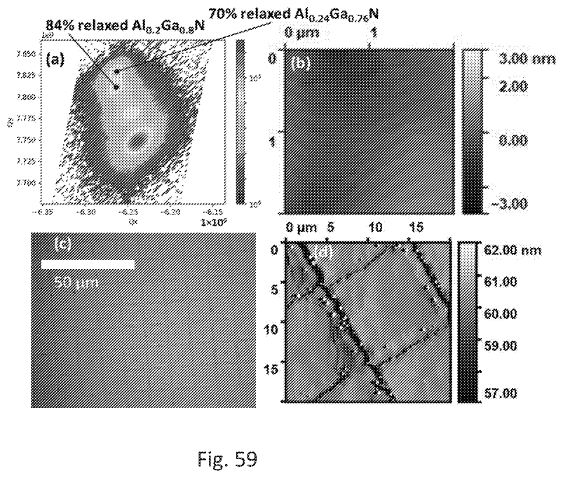

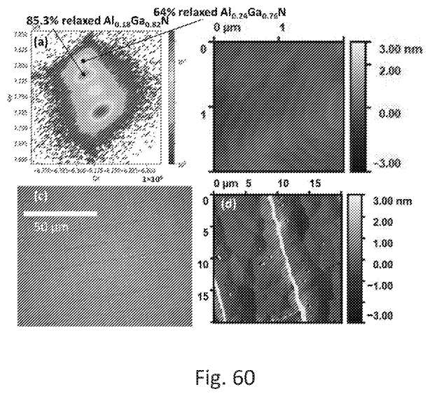

The results obtained after the first regrowth R1, involving the regrowth of the AlₓGa₁₋ₓN layers with x_{Al}˜0.04 to 0.16 on the GaN-on-porous GaN pseudo-substrates and the GaN-on-sapphire planar reference samples are displayed in FIG. 57. Cracks appeared on the reference sample as shown in FIG. 57 (f) due to plastic relaxation. In contrast, the GaN-on-porous GaN sample did not exhibit any cracks (FIG. 57(d)). The 2 μm×2 μm AFM scans on these tiles as well as crack-free region of the template, show extremely smooth surface with a root mean square (RMS) surface roughness below 0.5 nm for both samples. The RSM of the AlGaN on GaN-on-porous GaN sample shown in FIG. 57 (a) displayed a stretched out AlGaN peak due to the step graded composition of the AlGaN layer. A local maximum peak was observed for Al_{0.15}Ga_{0.85}N which was 13% relaxed. After the second regrowth R2, involving regrowth of 300 nm AlₓGa₁₋ₓN with a nominal constant composition x_{Al}=0.16, the sample was characterized again. The optical microscopy image (FIG. 58 (c)) showed evidence of lateral growth at the edges of the square tiles, as the width of the etched region in between the tiles (seen as the dark lines in between the square tiles) was visibly reduced when compared to the microscopy image of the sample after regrowth R1 displayed in FIG. 57 (d). The AFM scan in FIG. 58 (b) again showed a smooth surface with an RMS surface roughness below 0.5 nm. The RSM of this sample depicted in FIG. 58 (a) showed an additional peak corresponding to Al_{0.24}Ga_{0.76}N which was 63% relaxed. A lower composition Al_{0.09}Ga_{0.91}N peak also emerged in the RSM between the Al_{0.24}Ga_{0.76}N and GaN peaks, which we speculate to be a result of overlap of AlGaN composition shoulders from regrowth R1 and R2. After the third regrowth R3, involving 400 nm AlₓGa₁₋ₓN with a nominal composition x=0.16, the gaps between the a-AlGaN sidewalls of the tiles (characterized by the dark lines in between the tiles as in FIG. 57(e) or 57(c) following regrowths R1 and R2, respectively) were small and difficult to locate under the optical microscope, suggesting near lateral coalescence of tiles as shown in FIG. 59(c). Additionally, the tiles appeared somewhat lighter than the rest of the sample surface, due to a different refractive index of the underlying porous GaN layer. The main purpose of this microscopy image was to locate any cracks on the sample surface, and as can be seen from FIG. 59(c) no cracks were found. The RMS surface roughness on the tiles determined from the 2 μm×2 μm area AFM scan was approximately 0.5 nm (FIG. 59(b)). For better visualization of the growth on the sidewalls of the tiles, large area 20 μm×20 μm AFM scans were also performed (FIG. 59(d)). The AFM images confirmed the preferential growth at the top and bottom sidewalls of the tiles corresponding to the (112̅0) (Al,Ga)N a-plane compared to their orthogonal sidewalls corresponding to the (11̅00) (Al,Ga)N m-plane, indicating a lower lateral growth rate in the m-direction compared to the a-direction similar to observations in epitaxial lateral growth experiments[25-26]. The RSM of this sample displayed a new peak corresponding to 84% relaxed Al_{0.2}Ga_{0.8}N, in addition to the previously observed Al_{0.24}Ga_{0.76}N peak, which was now 71% relaxed (FIG. 59 (a)). After the fourth regrowth R4 of another 400 nm AlₓGa₁₋ₓN with a nominal composition of x=0.16, the microscopy image showed no cracks on the sample surface (FIG. 60(c)). The 2 μm×2 μm and 20 μm×20 μm AFM scans on this sample suggested almost complete tile coalescence in the (Al,Ga)N a-direction as shown in FIGS. 60(b) and 60(d), with an RMS surface roughness under 0.3 nm for the 2 μm×2 μm area AFM scan. A broad and higher intensity peak corresponding to 85.3% relaxed Al_{0.18}Ga_{0.82}N was observed in the RSM as shown in FIG. 60 (a). Note, that the Al_{0.24}Ga_{0.76}N peak from regrowth R3 moved slightly as well, indicating that the degree of relaxation of the layer decreased from 71% to 64%.

Despite the constant growth conditions during regrowth R2, R3, and R4, a different aluminum uptake from the gas phase was observed in the different AlGaN regrowth steps. After regrowth R1, with 50 nm each of AlₓGa₁₋ₓN with nominal x_{Al}=0.04, 0.08, 0.12 and 0.16, corresponding to a 200 nm thick AlGaN layer with an average x_{Al}(av)=0.1, a peak for 13% relaxed Al_{0.15}Ga_{0.85}N was observed. The subsequent regrowth R2 of 300 nm AlₓGa₁₋ₓN with a nominal constant composition of x_{Al}=0.16 resulted in the deposition of Al_{0.24}Ga_{0.76}N which was 63% relaxed. Not only was the Al composition significantly higher compared to that observed for growth on GaN-on-sapphire base layers, also the degree of relaxation increased from 13% observed for the first regrowth to 63% in the second regrowth step.

In elastic continuum theory, the strain energy per unit area, Eₕ, for a pseudomorphic epilayer of thickness ‘h’ on a (0001) substrate, with misfit strain ‘ϵ’, have the following relation [14]:

Eₕ∝ϵ²×h (1)

The elastic strain energy in a lattice mismatched structure has a linear relationship with layer thickness as stated in eq. (1). With an increased layer thickness, the degree of relaxation increased to compensate for the higher strain energy in the structure, thus accounting for the high degree of relaxation of 63% for the Al_{0.24}Ga_{0.76}N layer grown in regrowth R2. The enhanced aluminum uptake from the gas phase between the expected x_{Al}=0.16 and measured x_{Al}=0.24 for the 300 nm AlₓGa₁₋ₓN during regrowth R2 was attributed to the decrease in the lattice mismatch between the AlGaN layer deposited during regrowth R2 and the partially relaxed AlGaN underlayer, as seen in studies as well [27-28]. Compared to x_{Al}=0.24 in regrowth R2, a reduced aluminum uptake resulting in AlₓGa₁₋ₓN with x_{Al}=0.2 was observed in regrowth R3, and x_{Al}=0.18 was obtained in regrowth R4. We speculate that this behavior was associated with the gradual coalescence of tiles across the (Al,Ga)N a-plane, enhancing the tensile strain in the structure, resulting in a reduction of the composition pulling effect and leading to a lower aluminum uptake [27-29]. Another possibility may be that the coalescence started in the lower part of the layer structure where xv was lower than 0.2, since the final lattice constant of the top layer is nominally the same as that established after the onset of the tile coalescence. Further investigations are needed to clarify this process. To summarize, a significantly enhanced aluminum uptake on GaN-on-porous GaN PSs owing to composition pulling effect was observed only as long as the tiles were apart from each other as after regrowth R2. Upon the emergence of tile coalescence from regrowth R3 onward, the aluminum uptake was lower, but still higher compared to coherently strained growth on GaN-on-sapphire base layers (x_{Al}=0.16).

The Al_{0.2}Ga_{0.8}N layer deposited during regrowth R3 relaxed 84% and was almost lattice matched to the 71% relaxed Al_{0.24}Ga_{0.76}N layer underneath. Similarly, after regrowth R4, the lattice constant of the 85.3% relaxed Al_{0.18}Ga_{0.82}N layer on top was nominally the same as the 64% relaxed Al_{0.24}Ga_{0.76}N layer underneath, lowering the total elastic strain energy of the structure by reducing the misfit strain between subsequently grown layers (eq. (1)). Thereby no indication of crystal defect formation was observed suggesting that the AlₓGa₁₋ₓN relaxation processes were elastic, similar to the behavior observed for InₓGa₁₋ₓN in our previous studies [14]. The aluminum composition for AlₓGa₁₋ₓN grown on patterned surfaces often differs between, for example the composition on top of a mesa compared to the sidewall [30-31]. In this study the focus was directed towards the investigation of the primary area on top of the 10 μm×10 μm tiles, which could be evaluated by XRD analysis. Further investigations using transmission electron microscopy to determine the properties of the laterally grown AlGaN leading to the coalescence of the tiles are in preparation and will be presented in an upcoming publication.

The above results indicate that the aluminum composition of the top layer can likely be increased by increasing the distance between the tiles, thereby delaying the onset of tile coalescence. Additionally, if the tiles were shaped and oriented in a way to only expose a-plane GaN sidewalls, fully coalesced planar AlGaN films can be obtained. In our previous InGaN-on-porous GaN work [20], we also observed that the InGaN strain relaxation was strongly dependent upon the feature size, with larger features relaxing to a lesser extent due to the presence of higher spatial restraints when compared to smaller feature sizes. Hence, with a smaller starting tile size, a larger degree of relaxation can be achieved. Therefore, engineering the shape, size and orientation of the tiles, as well as the distance between the tiles on the GaN-on-porous-GaN PSs offers a promising path towards the development of large area AlGaN substrate with a desired lattice constant and relaxation.

In conclusion, the growth of 1.3 μm thick crack-free AlGaN was investigated on patterned compliant GaN-on-porous-GaN pseudo-substrates. Preferential coalescence of patterns along the a-GaN plane was observed, suggesting a pathway for the fabrication of large area elastically relaxed AlGaN substrates. The tile coalescence led to the locking of the lattice constant of the top AlGaN layers, enabling the ability to control the lattice constant of the AlGaN substrates fabricated with this method. Thereby the dislocation density in the AlGaN layers is expected to correspond to that of the underlaying GaN base layer. The developed AlGaN on GaN-on-porous-GaN growth technique is attractive for the fabrication of efficient ultra-wide bandgap electronic and optoelectronic devices.

### REFERENCES FOR EXAMPLE 2

[1] Kneissl, M., Seong, T. Y., Han, J. and Amano, H., “The emergence and prospects of deep-ultraviolet light-emitting diode technologies”, Nat. Photonics, vol. 13, pp. 233-244 (2019)
[2] Amano, H., Baines, Y., Beam, E., Borga, M., Bouchet, T., Chalker, P. R., Charles, M., Chen, K. J., Chowdhury, N., Chu, R., Santi, C. D., Souza, M. M. D., Decoutere. S., Cioccio, L. D., Eckardt, B., Egawa, T., Fay. P., Freedsman, J. J., Guido. L., Hberlen, O., Haynes, G., Heckel, T., Hemakumara, D., Houston, P., Hu, J., Hua, M., Huang, Q., Huang, A., Jiang, S., Kawai, H., Kinzer, D., Kuball, M., Kumar, A., Lee, K. B., Li, X., Marcon, D., MBrz, M., McCarthy, R., Meneghesso, G., Meneghini, M., Morvan. E., Nakajima, A., Narayanan, E. M. S., Oliver, S., Palacios, T., Piedra, D., Plissonnier, M., Reddy, R., Sun, M., Thayne, I., Torres, A., Trivellin, N., Unni, V., Uren, M. J., Hove, M. V., Wallis, D. J., Wang, J., Xie, J., Yagi, S., Yang, S., Youtsey, C., Yu, R., Zanoni. E., Zeltner. S. and Zhang, Y., “The 2018 GaN power electronics roadmap,” J. Phys. D 51, 163001 (2018)
[3] Ban, K., Yamamoto, J., Takeda, K., Ide, K., Iwaya. M., Takeuchi, T., Kamiyama, S., Akasaki, I. and Amano, H., “Internal Quantum Efficiency of Whole-Composition-Range AlGaN Multiquantum Wells”, Appl. Phys. Express. vol. 4, 052101 (2011)
[4] Reentila. O., Brunner, F., Knauer, A., Mogilatenko, A., Neumann, W., Protzmann, H., Heuken, M., Kneissl, M., Weyers, M. and Trinkle. G.; “Effect of the AlN nucleation layer growth on AlN material quality”, J. Cryst. Growth, vol. 310, pp. 4932-4934 (2008)
[5] Ito, K., Hiramatsu, K., Amano, H. and Akasaki, I., “Preparation of AlₓGa₁₋ₓN/GaN heterostructure by MOVPE”. J. Cryst. Growth. vol. 104, pp. 533-538 (1990)
[6] Bethoux, J.-M., Venndgues, P., Natali, F., Feltin, E., Tottereau, O., Nataf, G., De Mierry, P. and Semond, F., “Growth of high quality crack-f-ee AlGaN films on GaN templates using plastic relaxation through buried cracks”, J. Appl. Phys., vol. 94, pp. 6499 (2003)
[7] Wang, T., Bai, J., Parbrook, P. J. and Cullis, A. G., “Air-bridged lateral growth of an Al_{0.98}Gaa_{0.02}N layer by introduction of porosity in an AlN buffer”, Appl. Phys. Lett., vol. 87, pp. 151906 (2005)
[8] Qhalid Farced, R. S., Adivarahan, V., Chen, C. Q., Rai, S., Kuokstis, E., Yang, J. W., Khan, M. A., Caissie, J. and Molnar, R. J., “Air-bridged lateral growth of crack-free Al_{0.24}Ga_{0.76}N on highly relaxed porous GaN”, Appl. Phys. Lett., vol. 84, pp. 696 (2004)
[9] Bergmann, M. A., Enslin, J., Yapparov, R., Hjort, F., Wickman, B., Mercinkevičius, S., Wernicke, T., Kneissl, M. and Haglund, Å., “Electrochemical etching of AlGaN for the realization of thin-film devices”, Appl. Phys. Lett., vol. 115, pp. 182103 (2019)
[10] Bondokov, R. T., Mueller, S. G., Morgan, K. E., Slack, G. A., Schujman, S., Wood, M. C., Smart, J. A. and Schowalter. L. J., “Large area AlN substrates for electronic applications: An industrial perspective”, J. Cryst. Growth, vol. 310, pp. 4020-4026(2008)
[11] Pasayat, S. S., Gupta, C., Wong, M. S., Wang, Y., Nakamura. S., DenBaars, S. P., Keller, S. and Mishra. U. K., “Growth of strain-relaxed InGaN on micrometer-sized patterned compliant GaN pseudo-substrates”, Appl. Phys. Lett., vol. 116, pp. 111101 (2020)
[12] Huang, S., Zhang, Y., Leung, B., Yuan, G., Wang, G., Jiang, H., Fan, Y., Sun, Q., Wang J., Xu, K. and Han J., “Mechanical Properties of Nanoporous GaN and Its Application for Separation and Transfer of GaN Thin Films”, ACS Appl. Mater. Interfaces, vol. 5, 11074 (2013)
[13] Fakir, S., Montagne, A., Rahmoun. K., lost, A. and Ziouche, K., “Mechanical properties of porous silicon and oxidized porous silicon by nanoindentation technique”, Mater. Sci. Eng. A, vol. 711, 470 (2018)
[14] Pasayat, S. S.; Gupta, C.; Wang, Y.; DenBaars, S. P.; Nakamura, S.; Keller, S.; Mishra, U. K., “Compliant Micron-Sized Patterned InGaN Pseudo-Substrates Utilizing Porous GaN”, Materials, vol. 13, 213 (2020)
[15] Kobayashi, A., Ohta, J. and Fujioka, H. “Low temperature epitaxial growth of In_{0.25}Ga_{0.75}N on lattice-matched ZnO by pulsed laser deposition”, J. Appl. Phys., vol. 99, 123513 (2006)
[16] Even, A., Laval, G., Ledoux. O., Ferret, P., Sotta, D., Guiot, E., Levy, F., Robin, I. C. and Dussaigne, A., “Enhanced In incorporation in full InGaN heterostructure grown on relaxed InGaN pseudo-substrate”, Appl. Phys. Lett., vol. 110, 262103 (2017)
[17] Daubler, J., Passow, T., Aidam, R., Köhler, K., Kirste, L., Kunzer, M. and Wagner, J., “Long wavelength emitting GaInN quantum wells on metamorphic GaInN buffer layers with enlarged in-plane lattice parameter”, Appl. Phys. Lett., vol. 105, 111111 (2014)
[18] Hestroffer, K., Wu, F., Li, H., Lund, C., Keller, S., Speck, J. S. and Mishra, U. K., “Relaxed c-plane InGaN layers for the growth of strain-reduced InGaN quantum wells”, Semicond. Sci. Technol., vol. 30, 105015 (2015)
[19] Lund, C., Hestroffer, K., Hatui, N., Nakamura, S., DenBaars, S. P., Mishra, U. K. and Keller, S., “Digital growth of thick N-polar InGaN films on relaxed InGaN pseudosubstrates”. Appl. Phys. Express, 2017, 10, 111001(2017)
[20] Pasayat, S. S., Gupta. C., James, D. A., Cohen, D., DenBaars, S. P., Nakamura, S., Keller S., and Mishra, U. K., “Fabrication of relaxed InGaN pseudo-substrates composed of micron-sized pattern arrays with high fill factors using porous GaN”, Semicond. Sci. Technol., vol. 34, 115020 (2019)
[21] Zhang, Yu., Ryu, S. W., Yerino, C., Leung, B., Sun, Q., Cao, H. and Han, J., “A conductivity-based selective etching for next generation GaN devices”, Phys. Status Solidi B, vol. 247, 1713 (2010)
[22] Chen, C. H., Liu, H., Steigerwald, D., Imler, W., Kuo, C. P., Craford, M. G., Ludowise, M., Lester, S. and Amano, J., “A study of parasitic reactions between NH₃ and TMGa or TMAl”, J. Electron. Mater., vol. 25. pp. 1004-1008 (1996)
[23] Han, J., Figiel, J. J., Crawford, M. H., Banas, M. A., Bartram, M. E., Biefeld, R. M., Song. Y. K. and Nurmikko. A. V., “OMVPE growth and gas-phase reactions of AlGaN for UV emitters”, J. Cryst. Growth, vol. 195, pp. 291-296 (1998)
[24] Matsumoto, K. and Tachibana, A., “Growth mechanism of atmospheric pressure MOVPE of GaN and its alloys: gas phase chemistry and its impact on reactor design”. J. Cryst. Growth, vol. 272, pp. 360-369 (2004)
[25] Kapolnek, D., Keller, S., Vetury, R., Underwood, R. D., Kozodoy, P., DenBaars, S. P. and Mishra, U. K., “Anisotropic epitaxial lateral growth in GaN selective area epitaxy”, Appl. Phys. Lett., vol. 71, 1204 (1997)
[26] Beaumont, B., Vennéguès, Ph. and Gibart, P., “Epitaxial Lateral Overgrowth of GaN”, Phys. Stat. Sol. (b), vol. 227, pp. 1-43 (2001)
[27] Hiramatsu, K., Kawaguchi. Y., Shimizu, M., Sawaki, N., Zheleva. T., Davis, R. F., Tsuda, H., Taki, Kuwano, N. and Oki, K., “The Composition Pulling Effect in MOVPE Grown InGaN on GaN and AlGaN and its TEM Characterization. MRS Internet J. Nitride Semicond., vol. 2, e6 (1997)
[28] Chen, Z., Pei, Y., Newman, S., Brown, D., Chung, R., Keller, S., DenBaars, S. P., Nakamura, S. and Mishra, U. K., Growth of AlGaN/GaN/AlGaN double heterojunction field-effect transistors and the observation of a composition pulling effect”, Appl. Phys. Lett., vol. 94, 171117 (2009)
[29] Nix, W. D. and Clemens, B. M., “Crystallite coalescence: A mechanism for intrinsic tensile stresses in thin films”, J. Mater. Res., vol. 14, pp. 3467-3473 (1999)
[30] Bell, A., Liu, R., Parasuraman, U. K., Ponce, F. A., Kamiyama, S., Amano, H. and Akasaki, I., “Spatial variation of luminescence form AlGaN grown by facet controlled epitaxial lateral overgrowth”, Appl. Phys. Lett., vol. 85, pp. 3417 (2004)
[31] Follstaedt, D. M., Allerman, A. A., Lee, S. R., Michael, J. R., Bogart, K. H. A., Crawford, M. H. and Missert, N. A., “Dislocation reduction in AlGaN grown on patterned GaN”, J. Cryst. Growth, vol. 310, pp. 766-776 (2008)

### Example 3: Growth of Strain-Relaxed InGaN on Micron-Sized Patterned Compliant GaN Pseudo-Substrates

The compliant behavior of high fill-factor 10×10 μm² square patterned 60-140 nm thick GaN-on-porous-GaN tiles was demonstrated by utilizing porous GaN as semi-flexible under-layer. High resolution x-ray diffraction measurements showed a larger a-lattice constant of InGaN layers deposited on these patterned GaN-on-porous GaN pseudo-substrates in comparison to those deposited on co-loaded planar GaN-on-sapphire templates. Additionally, InGaN based light emitting diode (LED) structures deposited on these GaN pseudo-substrates exhibited room temperature electroluminescence at 547 nm compared to 506 nm for the LED structures grown on the co-loaded planar GaN on sapphire templates, corresponding to a redshift of around 40 nm. The longer emission wavelength was associated with the higher indium incorporation into the InGaN quantum wells deposited on the compliant GaN pseudo-substrates, owing to a reduced lattice mismatch between the quantum well and the n-InGaN base layers grown on the compliant pseudo-substrates, due to the composition pulling effect.

The large bandgap energy tunability of (Ga,In)N from 0.7 eV for InN to 3.4 eV for GaN is very attractive for both optoelectronic and electronic applications. However, it is difficult to grow high-quality InGaN with composition greater than 30%, mainly due to the large lattice mismatch of 10% between InN and GaN [1-3]. The misfit strain also leads to a reduced indium incorporation through the so-called composition pulling effect [4-5]. The availability of a relaxed InGaN buffer layer which would reduce the lattice mismatch between the base layers and the quantum wells (QWs), is hence highly desirable to obtain high efficiency long wavelength (>500 nm) III-N LEDs or lasers. Attempts have been made to fabricate as-grown relaxed InGaN buffers on substrates such as ZnO [6-8] and ScAlMgO₄ [9-10], however, the very low growth temperatures required for deposition on ZnO and the high n-type conductivity of InGaN grown on ScAlMgO₄ substrates have made MOCVD growth efforts on these substrates very challenging. Alternately, partially relaxed engineered InGaN substrates have been explored [3] and relaxed InGaN buffer layers have been fabricated by MBE and used as pseudo substrates for MOCVD growth [11-13]. Attempts have also been undertaken to fabricate InGaN pseudo-substrates via coalescence of relaxed nano-feature arrays [14]. Additionally, previous theoretical studies have established the advantages of ternary InGaN substrates with enlarged in-plane lattice parameters compared to GaN for the growth of high In-content InGaN QWs [15-19]. 80 to 200-nm wide InGaN fins were shown to uni-axially relax perpendicular to the fin direction [14, 20-21]. We demonstrated uni-axial and bi-axial InGaN relaxation in the micron-sized regime using porous GaN under layers [22]. Due to its high surface-to-volume ratio, porous GaN exhibits reduced mechanical stiffness with increased porosity [23], akin to porous silicon [24]. Using these relaxed InGaN-on-porous-GaN wafers as pseudo-substrates for the growth of InGaN/GaN multi-quantum wells (MQWs) we observed enhanced indium incorporation into InGaN layers grown on the pseudo-substrates and a red shift in the emission wavelength of MQWs compared to the same structures grown on GaN base layers. We also reported on the compliant nature of these InGaN pseudo-substrates [25]. Upon performing bulk In_{y}Ga_{1-y}N regrowths on relaxed InₓGa₁₋ₓN-on-porous-GaN pseudo-substrates where y≥x and measuring the lattice constant of each film, an increase in the lattice constant of the InₓGa₁₋ₓN under-layer was observed. The compliant nature of these pseudo-substrates enabled elastic strain relaxation, as opposed to plastic relaxation observed, for example, for the thick graded InGaN films grown by MBE [12]. Thereby the initial InₓGa₁₋ₓN layer was originally grown strained to GaN and relaxed after porosification of the silicon doped GaN underlayer. This approach, however, had the drawback, that the pseudo-substrate was composed of InGaN, exhibiting V-defects on the surface which had formed in part due to the initially coherently strained InGaN growth on GaN. Once formed the V-defects in InGaN layers are well known to be difficult to planarize upon subsequent growths of InGaN at reduced growth temperatures in N₂ ambient, leading to a degradation of the surface morphology [26-28]. In quantum well structures the V-defects formation is typically suppressed by implementing GaN barrier layers which are grown in the presence of H₂ at temperatures higher than that of the InGaN quantum well [29-30].

In this example, we replaced the compliant InGaN-on-porous-GaN base structure by GaN-on-porous-GaN, where the GaN top layer was free of V-defects. Upon performing bulk InₓGa₁₋ₓN regrowths on these GaN-on-porous-GaN pseudo-substrates again an increased a-InGaN lattice constant was observed in comparison to the structures grown on co-loaded GaN-on-sapphire templates. With this approach 200 nm thick 65% relaxed In_{0.12}Ga_{0.88}N with good surface morphology was obtained, corresponding to a fully relaxed InGaN film with an indium mole fraction of 0.076, which was higher than the value of 0.056 reported using InGaN-on-porous-GaN pseudo-substrate [25]. A green 5 μm×5 μm micro-LED was demonstrated using the developed complaint GaN pseudo-substrates.

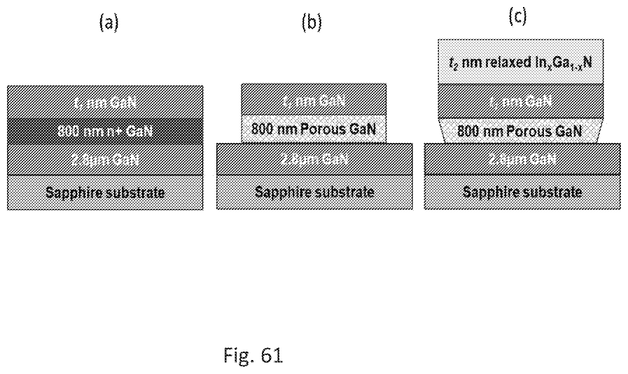

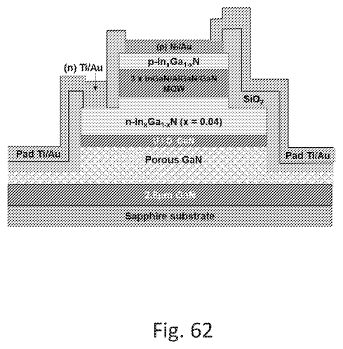

All epitaxial layers in this example were grown by metal-organic chemical vapor deposition using the precursors trimethylgallium (TMGa), triethylgallium (TEG, for InGaN growths), trimethylindium (TMI), ammonia, and disilane on c-plane sapphire substrates. The epitaxial layer structure of the samples for porosification consisted of a 2.8 μm-thick unintentionally doped (UID) GaN layer followed by 800-nm-thick Si-doped GaN with a doping of 5×10¹⁸ cm⁻³, and a 60, 100 or 140-nm-thick UID GaN cap layer (FIG. 61(a)). The samples were first patterned and dry etched using a 100 W BCl₃/Cl₂ etch chemistry resulting in 10 μm×10 μm wide tiles. The spacing between each tile was 2 μm, making the fill factor for tiles 10 μm×10 μm over 12 μm×12 μm, or 69%. The total etch depth was 510, 550 or 590 nm, corresponding to GaN cap layer thicknesses of 60, 100 or 140 nm, respectively. Afterwards a doping selective electrochemical (EC) etch was used for the porosification of the exposed regions of the 800 nm thick GaN:Si layers (FIG. 61(b)) [22]. The EC etch was performed with a metal contact to the 800-nm-thick n+ GaN:Si layer on the sample as anode and a Pt wire which acted as the cathode. The etch progressed as a result of the current flowing through this GaN:Si layer etching the region exposed to the 0.3 M oxalic acid electrolyte resulting in the formation of tiles comprised of planar GaN on top of porous GaN as shown in FIG. 61(b) [31]. Following this process, the samples were used as pseudo-substrates for subsequent regrowth of 100 or 200 nm thick InₓGa₁₋ₓN with TMI and TEG flows of 11.3 and 6.5 μmol/min at 869° C., as shown in FIG. 61(c). Co-loaded GaN-on-sapphire templates served as reference samples for each experiment. Note that in our previous experiments [22,25], an additional tile-patterned GaN-on-sapphire templates had been co-loaded with the planar GaN-on-sapphire reference wafers in order to study the effect of patterning on the properties of the regrown (In,Ga)N films. Thereby the results obtained from the patterned GaN-on-sapphire samples were similar to those from the planar reference samples. For this reason, only planar reference samples were used in subsequent experiments. Additionally, a test LED structure was deposited on a pseudo-substrate with 100 nm thick GaN layer on top of porous GaN, to establish the electroluminescence. The regrown LED structure consisted of 180 nm of Si-doped In_{0.04}Ga_{0.96}N, capped by 30 nm of Si-doped n-type GaN layer and a 10 nm UID GaN layer, prior to the growth of the active region. The active region consisted of three multi-quantum wells (MQWs) consisting of 3 nm In_{0.24}Ga_{0.76}N, a 2-nm-thick Al_{0.3}Ga_{0.7}N cap layer and 10 nm UID GaN, grown as discussed in detail elsewhere [32]. A 120 nm Mg-doped p-In_{0.04}Ga_{0.96}N layer was grown on top of the last QW followed by a 16-nm-thick Mg-doped p++-In_{0.04}Ga_{0.96}N contact layer. The thicknesses and compositions of each layer were verified via x-ray diffraction (XRD) from separate calibration samples. Following growth, mesa isolation was performed using a low power BCl₃/Cl₂ based RIE etch, followed by 200 nm SiO₂ dielectric deposition using plasma-assisted CVD. The contact regions were opened with a wet etch using buffered HF, followed by deposition of the 2 nm/5 nm Ni/Au p-contact metal stack and a combined n-contact and pad contact stack consisting of 30 nm/500 nm Ti/Au. It should be noted that this fabrication process can be significantly optimized to enhance the light output performance. However, in this study, with the goal of establishing higher Indium incorporation with electroluminescence, a basic fabrication process was used. The cross-sectional schematic of the micro-LED structure is shown in FIG. 62.

The surface morphology of the samples was assessed using an Asylum MFP3D atomic force microscope (AFM) and a JOEL7600F SEM operated at 10 kV. High resolution X-ray diffraction (XRD) (ω-2θ)-ω reciprocal space maps (RSMs) were recorded around the GaN (1̅1̅24) reflection to evaluate the InGaN relaxation across the tiles. The lattice constant of the InₓGa₁₋ₓN layer after regrowth was determined using the X-pert Epitaxy software using ‘a’ lattice constants of 3.1893 Å and 3.538 Å for GaN and InN, respectively. The lattice constant ‘ae’ of an In_{z}Ga_{1-z}N layer which was relaxed R % was calculated following Vegard's law:

$${a}_{new} = 3.1893 \times \{ 1 - ( \frac{z \times R}{100} ) \} + 3.538 \times ( \frac{z \times R}{100} ) \qquad ( 1 )$$

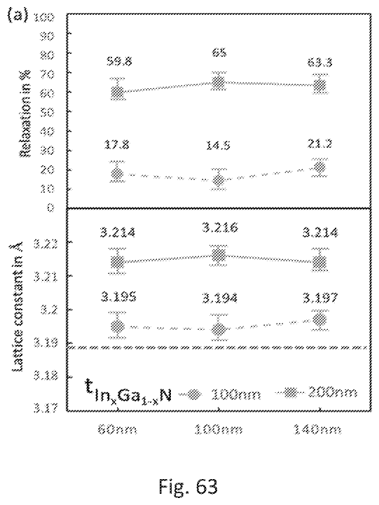

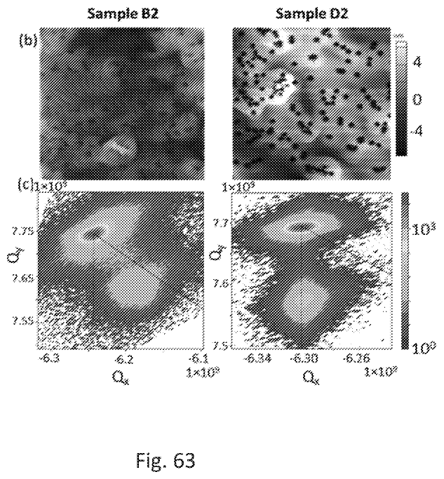

In the first experiment, we investigated the regrowth of InₓGa₁₋ₓN layers with x˜0.10-0.12 on the GaN-on-porous GaN pseudo-substrates with 60 nm, 100 nm and 140 nm thick GaN cap layers. After tile fabrication and porosification (to be referred to as samples A0, B0 and C0 corresponding to the varying cap thickness of 60, 100 and 140 nm, respectively), 100 and 200-nm-thick InₓGa₁₋ₓN layers were grown. The samples with 100 nm thick InₓGa₁₋ₓN will be referred to as samples A1. B1 and C1, and those with 200 nm thick InₓGa₁₋ₓN as samples A2, B2 and C2. Planar GaN-on-sapphire templates were co-loaded in the reactor with these samples to ensure the same growth conditions as on the pseudo-substrates, to be referred to as D1 and D2, for the two different InₓGa₁₋ₓN thicknesses, respectively. The lattice constants obtained from the reciprocal space maps of samples A1, B1 and C1 after 100 nm InₓGa₁₋ₓN deposition were very similar, approximately 3.195 Å. The average relaxation was around 20%. However, after deposition of 200-nm-thick InₓGa₁₋ₓN, the average relaxation increased to values around 60% for samples A2, B2 and C2. With increasing InₓGa₁₋ₓN thickness, the driving force towards relaxation of the InₓGa₁₋ₓN layer rose as observed when growing InGaN on InGaN-on-porous-GaN previously [25]. The lattice constants and relaxation values for samples A1, B1, C1, A2, B2 and C2, are shown in FIG. 63(a), with a grey dashed line in the lower region of the bottom plot, corresponding to the InₓGa₁₋ₓN layers grown on the co-loaded GaN template, which were coherently strained exhibiting a lattice constant equal to that of GaN. The indium mole-fraction for each of these samples along with the data plotted in FIG. 63 (a) are also summarized in table I. FIG. 63(b) illustrates the AFM images of sample B2 with 100 nm GaN cap and 200 nm regrown InₓGa₁₋ₓN, and the corresponding reference sample D2 with 200 nm InₓGa₁₋ₓN grown strained on the co-loaded GaN-on-sapphire template. The RSMs of the two samples are depicted in in FIG. 63(c). The AFM images show a drastic reduction in V-defect density for sample B2 grown on the GaN-on-porous-GaN pseudo-substrate compared to the reference sample D2 grown on the GaN-on-sapphire template, which can be attributed to the strain relaxation in sample B2, as was shown previously [26-28,33].

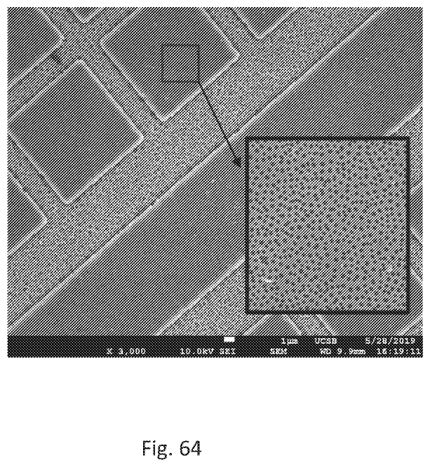

Interestingly, the relaxation of In % Ga₁₋ₓN, was independent of the GaN cap layer thickness in the range of 60 to 140 nm, suggesting that the compliant behavior of the GaN cap layer was not affected by its thickness in the investigated parameter range. Note that for a GaN cap thickness of only 30 nm, the pores penetrated through the cap layer as can be seen in the plan view SEM image depicted in FIG. 64.

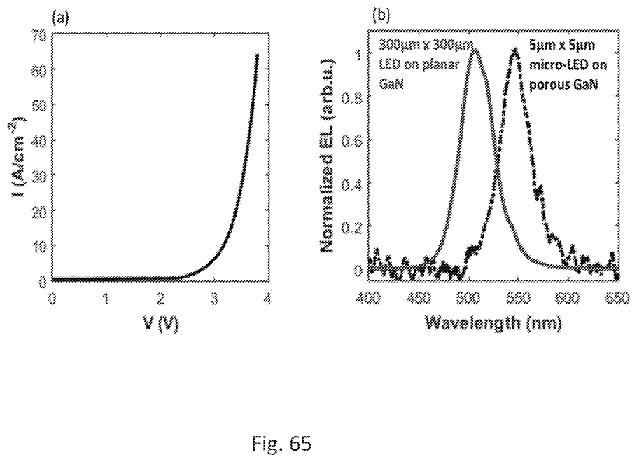

In the second experiment, a sample with 100 nm thick GaN cap and a tile size similar to sample B0 was used as a pseudo-substrate to deposit the all InGaN LED structure described above, with a co-loaded planar GaN-on-sapphire template wafer for reference. The starting pseudo-substrate for the LED deposition was patterned using an optical mask with a tile arrangement compatible with a micro-LED process, different from the mask used for the previous experiments with a periodic 10 μm×10 μm tile array, which had been chosen to ease the epitaxial layer characterization. A micro-LED with a lateral dimension of 5 μm×5 μm was fabricated on the pseudo-substrate wafer as mentioned before. The device exhibited a turn-on voltage of about 3.5 V (FIG. 65(a)), and room temperature electroluminescence at 547 nm under 50 A/cm² direct current (DC) (FIG. 65(b)). For comparison purpose, a large 300 μm×300 μm LED was tested on the co-loaded GaN-on-sapphire template, which showed emission at 506 nm at the same current density. Hence, using compliant GaN pseudo-substrates, a redshift in EL of almost 40 nm was obtained. Similar to the results on InGaN-on-porous-GaN tiles as well [25], an increased indium uptake into thick InGaN layers grown on the GaN-on-porous-GaN pseudo-substrates compared to the GaN-on-sapphire reference samples was seen in the RSMs in this study. This effect was more pronounced the thicker the regrown InGaN layers, as the degree of relaxation and the in-plane lattice constant of the InGaN layers increased (Table I). For the 200 nm thick regrown InₓGa₁₋ₓN layers, the indium mole fraction rose from 0.1 to 0.117, comparable to the increase in the indium composition observed on InGaN-on-porous-GaN tiles [25]. Hence, during the deposition of the quantum well region of the LED structure, the indium incorporation was enhanced on the GaN-on-porous-GaN pseudo-substrates due to the increased indium uptake during growth on the partially relaxed n-InGaN region, which acted similar to the compliant InGaN-on-porous-GaN pseudo-substrate demonstrated in our previous study [25], resulting in the 40 nm red-shift of the electroluminescence peak. The enhanced indium uptake into the partially relaxed InGaN layers with an in-plane lattice constant larger than GaN was attributed to the composition pulling effect as demonstrated in previous studies [3, 6, 11-13, 15-20, 22].

Note that estimates suggested that the presence of the porous GaN did not lead to a significant change in the surface temperature (<0.2 K) in comparison to the co-loaded planar GaN-on-sapphire templates. These estimates were based on findings that the thermal conductivity of porous GaN with volumetric porosity of 50-60% is similar to that of sapphire [34-36].

In conclusion, the investigated compliant GaN-on-porous-GaN pseudo-substrates enabled the regrowth of (In,Ga)N heterostructures with significantly improved surface morphology compared to those grown on InGaN-on-porous-GaN previously, allowing the demonstration of a 5 μm×5 μm micro-LED. Similar to the observations for InGaN-on-porous-GaN pseudo substrates, an enhanced indium uptake and a red shift in the luminescence compared to growth on standard GaN-on-sapphire base layers were observed. Both findings were associated with the relaxation of the strain in the (In,Ga)N layers, enabled by the presence of the porous GaN underlayers with reduced mechanical stiffness. The developed GaN-on-porous-GaN pseudo-substrates are attractive for the fabrication of longer wavelength InGaN LEDs and specifically micro-LEDs for next generation micro-displays.

TABLE I
Summary of GaN cap layer thickness, Indium mole fraction,
relaxation, and lattice constant for various samples

| | | | | | | Correspo [symbol] |
|---|---|---|---|---|---|---|
| | | | | | | composit [symbol] |
| | GaN cap | InₓGa₁₋ₓN | | Relaxation of | | fully rela [symbol] |
| Sample id | thickness (nm) | thickness (nm) | x_{In} | InₓGa₁₋ₓN (%) | a (Å) | In_{y}Ga_{1-y} [symbol] |
| A1 | 60 | 100 | 0.102 | 17.8 | 3.195 | 0.018 |
| B1 | 100 | 100 | 0.101 | 14.5 | 3.194 | 0.015 |
| C1 | 140 | 100 | 0.1035 | 21.2 | 3.197 | 0.022 |
| D1 | Reference | 100 | 0.099 | 0 | 3.189 | 0 |
| A2 | 60 | 200 | 0.1174 | 59.8 | 3.214 | 0.07 |
| B2 | 100 | 200 | 0.1176 | 65 | 3.216 | 0.076 |
| C2 | 140 | 200 | 0.1110 | 63.3 | 3.214 | 0.07 |
| D2 | Reference | 200 | 0.1 | 0 | 3.189 | 0 |

[symbol]

indicates data missing or illegible when filed

### REFERENCES FOR EXAMPLE 3

[1] Matthews, J. W. and Blakeslee, A. E., “Defects in epitaxial multilayers: 1. Misfit dislocations”, J. Cryst. Growth, vol. 27, pp. 118-125 (1974)
[2] Holec, D; Costa, P. M. F. J., Kappers, M. J. and Humphreys, C. J., “Critical thickness calculation for InGaN/GaN”, J. Cryst. Growth. vol. 303, pp. 314-317 (2007)
[3] Even, A., Laval, G., Ledoux, O., Ferret, P., Sotta, D., Guiot, E., Levy, F., Robin, I. C. and Dussaigne, A., “Enhanced In incorporation in full InGaN heterostructure grown on relaxed InGaN pseudo-substrate”, Appl. Phys. Lett., vol. 110, 262103 (2017)
[4] Pereira, S., Correia, M. R., Pereira, E., O'Donnel, K. P., Trager-Cowan, C., Sweeny, F. and Alves, E., “Compositional pulling effects in InₓGa₁₋ₓN/GaN layers: A combined depth-resolved cathodoluminescence and Rutherford backscattering/channeling study”, Phys. Rev. B, vol. 64, 205311 (2011)
[5] Hiramatsu, K., Kawaguchi, Y., Shimizu, M., Sawaki, N., Zheleva., T., Davis, R. F., Tsuda, H., Taki, Kuwano, N. and Oki, K., “The Composition Pulling Effect in MOVPE Grown InGaN on GaN and AlGaN and its TEM Characterization” MRS Internet J. Nitride Semicond., vol. 2, e6 (1997)
[6] Kobayashi, A., Ohta, J. and Fujioka, H. “Low temperature epitaxial growth of In_{0.25}Ga_{0.75}N on lattice-matched ZnO by pulsed laser deposition”, J. Appl. Phys., vol. 99, 123513 (2006)
[7] Wang, S. J., Li, N., Park, E. H., Feng, Z. C., Valencia, A., Nause, J., Kane, M., Summers, C. and Ferguson, I. “MOCVD growth of GaN-based materials on ZnO substrates”, Phys. Status Solidi C, vol. 5, pp. 1736-1739 (2008)
[8] Lei, Y., Xu, J., Zhu, K., He, M., Zhou, J., Gao, Y., Zhang, L. and Chen, Y. “A GaN-Based LED With Perpendicular Structure Fabricated on a ZnO Substrate by MOCVD”, J. Disp. Technol., vol 9, pp. 377-381 (2013)
[9] Ozaki, T., Takagi, Y., Nishinaka, J., Funato, M. and Kawakami, Y. “Metalorganic vapor phase epitaxy of GaN and lattice-matched InGaN on ScAlMgO₄ (0001) substrates”, Appl. Phys. Express, vol. 7, 091001 (2014)
[10] Ozaki, T., Funato, M. and Kawakami, Y. “InGaN-based visible light emitting diodes on ScAlMgO₄ (0001) substrates”, Appl. Phys. Express, vol. 8, 062101 (2015)
[11] Daubler, J., Passow, T., Aidam, R., Kohler, K., Kirste, L., Kunzer, M. and Wagner, J., “Long wavelength emitting GaInN quantum wells on metamorphic GaInN buffer layers with enlarged in-plane lattice parameter”, Appl. Phys. Lett., vol. 105,111111(2014)
[12] Hestroffer, K., Wu, F., Li, H., Lund, C., Keller, S., Speck, J. S. and Mishra, U. K., “Relaxed c-plane InGaN layers for the growth of strain-reduced InGaN quantum wells”, Semicond. Sci. Technol., vol. 30, 105015 (2015)
[13] Lund, C., Hestroffer, K., Hatui, N., Nakamura, S., DenBaars, S. P., Mishra, U. K. and Keller, S., “Digital growth of thick N-polar InGaN films on relaxed InGaN pseudosubstrates”. Appl. Phys. Express, 2017, 10, 111001(2017)
[14] Keller, S., Lund, C., Whyland, T., Hu, Y., Neufeld, C., Chan, S., Wienecke, S., Wu, F., Nakamura, S., Speck, J. S., DenBaars, S. P. and Mishra, U. K., “InGaN lattice constant engineering via growth on (In, Ga) N/GaN nanostripe arrays”, Semicond. Sci. Technol., vol. 30, 105020 (2015)
[15] Zhang, J. and Tansu, N., “Improvement in spontaneous emission rates for InGaN quantum wells on ternary InGaN substrate for light-emitting diodes”, J. Appl. Phys., vol. 110, 113110 (2011)
[16] Zhang, J. and Tansu, N., “Optical Gain and Laser Characteristics of InGaN Quantum Wells on Ternary InGaN Substrates”, IEEE Photonics J., vol. 5, 2600111 (2011)
[17] Pal, J., Migliorato, M. A., Li, C. K., Wu, Y. R., Crutchley, B. G., Marko, I. P. and Sweeney, S. J., “Enhancement of efficiency of InGaN-based light emitting diodes through strain and piezoelectric field management”, J. Appl. Phys., vol. 114, 073104 (2013)
[18] Sharma, T. K. and Towe, E., “On ternary nitride substrates for visible semiconductor light-emitters”, Appl. Phys. Lett., vol. 96, 191105 (2010)
[19] Park, S. H., Moon, Y. T., Lee, J. S., Kwon, H. K., Speck, J. S., and Ahn, D., “Spontaneous emission rate of green strain-compensated InGaN/InGaN LEDs using InGaN substrate”. Phys. Status Solidi A, vol. 208, 195 (2011)
[20] Keller, S., Schaake, C., Fichtenbaum, N. A., Neufeld, C. J., Wu, Y., McGroddy, K., David, A., DenBaars, S. P., Weisbuch, C., Speck, J. S. and Mishra, U. K., “Optical and structural properties of GaN nanopillar and nanostripe arrays with embedded InGaN/GaN multi-quantum wells”, J. Appl. Phys., vol. 100, 054314 (2006)
[21] Gupta, C., Tsukada, Y., Romanczyk, B., Pasayat, S. S., James, D. A., Ahmadi, E., Keller, S. and Mishra, U. K., “First demonstration of improvement in hole conductivity in c-plane III-Nitrides through application of uniaxial strain”, Jpn. J. Appl. Phys., vol. 58, 030908 (2019)
[22] Pasayat, S. S., Gupta, C., James, D. A., Cohen, D., DenBaars, S. P., Nakamura, S., Keller S., and Mishra, U. K., “Fabrication of relaxed InGaN pseudo-substrates composed of micron-sized pattern arrays with high fill factors using porous GaN”, Semicond. Sci. Technol., vol. 34, 115020 (2019)
[23] Huang, S., Zhang, Y., Leung, B., Yuan, G., Wang, G., Jiang, H., Fan, Y., Sun, Q., Wang J., Xu, K. and Han J., “Mechanical Properties of Nanoporous GaN and Its Application for Separation and Transfer of GaN Thin Films”, ACS Appl. Mater. Interfaces, vol. 5, 11074 (2013)
[24] Fakir, S., Montagne, A., Rahmoun, K., lost, A. and Ziouche, K., “Mechanical properties of porous silicon and oxidized porous silicon by nanoindentation technique”, Mater. Sci. Eng. A, vol. 711, 470 (2018)
[25] Pasayat, S. S.; Gupta, C.; Wang, Y.; DenBaars, S. P.; Nakamura, S.; Keller, S.; Mishra, U. K., “Compliant Micron-Sized Patterned InGaN Pseudo-Substrates Utilizing Porous GaN”, Materials. vol. 13, 213 (2020)
[26] Won, D., Weng, X. and Redwing, J. M., “Effect of indium surfactant on stress relaxation by V-defect formation in GaN epilayers grown by metalorganic chemical vapor deposition”, J. Appl. Phys., vol. 108, 093511 (2010)
[27] Wu, X. H., Elsass, C. R., Abare, A., Mack, M., Keller, S., Petroff, P. M., DenBaars, S. P. and Speck, J. S., “Structural origin of V-defects and correlation with localized excitonic centers in InGaN/GaN multiple quantum wells”, Appl. Phys. Lett., vol. 72, 692 (1998)
[28] Rhode, S. L., Fu, W. Y., Moram, M. A., Massabuau, F. C. P., Kappers, M. J., McAleese, C., Oehler, F., Humphreys, C. J., Dusane, R. O., and Sahonta, S. L., “Structural and strain relaxation effects of defects in InₓGa₁₋ₓN epilayers”, J. Appl. Phys., vol. 116, 103513 (2014)
[29] Suihkonen, S., Svensk, O., Lang, T., Lipsanen, H., Odnoblyudov, M. A., and Bougrov V. E., “The effect of InGaN/GaN MQW hydrogen treatment and threading dislocation optimization on GaN LED efficiency”, J. Cryst. Growth, vol. 298, pp. 740-743 (2007)
[30] Leem, S. J., Shin, Y. C., Kim, E. H., Kim, C. M., Lee, B. G., Moon, Y., Lee, I. H. and Kim, T. G., “Optimization of InGaN/GaN multiple quantum well layers by a two-step varied-barrier-growth temperature method”, Semicond. Sci. Technol., vol. 23, 125039 (2008)
[31] Zhang, Yu., Ryu, S. W., Yerino, C., Leung, B., Sun, Q., Cao, H. and Han, J., “A conductivity-based selective etching for next generation GaN devices”, Phys. Status Solidi B, vol. 247, 1713 (2010)
[32] Alhassan A. I, Farrell R. M., Saifaddin, B., Mughal, A., Wu, F., DenBaars, S. P., Nakamura, S. and Speck, J. S., “High luminous efficacy green light emitting diodes with AlGaN cap layer”, Opt. Express, vol. 24, 17868 (2016)
[33] Oliver, R. A., Kappers, M. J., and Humphreys, C. J., “Growth modes in heteroepitaxy of InGaN on GaN”, J. Appl. Phys., vol. 97, 013707 (2005)
[34] Vargaftik, N. B., Vinogradov, Y. K. and Yargin, V. S., Handbook of Physical Properties of Liquids and Gases, Begell House, New York (1996)
[35] Spiridon, B. F., Griffin. P. H., Jarman, J. C., Liu, Y., Zhu, T., De Luca, A., Oliver, R. A. and Udrea, F., “On-chip Thermal Insulation using Porous GaN”, Proceedings, vol. 2, 776 (2018)
[36] Li, Z., Jiang, Y., Yu, T., Yang, Z., Tao, Y., Jia. C., Chen, Z., Yang, Z., and Zhang, G., “Analyses of surface temperatures on patterned sapphire substrate for the growth of GaN with metal organic chemical vapor deposition”. Appl. Surface Science, vol. 257, 8062 (2011)

### Example 4: Compliant Micron-Sized Patterned InGaN Pseudo-Substrates Utilizing Porous GaN

The compliant behavior of densely packed 10×10 μm² square patterned InGaN layers on top of porous GaN was demonstrated. The elastic relaxation of the InGaN layers was enabled by the low stiffness of the porous GaN under layer. High resolution X-ray diffraction measurements showed that upon InGaN re-growths on these InGaN-on-porous GaN pseudo-substrates, not only the regrown layer partially relaxed, but the degree of relaxation of the InGaN pseudo-substrate layer on top of the porous GaN also showed an increase in a-lattice constant. Furthermore, methods to improve the surface morphology of the InGaN layers grown by metal-organic chemical vapor deposition (MOCVD) were explored in order to fabricate InGaN pseudo-substrates for future optoelectronic and electronic devices. The largest a-lattice constant demonstrated in this study using this improved method was 3.209 Å, corresponding to fully relaxed InGaN film with an indium composition of 0.056.

### 1. Introduction

The (In,Ga)N alloy system is attractive for various optoelectronic and electronic applications, owing to its wide tunable bandgap spanning from 0.7 to 3.4 eV. While high brightness blue and white light emitting diodes (LEDs) are commercially available, the fabrication of highly efficient (Ga, In) N based green, yellow, or red light emitting diodes (LEDs) still remains challenging [1]. Achieving high indium incorporation into InGaN alloys while maintaining high film quality remains difficult in particular due to the large lattice mismatch of 10% between GaN and InN [2-3]. The misfit strain also leads to reduced indium incorporation through the so-called compositional pulling effect [4]. A suppression of the indium incorporation into compressively strained InGaN films compared to relaxed, strain-free InGaN was found in both, experimental as well as thermodynamic studies [5-10]. Due to the reduced lattice mismatch between a relaxed InGaN buffer and the QWs, a higher Indium incorporation efficiency can be achieved. Typically, the indium composition in the quantum wells (QWs) must stay below 20%-25% to maintain good film quality [6]. The availability of a relaxed InGaN buffer layer with a lattice parameter closer to that of the QWs is hence highly desirable to obtain high efficiency long wavelength (>500 nm) III-N LEDs or lasers. Attempts have been made to fabricate as-grown relaxed InGaN buffers on substrates such as ZnO [11-13] and ScAlMgO₄ [14-15], however, the very low growth temperatures required for deposition on ZnO and the high n-type conductivity of InGaN grown on ScAlMgO₄ substrates have made MOCVD growth efforts on these substrates very challenging.

Alternately, partially relaxed engineered InGaN substrates have been explored [6] and relaxed InGaN buffer layers have been fabricated by MBE and used as pseudo substrates for MOCVD growth [9,16,17]. Attempts have also been undertaken to fabricate InGaN pseudo-substrates via coalescence of relaxed nano-feature arrays [18]. Additionally, previous theoretical studies have established the advantages of ternary InGaN substrates with enlarged in-plane lattice parameters compared to GaN for the growth of high In-content InGaN QWs [19-23]. 80 to 200-nm wide InGaN fins were shown to uni-axially relax perpendicular to the fin direction [17, 24-25]. Recently, we demonstrated uni-axial and bi-axial InGaN relaxation in the micron-sized regime [10] using porous GaN under layers. Using these relaxed InGaN-on-porous-GaN wafers as pseudo-substrates for the growth of InGaN/GaN multi-quantum wells (MQWs) we observed enhanced indium incorporation into the InGaN QWs grown on the pseudo-substrates compared to the same structure grown on GaN base layers. In this work, we report on the compliant nature of InGaN layers on top of porous GaN. Upon performing bulk In_{y}Ga_{1-y}N regrowths on relaxed InₓGa₁₋ₓN-on-porous-GaN pseudo-substrates (where y≥x), and measuring the lattice constant of each film, an increase in the lattice constant of the InₓGa₁₋ₓN layer was observed. Furthermore, the pseudo-substrate design was optimized and an InGaN-pseudo-substrate with a lattice constant corresponding to fully relaxed InGaN with an indium composition of 0.0565 and good surface morphology was obtained, which is essential for future electronic and opto-electronic devices.

### 2. Materials and Methods

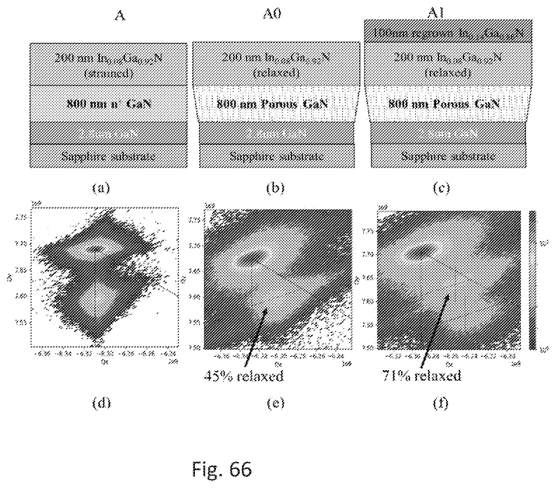

All epitaxial layers in this study were grown by metal-organic chemical vapor deposition using the precursors trimethylgallium (TMGa), triethylgallium (TEG, for InGaN growths), trimethylindium (TMI), ammonia, and disilane on c-plane sapphire substrates. The epitaxial layer structure of the samples for porosification consisted of a 2.8 μm-thick unintentionally doped (u.i.d.) GaN layer followed by 800-nm-thick Si-doped GaN with a doping of 5×10¹⁸ cm⁻³, and a 80 or 200-nm-thick compressively strained InₓGa₁₋ₓN (0.05≤x≤0.125) top layer (FIG. 66(a)). The samples were first patterned and dry etched using a 100 W BCl₃/Cl₂ etch chemistry resulting in 10 μm×10 μm wide tiles. The spacing between each tile was 2 μm, making the fill factor for tiles 10 μm×10 μm over 12 μm×12 μm, or 69%. The total etch depth was 580 or 700 nm, corresponding to InₓGa₁₋ₓN layer thicknesses of 80 or 200 nm, respectively. Afterwards a doping selective electrochemical (EC) etch was used for the porosification of the exposed regions of the 800 nm thick GaN:Si layers [10]. The EC etch was performed with a metal contact to the 800-nm-thick n+ GaN:Si layer on the sample as anode and a Pt wire which acted as the cathode. The redox reaction resulting in etching progressed as a result of the current flowing through this GaN:Si layer etching the region exposed to the 0.3 M Oxalic acid electrolyte resulting in the formation of tiles comprised of InₓGa₁₋ₓN on top of porous GaN as shown in FIG. 66(b) [26]. Following this process, the samples were used as pseudo-substrates for subsequent regrowth of 100 or 200 nm thick In_{y}Ga_{1-y}N with TMI and TEG flows of 11.3 and 6.5 μmol/min at 869° C. A co-loaded GaN-on-sapphire template served as the reference sample for each experiment.

The surface morphology of the samples was assessed using an Asylum MFP3D atomic force microscope (AFM). The V-defect density on the sample surface was determined by counting the V defects over an area of 5 μm×5 μm from multiple AFM scans and averaged to obtain the V defect density for each sample. The cross-sectional images were taken using a FEI Helios Dualbeam Nanolab 600 Focused Ion Beam (FIB) tool operated at 5 kV. High-resolution X-ray diffraction (XRD) (ω-2θ)-ω reciprocal space maps (RSMs) were recorded around the GaN (1̅1̅24) reflection to evaluate the InGaN relaxation across the tiles. In addition, ω-2θ scans around the GaN (0002) reflection were measured, all using an X'PertPro Panalytical Pixcel 3D diffractometer. The lattice constants of the InₓGa₁₋ₓN layer before and after regrowth and the In_{y}Ga_{1-y}N after regrowth, were determined using the X-pert Epitaxy software using ‘a’ lattice constants of 3.1893 Å and 3.538 Å for GaN and InN, respectively. The lattice constant ‘a_{new}’ of an In_{z}Ga_{1-z}N layer which was relaxed R % was calculated following Vegard's law:

a_{new}=3.1893×{1−(z×R/100)}+3.538×z×R/100 (1)

### 3. Results and Discussion

### 3.1. Experiment 1. InₓGa₁₋ₓN Layer Thickness 200 nm (Sample Series A)

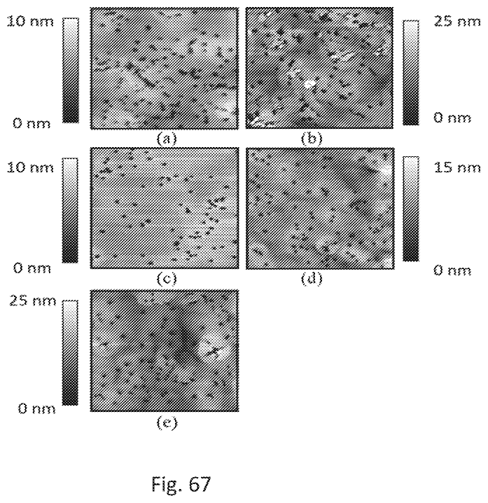

In the first experiment, we investigated the relaxation of a 200 nm-thick In % Ga₁₋ₓN layer with x=0.08, which was initially grown strained to the GaN base layers (sample A, FIG. 66(a)), after porosification of the GaN:Si underlayer (sample A0, FIG. 66(b)), and after a subsequent regrowth of an additional 100-nm-thick-In_{y}Ga_{1-y}N layer with y=0.145 (sample A1, FIG. 66(c)). Post EC etch at a bias of ˜30V, the InₓGa₁₋ₓN layer with x=0.08 was ˜45% relaxed (FIG. 66(e)) or R=45, resulting in a lattice constant of 3.202 Å. Upon subsequent regrowth of 100 nm In_{y}Ga_{1-y}N under the conditions described above, an indium mole fraction of y=0.145 was measured for the In_{y}Ga_{1-y}N regrown on the tile sample, compared to only y=0.12 for the co-loaded GaN-on-sapphire reference sample. The enhanced indium uptake can be explained by the composition pulling effect, as the lower misfit strain on the tiles led to a higher indium incorporation in the regrown layer [9]. Interestingly, regrowth of the In_{y}Ga_{1-y}N layer with a higher indium content (y=0.145) than that of the InₓGa₁₋ₓN layer underneath (x=0.08) led to an increase in the degree of relaxation of the InₓGa₁₋ₓN layer from 45% to ˜71% as shown in FIG. 66(f), corresponding to an increase of its ‘a’ lattice constant from 3.202 to 3.209 Å. This result indicates that the use of porous GaN as a mechanically flexible layer allows the InₓGa₁₋ₓN layer on the top to change its lattice constant, as known for compliant layers. The reciprocal space map displayed in FIG. 66(f) also shows a slight offset in x direction between the peaks of the InₓGa₁₋ₓN and In_{y}Ga_{1-y}N layers, indicating that the In_{y}Ga_{1-y}N layer was about 20% relaxed compared to the InₓGa₁₋ₓN layer, with an ‘a’ lattice constant of 3.214 Å. This may be attributed to the formation of additional V-defects as their density increased from 4.1×10⁸ cm⁻² to about 4.8×10⁸ cm⁻² after In_{y}Ga_{1-y}N layer regrowth, resulting in additional relaxation of the In_{y}Ga_{1-y}N layer. The V-defects often originate at the GaN/InGaN hetero-interface and their diameter increases with increasing layer thickness [27-28]. The AFM image displayed in FIG. 67(a) shows that the V-defect density was already relatively high, and larger V defects were visible upon the deposition of the 200 nm thick strained InₓGa₁₋ₓN (x=0.08) layer. Upon regrowth of the 100-nm-thick In_{y}Ga_{1-y}N (y=0.145) layer (FIG. 67(b)) the V-defects started to coalesce, and additional defect features were visible on the surface. Similar defects had been observed for thick InGaN layers [29]. In view of the deteriorating surface morphology after 100 nm In_{y}Ga_{1-y}N deposition, regrowth on 200-nm-thick InₓGa₁₋ₓN layers was not further pursued.

### 3.2. Experiment 2: InₓGa₁₋ₓN Layer Thickness 80 nm. With Varying ‘x’ (Sample Series B, C and D)

In the following experiments, the thickness of the InₓGa₁₋ₓN layer was reduced to 80 nm to reduce both the size and the density of the V-defects. Three samples with indium mole fractions of 0.05 (referred to as sample B), 0.09 (referred to as sample C), and 0.12 (referred to as sample D) were grown. After tile fabrication and porosification (samples B0, C0 and D0), 100 and 200 nm thick In_{y}Ga_{1-y}N layers were regrown. The samples with 100 nm thick In_{y}Ga_{1-y}N layers will be referred to as samples B1, C1 and D1, and those with 200 nm thick In_{y}Ga_{1-y}N as samples B2, C2, and D2.

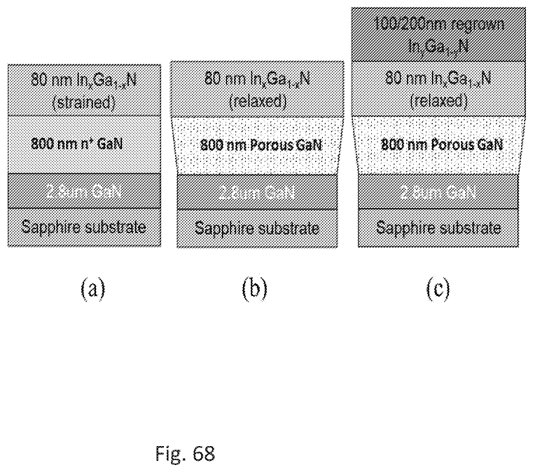

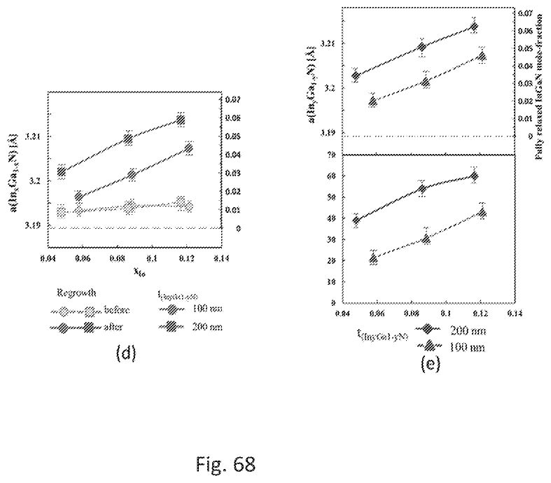

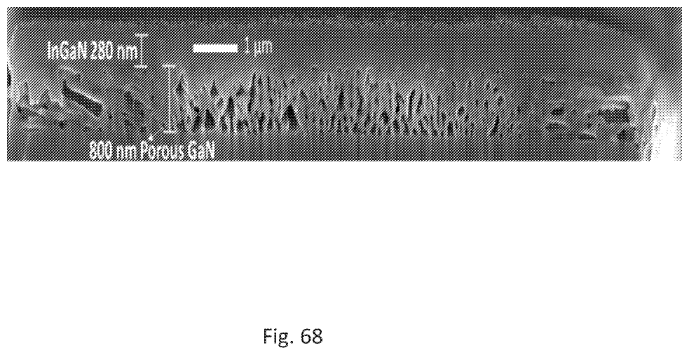

The lattice constants obtained from the reciprocal space maps of samples B0, C0, and D0 taken after tile fabrication and porosification are displayed in FIG. 68(d). The extracted lattice constants were 3.193 Å, 3.194 Å and 3.194 Å for the In_{0.05}Ga_{0.95}N, In_{0.09}Ga_{0.91}N, and In_{0.12}Ga_{0.88}N samples, respectively. This lattice constant corresponds to a fully relaxed InGaN layer with mole-fraction 0.01-0.02. The small differences between the lattice constants reflected limited relaxation of the InₓGa₁₋ₓN layer for the three samples due to the thin InₓGa₁₋ₓN layer thickness. After regrowth of 100 nm In_{y}Ga_{1-y}N the samples were examined again (samples B1, C1, and D1). The measured indium compositions of the 100 nm thick regrown In_{y}Ga_{1-y}N layers were approximately 0.105, 0.11 and 0.12 for samples B1, C1, and D1, respectively. Note that these samples were co-loaded in the reactor to ensure the same growth conditions. The extracted ‘a’ lattice constants were 3.197 Å, 3.201 Å, and 3.207 Å, respectively (FIG. 68(e)), corresponding to a degree of relaxation of the In_{y}Ga_{1-y}N layers of 21%, 31% and 43%, respectively (FIG. 68(e)). After regrowth of the 100-nm-thick In_{y}Ga_{1-y}N layer, the lattice constants of the InₓGa₁₋ₓN layer increased as well, from 3.193 to 3.197 Å for samples B0/B1 (x=0.05), from 3.194 to 3.201 Å for samples C0/C1 (x=0.09), and 3.194 to 3.207 Å for samples D0/D1 (x=0.12), as illustrated in FIG. 68(d). Comparing sample C1 (lattice constant 3.201 Å) with sample A0 (lattice constant 3.202 Å), with similar mole-fraction and total InGaN layer thickness, we observe that sample C1 has nominally the same lattice constant but without the penalty of degraded morphology as can be observed from their AFM scans in FIGS. 67(d) and 2(a), respectively.

For the samples with 200 nm thick In_{y}Ga_{1-y}N layers (B2, C2, and D2), which were all co-loaded in the reactor again, the following results were obtained (FIGS. 68 (d-e)): the measured indium compositions of the 200-nm-thick regrown In_{y}Ga_{1-y}N layers were 0.106, 0.11, and 0.12 for samples B2, C2, and D2, respectively. The extracted ‘a’ lattice constants were 3.203 Å, 3.209 Å and 3.214 Å, respectively (FIG. 68(e)), corresponding to a degree of relaxation of the In_{y}Ga_{1-y}N layers of 39%, 54% and 60% (FIG. 68(e)). Similar to the other observations, upon regrowth of the In_{y}Ga_{1-y}N layer, the lattice constants of the InₓGa₁₋ₓN layer increased again, from 3.193 to 3.203 Å for samples B0/B2 (x=0.05), from 3.194 to 3.209 Å for samples C0/C2 (x=0.09), and 3.195 to 3.214 Å and for samples D0/D2 (x=0.12) (FIG. 68(d)). The increase in In_{y}Ga_{1-y}N thickness resulted in additional stretching of InₓGa₁₋ₓN layer, which behaved as compliant layer due to its position on top of porous GaN. In addition, the relaxation of the In_{y}Ga_{1-y}N layer itself increased, from 21 to 39% (samples B1/B2), 31 to 54% (samples C1/C2), and 43 to 60% (samples D1/D2) with higher thickness of the regrown In_{y}Ga_{1-y}N layer. With increasing In_{y}Ga_{1-y}N thickness, the nominal strain in the layer rose resulting in a stronger driving force towards relaxation. In elastic continuum theory, the strain energy per unit area, Eₕ, for a pseudomorphic epilayer of thickness ‘h’ on a (0001) substrate, with misfit strain ‘c’, shear modulus ‘G’ and poisson's ratio ‘υ’ is given by [30]:

Eₕ={2G×(1+υ)ϵ²h}÷(1−υ) (2)

Considering the In_{y}Ga_{1-y}N layer as the epilayer and the InₓGa₁₋ₓN layer underneath as the substrate, the strain energy per unit area is directly proportional to the thickness of the In_{y}Ga_{1-y}N layer. When both layers are positioned on top of porous GaN, the a lattice constant of the InₓGa₁₋ₓN bottom layer is allowed to change and the strain energy can be lowered. For y≥x the a-lattice constant of the InₓGa₁₋ₓN layer increased leading to a reduction in the lattice mismatch between the In_{y}Ga_{1-y}N and InₓGa₁₋ₓN layers and a decrease of the misfit strain in equation (2). This effect was the more pronounced with the thicker In_{y}Ga_{1-y}N layer as the strain energy increased with thickness. To compensate this strain energy increase, the degree of relaxation of the In_{y}Ga_{1-y}N layers increased (FIG. 68(e)).

In addition, the decrease in lattice mismatch between the In_{y}Ga_{1-y}N and InₓGa₁₋ₓN layers with increasing x value resulted in an increase in the mole fraction y of the regrown In_{y}Ga_{1-y}N layers from 0.105 to 0.12 due to the composition pulling effect. Thereby the compositions measured for samples B1 and B2 with the lowest x value of 0.05 were similar to those obtained for the In_{y}Ga_{1-y}N layers on the corresponding GaN-on-sapphire reference samples, which amounted to y=0.1 and y=0.104 after 100 and 200 nm In_{y}Ga_{1-y}N regrowth, respectively.

### 3.3. Morphology Analysis Based on V Defect Density

While a higher indium mole fraction and thickness of the InGaN layers allowed the demonstration of layers with larger a lattice constants, the epitaxial parameter space was limited by the formation of defects. In MOCVD growth of strained InₓGa₁₋ₓN on GaN typically V-defects form in order to release strain energy [27, 28, 31]. Their density increases with increasing InₓGa₁₋ₓN composition and thickness (equation 2). As expected the V-defect density on the surface of sample A with 200-nm-thick In_{0.08}Ga_{0.92}N layer (FIG. 67 (a)), 4.1×10⁸ cm⁻², was higher than that of 3.3×10⁸ cm⁻² observed for sample C with 80-nm-thick In_{0.09}GaN_{0.91} layer (FIG. 67(c)). As discussed earlier, when the V-defect density is high and the V-defects penetrate deep into the (In,Ga)N layer, strain relaxation can occur as the sidewalls of the V-defects are free to move to accommodate the strain, often resulting in a measurable enhancement of the In incorporation in the near surface region of InGaN layers (as observed for sample A 1) or InGaN/GaN superlattices [32], due to the composition pulling effect. If the strain is too high, additional defects will form leading to a degradation of the InGaN layer properties, as observed for sample A1 (FIG. 67(b)) in this study and as has been widely studied in the past [3, 27, 28, 33, 34].

In order to mitigate the degradation in layer properties when starting with 200 nm thick as-grown strained InₓGa₁₋ₓN layers (A series of samples), an alternate approach to achieve thicker InGaN layers was to start out with a thinner, only 80-nm-thick as-grown strained InₓGa₁₋ₓN layer with a lower V-defect density. Following with porosification of the GaN:Si underneath in order to allow partial relaxation of the InₓGa₁₋ₓN layer, and continuing the InGaN deposition process afterwards, utilizing the compliant property of the 80-nm-thick InₓGa₁₋ₓN layer during the deposition, resulted in much lower V defect density. Sample C0 with 80-nm-thick In_{0.09}Ga_{0.91}N, for example, exhibited only 3.3×10⁸ cm⁻² V-defects (FIG. 67(c)) compared to 4.1×10⁸ cm⁻² for sample A0 with 200-nm-thick In_{0.09}Ga_{0.91}N (FIG. 67 (a)). After depositing a further 100-nm-thick In_{y}Ga_{1-y}N layer with y=0.11 on top of sample C0, the V-defect density on the surface increased only slightly to 3.5×10⁸ cm⁻² (sample C1. FIG. 67 (d)) and was still lower than that of sample A0 (200 nm In_{0.08}Ga_{0.92}N, V-defect density 4.1×10⁸ cm⁻²). When increasing the In_{y}Ga_{1-y}N (y=0.11) layer thickness to 200 nm (sample C2, FIG. 67 (e)), the V-defect density rose to 3.8×10⁸ cm⁻², but was still lower than that of sample A0, despite its higher average indium composition of 0.105 and higher thickness of 280 nm, compared to sample A0 with an average indium composition of x=0.08 and for the only 200 nm thick sample A0.

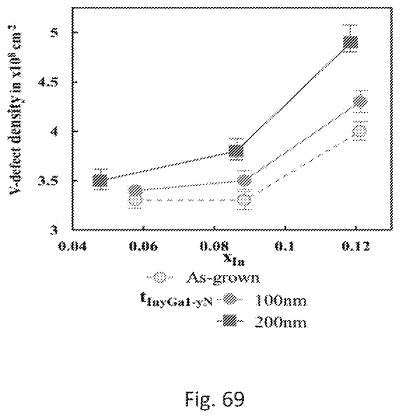

The average V-defect densities of all samples belonging to series B to D are shown in FIG. 69. Note that upon porosification of the as-grown samples no change in the V-defect density was observed. For the as-grown samples with 80-nm-thick InₓGa₁₋ₓN layers, the V-defect density increased from 3.3×10⁸ cm⁻² to 4×10⁸ cm⁻² when increasing x from 0.05 to 0.12. Although the differences in v-defect densities may not seem drastic, but it provides us with an overall guidance towards the trends to be observed for samples with different mole-fraction and total InGaN thickness.

As the InₓGa₁₋ₓN layers are initially grown coherently strained on top of the GaN:Si layers (samples B, C, and D) the strain energy increases with increasing mole fraction x, leading to a higher number of V-defects for MOCVD grown samples. Similarly, the number of V-defects in the regrown In_{y}Ga_{1-y}N layers increased with increasing x value, as the average composition of the combined layers, InₓGa₁₋ₓN and the In_{y}Ga_{1-y}N, rose as well. The more pronounced increase in V-defect density with increasing thickness of the In_{y}Ga_{1-y}N layer, samples B2, C2, and D2 versus samples B1, C1, and D1, can be attributed to the higher strain energy in the thicker layers. The circumstance, that once a V-defect has formed it typically does not coalesce or fill under the growth conditions required for InGaN deposition, low temperatures and the use of nitrogen as carrier gas in order to obtain sufficient indium incorporation in the MOCVD process, may contribute to this trend. For the above reasons, a low strain energy in the initially coherently strained InₓGa₁₋ₓN layers aided in achieving compliant partially relaxed In % Ga₁₋ₓN/In_{y}Ga_{1-y}N composite layers with low V-defect density. The degree of relaxation and the a-lattice constant of the InₓGa₁₋ₓN/In_{y}Ga_{1-y}N layer stack can be further increased through continued process optimization. In addition to thickness and composition of the layers on top of porous GaN, the degree of relaxation of the top layers is strongly dependent on the size of the etched patterns. Our study on stripe patterns showed that when the stripe width was reduced from 10 to 2 μm, the relaxation perpendicular to the stripes dramatically increased from about 60% to 100%, respectively [10]. The 10 μm×10 μm tiles in this study were chosen for their compatibility with the micro-LED size regime. As micro-LEDs are pushed towards smaller sizes for application in advanced micro displays, the pattern size for the InGaN pseudo-substrate fabrication process described here can be reduced as well, taking advantage of the larger lattice constants which can be obtained using smaller patterns.

### 4. Conclusions

In conclusion, a method to fabricate compliant InGaN pseudo-substrates was demonstrated allowing the fabrication of partially relaxed InₓGa₁₋ₓN/In_{y}Ga_{1-y}N (x=0.09, y=0.11) composite pseudo-substrates with an a-lattice constant of 3.209 Å, corresponding to fully relaxed InGaN with an indium mole fraction of 0.056. The presence of the porous GaN under-layer enabled the compliant behavior of the InGaN top layers. The fabricated InGaN pseudo-substrates are attractive for the fabrication of future electronic and optoelectronic devices.

### REFERENCES FOR EXAMPLE 4

1. Maur, M. A.; Pechhia, A.; Penazzi G.; Rodrigues, W.; Carlo, A. D. Efficiency Drop in Green InGaN/GaN Light Emitting Diodes: The Role of Random Alloy Fluctuations. Phys. Rev. Letters 2016, 116, pp. 027401. [CrossRef]
2. Matthews, J. W.; Blakeslee, A. E. Defects in epitaxial multilayers: 1. Misfit dislocations. J. Cryst. Growth, 1974, 27. pp. 118-125.[CrossRef]
3. Holec, D; Costa, P. M. F. J.; Kappers, M. J.; Humphreys, C. J. Critical thickness calculation for InGaN/GaN. J. Cryst. Growth, 2007, 303. pp. 314-317.[CrossRef]
4. Kawaguchi, Y.; Shimizu, M.; Hiramatsu, K.; Sawaki, N. The Composition Pulling Effect in InGaN Growth on the GaN and AlGaN Epitaxial Layers Grown by MOVPE. Proceedings of the Mater. Res. Soc. Symp. Vol. 449, Pittsburgh, USA, 1996; Cambridge University Press: Cambridge, UK, 2011.[CrossRef]
5. Yayama, T.; Kangawa, Y.; Kakimoto, K; Koukitu, A. Theoretical analyses of In incorporation and compositional instability in coherently grown InGaN thin films. Phys. Status Solidi C, 2010, 7-8, 2249 [CrossRef]
6. Even, A.; Laval, G.; Ledoux, O.; Ferret, P.; Sotta, D.; Guiot, E.; Levy, F., Robin. I. C.; Dussaigne, A. Enhanced In incorporation in full InGaN heterostructure grown on relaxed InGaN pseudo-substrate. Appl. Phys. Lett., 2017, 110, 262103 [CrossRef]
7. Pereira, S.; Correia. M. R.; Pereira, E., O'Donnel, K. P.; Trager-Cowan, C.; Sweeny, F.; Alves. E. Compositional pulling effects in InₓGa₁₋ₓN/GaN layers: A combined depth-resolved cathodoluminescence and Rutherford backscattering/channeling study. Phys. Rev. B, 2011, 64, 205311.[CrossRef]
8. Hiramatsu, K., Kawaguchi, Y.; Shimizu, M.; Sawaki, N.; Zheleva, T.; Davis, R. F.; Tsuda, H.; Taki, Kuwano, N.; Oki, K. The Composition Pulling Effect in MOVPE Grown InGaN on GaN and AlGaN and its TEM Characterization. MRS Internet J. Nitride Semicond. 1997, 2, e6.[CrossRef]
9. Daubler, J.; Passow, T.; Aidam, R.; Köhler, K.; Kirste, L.; Kunzer, M.; Wagner, J. Long wavelength emitting GaInN quantum wells on metamorphic GaInN buffer layers with enlarged in-plane lattice parameter. Appl. Phys. Lett., 2014, 105, 111111.[CrossRef]
10. Pasayat, S. S.; Gupta, C.; James, D. A.; Cohen, D.; DenBaars, S., P.; Nakamura. S.; Keller S.; Mishra. U. K. Fabrication of relaxed InGaN pseudo-substrates composed of micron-sized pattern arrays with high fill factors using porous GaN. Semicond. Sci. Technol., 2019, 34, 115020.[CrossRef]
11. Kobayashi, A.; Ohta, J.; Fujioka, H. Low temperature epitaxial growth of In_{0.25}Ga_{0.75}N on lattice-matched ZnO by pulsed laser deposition. J. Appl. Phys., 2006, 99, 123513.[CrossRef]
12. Wang, S. J.; Li, N.; Park, E. H.; Feng, Z. C.; Valencia, A.; Nause, J.; Kane, M.; Summers, C., Ferguson, I. MOCVD growth of GaN-based materials on ZnO substrates. Phys. Status Solidi C, 2008, 5, pp. 1736-1739.[CrossRef]
13. Lei, Y.; Xu, J.; Zhu, K.; He, M.; Zhou, J.; Gao, Y.; Zhang, L.; Chen, Y. A GaN-Based LED With Perpendicular Structure Fabricated on a ZnO Substrate by MOCVD. J. Disp. Technol., 2013, 9, pp. 377-381.[CrossRef]
14. Ozaki, T.; Takagi, Y.; Nishinaka, J.; Funato, M.; Kawakami, Y. Metalorganic vapor phase epitaxy of GaN and lattice-matched InGaN on ScAlMgO₄ (0001) substrates. Appl. Phys. Express, 2014, 7, 091001.[CrossRef]
15. Ozaki, T.; Funato, M.; Kawakami, Y. InGaN-based visible light emitting diodes on ScAlMgO₄ (0001) substrates. Appl. Phys. Express, 2015, 8, 062101.[CrossRef]
16. Hestroffer, K.; Wu, F.; Li, H.; Lund, C.; Keller, S.; Speck. J. S.; Mishra, U. K. Relaxed c-plane InGaN layers for the growth of strain-reduced InGaN quantum wells. Semicond. Sci. Technol., 2015, 30, 105015.[CrossRef]
17. Lund, C.; Hestroffer, K.; Hatui, N.; Nakamura, S.; DenBaars, S. P.; Mishra, U. K.; Keller, S. Digital growth of thick N-polar InGaN films on relaxed InGaN pseudosubstrates. Appl. Phys. Express, 2017, 10, 111001.[CrossRef]
18. Keller, S.; Lund, C.; Whyland, T.; Hu, Y.; Neufeld, C.; Chan, S.; Wienecke, S.; Wu, F.; Nakamura, S.; Speck, J. S.; DenBaars, S. P.; Mishra, U. K. InGaN lattice constant engineering via growth on (in, Ga) N/GaN nanostripe arrays. Semicond. Si. Technol., 2015, 30, 105020.[CrossRef]
19. Zhang, J.; Tansu, N. Improvement in spontaneous emission rates for InGaN quantum wells on ternary InGaN substrate for light-emitting diodes. J. Appl. Phys., 2011, 110, 113110.[CrossRef]
20. Zhang, J.; Tansu, N. Optical Gain and Laser Characteristics of InGan Quantum Wells on Ternary InGaN Substrates. IEEE Photonics J., 2011, 5, 2600111.[CrossRef]
21. Pal, J.; Migliorato, M. A.; Li. C. K.; Wu, Y. R.; Crutchley, B. G.; Marko. I. P.; Sweeney, S. J. Enhancement of efficiency of InGaN-ased light emitting diodes through strain and piezoelectric field management. J. Appl. Phys., 2013, 114, 073104.[CrossRef]
22. Sharma, T. K.; Towe, E. On ternary nitride substrates for visible semiconductor light-emitters. Appl. Phys. Lett., 2010, 96, 191105.[CrossRef]
23. Park, S. H.; Moon, Y. T.; Lee, J. S.; Kwon, H. K.; Speck, J. S.; Ahn, D.
Spontaneous emission rate of green strain-compensated InGAN/InGaN LEDs using InGaN substrate. Phys. Status Solidi A. 2011, 208, pp. 195-198.[CrossRef]
24. Keller, S.; Schaake, C.; Fichtenbaum, N. A.; Neufeld, C. J., Wu, Y.; McGroddy, K.; David, A.; DenBaars, S. P.; Weisbuch, C.; Speck, J. S.; Mishra, U. K. Optical and structural properties of GaN nanopillar and nanostripe arrays with embedded InGaN/GaN multi-quantum wells. J. Appl. Phys., 2006, 100, 054314.[CrossRef]
25. Gupta, C.; Tsukada. Y.; Romanczyk, B.; Pasayat, S. S.; James, D. A.; Ahmadi, E.; Keller, S.; Mishra, U. K. First demonstration of improvement in hole conductivity in c-plane III-Nitrides through application of uniaxial strain. Jpn. J. Appl. Phys., 2019, 58, 030908.[CrossRef]
26. Zhang, Yu.; Ryu, S. W.; Yerino, C.; Leung, B.; Sun, Q.; Cao, H.; Han, J. A conductivity-based selective etching for next generation GaN devices. Phys. Status Solidi B, 2010, 247, pp. 1713-1716.[CrossRef]
27. Won, D.; Weng, X.; Redwing, J. M. Effect of indium surfactant on stress relaxation by V-defect formation in GaN epilayers grown by metalorganic chemical vapor deposition. J. Appl. Phys., 2010, 108, 093511.[Cross Ref]
28. Wu, X. H.; Elsass, C. R., Abare, A.; Mack, M.; Keller, S.; Petroff, P. M.; DenBaars, S. P.; Speck, J. S. Structural origin of V-defects and correlation with localized excitonic centers in InGaN/GaN multiple quantum wells. Appl. Phys. Lett., 1998, 72, 692.[CrossRef]
29. Rhode, S. L. Fu, W. Y.; Moram, M. A.; Massabuau, F. C. P.; Kappers, M. J.; McAleese, C.; Oehler, F.; Humphreys. C. J.; Dusane, R. O.; Sahonta, S. L. Structural and strain relaxation effects of defects in InₓGa₁₋ₓN epilayers. J. Appl. Phys., 2014, 116, 103513.[CrossRef]
30. Fischer, A.; Kiihne, H.; Roos, B.; Richter. H. Elastic strain relaxation in patterned heteroepitaxial structures. Semicond. Sci. Technol., 1994, 9, pp. 2195-2198.[CrossRef]
31. Cho, H. K.; Lee, J. Y.; Kim, C. S.; Yang, G. M.; Sharma, N.; Humphreys, C. Microstructural characterization of InGaN/GaN multiple quantum wells with high indium composition. J. Cryst. Growth, 2001, 231, pp. 466-473.[CrossRef]
32. Jiang, F.; Xhang, J.; Xu, L.; Ding, J.; Wang, G.; Wu, X.; Wang, X.; Mo, C.; Quan, Z.; Guo, X.; Zheng, C.; Pan, S.; Liu, J. Efficient InGaN-based yellow-light-emitting diodes. Photon. Res., 2019, 7, pp 144-148.[CrossRef]
33. Oliver, R. A.; Kappers, M. J.; Humphreys, C. J. Growth modes in heteroepitaxy of InGaN on GaN. J. Appl. Phys., 2005, 97, 013707.[CrossRef]
34. Kobayashi, Y.; Perez-Solorzano, V.; Off, J.; Kuhn, B.; Gräbeldinger. H.; Schweizer, H.; Scholz, F. Investigations of growth of self-assembled GaInN—GaN islands on SiC substrate by metalorganic vapor phase epitaxy, J. Cryst. Growth, 2002, 243, pp. 103-107. [CrossRef]

### Example 5: Fabrication of Relaxed InGaN Pseudo-Substrates Composed of Micron-Sized Pattern Arrays with High Fill Factors Using Porous GaN

Fully or partially relaxed micron-sized InGaN patterns with fill factors up to 69% were demonstrated via porosification of the underlying GaN:Si layer. The impact of the porosification etch conditions and the pattern geometry on the degree of InGaN relaxation were studied and monitored via high resolution x-ray diffraction reciprocal space maps. Additionally, a 45 nm redshift in the photoluminescence emission from InₓGa₁₋ₓN/In_{y}Ga_{1-y}N multi-quantum wells (MQWs) regrown on bi-axially relaxed InGaN buffer layers was observed when compared to a co-loaded reference sample grown on GaN. The longer emission wavelength was associated with higher indium incorporation into the InGaN layers deposited on the InGaN base layers with a lattice constant larger than GaN, due to the reduced lattice mismatch between MQW and InGaN base layer, also called compositional pulling effect.

### 1. Introduction

The (In,Ga)N alloy system is attractive for various optoelectronic and electronic applications, owing to its wide tunable bandgap spanning from 0.7 to 3.4 eV. While high brightness blue and white light emitting diodes (LEDs) are commercially available, the fabrication of highly efficient (Ga, In)N based green, yellow, or red light emitting diodes (LEDs) still remains challenging [1]. Achieving high Indium incorporation into InGaN alloys while maintaining high film quality has been difficult in particular due to the large lattice mismatch of 10% between GaN and InN [2-3]. The misfit strain also leads to reduced indium incorporation through the so-called compositional pulling effect [4]. Typically, the indium composition in the quantum wells (QWs) has to stay below 20%-25% to maintain good film quality [5]. For standard Ga-polar devices, the presence of the Quantum Confined Stark Effect (QCSE) enables green emission even with an indium content lower than 20%, with an increased well width; however, a reduced electron-hole wave-function overlap leads to lower quantum efficiency [6-9]. Additionally, a blue shift occurs when the injection current is increased, caused by the screening of internal electric fields by free carriers. These effects can be avoided by the use of non-polar or semi-polar growth planes, however, at the cost of higher Indium content to achieve similar emission wavelength [9-12]. The availability of a relaxed InGaN buffer layer with a lattice parameter closer to that of the QWs is hence highly desirable to obtain high efficiency long wavelength (>500 nm) III-N LEDs or lasers. Due to the reduced lattice mismatch between the buffer and the QWs, better material quality and higher Indium incorporation efficiency can be achieved [13-15]. Additionally, the lowered strain in a potential, all InGaN LED structure results in lower internal electric fields. This leads to a reduced emission shift with increasing carrier density, an increased electron-hole wave-function overlap, and hence an enhanced spontaneous emission [15-18]. Attempts have been made to achieve as grown relaxed InGaN buffers on substrates such as ZnO [19-21] and ScAlMgO₄ [22-23], however, the very low growth temperatures required for deposition on ZnO and the high n-type conductivity of InGaN grown on ScAlMgO₄ substrates have made MOCVD growth efforts on these substrates very challenging. Alternately, partially relaxed engineered InGaN substrates have been explored [5] and relaxed InGaN buffer layers have been fabricated by MBE and used as pseudo substrates for MOCVD growth [15, 24-25]. Attempts have also been undertaken to fabricate InGaN pseudo-substrates via coalescence of relaxed nanofeature arrays [26]. Additionally, theoretical studies have established the advantages of ternary InGaN substrates with enlarged in-plane lattice parameters compared to GaN for growth of high In-content InGaN QWs [27-31]. 80 to 200-nm-wide InGaN fins were shown to uni-axially relax perpendicular to the fin direction [26, 32-33]. In this work, we present a novel technique which allows elastic InGaN relaxation in the micron regime (1-10 μm) without substrate transfer [5] as well as enabling the use of conventional substrates such as sapphire, SiC, Si, etc. Here, we utilized porous GaN interlayers to allow relaxation of InₓGa₁₋ₓN layers on top, which were biaxially strained to GaN prior to porosification. Akin to porous Si [34], the porous GaN exhibits reduced mechanical stiffness with increased porosity [35]. This property was instrumental in devising our novel relaxation technique which enabled the demonstration of relaxed and partially relaxed InGaN layers. In addition, multi-quantum wells (MQWs) regrown on the relaxed InGaN base layers exhibited a 45 nm redshift of the luminescence peak compared to those grown on the co-loaded GaN templates.

### 2. Experiment

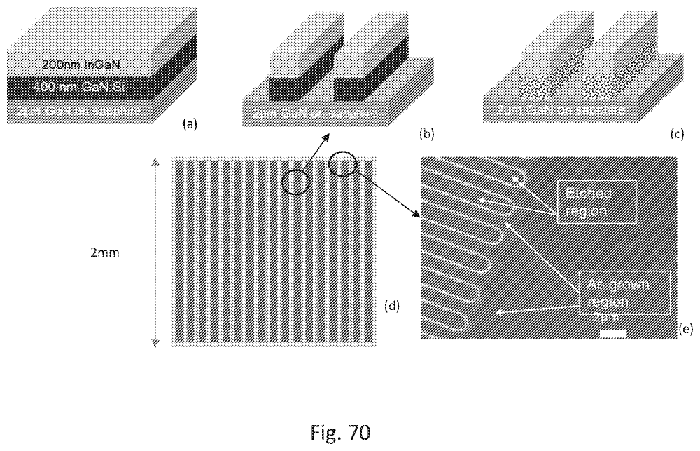

All epitaxial layers in this study were grown by metal-organic chemical vapor deposition using the precursors trimethylgallium (TMGa), triethylgallium (TEG, for the InGaN growths), trimethylindium (TMI), ammonia, and disilane on c-plane sapphire substrates. The epitaxial layer structure of the samples for porosification consisted of a 2-μm-thick unintentionally doped (u.i.d.) GaN layer followed by 400 to 800-nm-thick Si-doped GaN with a doping of (4-5)×10¹⁸ cm⁻³, and a 200-nm-thick compressively strained InₓGa₁₋ₓN (x>0.08) top layer (FIG. 70(a)). The samples were first patterned and dry etched using a 100 W BCl₃/Cl₂ etch chemistry to form the desired pattern geometry. Afterwards a doping selective electrochemical (EC) etch was used for the porosification of the 400-800 nm thick GaN:Si layers, similar to the process described in ref. 36.

In the first set of experiments fin-type geometries (FIG. 70(b)) were explored. Three samples with different fin-widths of 2, 5 and 10 μm, respectively, were fabricated. In order to ease sample alignment, the fins were aligned parallel to the GaN [11̅00] direction and were separated by 2 μm wide, 2 mm long, and 700 nm deep trenches. The EC etch was performed with a metal contact to the 400-nm-thick n⁺ GaN:Si layer on the sample as anode and a Pt wire which acted as the cathode. The etch progressed as a result of the current flowing through this GaN:Si layer etching the region exposed to the 0.3 M Oxalic acid electrolyte resulting in the formation of fins comprised of InGaN on top of porous GaN as shown in FIG. 70(c). The top view of the patterned die and scanning electron microscopy (SEM) image of the edge of the die is shown in FIGS. 70(d) and 70(e), respectively.

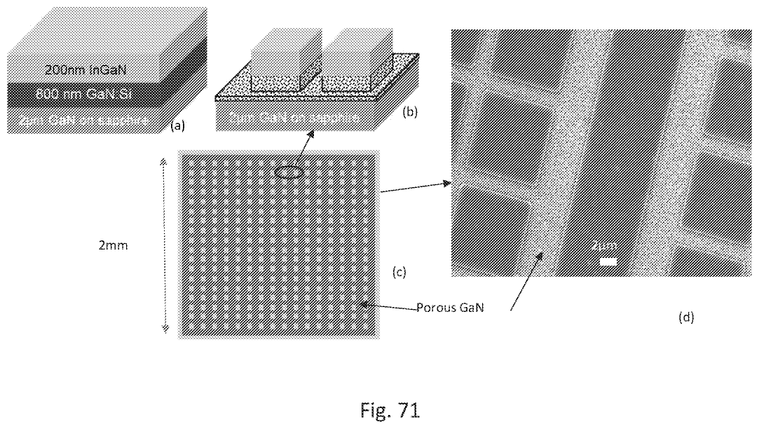

In the second set of experiments, the pattern geometry was changed from fins to squares. The epitaxial layer structure of the samples consisted of a 2-μm-thick u.i.d. GaN layer followed by 800 nm Si-doped GaN with a doping of 5×10¹⁸ cm⁻³ and a 200-nm-thick compressively strained In_{0.08}Ga_{0.92}N top layer (FIG. 71(a)). The samples were first patterned and dry etched using a 100 W BCl₃/Cl₂ etch chemistry resulting in 10 μm×10 μm wide tiles. The spacing between each tile was 2 μm, making the fill factor for tiles 10 μm×10 μm over 12 μm×12 μm, or 69%. The total etch depth was again˜700 nm. Afterwards the EC etch was performed as described before (FIG. 71(b)). The top view SEM image of this sample is depicted in FIG. 71(d) and the top view schematic of the 2 mm×2 mm die shown in FIG. 71(c).

In the third part of this study the 10 μm×10 μm tiled samples were used as pseudo-substrate for the regrowth of 4 period (2.5 nm InₓGa_{1-z}N/8.3 nm In_{y}Ga_{1-y}N) MQWs (z>y). A co-loaded GaN-on-sapphire template served as the reference sample. The wells were grown with TMI and TEG flows of 17 and 6.5 μmol/min at 835° C., the barriers with TMI and TEG flows of 3.7 and 6.5 μmol/min at 869° C., respectively.

The samples were characterized using JEOL7600F SEM tool operated at 10 kV. The cross-sectional images were taken using FEI Helios Dualbeam Nanolab 600 Focused Ion Beam (FIB) tool operated at 5 kV. High-resolution X-ray diffraction (XRD) (ω-2θ)-ω reciprocal space maps (RSMs) were recorded around the GaN (1̅1̅24) reflection to evaluate the InGaN relaxation perpendicular to the fins, around the GaN (1̅105) reflection to evaluate the strain state parallel to the fins. In addition, ω-2θ scans around the GaN (0002) reflection were measured, all using an X′PertPro Panalytical Pixcel 3D diffractometer. Room-temperature photoluminescence was obtained using the 325 nm line of a He—Cd laser with an excitation density of 220 W cm⁻².

### 3. Results and Discussion

### 3.1 Fin Structures

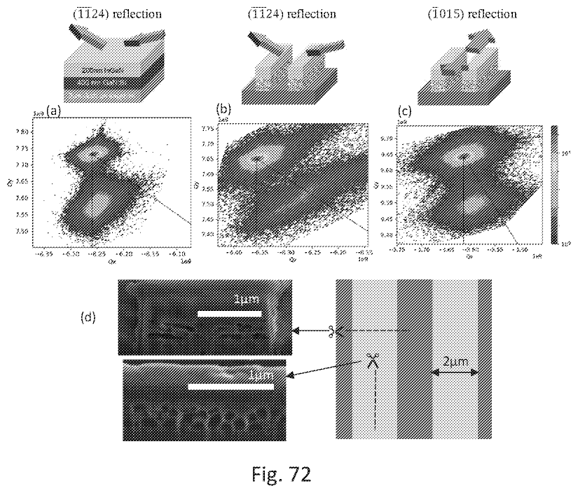

To study the effect of the porosity on the InGaN relaxation of the 2 to 10 μm wide fins in this study, EC etch experiments were performed. The applied bias was varied from 10V to 35V, as the applied bias was shown to have a significant impact on the size of the pores forming in the GaN:Si layer [35]. Post processing, (ω-2θ)-ω reciprocal space maps (RSMs) were recorded around the GaN (1̅1̅24) reflection for the analysis of the strain state perpendicular to the fins (as depicted by the arrows in FIG. 72) and around the GaN (1̅105) reflection for the analysis parallel to the fins. FIG. 72(a) shows the RSM for the as-grown sample, depicting the InGaN peak being almost fully strained to the GaN base layer. FIGS. 72(b) and 72(c) show the RSMs of the same sample in the direction perpendicular and parallel to the fins, corresponding to the GaN (1̅1̅24) and (1̅015) reflections, respectively, after patterning into 2-μm-wide fins and porosification using an applied bias of 30 V during the EC etch. Here, the n-GaN:Si layer, or the conducting layer during the EC etch was connected along the fins as the fins were hinged at the edges of the die (FIGS. 70(d-e)). FIG. 72(d) shows the cross sectional FIB images of the sample, depicting the cross section of the 2-μm-wide fin, with cuts both across and along the fins. It can be clearly seen that a porosity of almost 50-60% was achieved. This sample demonstrated full relaxation perpendicular to the fins. Parallel to the fins, the relaxation was ˜42% (FIG. 72(c)), which is less than its orthogonal counterpart due to the fact that the fins were hinged at the edge of the die, as shown in FIGS. 70(d-e), restricting the degree of relaxation along the fins.

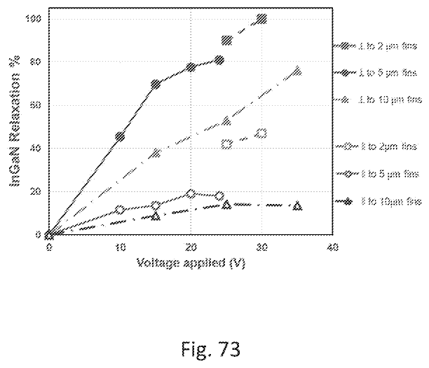

The experiment was repeated, but now with different fin widths. From 2 μm, the width was increased to 5 μm and subsequently 10 μm. FIG. 73 shows the degree of relaxation achieved for these fins in the directions both perpendicular to the fins (GaN (1̅1̅24) reflection) and parallel to the fins (GaN (1̅105) reflection). The samples with 5-μm-wide fins showed a similar behavior as the ones with 2-μm-wide fins perpendicular to the fin direction, however exhibited less relaxation along the fins. When the fin width was increased to 10 μm the degree of relaxation decreased for the same applied bias, both perpendicular as well as parallel to the fins. The decreased degree of relaxation with higher fin width can be explained by the higher spatial restraints perpendicular to the stripes as the stripe width increases. The lower degree of relaxation in the direction parallel to the fins, in comparison to its orthogonal counterpart, were again due to the fins being hinged together at the edge of the die, as the lithographic pattern was aimed at etching of trenches. As illustrated in FIG. 73, the degree of relaxation increased with increasing voltage during EC etching and increasing porosity [35]. These findings show that the InGaN relaxation can be controlled by the voltage applied during the EC etch.

### 3.2 Tile Structures

For enhanced Indium incorporation, bi-axial relaxation of the InGaN base layers is necessary [15,25]. As a fin geometry results primarily in uni-axial relaxation, the pattern geometry was modified to 10 μm×10 μm square tiles (μLED regime) to enable bi-axial relaxation.

In the fin experiments, the n⁺ GaN:Si layer, or the conducting layer during the EC etch, was connected in all dies along the fins and at the ends, thereby ensuring the applied bias to reach the fin geometry. For the tile geometry, if the same epitaxial structure with a 400-nm-thick n⁺ layer would be used, when etching 700 nm deep the current carrying layer would be isolated from the applied bias which is needed for the EC etch. Therefore, the epitaxial structure was modified to increase the thickness of the GaN:Si layer from 400 to 800 nm. During tile fabrication, instead of etching all the way through the GaN:Si layer, as was done for the fins, the GaN:Si was partially etched to ensure continuous current flow to the tile features during the EC etch. Post EC etching, the porous layer is seen exposed from the top as depicted in the SEM image in FIG. 71(d).

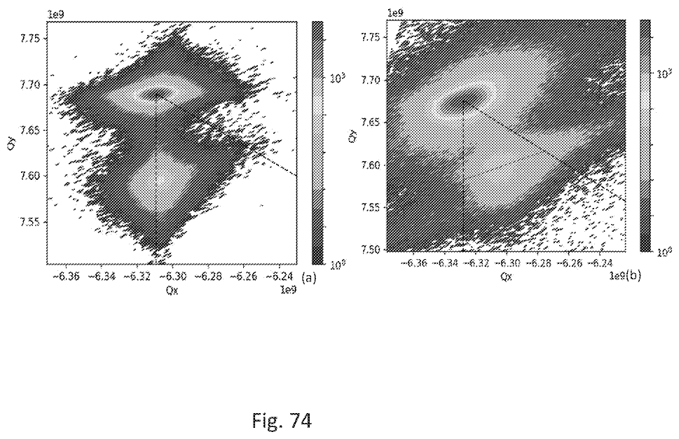

Varying the EC etch bias voltage from 25V to 35V yielded the same relaxation of 45-50% as observed for the 10 μm-wide fins. FIG. 74a-b depicts the RSMs measured along the GaN (1̅1̅24) reflection for the as-grown sample as well as of the same sample post patterning and EC etching at 25V, clearly demonstrating the shift in the InGaN peak position. As expected for a tile geometry, the same peak shift was observed for the complementary RSMs taken in (1̅105) geometry (not shown). Thereby the degree of relaxation can be enhanced through further process optimizations. With about 50% relaxation, the in plane lattice constant of the In_{0.08}Ga_{0.92}N tiles corresponded to that of fully relaxed In_{0.04}Ga_{0.96}N. Note that initial atomic force microscopy measurements did not show any differences in the density of threading dislocations intersecting the InGaN surface before and after porosification of the GaN:Si underlayer, suggesting that the threading dislocation density in the InGaN top layers was not affected by this porosification process. Transmission electron microscopy investigations are currently underway for further characterization of the samples, and the results will be presented in a separate report.

### 3.3 Regrowth on Bi-Axially Relaxed InGaN Tile Arrays

Partially relaxed InGaN tile samples were now tested as pseudo-substrates for the regrowth of InGaN/InGaN MQWs as described in the experimental section. For reference a GaN-on-sapphire sample with tile geometry and a planar GaN-on-sapphire sample were co-loaded in the experiment.

Using 325 nm line of a He—Cd laser at room temperature (RT) for excitation, the MQW grown on the porosified tile sample demonstrated luminescence at 527 nm, compared to 482 nm for the MQW deposited on the co-loaded planar GaN template, resulting in a redshift of 45 nm (FIG. 75). The tiled GaN template sample exhibited emission at 481 nm similar to the MQW on the planar GaN sample. These results suggest that the red shift in the emission wavelength observed for the MQW deposited on the porosified tile sample was indeed caused by an increased In uptake due to the reduced lattice mismatch to the partially relaxed InGaN tiles and not by changes in the well thickness caused by modifications in the precursor transport due to the tile geometry [8]. The somewhat lower intensity of the 527 nm luminescence from the porosified tile sample is currently not well understood, but most likely related to the unoptimized growth conditions at the higher In compositions.

The observed the red shift in emission wavelength due to the decrease in lattice mismatch between the QW and the partially relaxed InGaN tiles compares well with results obtained when growing QWs on relaxed InGaN base layers [5,15,25]. The reduced strain led to a reduction in the compositional pulling effect, resulting in an enhanced Indium incorporation. This result is encouraging, as the in-plane lattice constant of the partially relaxed InₓGa₁₋ₓN tiles corresponded to a relatively low indium mole fraction of x˜0.04 only. Future experiments towards improving the degree of bi-axial relaxation of the InGaN tiles and achieving further enhancement of the indium uptake upon regrowth are currently underway.

### 4 Conclusions

In summary the results of this investigation illustrate the potential of using porous GaN for the relaxation of previously strained InGaN layers opening a pathway for the fabrication of (Al,Ga,In)N heterostructures for long wavelength III-N optoelectronics. While elastic relaxation of strained layers was only observed in the nanoscale, the incorporation of porous GaN underlayers allowed moving the feature size to several micrometers. The described process can be scaled to large diameter wafers. The fill factor of the tile samples in this study was as high as 69% and can be further increased through process optimization. With relaxed InGaN pattern sizes in the μLED regime, the technique is particularly attractive for the fabrication of efficient green, yellow and red μLEDs.

### REFERENCES FOR EXAMPLE 5

[1] M. A. Maur, A. Pecchia, G. Penazzi, W. Rodrigues, and A. D. Carlo, Phys. Rev. Letters 116, 027401 (2016).
[2] J. W. Matthews and A. E. Blakeslee. J. Cryst. Growth Vol. 27, pp. 118-125 (1974).
[3] D. Holec, P. M. F. J. Costa, M. J. Kappers and C. J. Humphreys, J. Cryst. Growth Vol. 303, No. 1, pp. 314-317 (2007).
[4] Y. Kawaguchi, M. Shimizu, K. Hiramatsu. and N. Sawaki, Mater. Res. Soc. Symp. Proc. Vol. 449 (1997)
[5] A. Even, G. Laval, O. Ledoux, P. Ferret, D. Sotta. E. Guiot, F. Levy, I. C. Robin and A. Dussaigne, Appl. Phys. Letters 110, 262103 (2017)
[6] J. S. Im, H. Kollmer, J. Off, A. Sohmer, F. Scholz, and A. Hangleiter, Phys. Rev. B Vol. 57, No. 16 (1998)
[7] T. Deguchi, K. Sekiguchi, A. Nakamura, T. Sota, R. Matsuo, S. Chichibu and S. Nakamura. Jpn. J. Appl. Phys., Part 2 38. L914 (1999)
[8] S. F. Chichibu, A. C. Abare, M. S. Minsky, S. Keller, S. B. Fleischer, J. E. Bowers, E. Hu, U. K. Mishra, L. A. Coldren, S. P. DenBaars, and T. Sota, Appl. Phys. Lett. 73, 2006 (1998).
[9] T. Takeuchi, H. Amano, and I. Akasaki, Jpn. J. Appl. Phys. Part 1 39, 413 (2000)
[10] P. Waltereit, O. Brandt, A. Trampert, H. T. Grahn, J. Menniger, M. Ramsteiner, M. Reiche, and K. H. Ploog, Nature London 406, 865 (2000).
[11] R. Sharma, P. M. Pattison, H. Masui, R. M. Farrel, T. J. Baker, B. A. Haskell, F. Wu, S. P. DenBaars, J. S. Speck, and S. Nakamura, Appl. Phys. Lett. 87, 231110 (2005)
[12] A. Chakraborty, B. A. Haskell. S. Keller, J. S. Speck, S. P. DenBaars, S. Nakamura, and U. K. Mishra, Jpn. J. Appl. Phys. 44, L173 (2005).
[13] S. Pereira, M. R. Correia, E. Pereira, K. P. O'Donnel, C. Trager-Cowan, F. Sweeny, and E. Alves, Phys. Rev. B 64, 205311 (2001).
[14] K. Hiramatsu, Y. Kawaguchi. M. Shimizu. N. Sawaki, T. Zheleva, R. F. Davis, H. Tsuda, W. Taki, N. Kuwano, and K. Oki, MRS Internet J. Nitride Semicond. Res. 2, e6 (1997)
[15] J. DAubler, T. Passow, R. Aidam, K. Kohler, L. Kirste, M. Kunzer, and J. Wagner, Appl. Phys. Lett. 105, 111111 (2014).
[16] J. Zhang and N. Tansu, J. Appl. Phys. 110, 113110 (2011).
[17] S. W. Park, T. H. Chung, J. H. Baek, and D. Ahn, Jpn. J. Appl. Phys. 54, 022101 (2015).
[18] I. C. Robin and H. Bono, US patent US20160270176A1 (15 Sep. 2016)
[19] A. Kobayashi, J. Ohta, and H. Fujioka, J. Appl. Phys. 99, 123513 (2006).
[20] S. J. Wang, N. Li, E. H. Park, Z. C. Feng, A. Valencia, J. Nause, M. Kane, C. Summers, and I. Ferguson, Phys. Status Solidi C 5, 1736 (2008).
[21] Y. Lei. J. Xu, K. Zhu, M. He, J. Zhou, Y. Gao, L. Zhang, and Y. Chen, J. Disp. Technol. 9, 377 (2013).
[22] T. Ozaki, Y. Takagi, J. Nishinaka, M. Funato, and Y. Kawakami, Appl. Phys. Express 7, 091001 (2014).
[23] T. Ozaki, M. Funato, and Y. Kawakami, Appl. Phys. Express 8, 062101 (2015).
[24] K. Hestroffer, F. Wu, H. Li, C. Lund, S. Keller, J. S. Speck, and U. K. Mishra, Semicond. Sci. Technol. Vol. 30, No. 10 (2015).
[25] C. Lund, K. Hestroffer, N. Hatui, S. Nakamura, S. P. DenBaars, U. K. Mishra and S. Keller, Appl. Phys. Express 10, 111001 (2017).
[26] S. Keller, C. Lund, T. Whyland, Y. Hu, C. Neufeld, S. Chan, S. Wienecke, F. Wu, S. Nakamura, J. S. Speck, S. P. DenBaars, and U. K. Mishra, Semicond. Sci. Technol. Vol. 30, No. 10 (2015)
[27] J. Zhang and N. Tansu, J. Appl. Phys. 110, 113110 (2011).
[28] J. Zhang and N. Tansu, IEEE Photonics J. 5, 2600111 (2013).
[29] J. Pal, M. A. Migliorato, C. K. Li, Y. R. Wu, B. G. Crutchley, I. P. Marko, and S J. Sweeney, J. Appl. Phys. 114, 073104 (2013).
[30] T. K. Sharma and E. Towe, Appl. Phys. Lett. 96, 191105 (2010).
[31] S. H. Park, Y. T. Moon, J. S. Lee, H. K. Kwon, J. S. Speck, and D. Ahn, Phys. Status Solidi A 208, 195 (2011).
[32] S. Keller, C. Schaake, N. A. Fichtenbaum, C. J. Neufeld, Y. Wu, K. McGroddy, A. David, S. P. DenBaars, C. Weisbuch, J. S. Speck, and U. K. Mishra, J. Appl. Phys. 100, 054314 (2006).
[33] C. Gupta, Y. Tsukada. B. Romanczyk. S. S. Pasayat, D. A. James. E. Ahmadi, S. Keller, U. K. Mishra, Jpn. J. Appl. Phys. Vol. 58, No. 3, 030908 (2019)
[34] S. Fakiri, A. Montage, K. Rahmoun, A, lost and K. Ziouche, Mat. Sc. and Engineering A 711, pp 470-475 (2018).
[35] S. Huang, Y. Zhang, B. Leung, G. Yuan, G. Wang, H. Jiang, Y. Fan, Q. Sun, J. Wang, K. Xu, and J. Han, ACS Appl. Mater. Interfaces 5, pp. 11074-11079 (2013).
[36] Y. Zhang, S. W. Ryu, C. Yerino, B. Leung, Q. Sun, Q. Song, H. Cao, and J. Han, Phys. Status Solidi B 247, No 7, 1713-1716 (2010).

### Example 6

Indium Gallium Nitride or (In,Ga)N based micron-sized LEDs (μLEDs) have gained increased attention for full color μLED display applications owing to their reliability, high luminous efficiency, chemical robustness and small form-factor. Even though monochromic III-nitride blue and green μLEDs have demonstrated remarkable device performances, it is extremely difficult to fabricate red μLEDs. AlGaInP is one of the most mature material system for red LEDs, yet it suffers from high efficiency loss from the high surface recombination as the device dimensions shrink.

One major obstacle in the development of InGaN based red LEDs is the increase in lattice mismatch between the InGaN active region of the LED and the n-GaN base layer with increasing indium composition, which can induce various defects in the active region. Hence a reduction in the lattice mismatch between active region and base layer, achieved through the implementation of relaxed InGaN base layers, is highly desirable, as it yields better QW material quality and higher indium incorporation efficiency.

We have used compliant GaN pseudo-substrates with porous GaN as described herein as the strain relieving under-layer, to grow as-grown relaxed InGaN LED structures. With porous GaN underlayers to manage the strain in the entire epitaxial structure we are able to demonstrate red InGaN LEDs sized <10 μm with a peak external quantum efficiency of ˜0.08 (highest reported in literature for any red μLED for that dimension). With this technique, color-tunable monolithically integrated nitride based RGB μLED arrays can be fabricated. It must be noted that the external quantum efficiency was calculated based on the amount of light which was collected by the detector.

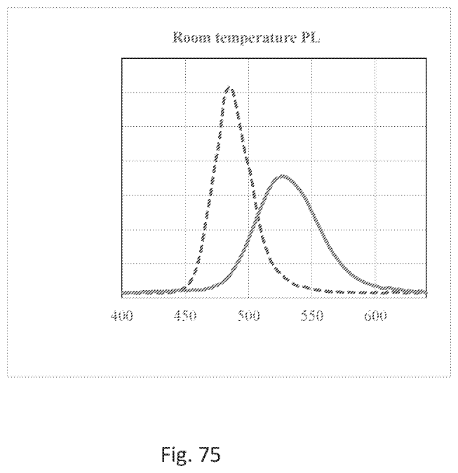

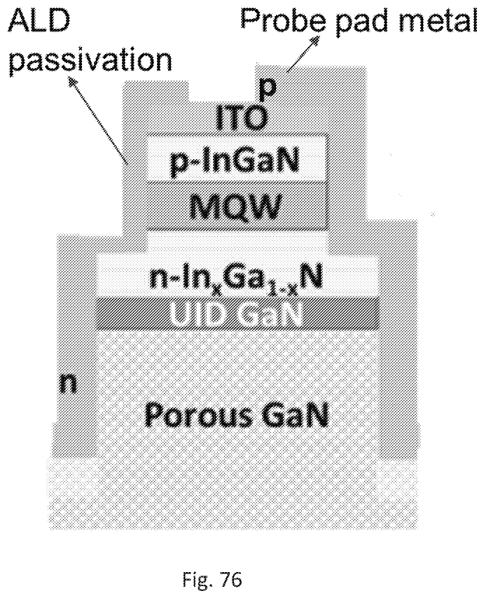

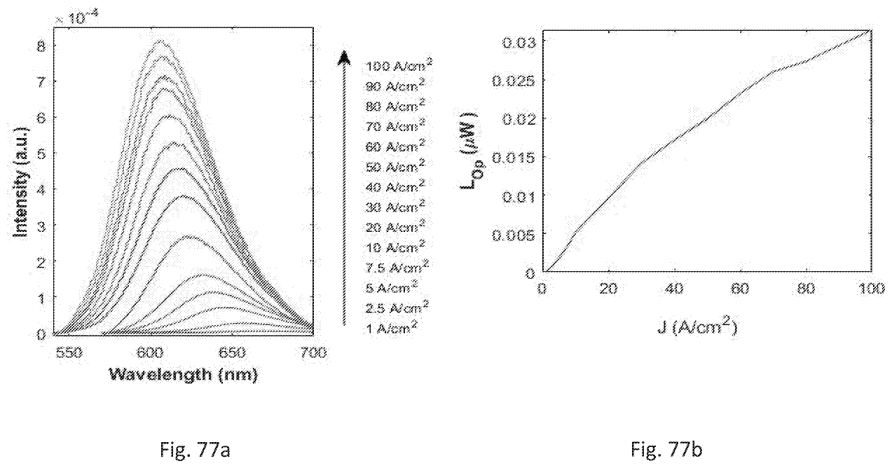

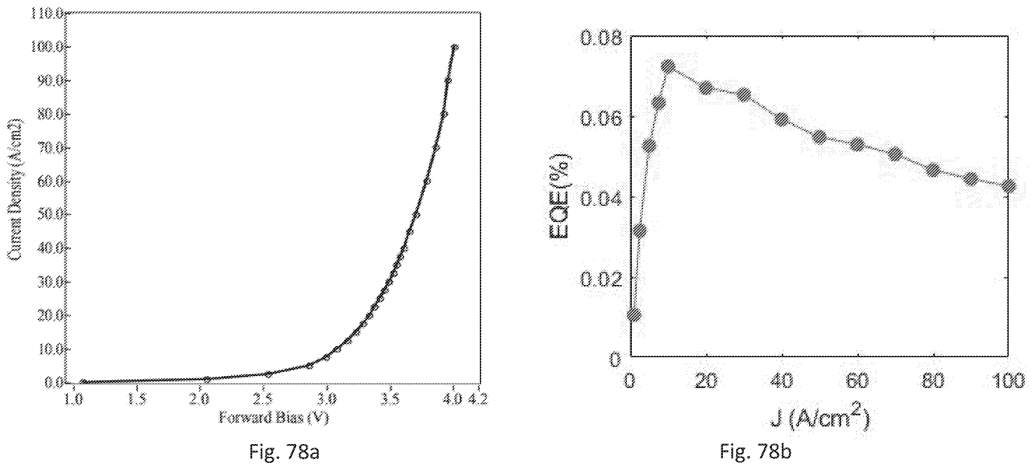

FIG. 76 is a schematic of the device structure and the electroluminescence spectrum, light output power and the extracted external quantum efficiency trends with current density are shown in FIG. 77 and FIG. 78.

Optical measurements were conducted on-wafer, with light being collected through the sapphire substrate within approximately a 60° half-angle cone normal to the substrate. This geometry was preferred over the measurement of packaged devices in an integrating sphere as it more accurately imitated how micro-LEDs are used in displays. The limited collection angle, however, caused the measured EQE values to be lower compared to values obtained if the devices were packaged with the total extracted light collected in an integrating sphere, a standard methodology used to report EQE values of micro-LEDs with dimensions of 20 μm×20 μm and larger. Additionally, the external quantum efficiency shown in FIG. 78b was calculated based on the amount of light which was captured by the detector, which is a very small fraction of the light emitted from the back-side of the device (traveling through GaN buffer layer and sapphire substrate).

If P_{source} is the light output power emitted by the microLED and P_{escape} is the light output power collected by the detector:

P_{escape}/P_{source}=0.5×(1−cos φ_{c}), where the critical angle φ_{c}=34.4° for sapphire/air interface, leading to 8.74% light extracted from the back of the sample.

Various techniques to enhance the light extraction can be employed to achieve a significantly higher light extraction that can increase the EQE by at least 3-4 times the values shown in FIG. 78b (right).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A substrate or pseudo-substrate, comprising:
a first semiconductor layer on a layer comprising at least one of a porous layer or a compliant layer; and
a second semiconductor layer on the first semiconductor layer so as to stretch or pull the underlying first semiconductor layer to conform the first semiconductor layer to the second semiconductor layer.

2. The substrate of claim 1, wherein the layer is a porous layer.

3. The substrate of claim 1, wherein at least one of the first semiconductor layer or the layer comprise silicon, a III-Nitride, a group III-V material, a group II-VI material, a group I-III-VI material, a group IV semiconductor, an oxide material or a metal.

4. The substrate of claim 3, wherein the second semiconductor layer comprises a III-Nitride, a III-V material, a II-VI material, a I-III-VI material, or a group IV semiconductor, oxide or metal.

5. The substrate of claim 4, wherein the stretching or pulling of the first semiconductor layer to conform the first semiconductor layer to the second semiconductor layer comprises straining the first semiconductor layer so that the first semiconductor layer has a lattice constant between a relaxed value for the lattice constant of the first semiconductor layer and a relaxed value for the lattice constant of the second semiconductor layer.

6. The substrate of claim 1, wherein the first semiconductor layer is grown on or bonded to the porous semiconductor layer.

7. The substrate of claim 1, further comprising a plurality of layers including the first semiconducting layer and the second semiconducting layer on top of the porous semiconducting layer, wherein the plurality of layers have a top continuous surface formed via coalescence of a layer or multiple layers in the plurality of layers which were segmented into an array of features.

8. The substrate of claim 7, wherein the features comprise mesas or tiles having a square, triangular, circular, or rhombus shape.

9. The substrate of claim 1, wherein the porous semiconductor layer is formed by electrochemical etching of a semiconductor comprising gallium nitride.

10. The substrate of claim 9, wherein the porous layer comprises pores having a diameter in a range of 0.001-1000 micrometers.

11. The substrate of claim 1, wherein the porous layer is comprised of nano-feature arrays.

12. The substrate of claim 1, wherein the porous semiconductor layer comprises etched pores.

13. The substrate of claim 1, further comprising:
a growth substrate;
the layer comprising a porous semiconductor layer on or above the substrate; and
the first semiconductor layer comprising an at least partially relaxed semiconductor layer having a lattice constant that is different than a lattice constant of the growth substrate such that the at least partially relaxed semiconductor layer would be coherently strained if grown directly on the growth substrate, or
such that the at least partially relaxed semiconductor layer would plastically relax under formation of crystal defects if grown directly on the growth substrate

14. The substrate of claim 13, further including an intermediate semiconductor layer between the growth substrate and the porous semiconductor layer.

15. The substrate of claim 14, with the substrate is removed so that a surface of the intermediate semiconductor layer, having an opposite polarity to an interface with the porous semiconductor layer, is exposed so as to flip a polarity of the device.

16. The substrate of claim 13, wherein:
the layer comprising at least one of a porous layer or a compliant layer comprises etched patterns or openings;
the first semiconductor layer and/or the second semiconductor layer, or any further layer grown on top closes up a gap between the etched patterns or openings.

17. The substrate of claim 13, wherein the porous layer comprises n-type gallium nitride and the at least partially relaxed layer comprises Indium, gallium, and nitrogen, or aluminum, gallium, and nitrogen.

18. The substrate of claim 1, wherein:
the first semiconductor layer comprises a first at least partially relaxed InGaN layer,
the second semiconductor layer comprises a second at least partially relaxed InGaN layer having a higher indium composition and a larger thickness than the first at least partially relaxed InGaN layer.

19. The substrate of claim 1, wherein the substrate comprises a compliant substrate for a device such that a lattice constant of the second semiconductor layer conforms to a lattice constant of the device bonded or grown on the second semiconductor layer.

20. The substrate of claim 19, wherein the device comprises a III-Nitride layer bonded to the second semiconductor layer and the bond flips a polarity of the III-nitride layer.

21.-54. (canceled)
